(19) United States
(12) Patent Application Publication
(10) Pub. No.: US 2025/0015193 A1
(43) Pub. Date: Jan. 9, 2025

(54) OXIDE SEMICONDUCTOR LAYER, METHOD FOR FORMING THE OXIDE SEMICONDUCTOR LAYER, SEMICONDUCTOR DEVICE, AND METHOD FOR MANUFACTURING THE SEMICONDUCTOR DEVICE

(71) Applicant: Semiconductor Energy Laboratory Co., Ltd., Atsugi-shi (JP)

(72) Inventors: Shunpei YAMAZAKI, Setagaya (JP); Fumito ISAKA, Zama (JP); Yuichi SATO, Isehara (JP); Toshikazu OHNO, Atsugi (JP); Hitoshi KUNITAKE, Machida (JP); Tsutomu MURAKAWA, Isehara (JP)

(21) Appl. No.: 18/748,238

(22) Filed: Jun. 20, 2024

(30) Foreign Application Priority Data
Jul. 6, 2023 (JP) 2023-111713
Aug. 10, 2023 (JP) 2023-131436
Sep. 20, 2023 (JP) 2023-152146

(51) Int. Cl. H01L 29/786; H01L 21/02; H01L 29/66; H10B 12/00; H10K 59/121

(52) U.S. Cl. CPC H01L 29/7869; H01L 21/02565; H01L 21/02631; H01L 29/66969; H01L 29/78696; H10B 12/33; H10B 12/50; H10K 59/1213

(57) ABSTRACT

Provided are a transistor with favorable electrical characteristics, a transistor with a high on-state current, a transistor with low parasitic capacitance, or a transistor, a semiconductor device, or a memory device which can be miniaturized or highly integrated. An oxide semiconductor layer included in the transistor, the semiconductor device, or the memory device includes a first region, a second region over the first region, and a third region over the second region. The first region is located in a range from a surface on which the oxide semiconductor layer is to be formed to greater than or equal to 0 nm to less than or equal to 3 nm in a direction substantially perpendicular to the surface. In cross-sectional observation of the oxide semiconductor layer using a transmission electron 10 microscope, bright spots arranged in a layered manner in a direction parallel to the surface are observed in each of the first region, the second region, and the third region.

### BACKGROUND OF THE INVENTION

### 1. Field of the Invention

One embodiment of the present invention relates to a semiconductor device, a memory device, a display device, and an electronic device. One embodiment of the present invention also relates to a method for manufacturing the semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### 2. Description of the Related Art

In recent years, semiconductor devices have been developed to be used mainly for an LSI, a CPU, a memory, and the like. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. A silicon-based semiconductor material is widely known as a material of a semiconductor thin film that can be used in a transistor. As another material, an oxide semiconductor has been attracting attention.

A transistor using an oxide semiconductor is known to have an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by forming a channel of a transistor including an oxide semiconductor film in the vertical direction.

Non-patent Document 2 discloses a CAAC-IGZO as a crystalline oxide semiconductor. Non-patent Document 2 also discloses a growth mechanism and the like of CAAC-IGZO.

### REFERENCE

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota, et al., “3D-Stacked CAAC-In—Ga—Zn Oxide FETs with Gate Length of 72 nm”, IEDM Tech. Dig., 2019, pp. 50-53
[Non-Patent Document 2] Noboru Kimizuka and Shunpei Yamazaki, “PHYSICS AND TECHNOLOGY OF CRYSTALLINE OXIDE SEMICONDUCTOR CAAC-IGZO” FUNDAMENTALS (the United States), Wiley-SID Series in Display Technology, 2017, pp. 50-150

### SUMMARY OF THE INVENTION

An object of one embodiment of the present invention is to provide a transistor with high electrical characteristics. Another object of one embodiment of the present invention is to provide a transistor with a high on-state current. Another object of one embodiment of the present invention is to provide a transistor with small parasitic capacitance. Another object of one embodiment of the present invention is to provide a transistor, a semiconductor device, or a memory device which can be miniaturized or highly integrated. Another object of one embodiment of the present invention is to provide a display device with a high resolution or a high aperture ratio. Another object of one embodiment of the present invention is to provide a highly reliable transistor, semiconductor device, display device, or memory device. Another object of one embodiment of the present invention is to provide a semiconductor device, display device, or memory device with low power consumption. Another object of one embodiment of the present invention is to provide a memory device with high operating speed. Another object of one embodiment of the present invention is to provide a method for manufacturing the above-described transistor, semiconductor device, display device, or memory device.

Note that the description of these objects does not preclude the existence of other objects. One embodiment of the present invention does not necessarily achieve all of these objects. Other objects can be derived from the description of the specification, the drawings, and the claims.

An embodiment of the present invention is an oxide semiconductor layer including indium. The oxide semiconductor layer includes a first region, a second region over the first region, and a third region over the second region. The first region is located in a range from a surface on which the oxide semiconductor layer is formed to greater than or equal to 0 nm to less than or equal to 3 nm in a direction substantially perpendicular to the surface. In cross-sectional observation of the oxide semiconductor layer using a transmission electron microscope, bright spots arranged in a layered manner in a direction parallel to the surface are observed in each of the first region, the second region, and the third region.

In a preferred mode of the oxide semiconductor layer, the second region includes zinc, the second region includes a crystal, and the c-axis of the crystal is substantially parallel to a normal direction of the surface on which the oxide semiconductor layer is formed.

In a preferred mode of the oxide semiconductor layer, the c-axis alignment proportion of the second region is higher than that of the first region.

In a preferred mode of the oxide semiconductor layer, the c-axis alignment proportion of the third region is higher than that of the first region.

In a preferred mode of the oxide semiconductor layer, the content of indium in the first region is higher than that in the second region, and the content of indium in the third region is higher than that in the second region.

Another embodiment of the present invention is a method for forming an oxide semiconductor layer, including the steps of: forming a first metal oxide; forming a second metal oxide over the first metal oxide; and forming a third metal oxide over the second metal oxide. Each of the first metal oxide and the third metal oxide is formed by an ALD method using an oxidizer and a precursor comprising indium. The second metal oxide is formed by a sputtering method using a sputtering target including indium.

In a preferred mode of the method for forming an oxide semiconductor layer, the sputtering target includes zinc, and the sputtering method is performed in an atmosphere comprising oxygen.

In a preferred mode of the method for forming an oxide semiconductor layer, the substrate heating temperature in the ALD method is higher than or equal to 100° C. and lower than or equal to 350° C.

In a preferred mode of the method for forming an oxide semiconductor layer, in cross-sectional observation of the oxide semiconductor layer using a transmission electron microscope, bright spots arranged in a layered manner in a direction parallel to a surface on which the oxide semiconductor layer is formed are observed in each of the first metal oxide, the second metal oxide, and the third metal oxide.

In a preferred mode of the method for forming an oxide semiconductor layer, no clear boundary is observed between the first metal oxide and the second metal oxide, and no clear boundary is observed between the second metal oxide and the third metal oxide.

In a preferred mode of the method for forming an oxide semiconductor layer, after the third metal oxide is formed over the second metal oxide, heat treatment at higher than or equal to 350° C. and lower than or equal to 550° C. is performed.

Another embodiment of the present invention is a semiconductor device including a transistor over a first insulating layer and a second insulating layer. The transistor includes a first conductive layer over the first insulating layer, a second conductive layer, an oxide semiconductor layer, a gate insulating layer, and a gate electrode. The second insulating layer is positioned between the first conductive layer and the second conductive layer. The second conductive layer is positioned over the second insulating layer. The second insulating layer and the second conductive layer comprise a first opening portion reaching the first conductive layer. The oxide semiconductor layer is in contact with a side surface of the second insulating layer in the first opening portion and a side surface of the second conductive layer in the first opening portion. The gate insulating layer is positioned over the oxide semiconductor layer. In the first opening portion, the gate electrode includes a region overlapping with the oxide semiconductor layer with the gate insulating layer therebetween. The oxide semiconductor layer includes a first region, a second region over the first region, and a third region over the second region. The first region is located in a range from a surface on which the oxide semiconductor layer is formed to greater than or equal to 0 nm to less than or equal to 3 nm in a direction substantially perpendicular to the surface. In cross-sectional observation of the oxide semiconductor layer using a transmission electron microscope, bright spots arranged in a layered manner in a direction parallel to the surface are observed in each of the first region, the second region, and the third region.

In a preferred mode of the semiconductor device, the side surface of the second insulating layer in the first opening portion includes a fourth region. An angle formed by a top surface of the first conductive layer and the fourth region is greater than or equal to 75° and less than or equal to 90°. The first region is in contact with the fourth region.

Another embodiment of the present invention is a method for manufacturing a semiconductor device, including the steps of: forming a first insulating layer over a first conductive layer; forming a second conductive layer over the first insulating layer; removing a part of the second conductive layer and a part of the first insulating layer, thereby forming a first opening portion reaching the first conductive layer and exposing a top surface of the first conductive layer; forming a first metal oxide in contact with the top surface of the first conductive layer, a side surface of the first opening portion of the first insulating layer, a side surface of the first opening portion of the second conductive layer, and a top surface of the second conductive layer; forming a second metal oxide over the first metal oxide; forming a third metal oxide over the second metal oxide; forming a second insulating layer in contact with a top surface of the third metal oxide; and forming a third conductive layer over the second insulating layer. Each of the first metal oxide and the third metal oxide is formed by an ALD method using an oxidizer and a precursor comprising indium. The second metal oxide is formed by a sputtering method using a sputtering target comprising indium.

In a preferred mode of the method for manufacturing a semiconductor device, the third conductive layer is formed by a metal CVD method at a temperature higher than or equal to 250° C.

With one embodiment of the present invention, a transistor with high electrical characteristics can be provided. With one embodiment of the present invention, a transistor with a high on-state current can be provided. With one embodiment of the present invention, a transistor with small parasitic capacitance can be provided. With one embodiment of the present invention, a transistor, a semiconductor device, or a memory device which can be miniaturized or highly integrated can be provided. With one embodiment of the present invention, a display device with a high resolution or a high aperture ratio can be provided. With one embodiment of the present invention, a highly reliable transistor, semiconductor device, display device, or memory device can be provided. With one embodiment of the present invention, a semiconductor device, display device, or memory device with low power consumption can be provided. With one embodiment of the present invention, a memory device with high operating speed can be provided. With one embodiment of the present invention, a method for manufacturing the above-described transistor, semiconductor device, display device, or memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A to 1D are cross-sectional views illustrating an example of a method for forming an oxide semiconductor.

FIGS. 2A to 2D are cross-sectional views illustrating the example of a method for forming an oxide semiconductor.

FIGS. 3A to 3E are cross-sectional views illustrating a method for depositing metal oxide of one embodiment of the present invention.

FIGS. 4A to 4D illustrate atomic arrangement of metal oxide of one embodiment of the present invention.

FIGS. 5A to 5D are cross-sectional views illustrating a method for depositing metal oxide of one embodiment of the present invention.

FIGS. 6A to 6C are cross-sectional views illustrating the method for depositing metal oxide of one embodiment of the present invention.

FIG. 7A is a plan view illustrating an example of a semiconductor device. FIGS. 7B and 7C are cross-sectional views illustrating the example of a semiconductor device.

FIG. 8 is a cross-sectional view illustrating an example of a semiconductor device.

FIGS. 9A and 9B are cross-sectional views each illustrating an example of a semiconductor device.

FIG. 10A is a plan view illustrating an example of a semiconductor device. FIGS. 10B and 10C are cross-sectional views each illustrating an example of the semiconductor device.

FIG. 11A is a plan view illustrating an example of a semiconductor device. FIG. 11B is a cross-sectional view illustrating the example of a semiconductor device.

FIG. 12A is a plan view illustrating an example of a semiconductor device. FIG. 12B is a cross-sectional view illustrating the example of a semiconductor device.

FIGS. 13A to 13C are cross-sectional views each illustrating an example of a semiconductor device.

FIG. 14A is a plan view illustrating an example of a semiconductor device. FIGS. 14B and 14C are cross-sectional views illustrating the example of a semiconductor device.

FIG. 15A is a plan view illustrating an example of a semiconductor device. FIGS. 15B and 15C are cross-sectional views illustrating the example of a semiconductor device.

FIGS. 16A to 16C are cross-sectional views illustrating an example of a method for manufacturing a semiconductor device.

FIG. 17A is a plan view illustrating an example of a memory device. FIGS. 17B and 17C are cross-sectional views illustrating the example of a memory device.

FIGS. 18A and 18B are cross-sectional views illustrating an example of a memory device.

FIG. 19A is a plan view illustrating an example of a memory device. FIG. 19B is a cross-sectional view illustrating the example of a memory device.

FIG. 20 is a cross-sectional view illustrating an example of a memory device.

FIG. 21 is a cross-sectional view illustrating an example of a memory device.

FIG. 22 is a block diagram illustrating a structure example of a semiconductor device.

FIGS. 23A to 23H illustrate circuit structure examples of memory cells.

FIGS. 24A and 24B are perspective views illustrating structure examples of a semiconductor device.

FIG. 25 is a block diagram illustrating a CPU.

FIGS. 26A and 26B are perspective views illustrating a semiconductor device.

FIGS. 27A and 27B are perspective views illustrating semiconductor devices.

FIGS. 28A and 28B each show a hierarchy of various kinds of memory devices.

FIGS. 29A and 29B are perspective views illustrating an example of a display device.

FIG. 30 is a cross-sectional view illustrating an example of a display device.

FIG. 31 is a cross-sectional view illustrating an example of a display device.

FIGS. 32A to 32C illustrate structure examples of a display device.

FIGS. 33A and 33B illustrate examples of electronic components.

FIGS. 34A to 34C illustrate an example of a large computer. FIG. 34D illustrates an example of space equipment. FIG. 34E illustrates an example of a storage system that can be used for a data center.

FIGS. 35A to 35F illustrate examples of electronic devices.

FIGS. 36A to 36G illustrate examples of electronic devices.

FIGS. 37A to 37F illustrate examples of electronic devices.

FIG. 38 is a circuit diagram which is used for circuit simulation.

FIGS. 39A and 39B are timing charts showing the operation of a circuit.

FIGS. 40A and 40B show I_{d}-V_{g} characteristics of transistors.

FIGS. 41A and 41B show I_{d}-V_{g} characteristics of transistors.

FIGS. 42A and 42B show I_{d}-V_{g} characteristics of transistors.

FIGS. 43A and 43B show I_{d}-V_{d} characteristics of transistors.

FIGS. 44A to 44C show orientation mapping.

FIGS. 45A and 45B each show a TEM image and FFT images.

FIGS. 46A and 46B show orientation mapping.

FIGS. 47A and 47B each show a TEM image and FFT images.

FIGS. 48A and 48B each show a c-axis alignment proportion.

FIGS. 49A and 49B each show a c-axis alignment proportion.

FIGS. 50A to 50D show SIMS analysis results.

FIGS. 51A and 51B show I_{d}-V_{g} characteristics of transistors.

FIGS. 52A and 52B show I_{d}-V_{g} characteristics of transistors.

FIG. 53A shows I_{d}-V_{g} characteristics of transistors. FIG. 53B shows I_{d}-V_{d} characteristics of the transistors.

FIG. 54A shows I_{d}-V_{g} characteristics of transistors. FIG. 54B shows I_{d}-V_{d} characteristics of the transistors.

FIG. 55A shows I_{d}-V_{g} characteristics of transistors. FIG. 55B shows I_{d}-V_{d} characteristics of the transistors.

FIGS. 56A and 56B show I_{d}-V_{g} characteristics of transistors.

FIGS. 57A and 57B show I_{d}-V_{g} characteristics of transistors.

FIG. 58 shows I_{d}-V_{g} characteristics of transistors.

FIG. 59 shows I_{d}-V_{g} characteristics of transistors.

FIGS. 60A and 60B show results of circuit simulation.

FIGS. 61A and 61B show results of circuit simulation.

FIGS. 62A and 62B show results of circuit simulation.

FIGS. 63A and 63B show results of circuit simulation.

FIG. 64 shows measurement results of cutoff frequency.

FIG. 65 shows XPS analysis results.

FIGS. 66A and 66B show I_{d}-V_{g} characteristics and I_{g}-V_{g} characteristics of transistors.

FIG. 67 shows I_{d}-V_{g} characteristics and I_{g}-V_{g} characteristics of transistors.

FIG. 68 shows SIMS analysis results.

FIG. 69 shows a TEM image.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, a switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an OS transistor. In this specification and the like, a transistor including silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as V_{O}) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The contents of elements such as hydrogen, oxygen, carbon, and nitrogen in a film can be analyzed by secondary ion mass spectrometry (SIMS) or X-ray photoelectron spectroscopy (XPS), for example. Note that XPS is suitable when the content percentage of a target element is high (e.g., 0.5 atomic % or higher, or 1 atomic % or higher). By contrast, SIMS is suitable when the content percentage of a target element is low (e.g., 0.5 atomic % or lower, or 1 atomic % or lower). To compare the contents of elements, analysis with a combination of SIMS and XPS is preferably used.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 70° and less than or equal to 110°.

In this specification and the like, the term “electrically connected” includes the case where components are connected to each other through an object having any electric function. There is no particular limitation on an “object having any electric function” as long as electric signals can be transmitted and received between components that are connected through the object. Examples of the “object having any electric function” are a switching element such as a transistor, a resistor, a coil, and an element with a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, the off state of an n-channel transistor means that a gate-source voltage V_{gs} is lower than a threshold voltage Vₜₕ, and the off state of a p-channel transistor means that V_{gs} is higher than Vₜₕ.

Note that “normally-on characteristics” in this specification and the like mean a state where a channel exists and a current flows through a transistor even when no voltage is applied to a gate. Furthermore, “normally-off characteristics” means a state where a current does not flow through a transistor when no potential or a ground potential is applied to a gate.

Note that in this specification and the like, a top surface shape of a component means the outline of the component in a plan view. A plan view means a view to observe the component from a normal direction of a surface where the component is formed or from a normal direction of a surface of a support (e.g., a substrate) where the component is formed.

In this specification and the like, the expression “having substantially the same top surface shapes” means that the outlines of stacked layers at least partly overlap with each other. For example, the case of patterning or partly patterning an upper layer and a lower layer with the use of the same mask pattern is included. The expression “having substantially the same top surface shapes” also sometimes includes the case where the outlines do not completely overlap with each other; for instance, the edge of the upper layer may be positioned on the inner side or the outer side of the edge of the lower layer. In the case where the top surface shapes are the same or substantially the same, it can be said that the end portions are aligned or substantially aligned with each other or the side end portions are aligned or substantially aligned with each other.

In this specification and the like, a tapered shape refers to a shape such that at least part of a side surface of a component is inclined with respect to a substrate surface or a surface on which the component is formed. For example, a tapered shape preferably includes a region where the angle between the inclined side surface of the component and the substrate surface or the surface on which the component is formed (such an angle is also referred to as a taper angle) is greater than 0° and less than 90°. Note that the side surface of the component, the substrate surface, and the surface on which the component is formed are not necessarily completely flat and may be substantially flat with a slight curvature or with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure in which light-emitting layers of light-emitting elements (also referred to as light-emitting devices) having different emission wavelengths are separately formed may be referred to as a side-by-side (SBS) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may also be referred to as a mask layer) refers to a layer that is positioned above at least a light-emitting layer (specifically, a layer processed into an island shape among layers included in an EL layer) and has a function of protecting the light-emitting layer in the manufacturing process.

In this specification and the like, the term “island shape” refers to a state where two or more layers formed using the same material in the same step are physically separated from each other. For example, “island-shaped EL layer” means a state where the EL layer and its adjacent EL layer are physically separated from each other.

In this specification and the like, step disconnection refers to a phenomenon in which a layer, a film, or an electrode is split because of the shape of a surface on which the layer, the film, or the electrode is formed (e.g., a step).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

In this embodiment, an oxide semiconductor layer of one embodiment of the present invention is described. The oxide semiconductor layer of one embodiment of the present invention is preferably used as a semiconductor layer of a transistor. In the case where the oxide semiconductor layer of one embodiment of the present invention is used as a semiconductor layer of a transistor, the oxide semiconductor layer includes a channel formation region. The oxide semiconductor layer preferably includes a source region and a drain region.

### [Oxide Semiconductor Layer]

The oxide semiconductor layer of one embodiment of the present invention preferably includes a metal oxide layer having crystallinity. Examples of the structure of a metal oxide having crystallinity include a c-axis aligned crystalline (CAAC) structure, a polycrystalline structure, and a nanocrystalline (nc) structure. By using a metal oxide layer having crystallinity as the oxide semiconductor layer, the density of defect states in the oxide semiconductor layer can be reduced. Thus, the reliability of a transistor including the oxide semiconductor layer of one embodiment of the present invention can be enhanced, and the reliability of a semiconductor device including the transistor can be enhanced.

The oxide semiconductor layer of one embodiment of the present invention preferably includes a metal oxide having a CAAC structure, in particular. Note that the CAAC structure is a crystal structure in which a plurality of microcrystals (typically, a plurality of microcrystals having a hexagonal crystal structure) have c-axis alignment and are connected on the a-b plane without alignment. In cross-sectional observation of an oxide semiconductor layer having a CAAC structure with use of a high-resolution transmission electron microscope (TEM) image, metal atoms are observed to be arranged in a layered manner in a crystal part. Thus, the oxide semiconductor layer having the CAAC structure can also be regarded as having a structure including the layered crystal part. The metal atoms arranged in a layered manner can be observed as arranged bright spots in a cross section of the oxide semiconductor layer observed with the TEM image.

The CAAC structure is formed such that the c-axis is perpendicular or substantially perpendicular to a surface on which the oxide semiconductor layer is formed, for example. In the CAAC structure, metal atoms are arranged in a layered manner in a direction parallel to or substantially parallel to the surface. In the region having the CAAC structure, the direction of the c-axis is preferably 90°±20° (greater than or equal to 70° and less than or equal to) 110°, further preferably 90°±15° (greater than or equal to 75° and less than or equal to) 105°, still further preferably 90°±10° (greater than or equal to 80° and less than or equal to) 100°, yet still further preferably 90°±5° (greater than or equal to 85° and less than or equal to) 95° from the surface.

The polycrystalline structure includes a crystal grain boundary (grain boundary). When an oxide semiconductor layer having a polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. In the CAAC structure, grain boundaries (grain boundaries) in the a-b plane are not observed clearly; thus, a highly reliable semiconductor device can be achieved. Furthermore, because the CAAC structure has a small number of crystal grain boundaries, an energy barrier for carrier conduction in a channel of a transistor is low, and an on-state current is expected to be increased.

The crystallinity of the oxide semiconductor layer can be analyzed by X-ray diffraction (XRD), TEM, or electron diffraction (ED), for example. Alternatively, these methods may be combined as appropriate for analysis.

When the oxide semiconductor layer having the CAAC structure is subjected to electron diffraction, a spot having c-axis alignment (a bright spot) is observed in the electron diffraction pattern. The c axes of the CAAC structure are preferably aligned in a direction parallel to the normal vector of the surface on which the oxide semiconductor layer is formed or the normal vector of the surface of the oxide semiconductor layer.

The FFT pattern obtained by performing fast Fourier transform (FFT) processing on a TEM image reflects reciprocal lattice space information like an electron diffraction pattern.

When the cross-sectional TEM image of the oxide semiconductor layer having the CAAC structure is obtained and each region in the cross-sectional TEM image is subjected to FFT processing to form the FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle formed by the crystal axis direction calculated from the FFT pattern and the surface on which the oxide semiconductor layer is formed is preferably within 90°±20° (greater than or equal to 70° and less than or equal to) 110°, further preferably within 90°±15° (greater than or equal to 75° and less than or equal to) 105°, still further preferably within 90°±10° (greater than or equal to 80° and less than or equal to) 100°, and yet still further preferably within 90°±5° (greater than or equal to 85° and less than or equal to) 95° can be regarded as having the CAAC structure.

When the oxide semiconductor layer having the CAAC structure is observed using the TEM image from the direction perpendicular to the surface on which the oxide semiconductor layer is formed, a triangular or hexagonal atomic arrangement and crystallinity are observed in the a-b plane. In a Voronoi diagram formed by analysis of the TEM image of the oxide semiconductor layer having the CAAC structure observed from the direction perpendicular to the surface on which the oxide semiconductor layer is formed, pentagonal, hexagonal, and heptagonal Voronoi regions are mainly observed, typically a hexagonal Voronoi region is observed. For example, the hexagonal Voronoi region accounts for higher than or equal to 30% and lower than 100% of the Voronoi regions observed in the Voronoi diagram.

A method for forming a Voronoi diagram is described. First, in TEM image analysis, FFT processing is performed, only information within a certain range is left by filtering, and then reverse fast Fourier transform is performed to obtain an FFT filtering image. Lattice points are extracted from the obtained FFT filtering image, and perpendicular bisectors of line segments each connecting adjacent lattice points are formed. A point at which three perpendicular bisectors intersect with each other is referred to as a Voronoi point, and a polygonal region surrounded by a line segment connecting the Voronoi points is referred to as a Voronoi region. In the above manner, a Voronoi diagram can be formed.

Note that as the TEM observation range for forming a Voronoi diagram, a rectangular region that is 50 nm wide and 50 nm long is observed, for example. Note that the observation range is not limited to this.

In addition, when distribution of hexagonal lattice orientations is analyzed using lattice points extracted by analysis of a plan-view TEM image, at a boundary between two structures with different hexagonal lattice orientations, the difference in hexagonal lattice orientation is small, the boundary is blurred, and the two structures are connected to be tangled with each other. That is, no clear boundary portion is observed in the CAAC structure.

Note that as the hexagonal lattice orientation, the orientation of a hexagon formed by six lattice points closest to each other can be calculated.

Note that there is no particular limitation on the crystallinity of a semiconductor material included in the oxide semiconductor layer. For example, at least one of an amorphous semiconductor (a semiconductor having an amorphous structure), a single crystal semiconductor (a semiconductor having a single crystal structure), and a semiconductor having other crystallinity than single crystal (a microcrystalline semiconductor, a polycrystalline semiconductor, or a semiconductor partly including crystal regions) may be included. The oxide semiconductor layer having crystallinity can inhibit deterioration of the transistor characteristics in some cases.

The metal oxide of one embodiment of the present invention preferably contains at least indium (In) or zinc (Zn), particularly preferably contains indium as its main component. Here, the metal oxide contains indium as its main component, and can further contain an element M. The metal oxide preferably contains two or three selected from indium, the element M, and zinc, and particularly preferably contains indium and zinc as its main components. Here, the metal oxide contains indium and zinc as its main components, and can further contain the element M. The element M is a metal element or metalloid element that has a high bonding energy with oxygen, such as a metal element or metalloid element whose bonding energy with oxygen is higher than that of In. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from aluminum, gallium, tin, and yttrium, still further preferably one or more selected from gallium and tin. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

In the cross section of the oxide semiconductor layer observed using the TEM image, metal atoms arranged in a layered manner in a direction parallel or substantially parallel to the surface on which the oxide semiconductor layer is formed are observed. In a TEM image, the metal atoms arranged in a layered manner are observed as arranged bright spots. For example, in a metal oxide containing indium, indium atoms arranged in a layered manner are observed. As another example, in a metal oxide containing indium and zinc, indium atoms and zinc atoms arranged in a layered manner are observed.

Examples of the metal oxide of one embodiment of the present invention include indium zinc oxide (also referred to as In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga-Sn oxide, IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO). Alternatively, indium tin oxide containing silicon (also referred to as ITSO), gallium tin oxide (Ga—Sn oxide), aluminum tin oxide (Al—Sn oxide), or the like can be given. As the metal oxide of one embodiment of the present invention, indium oxide can be used. As the metal oxide of one embodiment of the present invention, gallium oxide, zinc oxide, or the like can be used.

By increasing the proportion of the number of indium atoms in the total number of atoms of all the metal elements included in the metal oxide, a high on-state current and high frequency characteristics of the transistor can be achieved.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include Period 5 metal elements and Period 6 metal elements. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the element M atoms in the sum of atoms of all metal elements included in the metal oxide, oxygen vacancies can be prevented from being formed in the metal oxide. Accordingly, generation of carriers due to oxygen vacancies is inhibited, which reduces the off-state current of the transistor. Furthermore, a change in electrical characteristics of the transistor is suppressed and the transistor can have high reliability.

In the description of this embodiment, In—Ga—Zn oxide is sometimes given as an example of the metal oxide.

The oxide semiconductor layer of one embodiment of the present invention can be obtained by forming metal oxides by two kinds of formation methods. For example, the oxide semiconductor layer of one embodiment of the present invention can be obtained by forming metal oxides by a first formation method and a second formation method. The oxide semiconductor layer obtained by the two kinds of formation methods may be referred to as a hybrid OS.

In the formation of the oxide semiconductor layer of one embodiment of the present invention, a metal oxide having crystallinity is deposited by a first formation method. The metal oxide deposited at this time particularly preferably has a CAAC structure. A metal oxide film formed by, for example, a sputtering method is likely to have crystallinity.

In the case where a metal oxide is formed by the first formation method, a mixed layer is sometimes formed at the interface between the metal oxide and a layer (formation surface) on which the metal oxide is deposited. For example, in the case where a sputtering method is used as the first formation method, the mixed layer is sometimes formed by particles ejected from a target or the like (also referred to as sputtered particles), energy applied to the substrate side by the sputtered particles or the like. There is a concern that the mixed layer may hinder crystallization of the metal oxide.

For example, in the case where an insulating layer containing silicon, e.g., silicon oxide, is used as the formation surface and a metal oxide is formed over the silicon oxide by the first formation method, silicon is liable to enter the metal oxide. There is a concern that the entry of impurities such as silicon into the metal oxide may hinder crystallization of the metal oxide.

In view of the above, in one embodiment of the present invention, a metal oxide is formed by the second formation method before a metal oxide is formed by the first formation method. In other words, a metal oxide is formed by the second formation method as a first layer, and then a metal oxide is formed by the first formation method as a second layer over the first layer. In that case, the second formation method preferably causes less damage to a formation surface than the first formation method. When a formation method that causes less damage to a formation surface is used as the second formation method, formation of a mixed layer at an interface between the oxide semiconductor layer and a layer (the formation surface) on which the oxide semiconductor layer is formed can be inhibited. Moreover, entry of impurities such as silicon can be inhibited in the second layer, which can increase the crystallinity. For example, an atomic layer deposition (ALD) method and a chemical vapor deposition (CVD) method are suitable as the second formation method because they can reduce damages to a formation surface as compared with a sputtering method.

In addition, for example, a metal oxide having a microcrystalline structure or an amorphous structure that has lower crystallinity than the CAAC structure is sometimes formed as the first layer. Formation of the second layer having high crystallinity on the first layer having low crystallinity or the formation of the second layer followed by heat treatment can increase the crystallinity of the first layer with the second layer as a nucleus in some cases. Accordingly, the crystallinity can be increased in the whole oxide semiconductor layer including the vicinity of the interface with the formation surface in some cases.

In a preferred mode of the oxide semiconductor layer of one embodiment of the present invention, a metal oxide is formed over a formation surface by the second formation method, and then a metal oxide is formed thereover by the first formation method.

Examples of the first formation method include a sputtering method and a pulsed laser deposition (PLD) method.

Examples of the second formation method include an ALD method, a plasma enhanced CVD (PECVD) method, a thermal CVD method, a photo CVD method, a metal organic CVD (MOCVD) method, and a molecular beam epitaxy (MBE) method. The MBE method is a formation method in which a thin film having a crystal structure reflecting a crystal system of a substrate is grown, and is one of formation methods that causes less damage to a formation surface. A wet method can be used as the second formation method. The wet method is one of formation methods that cause less damage to a formation surface. An example of the wet method is a spray coating method.

For example, the oxide semiconductor layer of one embodiment of the present invention can be formed in the following manner: a metal oxide is formed as a first layer by the second formation method, and then a metal oxide is formed as a second layer by the first formation method. Specifically, an ALD method can be employed as the second formation method, and a sputtering method can be employed as the first formation method. The metal oxide formed by the first formation method preferably has a CAAC structure.

Furthermore, a third layer can be formed over the second layer. Because the second layer has high crystallinity, the third layer can grow with a crystal of the second layer as a nucleus or a seed. Thus, the third layer can be crystallized even when a formation method that easily gives crystallinity is not employed as the formation method of the third layer. Here, for example, when a formation method that gives higher coverage than that of the second layer is employed for formation of the third layer, the entire oxide semiconductor layer can have both high crystallinity and high coverage. For example, when a formation method that causes less damage than damage to the second layer is employed for formation of the third layer, damage to the second layer can be reduced and high crystallinity can be obtained in the entire oxide semiconductor layer.

Furthermore, when the second layer is less affected by the formation surface owing to the formation of the first layer, the second layer has improved crystallinity and extremely excellent crystallinity. Thus, the third layer grown with the second layer as a nucleus or a seed is also expected to have extremely excellent crystallinity.

Note that the third layer is the uppermost layer of the oxide semiconductor layer. In the case where the oxide semiconductor layer is used as a semiconductor layer of a transistor described later, the third layer is, for example, a layer in contact with a gate insulating layer. Increasing the crystallinity of the layer in contact with the gate insulating layer can increase the carrier mobility in an on state of the transistor.

In an example, the oxide semiconductor layer of one embodiment of the present invention can be formed in the following manner: a metal oxide is formed as the first layer by the second formation method, a metal oxide is formed as the second layer by the first formation method, and a metal oxide is formed as the third layer by the second formation method. Specifically, an ALD method can be employed for the second formation method, and a sputtering method can be employed for the first formation method. The metal oxide formed by the first formation method preferably has a CAAC structure. The ALD method is a formation method that achieves higher coverage than a sputtering method, and when the ALD method is employed for the formation methods of the first layer and the third layer, the coverage with the oxide semiconductor layer can be improved. Thus, the oxide semiconductor layer can be formed to favorably cover a step with a high aspect ratio, an opening portion, or the like.

Examples of the sputtering method include an RF sputtering method using a high-frequency power source for a sputtering power source, a DC sputtering method using a DC power source, and a pulsed DC sputtering method in which a voltage applied to an electrode is changed in a pulsed manner. The RF sputtering method is mainly employed in the case where an insulating film is formed, and the DC sputtering method is mainly employed in the case where a metal conductive film is formed. The pulsed DC sputtering method is mainly employed in the case where a compound such as an oxide, a nitride, or a carbide is deposited by a reactive sputtering method.

Examples of the ALD method include a thermal ALD method, in which a precursor and a reactant react with each other only by a thermal energy, and a plasma-enhanced ALD (PEALD) method, in which a reactant excited by plasma is used.

The ALD method enables deposition of one-by-one atomic layer, and has various advantages such as formation of an extremely thin film, deposition on a component with a high aspect ratio, deposition on a surface having a large step, formation of a film with few defects such as pinholes, deposition with excellent coverage, and low-temperature deposition. The PEALD method utilizing plasma may be preferred because deposition at lower temperature is possible. Note that some precursors used in the ALD method contain an element such as carbon or chlorine. Thus, a film formed by the ALD method sometimes contains an element such as carbon or chlorine in a larger quantity than a film formed by another formation method. Note that these elements can be quantified by XPS or SIMS. The formation method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike in a formation method in which particles ejected from a target or the like are deposited, the ALD method is a formation method in which a film is formed by reaction at a surface of an object to be processed. Thus, the ALD method can provide good step coverage, almost regardless of the shape of an object. In particular, the ALD method allows excellent step coverage and excellent thickness uniformity and is suitable for covering a surface of an opening portion with a high aspect ratio, for example.

A high-quality film can be obtained at a relatively low temperature by a PECVD method. A thermal CVD method does not use plasma and thus can cause less plasma damage to an object. The thermal CVD method yields a film with few defects because of no plasma damage during deposition.

By a CVD method, a film with a certain composition can be deposited by adjusting the flow rate ratio of source gases. For example, a CVD method enables a film with a gradually-changed composition to be deposited by changing the flow rate ratio of source gases during deposition. In the case where a film is deposited while the flow rate ratio of source gases is changed, as compared to the case where a film is deposited using a plurality of deposition chambers, the time taken for the deposition can be shortened because the time taken for transfer and pressure adjustment is removed. Hence, the productivity of the semiconductor device can be improved in some cases.

### [Formation Method of Oxide Semiconductor Layer]

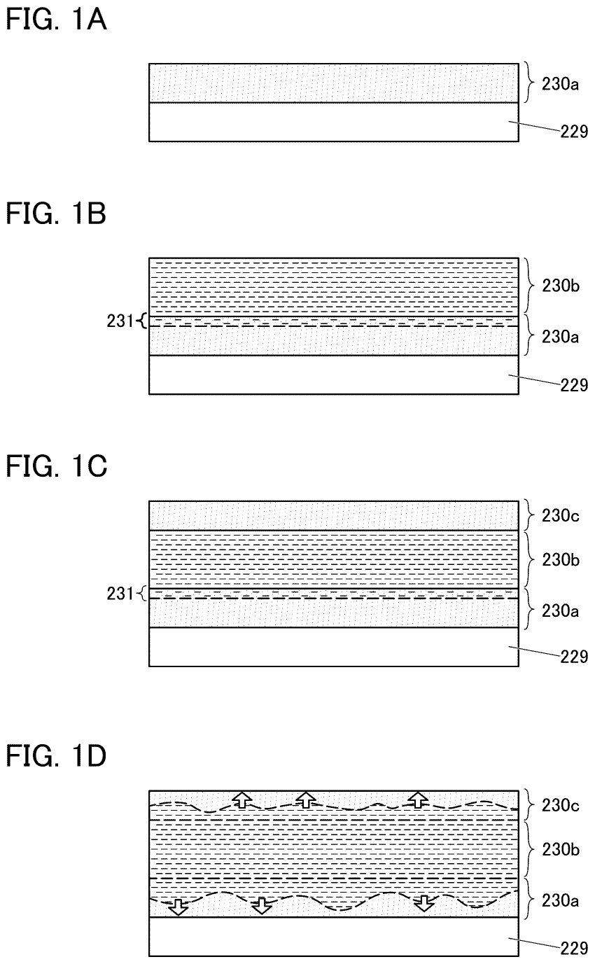

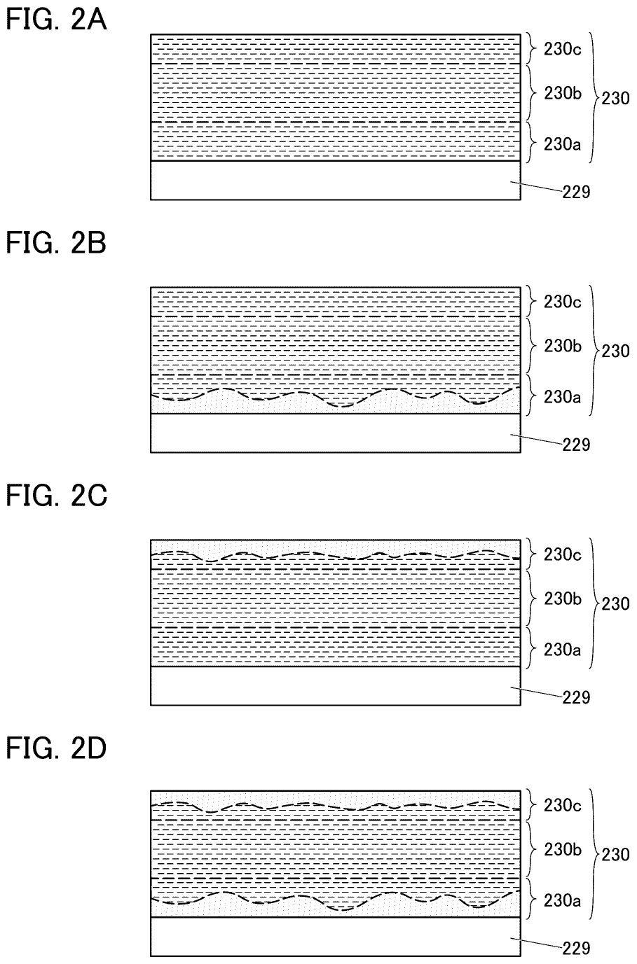

An example of a method for forming the oxide semiconductor layer 230 is described with reference to FIG. 1A to FIG. 2D.

For example, the oxide semiconductor layer 230 can be formed in the following manner: an oxide semiconductor layer 230a is formed on a layer 229 that is a surface on which the oxide semiconductor layer is to be formed by an ALD method, an oxide semiconductor layer 230b is formed over the oxide semiconductor layer 230a by a sputtering method, and an oxide semiconductor layer 230c is formed over the oxide semiconductor layer 230b by an ALD method. Moreover, heat treatment is preferably performed after the formation of the oxide semiconductor layer 230. By performing the heat treatment, the crystallinity of the oxide semiconductor layer 230 can be increased. Here, the heat treatment is not limited to heating. For example, the heat treatment may be performed with heat applied in the manufacturing process. The layer 229 is an insulating film, and examples of the insulating film include silicon oxide, silicon oxynitride, silicon nitride, silicon nitride oxide, aluminum oxide, and hafnium oxide. As the layer 229, a film that is described later as an insulator included in the semiconductor device can be used.

Alternatively, the layer 229 may be a conductive film. For example, the oxide semiconductor layer 230 can also be formed over a conductive film functioning as an electrode of the semiconductor device.

The layer 229 does not need to have crystallinity. In other words, the layer 229 may have an amorphous structure. In the case where the layer 229 has crystallinity, the layer 229 may have a crystal structure with low lattice matching with the metal oxide included in the oxide semiconductor layer 230.

First, the oxide semiconductor 230a is formed over the layer 229 (FIG. 1A). Next, the oxide semiconductor layer 230b is formed over the oxide semiconductor layer 230a (FIG. 1B).

The oxide semiconductor layer 230b is preferably formed by a sputtering method. The oxide semiconductor layer 230b preferably has a composition suitable for forming the CAAC structure.

The oxide semiconductor layer 230a is preferably formed by a formation method that causes less damage to a surface on which it is to be formed than a formation method of the oxide semiconductor layer 230b. Here, the oxide semiconductor layer 230a is formed by an ALD method.

In the case where the metal oxide film is deposited by a sputtering method, damage to a surface on which the metal oxide film is to be formed may cause alloying of a component contained in the metal oxide film with a component contained in the layer on which the metal oxide film is to be formed. In the case where alloying occurs, it is difficult to increase the crystallinity of the alloyed region even when heat treatment described later is performed. When an oxide semiconductor layer including the alloyed region is used for a transistor, the initial characteristics or reliability of the transistor may be adversely affected. Therefore, it is preferable to inhibit alloying of the component contained in the metal oxide film with the component contained in the layer on which the metal oxide film is to be formed.

In the method for forming the oxide semiconductor layer of one embodiment of the present invention, the oxide semiconductor layer 230a is formed on the layer 229, and then the oxide semiconductor layer 230b is formed by a sputtering method. In this case, the oxide semiconductor layer 230a is preferably formed by a formation method that causes less damage to a surface of the layer 229. When the oxide semiconductor layer 230a is formed between the oxide semiconductor layer 230b and the layer 229 by a formation method that causes less damage to the surface of the layer 229, the alloying of the component contained in the oxide semiconductor layer 230 with the component contained in the layer 229 can be inhibited, so that the crystallinity of the oxide semiconductor layer 230 can be further increased.

The above structure can reduce the thickness of the alloyed region or reduce the thickness of the alloyed region to the extent that the alloyed region cannot be observed. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 1A and 1B illustrate an example in which an alloyed region is not formed between the layer 229 and the oxide semiconductor layer 230a.

Furthermore, the thickness of the alloyed region can sometimes be obtained by composition analysis of the region and its vicinity with SIMS or energy dispersive X-ray spectroscopy (EDX) line analysis.

For example, EDX line analysis is performed on the alloyed region and its vicinity on the assumption that the direction perpendicular to the surface on which the oxide semiconductor layer 230a is formed is the depth direction. Next, in profiles of quantitative values of elements in the depth direction obtained by the analysis, the depth at which the quantitative value of a metal that is the main component of the oxide semiconductor layer 230a and is not the main component of a layer (here, the layer 229) on which the oxide semiconductor layer 230a is formed (the metal is In when the oxide semiconductor layer 230a contains In) becomes half is defined as a depth (position) of the interface between the alloyed region and the oxide semiconductor layer 230a. Furthermore, the depth at which the quantitative value of an element (e.g., Si) that is the main component of the layer 229 and that is not the main component of the oxide semiconductor layer 230a becomes half is defined as a depth (position) of the interface between the alloyed region and the layer 229. In the above manner, the thickness of the alloyed region can be calculated.

When the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where SIMS analysis of the oxide semiconductor layer 230 formed over the layer 229 that is formed using a silicon oxide layer is performed, the depth at which the silicon concentration is 50% of the maximum value of the silicon concentration of the layer 229 is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

When the thickness t_s2 is a value within the above range, the thickness of the alloyed region is reduced, whereby the thickness t_s2 can be a value within the above range.

Note that when the thickness of the alloyed region is reduced, the CAAC structure can be formed in the vicinity of a surface on which the oxide semiconductor layer 230 is formed. Here, the vicinity of the surface refers to, for example, a region ranging from the surface on which the oxide semiconductor layer 230 is formed to greater than 0 nm and less than or equal to 3 nm, preferably greater than 0 nm and less than or equal to 2 nm, further preferably greater than or equal to 1 nm and less than or equal to 2 nm in a direction substantially perpendicular to the surface.

Note that the CAAC structure in the vicinity of the surface on which the oxide semiconductor layer is formed can be confirmed in TEM observation in some cases. For example, in high-resolution TEM cross-sectional observation of the oxide semiconductor layer 230, bright spots arranged in a layered manner in a direction parallel to the surface are observed in the vicinity of the surface.

Alternatively, the CAAC structure in the vicinity of the surface on which the oxide semiconductor layer is formed can be evaluated from a map showing crystal orientation in some cases. The map showing crystal orientation can be obtained by, for example, obtaining a cross-sectional TEM image, performing fast Fourier transform (FFT) processing on each region in the cross-sectional TEM image to create an FFT pattern, and calculating the direction of the crystal axis of each region. The FFT pattern reflects reciprocal lattice space information like an electron diffraction pattern. For example, a region in which an angle formed by the crystal axis direction calculated and the surface on which the oxide semiconductor layer is formed is preferably within 90°±20° (greater than or equal to 70° and less than or equal to) 110°, further preferably within 90°±15° (greater than or equal to 75° and less than or equal to) 105°, still further preferably within 90°±10° (greater than or equal to 80° and less than or equal to) 100°, and yet still further preferably within 90°±5° (greater than or equal to 85° and less than or equal to) 95° can be regarded as having the CAAC structure.

Note that when the oxide semiconductor layer 230a is formed by an ALD method, an oxide semiconductor layer having a microcrystalline structure or an amorphous structure that has lower crystallinity than the CAAC structure may be formed. That is, in the formation step illustrated in FIG. 1A, the oxide semiconductor layer 230a sometimes includes a region having lower crystallinity than the oxide semiconductor layer 230b.

Here, a method for forming an In-M-Zn oxide as the oxide semiconductor layer 230a by an ALD method is described. Note that the details of the formation of the metal oxide by an ALD method will be described later.

First, a source gas that contains a precursor containing indium is introduced into a chamber so that the precursor is adsorbed on the surface of the layer 229. Here, the substrate heating temperature is preferably a temperature corresponding to the decomposition temperature of the precursor.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than indium are released while indium is adsorbed on the substrate, whereby a layer in which indium and oxygen are bonded to each other is formed. Ozone, oxygen, water, or the like can be used as the oxidizer. After that, introduction of the oxidizer is stopped and the chamber is purged so that an excess reactant, a reaction product, and the like are removed from the chamber.

Subsequently, a source gas that contains a precursor containing the element M is introduced into the chamber, so that the precursor is adsorbed on the layer in which indium and oxygen are bonded to each other. Here, the substrate heating temperature is preferably a temperature corresponding to the decomposition temperature of the precursor.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than the element M are released while the element M is adsorbed on the substrate, whereby a layer in which the element M and oxygen are bonded to each other is formed. After that, introduction of the oxidizer is stopped and the chamber is purged so that an excess reactant, a reaction product, and the like are removed from the chamber.

Next, a source gas that contains a precursor containing zinc is introduced into the chamber and adsorbed on the layer in which the element M and oxygen are bonded to each other. Here, the substrate heating temperature is preferably a temperature corresponding to the decomposition temperature of the precursor.

Here, in the case of a thermal ALD method in which triethylindium is used as the precursor containing indium, triethylgallium is used as a precursor containing gallium, and diethylzinc is used as the precursor containing zinc, the substrate heating temperature is higher than or equal to 100° C. and lower than or equal to 350° C., preferably higher than or equal to 150° C. and lower than or equal to 300° C., for example.

Next, introduction of the source gas is stopped and the chamber is purged so that an excess precursor, a reaction product, and the like are removed from the chamber. Then, an oxidizer is introduced as a reactant into the chamber to react with the adsorbed precursor, and components other than zinc are released while zinc is adsorbed on the substrate, whereby a layer in which zinc and oxygen are bonded to each other is formed. After that, introduction of the oxidizer is stopped and the chamber is purged so that an excess reactant, a reaction product, and the like are removed from the chamber.

Next, the layer in which indium and oxygen are bonded to each other is formed again over the layer in which zinc and oxygen are bonded to each other. By repeating the above steps, an In-M-Zn oxide can be formed as the oxide semiconductor layer 230a over the layer 229 by an ALD method.

When an ALD method is used, the composition of a film to be formed can be controlled with the amount of introduced source gases. For example, a film with a certain composition can be formed by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be formed. In the case where a film is formed while the source gas is changed, as compared with the case where a film is formed using a plurality of deposition chambers, the time taken for the film formation can be shortened because the time taken for transfer and pressure adjustment is omitted. Hence, the productivity of the semiconductor device can be improved in some cases.

After the oxide semiconductor layer 230a is formed by an ALD method, an In-M-Zn oxide is formed over the oxide semiconductor layer 230a by a sputtering method as the oxide semiconductor layer 230b.

When the oxide semiconductor layer 230b is formed by a sputtering method, a mixed layer 231 is formed on the surface of the oxide semiconductor layer 230a or in the vicinity of the surface. A fine crystal region is sometimes formed in the mixed layer 231 by, for example, sputtered particles or energy or the like applied to the substrate side by sputtered particles or the like at the time of forming the oxide semiconductor layer 230b. In the subsequent heat treatment step, the mixed layer 231 or the fine crystal region formed in the mixed layer 231 serves as a nucleus, and at least part of the oxide semiconductor layer 230a is crystallized in some cases.

As a target used in a sputtering method, an In-M-Zn oxide can be used. In the case where a metal oxide is formed by a sputtering method, oxygen or a mixed gas of oxygen and a noble gas can be used as a sputtering gas. In addition, an increase in the proportion of oxygen in the sputtering gas can increase the amount of excess oxygen contained in the oxide film to be deposited.

A higher proportion of the flow rate of an oxygen gas to the flow rate of the whole formation gas (also referred to as oxygen flow rate ratio) used at the time of forming the metal oxide enables the formed metal oxide to have higher crystallinity in some cases.

When the metal oxide is formed by a sputtering method and the oxygen proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess oxide semiconductor layer in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, oxygen-deficient metal oxide is formed. A transistor including the oxygen-deficient metal oxide in a channel formation region can have relatively high field-effect mobility.

Note that in the case where the metal oxide is formed by a sputtering method, the atomic ratio of the deposited metal oxide may be different from the atomic ratio of the sputtering target. In particular, the zinc content of the deposited metal oxide may be reduced to approximately 50% of that of the sputtering target.

In the deposition of the oxide semiconductor layer 230b by a sputtering method, substrate heating is preferably performed. In forming a metal oxide, the substrate temperature (stage temperature) at the time of forming the metal oxide is increased, whereby a metal oxide with high crystallinity can be formed in some cases. In the deposition of the oxide semiconductor layer 230b by a sputtering method, the substrate heating temperature is preferably higher than or equal to 100° C. and lower than or equal to 400° C., further preferably higher than or equal to 200° C. and lower than or equal to 300° C., for example.

As described above, as illustrated in FIG. 1B, the oxide semiconductor layer 230a and the oxide semiconductor layer 230b over the oxide semiconductor layer 230a can be formed over the layer 229.

Next, the oxide semiconductor layer 230c is formed over the oxide semiconductor layer 230b (FIG. 1C). Here, the oxide semiconductor layer 230c is formed by an ALD method. For the formation of the oxide semiconductor layer 230c by an ALD method, the method for forming the oxide semiconductor layer 230a can be referred to.

When the oxide semiconductor layer 230c having lower crystallinity than the CAAC structure is formed over the oxide semiconductor layer 230b having the CAAC structure by an ALD method, the oxide semiconductor layer 230c may epitaxially grow with the oxide semiconductor layer 230b as a nucleus. Thus, at the time of forming the oxide semiconductor layer 230c, the oxide semiconductor layer 230c may include a region having a CAAC structure. The region having the CAAC structure is preferably formed throughout the oxide semiconductor layer 230c.

Next, heat treatment may be performed.

The heat treatment temperature may be higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature may be set to 400° C.±25° C. (higher than or equal to 375° C. and lower than or equal to 425° C.). The treatment time may be shorter than or equal to 10 hours, longer than or equal to 1 minute and shorter than or equal to 5 hours, or longer than or equal to 1 minute and shorter than or equal to 2 hours. In the case of using an RTA apparatus, the processing time may be longer than or equal to 1 second and shorter than or equal to 5 minutes, for example. By the heat treatment, the oxide semiconductor layer 230c (in other words, crystal molecules formed by an ALD method) is expected to fill the atomic-level space between crystal parts of the CAAC structure of the oxide semiconductor layer 230b.

The heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

By the heat treatment step, the crystallinity of the region having the CAAC structure in the oxide semiconductor layer 230c is increased in some cases. In the case where the region having the CAAC structure is formed only below the oxide semiconductor layer 230c after deposition by an ALD method, the region having the CAAC structure may be extended upward by the heat treatment step (FIG. 1D). That is, by the heat treatment, the region having a CAAC structure is sometimes formed in the whole layer of the oxide semiconductor layer 230c.

Through the heat treatment step, the oxide semiconductor layer 230b is further repaired by the oxide semiconductor layer 230c (in other words, crystal molecules formed by an ALD method) that fills the atomic-level space between crystal parts of the CAAC structure of the oxide semiconductor layer 230b in some cases.

At least part of the oxide semiconductor layer 230a preferably has a CAAC structure by the heat treatment step (FIG. 1D). The CAAC structure is expected to be easily generated when the mixed layer 231 formed in the oxide semiconductor layer 230a in the formation of the oxide semiconductor layer 230b becomes a nucleus or a seed. The oxide semiconductor layer 230a preferably has a large CAAC region, and the CAAC region preferably extends to the vicinity of the layer 229.

Since the CAAC region extends from the upper portion to the lower portion of the oxide semiconductor layer 230a, the CAAC region can extend to the vicinity of the layer 229, regardless of the material and crystallinity of the layer 229. For example, even when the layer 229 has an amorphous structure, the oxide semiconductor layer 230a having high crystallinity can be formed. Thus, the method for forming the oxide semiconductor layer of one embodiment of the present invention is suitable for the case where a layer on which the oxide semiconductor layer is to be formed has an amorphous structure, in particular.

FIGS. 1A to 1D are cross-sectional views illustrating the formation method of a metal oxide of one embodiment of the present invention. FIGS. 1A to 1D can also be regarded as conceptual diagrams illustrating a deposition model of the metal oxide of one embodiment of the present invention. As illustrated in FIGS. 1A to 1D, the crystallinity of each of the oxide semiconductor layers 230a and 230c is increased with the oxide semiconductor layer 230b as a nucleus or a seed. Specifically, the crystallinity of the oxide semiconductor layer 230a may be increased at the time of depositing the oxide semiconductor layer 230b or by heat treatment after the deposition of the oxide semiconductor layer 230c. In addition, the crystallinity of the oxide semiconductor layer 230c may be increased at the time of depositing the oxide semiconductor layer 230c or by heat treatment after the deposition of the oxide semiconductor layer 230c. Note that the heat treatment has an assisting function of increasing the crystallinity.

As described above, in the method for forming a metal oxide of one embodiment of the present invention, the crystallinity of the oxide semiconductors (here, the oxide semiconductor layers 230a and 230c) above and below the oxide semiconductor layer 230b can be increased by using the oxide semiconductor layer 230b (i.e., CAAC) having high crystallinity as a nucleus or a seed. This can increase the crystallinity of the whole oxide semiconductor layer. In other words, the oxide semiconductor layer 230b serves as a nucleus or a seed to cause solid-phase growths of the oxide semiconductors above and below the oxide semiconductor layer 230b, so that the oxide semiconductor with high crystallinity can be formed. An oxide semiconductor formed by such a formation method, here, a CAAC film, may be referred to as an axial growth CAAC (Axial Growth CAAC or AG CAAC).

The region having a CAAC structure preferably spreads in the whole layer of the oxide semiconductor layer 230 including the oxide semiconductor layers 230a and 230c. FIG. 2A illustrates a state where the oxide semiconductor layers 230a, 230b, and 230c are each crystallized. Crystals in the region having a CAAC structure in the oxide semiconductor layer 230a are connected to crystals in the region having a CAAC structure in the oxide semiconductor layer 230b. Crystals in the region having a CAAC structure in the oxide semiconductor layer 230c are connected to the crystals in the region having a CAAC structure in the oxide semiconductor layer 230b. As a result, a boundary between the oxide semiconductor layer 230a and the oxide semiconductor layer 230b is not observed in some cases. In addition, a boundary between the oxide semiconductor layer 230b and the oxide semiconductor layer 230c is not observed in some cases. The oxide semiconductor layer 230 may be expressed as one layer where the interfaces are not clearly observed. The oxide semiconductor layer 230 may be expressed as a single layer in some cases.

In cross-sectional observation with a high-resolution TEM, for example, in each of the oxide semiconductor layers 230a, 230b, and 230c, bright spots arranged parallel to the surface on which the oxide semiconductor layer 230a is formed are observed in the region having the CAAC structure. The c-axis of the CAAC structure included in each of the oxide semiconductor layers 230a, 230b, and 230c is preferably substantially parallel to the normal direction of the surface on which the oxide semiconductor layer 230a is formed.

Part of the oxide semiconductor layer 230a or part of the oxide semiconductor layer 230c is not crystallized in some cases. In addition, a region having crystallinity lower than that of the CAAC structure may be present in part of the oxide semiconductor layer 230a or part of the oxide semiconductor layer 230c. An example illustrated in FIG. 2B illustrates a state of the oxide semiconductor layer 230a where the vicinity of the interface between the oxide semiconductor layer 230a and the layer 229 is not crystallized or a region having crystallinity lower than that of the CAAC structure is present in the vicinity of the interface between the oxide semiconductor layer 230a and the layer 229. FIG. 2C illustrates a state where the vicinity of the surface of the oxide semiconductor layer 230c is not crystallized or a region having crystallinity lower than that of the CAAC structure is present in the vicinity of the surface of the oxide semiconductor layer 230c. FIG. 2D illustrates a state where the vicinity of the interface between the oxide semiconductor layer 230a and the layer 229 and the vicinity of the surface of the oxide semiconductor layer 230c are not crystallized or regions having crystallinity lower than that of the CAAC structure are present in the vicinity of the interface between the oxide semiconductor layer 230a and the layer 229 and in the vicinity of the surface of the oxide semiconductor layer 230c.

Increasing the crystallinity of the oxide semiconductor layer can inhibit an increase in the electric resistance of the semiconductor layer of a transistor including the oxide semiconductor layer or increase the initial characteristics (in particular, the on-state current) of the transistor, and thus a transistor suitable for high-speed operation can be expected. In addition, the reliability and the on current of the transistor can be improved.

By the method for forming the oxide semiconductor layer of one embodiment of the present invention, the crystallinities of the metal oxides positioned above and below can be improved with the metal oxide having the CAAC structure as the starting point, and the whole oxide semiconductor layer can have high crystallinity.

The oxide semiconductor layer of one embodiment of the present invention has high crystallinity throughout the whole layer. Thus, in the oxide semiconductor layer 230, the boundaries between the stacked films of the oxide semiconductor layers 230a, 230b, and 230c are not observed in some cases. In particular, after heat treatment is performed, the boundaries between the stacked films are difficult to observe in some cases. Whether the boundaries between the stacked films are present can be checked with a cross-sectional TEM or a cross-sectional STEM, for example.

As described above, when a metal oxide with a high In content is used for a transistor, the field-effect mobility of the transistor can be increased. On the other hand, an oxide semiconductor with a high In content tends to be polycrystallized. The use of a metal oxide having a polycrystalline structure for a transistor adversely affects the initial characteristics or reliability of the transistor. Thus, when an oxide semiconductor with a high In content is used for one or both of the oxide semiconductor layers 230a and 230c, crystals reflecting crystal orientations included in the oxide semiconductor layer 230b are formed, so that one or both of the oxide semiconductor layers 230a and 230c can be inhibited from being polycrystallized.

It is preferable that crystals included in the oxide semiconductor layer 230b and crystals included in the oxide semiconductor layer 230a or 230c have a small lattice mismatch. Thus, the oxide semiconductor layer 230a or 230c can form crystals reflecting the orientation of crystals included in the oxide semiconductor layer 230b. In this case, for example, in high-resolution TEM cross-sectional observation of the oxide semiconductor layer 230, bright spots arranged in a layered manner in a direction parallel to the surface on which the oxide semiconductor layer 230 is formed are observed in the oxide semiconductor layer 230a or 230c.

As long as crystals included in the oxide semiconductor layer 230b and crystals included in the oxide semiconductor layer 230a or 230c have a small lattice mismatch, there is no particular limitation on the crystal structure of the oxide semiconductor layer 230a or 230c. The crystal structure of the oxide semiconductor layer 230a or 230c may be any of a cubic crystal structure, a tetragonal crystal structure, an orthorhombic crystal structure, a hexagonal crystal structure, a monoclinic crystal structure, and a trigonal crystal structure.

### [Composition of Oxide Semiconductor Layer]

The oxide semiconductor layer 230a preferably has a composition different from that of the oxide semiconductor layer 230b. The oxide semiconductor layer 230c preferably has a composition different from that of the oxide semiconductor layer 230b. The oxide semiconductor layer 230a can have the same composition as the oxide semiconductor layer 230c. Alternatively, the oxide semiconductor layers 230a and 230c can have different compositions.

As described above, the oxide semiconductor layer 230b preferably has a composition suitable for forming the CAAC structure. The oxide semiconductor layer 230b can be formed by a sputtering method, for example. In addition, the oxide semiconductor layer 230b preferably contains zinc, for example. The oxide semiconductor layer 230b containing zinc can be a metal oxide having high crystallinity. The oxide semiconductor layer 230b preferably contains an element M in addition to zinc. When the oxide semiconductor layer 230b contains the element M, formation of oxygen vacancies in the metal oxide can be inhibited, for example. Thus, the reliability of the transistor including an oxide semiconductor layer can be improved. As the oxide semiconductor layer 230b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof may be specifically used. Note that the neighborhood of the atomic ratio includes ±30% of an intended atomic ratio. In this case, it is preferable to use one or more of gallium, aluminum, and tin as the element M.

The oxide semiconductor layer 230b may have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed. Examples of the composition include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

The oxide semiconductor layers 230a and 230c can be metal oxides with a high proportion of In. The oxide semiconductor layers 230a and 230c can each be formed by an ALD method, for example. In particular, a metal oxide in which the proportion of In is higher than that of the element M is preferably used. With the use of a metal oxide having a high proportion of In, the on-state current can be increased and the frequency characteristics can be enhanced in a transistor using an oxide semiconductor layer.

Alternatively, the oxide semiconductor layers 230a and 230c may each have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed for the oxide semiconductor layers 230a and 230c. Examples of the composition include a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, and a composition of In:Sn:Zn=2:0.1:1 [atomic ratio] or in the neighborhood thereof.

The oxide semiconductor layers 230a and 230c can each be a metal oxide having a higher proportion of In than that of the oxide semiconductor layer 230b.

For example, as the oxide semiconductor layers 230a and 230c, a metal oxide having a Ga proportion higher than that of the oxide semiconductor layer 230b can be used. For the oxide semiconductor layers 230a and 230c, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. When the proportion of Ga is increased, the band gap of each of the oxide semiconductor layers 230a and 230c can be larger than that of the oxide semiconductor layer 230b in some cases, for example. Thus, the oxide semiconductor layer 230b is sandwiched between the oxide semiconductor layers 230a and 230c each having a wide band gap, and the oxide semiconductor layer 230b mainly functions as a current path (channel). When the oxide semiconductor layer 230b is sandwiched between the oxide semiconductor layers 230a and 230c, trap states at the interfaces with the oxide semiconductor layer 230b and the vicinity thereof can be reduced. Accordingly, a buried-channel transistor where a channel is away from the interface with an insulating layer can be achieved, whereby the field-effect mobility can be increased. Furthermore, the influence of interface states that may be formed on the back channel side is reduced, so that light deterioration (e.g., light negative bias deterioration) of the transistor can be inhibited and the reliability of the transistor can be increased.

Alternatively, one of the oxide semiconductor layers 230a and 230c can be a metal oxide with a higher In proportion than the oxide semiconductor layer 230b, and the other can be a metal oxide with a higher Ga proportion than the oxide semiconductor layer 230b.

The oxide semiconductor layers 230a, 230b, and 230c may each include a stack of layers having the above compositions. For example, the oxide semiconductor layer 230c may have a structure where a metal oxide with a high Ga proportion is stacked over a metal oxide with a high In proportion.

In the oxide semiconductor layer of one embodiment of the present invention, even in the case where a composition in which the CAAC structure is less likely to be formed in the formation of a single layer is used for the oxide semiconductor layers 230a and 230c, crystal growth occurs with the oxide semiconductor layer 230b as a nucleus, so that the whole oxide semiconductor layer including the oxide semiconductor layers 230a and 230c can have a CAAC structure. Alternatively, a CAAC structure can be formed in a region that includes the oxide semiconductor layer 230b and at least part of each of the oxide semiconductor layers 230a and 230c.

In particular, even in a composition where the proportion of In in the oxide semiconductor layers 230a and 230c is high, crystallinity suitable for a semiconductor layer of a transistor can be obtained. For the oxide semiconductor layer of one embodiment of the present invention, it is possible to attain higher on-state characteristics of the transistor by increasing the proportion of In and a higher reliability by employing a CAAC structure with high crystallinity at the same time.

A metal oxide having the same composition as the oxide semiconductor layer 230b may be used for the oxide semiconductor layers 230a and 230c. By using the same composition, the oxide semiconductors each have easily a CAAC structure after heat treatment in some cases.

The oxide semiconductor layer having a CAAC structure formed by the two kinds of formation methods sometimes has one or more of a higher dielectric constant, higher film density, and higher film hardness than the oxide semiconductor layer having a CAAC structure formed by one kind of formation method.

With the use of the oxide semiconductor layer having a CAAC structure formed by the above two kinds of formation methods for a channel formation region of a transistor, the transistor can have excellent characteristics (e.g., a high on-state current, high field-effect mobility, a low S value, high frequency characteristics (also referred to as f characteristics), or high reliability).

Analysis of the composition of the metal oxide used for the oxide semiconductor layer 230 can be performed by energy dispersive X-ray spectrometry (EDX), XPS, inductively coupled plasma-mass spectrometry (ICP-MS), or inductively coupled plasma-atomic emission spectrometry (ICP-AES). Alternatively, these methods may be combined as appropriate for the analysis. As for an element whose content is low, the actual content may be different from the content obtained by analysis because of the influence of the analysis accuracy. In the case where the content of the element M is low, for example, the content of the element M obtained by analysis may be lower than the actual content.

### [Oxide Semiconductor Layer of Transistor]

The oxide semiconductor layer of one embodiment of the present invention can be used for a semiconductor layer of a transistor, for example.

The oxide semiconductor layer of one embodiment of the present invention has the CAAC structure. In an oxide semiconductor layer having the CAAC structure, metal atoms are arranged in a crystal part in a layered manner in a direction parallel or substantially parallel to the surface on which the oxide semiconductor layer is formed.

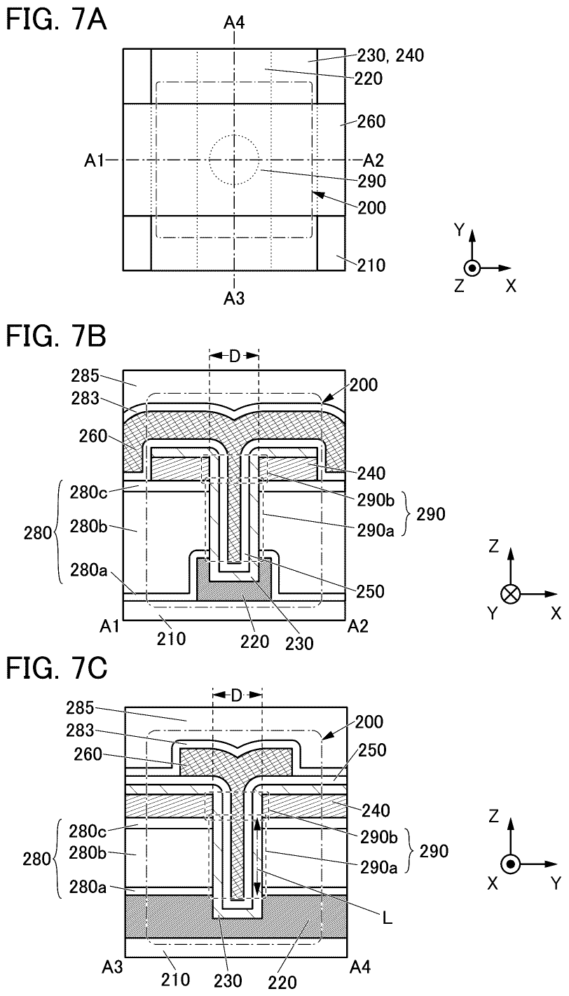

The case where the oxide semiconductor layer of one embodiment of the present invention is used for a semiconductor device described later with reference to FIGS. 7B and 7C and the like is described. In FIGS. 7B and 7C, in the oxide semiconductor layer 230, metal atoms are arranged in a layered manner in a direction parallel to or substantially parallel to a sidewall of the opening portion 290 (the side surface of the insulating layer 280 and the side surface of the conductive layer 240) that is a surface on which the oxide semiconductor layer 230 is formed. This can also be expressed that “the a-b plane of the CAAC structure is provided to be parallel or substantially parallel to the surface”. With such a structure, the a-b plane of the CAAC structure can be provided along a current flow direction in a channel of the transistor 200. Accordingly, the transistor can have a high on-state current.

In the case where the oxide semiconductor layer 230 described with reference to FIG. 1A to FIG. 2D and the like is used as a semiconductor layer of a transistor, the thickness of the oxide semiconductor layer 230 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, and yet still further preferably greater than or equal to 20 nm and less than or equal to 50 nm. In a transistor used for a miniaturized semiconductor device, the thickness of the oxide semiconductor layer 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm. The average thickness of the oxide semiconductor layer 230 in the channel formation region of the transistor is particularly preferably greater than or equal to 2 nm and less than or equal to 15 nm, for example.

The thickness of the oxide semiconductor layer 230b is preferably less than or equal to 200 nm, for example. In the case where the oxide semiconductor layer 230b is in a form of layer, the thickness of the oxide semiconductor layer 230b is preferably, for example, greater than or equal to 1 nm and less than or equal to 200 nm, further preferably greater than or equal to 1 nm and less than or equal to 100 nm, yet further preferably greater than or equal to 2 nm and less than or equal to 100 nm.

Alternatively, when the oxide semiconductor layer 230b can function as a crystal nucleus, the oxide semiconductor layer 230b is not in a form of layer and may be an aggregate of island-shaped regions. For example, such island-shaped regions included in the oxide semiconductor layer 230b are discretely located.

The thickness of each of the oxide semiconductor layers 230a and 230c is preferably greater than or equal to 0.5 nm and less than or equal to 50 nm, further preferably greater than or equal to 0.5 nm and less than or equal to 30 nm, still further preferably greater than or equal to 0.5 nm and less than or equal to 20 nm, yet still further preferably greater than or equal to 1 nm and less than or equal to 50 nm, yet still further preferably greater than or equal to 1 nm and less than or equal to 30 nm, yet still further preferably greater than or equal to 1 nm and less than or equal to 20 nm, and yet still further preferably greater than or equal to 2 nm and less than or equal to 20 nm. The thickness of the oxide semiconductor layer 230a is further preferably greater than or equal to 0.5 nm and less than or equal to 3.0 nm.

An oxide semiconductor layer of one embodiment of the present invention includes a metal oxide.

A metal oxide has a lattice defect in some cases. Examples of the lattice defect include point defects such as an atomic vacancy and an exotic atom, linear defects such as transition, plane defects such as a grain boundary, and volume defects such as a cavity. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide may cause generation, capture, or the like of a carrier. Thus, when a metal oxide with a large number of lattice defects is used for a semiconductor layer of a transistor, the electrical characteristics of the transistor may be unstable. Therefore, a metal oxide used for a semiconductor layer of a transistor preferably has a small number of lattice defects.

The kind of a lattice defect that is likely to be present in a metal oxide and the number of lattice defects vary depending on the structure of the metal oxide, a method for forming the metal oxide, or the like.

Therefore, a metal oxide with high crystallinity is preferably used for a semiconductor layer of a transistor. For example, a metal oxide having a CAAC structure or a metal oxide having a single crystal structure is preferably used. The use of the metal oxide for a transistor enables the transistor to have favorable electrical characteristics. In addition, the transistor can have high reliability.

For the channel formation region of a transistor, a metal oxide that can increase the on-state current of the transistor is preferably used. To increase the on-state current of the transistor, the mobility of the metal oxide used for the transistor is preferably increased. To increase the mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

### [Impurities in Oxide Semiconductor]

The influence of impurities in the oxide semiconductor will be described.

It is preferable that the channel formation region of the transistor including an oxide semiconductor in the semiconductor layer contain less oxygen vacancies or have a lower concentration of impurities such as hydrogen, nitrogen, or a metal element than the source region and the drain region. When oxygen vacancies (V_{O}) and impurities are in a channel formation region of an oxide semiconductor in a transistor, electrical characteristics of the transistor may easily vary and the reliability thereof may worsen. In some cases, hydrogen in the vicinity of oxygen vacancies forms V_{O}H and generates an electron serving as a carrier. Thus, if the channel formation region of the oxide semiconductor includes oxygen vacancies, the transistor tends to have normally-on characteristics. Therefore, V_{O}H in the channel formation region is also preferably reduced. Thus, the channel formation region of the transistor is a high-resistance region having a low carrier concentration. Accordingly, the channel formation region of the transistor can be regarded as an i-type (intrinsic) or substantially i-type region.

In order to obtain stable electrical characteristics of the transistor, reducing the impurity concentration in the oxide semiconductor is effective. Examples of the impurity include hydrogen, carbon, and nitrogen. Note that an impurity in an oxide semiconductor refers to, for example, elements other than the main components of the oxide semiconductor. For example, an element with a concentration of lower than 0.1 atomic % is an impurity.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This may make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region using the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, still further preferably lower than 1×10¹⁸ atoms/cm³, or yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region in a transistor, the transistor can have stable electrical characteristics.

[c-Axis Alignment Proportion]

The oxide semiconductor layer of one embodiment of the present invention has a CAAC structure. The crystallinity degree of the oxide semiconductor layer of one embodiment of the present invention can be evaluated with the use of crystal orientation, for example.

The crystal orientation can be obtained from an FFT pattern obtained by performing FFT processing on a TEM image. Specifically, the directions of the crystal axes can be obtained using an FFT pattern. The FFT pattern obtained by the FFT processing reflects reciprocal lattice space information like an electron diffraction pattern.

When FFT processing is performed on each region in the TEM image of the oxide semiconductor layer, crystal orientation in each region can be obtained. For example, crystal orientation is obtained in each region in a certain area range, so that a map indicating crystal orientation can be formed. Specifically, two spots with high intensity are observed in the FFT pattern of the region including a layered crystal part. The direction of the crystal axis of the region can be obtained from the angle of the line segment connecting the two spots.

In the map showing crystal orientation, the proportion of regions having c-axis alignment is calculated to obtain a c-axis alignment proportion. Here, the region having c-axis alignment represents a region where the orientation is aligned with the c-axis and a region where a difference between the orientation and the c-axis is preferably less than or equal to 20°, further preferably less than or equal to 15°, still further preferably less than or equal to 10°, yet still further preferably less than or equal to 5°. Here, the angle of the c-axis is an angle with respect to a surface on which the oxide semiconductor layer is formed.

In the oxide semiconductor layer of one embodiment of the present invention, the c-axis alignment proportion can be calculated by, for example, cross-sectional or plan-view TEM observation of the oxide semiconductor layer, using the above-described map showing crystal orientation. The region where the FFT is performed (also referred to as an FFT window) can be a circle with a diameter of 1.0 nm, for example. Note that the region where the FFT is performed is not limited to a circle.

In the case where analysis is performed using a cross-sectional TEM image, the cross-sectional TEM image observation range is, for example, a region having a width of 100 nm in the horizontal direction on the assumption that a direction perpendicular to the surface on which the oxide semiconductor layer is formed regarded as the vertical direction. Note that the observation range is not limited to this.

In the oxide semiconductor layer of one embodiment of the present invention, the c-axis alignment proportion is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Here, the c-axis alignment proportion is preferably calculated as the proportion of regions where the orientation is deviated from the c-axis by less than or equal to 20°, for example.

The c-axis alignment proportions of a region formed as the oxide semiconductor layer 230a, a region formed as the oxide semiconductor layer 230b, and a region formed as the oxide semiconductor layer 230c are Rc1, Rc2, and Rc3, respectively. Rc2 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Furthermore, Rc3 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Rc3/Rc1 is preferably greater than one. Furthermore, Rc2/Rc1 is preferably greater than one. Here, the c-axis alignment proportion is preferably calculated as the proportion of regions where the orientation is deviated from the c-axis by less than or equal to 20°, for example.

Note that after the formation of the oxide semiconductor layer 230, the boundaries between the oxide semiconductor layers 230a, 230b, and 230c are not clearly observed in some cases.

The oxide semiconductor layer 230 of one embodiment of the present invention can be divided into three regions: a first region, a second region, and a third region in this order from the top of the layer 229. Each of the regions is a layered region.

The first region, the second region, and the third region each have a CAAC structure. In addition, the c-axis alignment proportion of the third region is preferably higher than that of the first region. The c-axis alignment proportion of the second region is preferably higher than that of the first region. In addition, the c-axis alignment proportion of the third region is 50% or higher, preferably 60% or higher, further preferably 70% or higher, still further preferably 80% or higher, yet still further preferably 90% or higher, yet still further preferably 95% or higher. The c-axis alignment proportion of the second region is 50% or higher, preferably 60% or higher, further preferably 70% or higher, still further preferably 80% or higher, yet still further preferably 90% or higher, yet still further preferably 95% or higher. Here, the c-axis alignment proportion is preferably calculated as the proportion of regions where the orientation is deviated from the c-axis by less than or equal to 20°, for example.

The first region is positioned in a range of 0 nm to 3 nm, both inclusive, from the top surface of the layer 229, and the third region is positioned in a range of 0 nm to 3 nm, both inclusive, from the top surface of the oxide semiconductor layer 230.

Alternatively, the thicknesses of the layers in the regions are substantially equal, for example.

### [Method for Forming Metal Oxide by ALD Method]

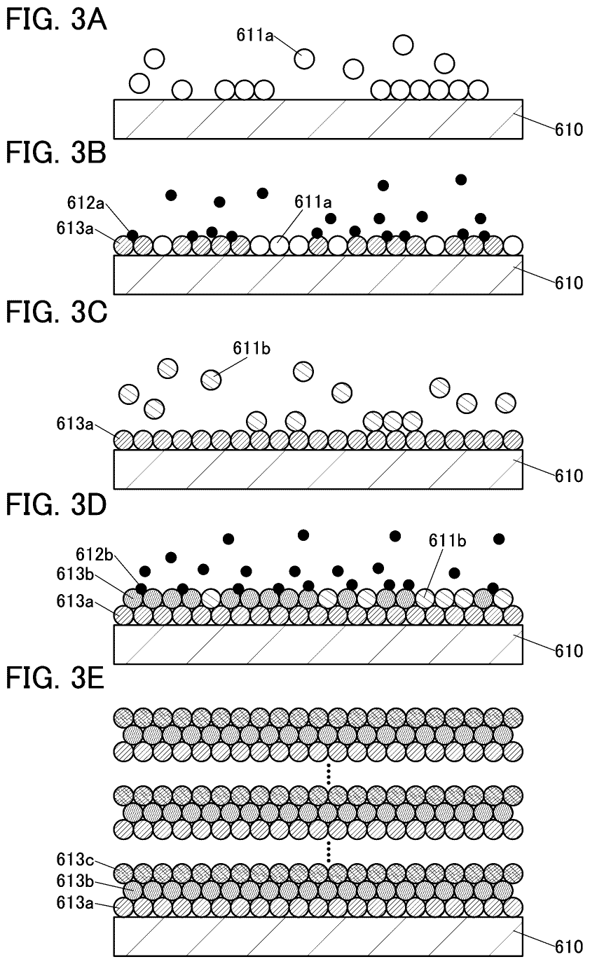

An example of a method employing an ALD method for forming a metal oxide having a layered crystal structure of three layers is described here with reference to FIGS. 3A to 3E. First, a precursor 611a is introduced into a chamber, and the precursor 611a is adsorbed on a surface of a substrate 610 (see FIG. 3A, this step is referred to as a first step in some cases). Here, as illustrated in FIG. 3A, the precursor 611a is adsorbed on the surface of the substrate 610, whereby a self-limiting mechanism of surface chemical reaction works and no more precursor 611a is adsorbed on a layer of the precursor 611a over the substrate 610. Note that the proper range of substrate temperatures at which the self-limiting mechanism of surface chemical reaction works is also referred to as an ALD window. The ALD Window is determined by the temperature characteristics, vapor pressure, decomposition temperature, and the like of a precursor and is set to higher than or equal to 100° C. and lower than or equal to 600° C., preferably higher than or equal to 200° C. and lower than or equal to 400° C., for example, in some cases.

Next, an inert gas (e.g., argon, helium, or nitrogen) or the like is introduced into the chamber, so that excess precursors 611a, a reaction product, and the like are removed from the chamber (hereinafter, the step is referred to as a second step in some cases). Instead of introduction of an inert gas into the chamber, vacuum evacuation can be performed to remove excessive precursors, a reaction product, and the like from the chamber. The second step is also called purge.

Next, a reactant 612a (e.g., an oxidizer (ozone (O₃), oxygen (O₂), water (H₂O), and plasma, a radical, and an ion thereof)) is introduced into the chamber to react with the precursor 611a adsorbed on the surface of the substrate 610, whereby part of components contained in the precursor 611a is released while the component molecules of the precursor 611a are kept adsorbed on the substrate 610 (see FIG. 3B; hereinafter, the step is referred to as a third step in some cases). Consequently, a layer of an oxide 613a, which is formed by oxidation of part of the precursor 611a, is formed over the surface of the substrate 610.

After that, introduction of an inert gas or vacuum evacuation is performed, whereby the excessive reactant 612a, a reaction product, and the like are removed from the chamber (hereinafter, the step is referred to as a fourth step in some cases).

Then, a precursor 611b containing a metal element different from that in the precursor 611a is introduced and a step similar to the first step is performed, so that the precursor 611b is adsorbed on a surface of the layer of the oxide 613a (see FIG. 3C). Here, as illustrated in FIG. 3C, the precursor 611b is adsorbed on the layer of the oxide 613a, whereby a self-limiting mechanism of surface chemical reaction works and no more precursor 611b is adsorbed on a layer of the precursor 611b over the substrate 610.

Next, as in the second step, introduction of an inert gas or vacuum evacuation is performed so that the excess precursor 611b, a reaction product, and the like are removed from the chamber.

Next, as in the third step, the reactant 612b is introduced into the chamber. Here, the reactant 612b that is the same as or different from the reactant 612a may be used (see FIG. 3D). Thus, a layer of the oxide 613b, which is formed by oxidation of part of the precursor 611b, is formed over the layer of the oxide 613a.

After that, as in the fourth step, introduction of an inert gas or vacuum evacuation is performed so that the excess reactant 612b, a reaction product, and the like are removed from the chamber.

Furthermore, the first to fourth steps are performed in a similar manner, whereby a layer of an oxide 613c can be formed over the layer of the oxide 613b. As described above, by performing the steps for forming the oxides 613a to 613c repeatedly, a metal oxide having a layered crystal structure where a stacked-layer structure including the oxides 613a to 613c is repeated can be formed (see FIG. 3E). That is, an oxide layer can be formed through the first to fourth steps, which are regarded as one set, and by repeating the set, a layered crystal structure where a plurality of oxide layers are stacked can be formed.

Note that the thickness of the metal oxide having a layered crystal structure may be greater than or equal to 1 nm and less than 100 nm, preferably greater than or equal to 3 nm and less than 20 nm.

The steps illustrated in FIGS. 3A to 3E are preferably performed while the substrate is heated to form the metal oxide having a layered crystal structure. For example, the substrate temperature may be set higher than or equal to 200° C. and lower than or equal to 600° C., preferably higher than or equal to 300° C. and lower than or equal to the decomposition temperature of the precursor. In the case where deposition is performed by an ALD method with use of different kinds of precursors, the substrate temperature is preferably lower than or equal to the lowest precursor decomposition temperature among the precursors. Accordingly, during deposition by an ALD method, a plurality of kinds of precursors that are used can be adsorbed on an object (e.g., a substrate) without being decomposed.

By performing the deposition while the substrate is heated within such a temperature range, an impurity such as hydrogen or carbon contained in the precursor, the reactant, and the like can be removed from the metal oxide in each of the first to fourth steps. For example, carbon in the metal oxide can be released as CO₂ and CO, and hydrogen in the metal oxide can be released as H₂O. Furthermore, metal atoms and oxygen atoms are rearranged concurrently with removal of the impurity, so that layers of oxides can be arranged orderly. Thus, a metal oxide having a layered crystal structure with high crystallinity can be formed.

In order to perform deposition while the substrate is heated within the above temperature range, the decomposition temperature of the precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, a precursor formed of an inorganic material (hereinafter, referred to as an inorganic precursor) is preferably used. In general, an inorganic precursor tends to have a higher decomposition temperature than a precursor formed of an organic material (hereinafter, referred to as an organic precursor); thus, some inorganic precursors have the ALD Window in the above temperature range. Moreover, an inorganic precursor does not contain an impurity such as hydrogen or carbon, which can prevent an increase in the concentration of an impurity such as hydrogen or carbon in a metal oxide to be deposited.

After the metal oxide film is formed, heat treatment is preferably performed. In particular, the heat treatment is preferably performed without exposure to the air successively after the deposition by an ALD method. The heat treatment can be performed under the conditions described with reference to FIGS. 1A to 1D, for example.

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which improves crystallinity. Thus, a metal oxide having a layered crystal structure with high crystallinity can be formed.

After the deposition of the metal oxide, microwave treatment is preferably performed in an oxygen-containing atmosphere so that the impurity concentration in the metal oxide can be reduced. Specific examples of the impurity include hydrogen and carbon. Although the microwave treatment in an oxygen-containing atmosphere is performed on the metal oxide in the above example, one embodiment of the present invention is not limited thereto. For example, the microwave treatment in an oxygen-containing atmosphere may be performed on an insulating film, more specifically a silicon oxide film, which is positioned in the vicinity of the metal oxide.

Note that FIGS. 3A to 3E illustrate the structure where the stacked-layer structure including the oxides 613a to 613c is repeated; however, the present invention is not limited to the structure. For example, a single layer, two layers, or four or more layers of an oxide may be repeatedly formed in a metal oxide.

In the following description of this specification and the like, in the case of using ozone, oxygen, and water as a reactant or an oxidizer, they include not only those in gas or molecular states but also those in a plasma, radical, and ion states, unless otherwise specified. In the case where a film is formed using an oxidizer in a plasma state, a radical state, or an ion state, a plasma ALD apparatus, which will be described later, is used.

In order to remove an impurity such as carbon or hydrogen contained in a precursor, the precursor is preferably made to react with an oxidizer sufficiently. For example, pulse time for introducing an oxidizer may be elongated. Alternatively, an oxidizer may be introduced a plurality of times. In the case where an oxidizer is introduced a plurality of times, the same kind of oxidizer may be introduced or different kinds of oxidizers may be introduced. For example, water may be introduced as a first oxidizer into a chamber, vacuum evacuation may be performed, ozone or oxygen that does not contain hydrogen may be introduced as a second oxidizer into the chamber, and vacuum evacuation may be performed.

As described above, the introduction of an oxidizer and the introduction of an inert gas (or vacuum evacuation) in the chamber are repeated a plurality of times in a short time, whereby excess hydrogen atoms, carbon atoms, chlorine atoms, and the like can be more certainly removed from the precursor adsorbed on the substrate surface and eliminated from the chamber. In the case where two kinds of oxidizers are introduced, more excess hydrogen atoms and the like can be removed from the precursor adsorbed on the substrate surface. In this manner, hydrogen atoms are prevented from entering the film during the deposition, so that the amounts of water, hydrogen, and the like in the formed film can be reduced.

In an ALD method, a film is formed through reaction between a precursor and a reactant using thermal energy. A temperature required for the reaction between the precursor and the reactant is determined by the temperature characteristics, vapor pressure, decomposition temperature, and the like thereof and is set to higher than or equal to 100° C. and lower than or equal to 600° C., preferably higher than or equal to 200° C. and lower than or equal to 600° C., further preferably higher than or equal to 300° C. and lower than or equal to 600° C.

Moreover, an ALD method in which deposition is performed by introducing a plasma-excited reactant into the chamber as a third source gas in addition to the reaction between the precursor and the reactant is referred to as a plasma ALD method in some cases. In this case, a plasma generation apparatus is provided in the introduction portion of the third source gas. Inductively coupled plasma (ICP) can be used for plasma generation. An ALD method in which reaction between the precursor and the reactant is performed using thermal energy is sometimes called a thermal ALD method.

In a plasma ALD method, deposition is performed by introducing a plasma-excited reactant in the third step. Alternatively, deposition is performed as follows: the first to fourth steps are repeated while a plasma-excited reactant (a second reactant) is introduced, in which case the reactant introduced in the third step is referred to as a first reactant. In the plasma ALD method, a material similar to the above-described oxidizer can be used for the second reactant used as the third source gas. In other words, plasma-excited ozone, oxygen, and water can be used as the second reactant. Other than oxidizer, a nitriding agent may be used as the second reactant. As the nitriding agent, nitrogen (N₂) or ammonia (NH₃) can be used. A mixed gas of nitrogen (N₂) and hydrogen (H₂) can also be used as the nitriding agent. For example, a mixed gas of nitrogen (N₂) of 5% and hydrogen (H₂) of 95% can be used as the nitriding agent. Deposition is performed while plasma-excited nitrogen or ammonia is introduced, whereby a nitride film such as a metal nitride film can be formed.

Argon (Ar), helium (He), or nitrogen (N₂) may be used as a carrier gas for the second reactant. The use of a carrier gas such as argon, helium, or nitrogen is preferable because plasma is easily discharged and the plasma-excited second reactant is easily generated. Note that in the case where an oxide film such as a metal oxide film is formed by a plasma ALD method and nitrogen is used as a carrier gas, nitrogen enters the film and a desired film quality cannot be obtained in some cases. In this case, argon or helium is preferably used as the carrier gas.

With the ALD method, an extremely thin film with a uniform thickness can be formed. In addition, the coverage of an uneven surface with the film is high.

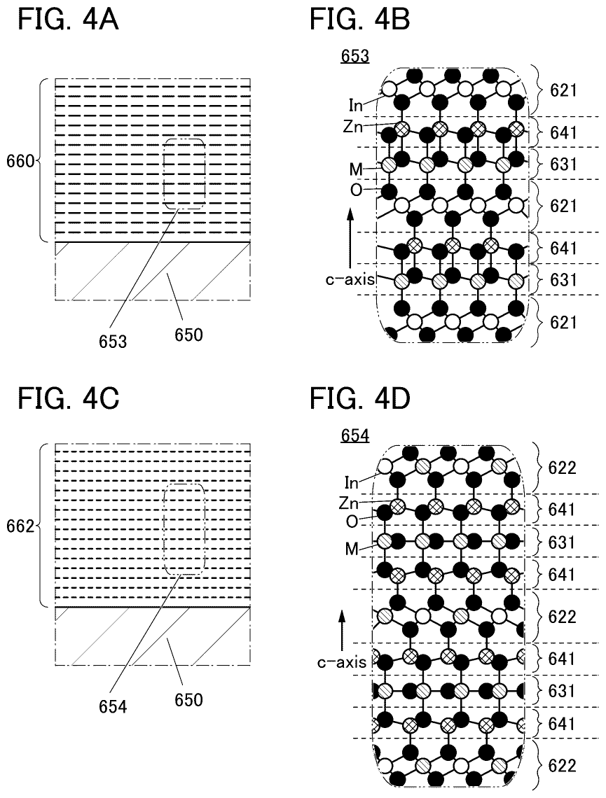

Here, atomic arrangement in the crystal when the metal oxide having a layered crystal structure is an In-M-Zn oxide is described with reference to FIGS. 4A to 4D. In FIGS. 4B and 4D, an atom is represented by a sphere (a circle) and a bond between a metal atom and an oxygen atom is represented by a line. In FIGS. 4B and 4D, the c-axis direction in the crystal structure of the In-M-Zn oxide is indicated by arrows in the drawings. The a-b plane direction in the crystal structure of the In-M-Zn oxide is the direction perpendicular to the c-axis direction indicated by the arrows in FIGS. 4B and 4D.

FIG. 4A illustrates an oxide 660 including an In-M-Zn oxide formed over a structure body 650. Here, the structure body refers to a component included in a semiconductor device such as a transistor. The structure body 650 includes a substrate, conductors such as a gate electrode, a source electrode, and a drain electrode, an insulator such as a gate insulating film, an interlayer insulating film, and a base insulating film, a semiconductor such as a metal oxide or silicon, and the like. In FIG. 4A, a formation surface of the structure body 650 is positioned parallel to a substrate (or a base not illustrated in the drawing).

FIG. 4B is an enlarged view illustrating the atomic arrangement in the crystal in a region 653, which is part of the oxide 660 in FIG. 4A. Note that the oxide 660 illustrated in FIGS. 4A and 4B has a composition of In:M:Zn=1:1:1 [atomic ratio] and a YbFe₂O₄ crystal structure. The element M is a metal element having a valence of +3.

As illustrated in FIG. 4B, the crystal included in the oxide 660 has repetitive stacking of a layer 621 containing indium (In) and oxygen, a layer 631 containing the element M and oxygen, and a layer 641 containing zinc (Zn) and oxygen in this order. The layers 621, 631, and 641 are placed in parallel or substantially in parallel with the formation surface of the structure body 650. That is, the a-b plane of the oxide 660 is substantially parallel to the formation surface of the structure body 650, and the c-axis of the oxide 660 is substantially parallel to the normal direction of the formation surface of the structure body 650.

When the layers 621, 631, and 641 included in the above crystal are each composed of one metal element and oxygen as illustrated in FIG. 4B, arrangement with favorable crystallinity is achieved to increase the mobility of the metal oxide.

Note that the In-M-Zn oxide with an atomic ratio of In:M:Zn=1:1:1 is not limited to having the structure illustrated in FIG. 4B. The stacking order of the layers 621, 631, and 641 may be changed. For example, the layers may be stacked repeatedly in the order of the layers 621, 641, and 631. Alternatively, the layers may be stacked repeatedly in the order of the layers 621, 631, 641, 621, 641, and 631. Part of the element M in the layer 631 may be replaced with zinc and part of zinc in the layer 641 may be replaced with the element M.

Although an example of forming the In-M-Zn oxide with an atomic ratio of In:M:Zn=1:1:1 is described above, a crystalline In-M-Zn oxide whose composition formula is represented by In_{(1+α)}M_{(1-α)}O₃(ZnO)ₘ (α is a real number greater than 0 and less than 1 and m is a positive number) can have a layered crystal structure in a similar manner. As an example, an In-M-Zn oxide with an atomic ratio of In:M:Zn=1:3:4 is described with reference to FIGS. 4C and 4D.

FIG. 4C illustrates an oxide 662 including an In-M-Zn oxide formed over the structure body 650. FIG. 4D is an enlarged view illustrating the atomic arrangement in the crystal in a region 654, which is part of the oxide 662 in FIG. 4C.

As illustrated in FIG. 4D, the crystal included in the oxide 662 includes a layer 622 containing indium (In), the element M, and oxygen, the layer 641 containing zinc (Zn) and oxygen, and the layer 631 containing the element M and oxygen. In the oxide 662, the plurality of layers are stacked repeatedly in the order of the layers 622, 641, 631, and 641. The layers 622, 631, and 641 are placed substantially in parallel with the formation surface of the structure body 650. That is, the a-b plane of the oxide 662 is substantially parallel to the formation surface of the structure body 650, and the c-axis of the oxide 662 is substantially parallel to the normal direction of the formation surface of the structure body 650.

Note that the In-M-Zn oxide with an atomic ratio of In:M:Zn=1:3:4 is not limited to having the structure illustrated in FIG. 4D, and the structure may change within a range where the atomic ratio of In:M:Zn=1:3:4 is maintained. For example, the stacking order of the layers 622, 631, and 641 may be changed. Part of the element M in the layer 631 may be replaced with zinc and part of zinc in the layer 641 may be replaced with the element M. The layer 621 or the layer 631 may be formed instead of the layer 622.

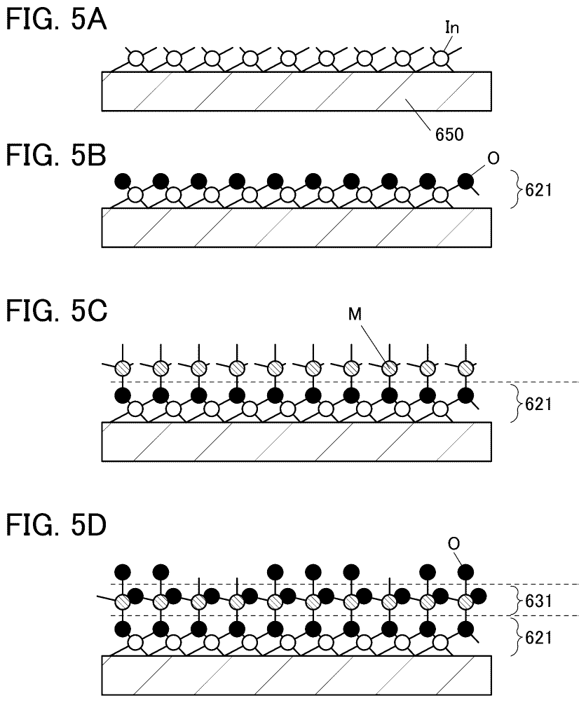

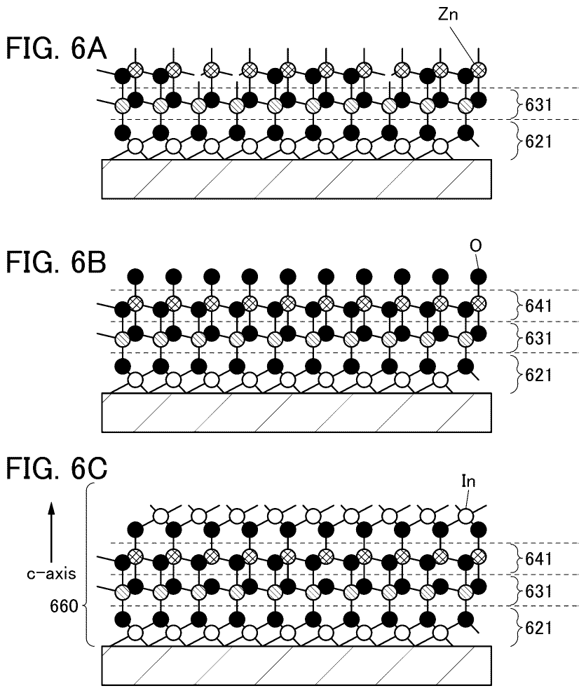

Next, details of a method for forming the oxide 660 including the In-M-Zn oxide illustrated in FIGS. 4A and 4B are described with reference to FIGS. 5A to 5D and FIGS. 6A to 6C.

First, a source gas containing a precursor containing indium is introduced into a chamber so that the precursor is adsorbed on the surface of the structure body 650 (see FIG. 5A). Here, the source gas contains a carrier gas such as argon, helium, or nitrogen in addition to the precursor. As the precursor containing indium, trimethylindium, triethylindium, tris(2,2,6,6-tetramethyl-3,5-heptanedionato)indium, cyclopentadienylindium, indium(III) acetylacetonate, (3-(dimethylamino)propyl)dimethylindium, or the like can be used.

As the precursor containing indium, an inorganic precursor not containing hydrocarbon may be used. As the inorganic precursor containing indium, a halogen-based indium compound such as indium trichloride, indium tribromide, or indium triiodide can be used. The decomposition temperature of indium trichloride is approximately 500° C. to 700° C. Thus, with use of indium trichloride, deposition can be performed by an ALD method while a substrate is being heated at approximately 400° C. to 600° C., for example, at 500° C.

Next, introduction of the source gas is stopped and the chamber is purged so that an excess precursor, a reaction product, and the like are removed from the chamber.

Then, an oxidizer is introduced as a reactant into the chamber to react with the adsorbed precursor, and components other than indium are released while indium is adsorbed on the substrate, whereby the layer 621 in which indium and oxygen are bonded to each other is formed (see FIG. 5B). Ozone, oxygen, water, or the like can be used as the oxidizer. After that, introduction of the oxidizer is stopped and the chamber is purged so that an excess reactant, a reaction product, and the like are removed from the chamber.

Subsequently, a source gas containing a precursor containing the element M is introduced into the chamber so that the precursor is adsorbed on the layer 621 (see FIG. 5C). Here, the source gas contains a carrier gas such as argon, helium, or nitrogen in addition to the precursor. When gallium is used as the element M, as the precursor containing gallium, trimethylgallium, triethylgallium, tris(dimethylamide)gallium(III), gallium(III) acetylacetonate, tris(2,2,6,6-tetramethyl-3,5-heptanedionato)gallium, dimethylchlorogallium, diethylchlorogallium, dimethylgallium isopropoxide, or the like can be used.

As the precursor containing gallium, an inorganic precursor not containing hydrocarbon may be used. As the inorganic precursor containing gallium, a halogen-based gallium compound such as gallium trichloride, gallium tribromide, or gallium triiodide can be used. The decomposition temperature of gallium trichloride is approximately 550° C. to 700° C. Thus, with use of gallium trichloride, deposition can be performed by an ALD method while a substrate is being heated at approximately 450° C. to 650° C., for example, at 550° C.

Next, introduction of the source gas is stopped and the chamber is purged so that an excess precursor, a reaction product, and the like are removed from the chamber.

Then, an oxidizer is introduced as a reactant into the chamber to react with the adsorbed precursor, and components other than the element M are released while the element M is adsorbed on the substrate, whereby the layer 631 in which the element M and oxygen are bonded to each other is formed (see FIG. 5D). At this time, part of oxygen contained in the layer 641 is adsorbed on the layer 631 in some cases. After that, introduction of the oxidizer is stopped and the chamber is purged so that an excess reactant, a reaction product, and the like are removed from the chamber.

Subsequently, a source gas containing a precursor containing zinc is introduced into the chamber so that the precursor is adsorbed on the layer 631 (see FIG. 6A). At this time, part of the layer 641 in which zinc is bonded to oxygen is formed in some cases. Here, the source gas contains a carrier gas such as argon, helium, or nitrogen in addition to the precursor. As the precursor containing zinc, dimethylzinc, diethylzinc, bis(2,2,6,6-tetramethyl-3,5-heptanedionato)zinc, zinc acetate, or the like can be used.

As the precursor containing zinc, an inorganic precursor not containing hydrocarbon may be used. As the precursor containing zinc, a halogen-based zinc compound such as zinc dichloride, zinc dibromide, or zinc diiodide can be used. The decomposition temperature of zinc dichloride is approximately 450° C. to 700° C. Thus, with use of zinc dichloride, deposition can be performed by an ALD method while a substrate is being heated at approximately 350° C. to 550° C., for example, at 450° C.

Next, introduction of the source gas is stopped and the chamber is purged so that an excess precursor, a reaction product, and the like are removed from the chamber.

Then, an oxidizer is introduced as a reactant into the chamber to react with the adsorbed precursor, and components other than zinc are released while zinc is adsorbed on the substrate, whereby the layer 641 in which zinc and oxygen are bonded to each other is formed (see FIG. 6B). After that, introduction of the oxidizer is stopped and the chamber is purged so that an excess reactant, a reaction product, and the like are removed from the chamber.

Next, the layer 621 is formed again over the layer 641 by the above-described method (see FIG. 6C). By repeating the above-described method, the oxide 660 can be formed over the substrate or the structure body.

Some of the above-described precursors containing the metal elements further contain one or both of carbon and chlorine. A film formed using a precursor containing carbon may contain carbon. A film formed using a precursor containing halogen such as chlorine may contain halogen such as chlorine.

As described above, the oxide 660 is formed by an ALD method, whereby the metal oxide in which the c-axis is aligned substantially parallel to the normal direction of the formation surface can be obtained. For example, in the oxide semiconductor layer 230 illustrated in FIGS. 7B and 7C and the like to be described later, a layered crystal substantially parallel to the sidewall of the opening portion 290, in particular, the side surface of the insulating layer 280, can be formed. With this structure, the layered crystals of the oxide semiconductor layer 230 are formed substantially in parallel with the channel length direction of the transistor 200, so that the on-state current of the transistor can be increased.

The steps illustrated in FIGS. 5A to 5D and FIGS. 6A to 6C are preferably performed while the substrate is being heated. For example, the substrate temperature may be set higher than or equal to 200° C. and lower than or equal to 600° C., preferably higher than or equal to 300° C. and lower than or equal to the decomposition temperature of the precursor.

In order to perform deposition while the substrate is heated within the above temperature range, the decomposition temperature of a precursor used for the deposition is preferably high. For example, the precursor decomposition temperature is preferably higher than or equal to 200° C. and lower than or equal to 700° C., further preferably higher than or equal to 300° C. and lower than or equal to 600° C. As such a precursor having a high decomposition temperature, an inorganic precursor is preferably used. In general, an inorganic precursor tends to have a higher decomposition temperature than an organic precursor. Thus, even when deposition is performed while the substrate is being heated as described above, the precursor is hardly decomposed.

As the inorganic precursor, for example, indium trichloride, gallium trichloride, or zinc dichloride described above can be used. As described above, the decomposition temperature of each of these precursors is approximately 350° C. to 700° C., which is much higher than the decomposition temperature of a common organic precursor. Note that as described above, the decomposition temperatures of indium trichloride, gallium trichloride, and zinc dichloride are different from each other. In the case where deposition is performed by an ALD method with use of different kinds of precursors, the substrate temperature is preferably lower than or equal to the lowest precursor decomposition temperature among the precursors. In the above example, the substrate temperature may be set within a range where zinc dichloride having the lowest precursor decomposition temperature is not decomposed. Accordingly, indium trichloride and gallium trichloride can also be adsorbed on an object (e.g., a substrate) without being decomposed.

Note that FIGS. 5A to 5D and FIGS. 6A to 6C illustrate an example where the layer 621 is formed as a layer containing indium, the layer 631 is formed thereover as a layer containing the element M, and further the layer 641 is formed thereover as a layer containing zinc; however, this embodiment is not limited to the example. One of the layers 631 and 641 may be formed, the layer 621 may be formed thereover, and further the other of the layers 631 and 641 may be formed thereover. Alternatively, one of the layers 631 and 641 may be formed, the other of the layers 631 and 641 may be formed thereover, and further the layer 621 may be formed thereover.

In the case of forming a metal oxide with an atomic ratio that is different from In:M:Zn=1:1:1, the layers 621, 631, and 641 may be formed as appropriate in accordance with the atomic ratio. For example, the formation of the layer 641 is repeated a plurality of times before and after the formation of the layer 631 illustrated in FIG. 6A so that a stack including the layer 631 and the layers 641 and having the desired number of atoms and layers and a desired thickness is formed between two layers 621.

This embodiment can be combined with any of the other embodiments and examples as appropriate. In this specification, in the case where a plurality of structure examples are shown in one embodiment, the structure examples can be combined as appropriate.

### Embodiment 2

In this embodiment, a semiconductor device of one embodiment of the present invention is described.

The semiconductor device of one embodiment of the present invention includes a first conductive layer, a second conductive layer, a third conductive layer, an oxide semiconductor layer, a first insulating layer, and a second insulating layer.

The first insulating layer is positioned over the first conductive layer, and the second conductive layer is positioned over the first insulating layer. The first insulating layer and the second conductive layer include an opening portion reaching the first conductive layer. The oxide semiconductor layer is in contact with at least a top surface of the first conductive layer, a side surface of the first insulating layer, and a side surface of the second conductive layer in the opening portion. The second insulating layer is positioned over the oxide semiconductor layer in the opening portion. The third conductive layer overlaps with the oxide semiconductor layer with the second insulating layer positioned therebetween in the opening portion. Note that the opening portion is also referred to as an opening.

The first conductive layer functions as one of a source electrode and a drain electrode of a transistor. The second conductive layer functions as the other of the source electrode and the drain electrode of the transistor. The third conductive layer functions as a gate electrode of the transistor, and the second insulating layer functions as a gate insulating layer.

Note that in this specification and the like, a simple expression “in a cross-sectional view” is replaced with a specific expression “in a cross-sectional view from the same direction” in some cases. For example, in the case where the relation between a plurality of components is described, a relation in a cross-sectional view from the same direction is described. In this case, the relation between the plurality of components can be described using one cross-sectional view.

In the transistor of one embodiment of the present invention, the source electrode and the drain electrode are positioned at different heights, so that a current flows in the semiconductor layer in the height direction. In other words, the channel length direction includes a height (vertical) component, so that the transistor of one embodiment of the present invention can also be referred to as a vertical field effect transistor (VFET), a vertical transistor, a vertical-channel transistor, or the like.

In the transistor of one embodiment of the present invention, the source electrode, the semiconductor layer, and the drain electrode can be provided to overlap with each other. Thus, the area occupied by the transistor can be significantly smaller than the area occupied by what is called a planar transistor in which a planar semiconductor layer is provided.

In this specification and the like, the expression “an end portion is aligned with another end portion” means that at least outlines of stacked layers partly overlap with each other in a plan view. For example, the case of processing or partly processing an upper layer and a lower layer with the use of the same mask pattern is included. The expression “an end portion is aligned with another end portion” also includes the case where the outlines do not completely overlap with each other; for instance, the outline of the upper layer may be positioned inside or outside the outline of the lower layer.

In general, it is sometimes difficult to clearly differentiate “completely aligned” from “substantially aligned”. Thus, in this specification and the like, the expression “aligned” includes both “completely aligned” and “substantially aligned”, in some cases.

### <Structure Example of Semiconductor Device>

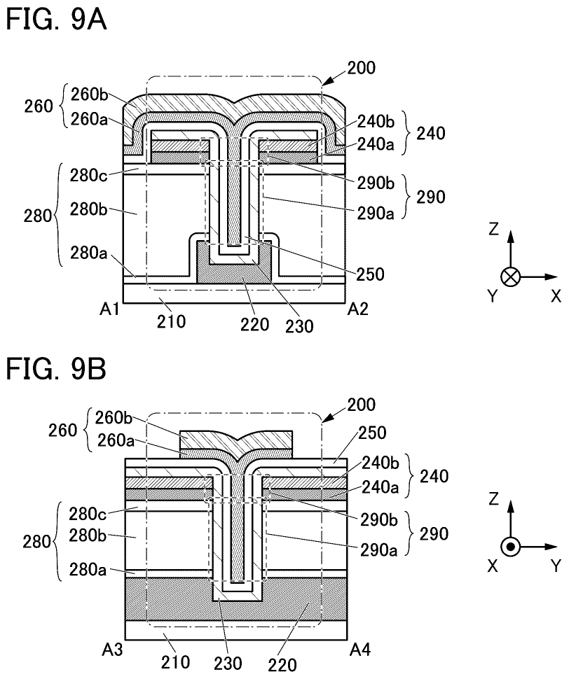

Structures of the semiconductor device of one embodiment of the present invention are described with reference to FIGS. 7A to 7C, FIG. 8, FIGS. 9A and 9B, FIGS. 10A to 10C, FIGS. 11A and 11B, FIGS. 12A and 12B, FIGS. 13A to 13C, and FIGS. 14A to 14C. FIG. 7A is a plan view of the semiconductor device including a transistor 200. FIG. 7B is a cross-sectional view taken along a dashed-dotted line A1-A2 in FIG. 7A. FIG. 7C is a cross-sectional view taken along a dashed-dotted line A3-A4 in FIG. 7A. FIG. 9A is a cross-sectional view along the XY plane including an insulating layer 280. Note that for simplification, some components are not illustrated in the plan view of FIG. 7A. Some components may be omitted also in the following plan views.

The semiconductor device illustrated in FIGS. 7A to 7C and FIG. 9A includes an insulating layer 210 over a substrate (not illustrated), the transistor 200 over the insulating layer 210, the insulating layer 280 over the insulating layer 210, and an insulating layer 283 and an insulating layer 285 over the transistor 200. The insulating layer 210, the insulating layer 280, the insulating layer 283, and the insulating layer 285 function as interlayer films.

The transistor 200 includes a conductive layer 220, a conductive layer 240 over the insulating layer 280, an oxide semiconductor layer 230, an insulating layer 250 over the oxide semiconductor layer 230, and a conductive layer 260 over the insulating layer 250. The conductive layer 220 and the conductive layer 240 are positioned at different heights.

In the transistor 200, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode.

A region of the oxide semiconductor layer 230 that is in contact with the conductive layer 220 and the conductive layer 240 preferably functions as a low-resistance region.

As illustrated in FIGS. 7B and 7C, the opening portion 290 reaching the conductive layer 220 is provided in the insulating layer 280 and the conductive layer 240. Furthermore, a depressed portion overlapping with the opening portion 290 is provided in the conductive layer 220. The opening portion 290 and the depressed portion of the conductive layer 220 form a continuous opening portion. The bottom of the continuous opening portion serves as the top surface of the conductive layer 220.

A sidewall of the opening portion 290 is a side surface of the insulating layer 280 and a side surface of the conductive layer 240. The opening portion 290 includes an opening portion of the insulating layer 280 and an opening portion of the conductive layer 240. In other words, the opening portion of the insulating layer 280 in a region overlapping with the conductive layer 220 is part of the opening portion 290, and the opening portion of the conductive layer 240 in a region overlapping with the conductive layer 220 is another part of the opening portion 290. Note that the part of the opening portion 290 provided in the insulating layer 280 is referred to as an opening portion 290a, and the part of the opening portion 290 provided in the conductive layer 240 is referred to as an opening portion 290b.

At least part of the components of the transistor 200 is provided inside the opening portion 290. Specifically, at least part of each of the oxide semiconductor layer 230, the insulating layer 250, and the conductive layer 260 is positioned inside the opening portion 290. The oxide semiconductor layer 230 is in contact with the top surface of the conductive layer 220, the side surface of the insulating layer 280, and the side surface of the conductive layer 240 in the opening portion 290.

The insulating layer 280 includes an insulating layer 280a, an insulating layer 280b over the insulating layer 280a, and an insulating layer 280c over the insulating layer 280b. The insulating layer 280a includes a region in contact with the top surface of the insulating layer 210, a region in contact with a side surface of the conductive layer 220, and a region in contact with the top surface of the conductive layer 220. The insulating layer 280c includes a region in contact with the bottom surface of the conductive layer 240.

The oxide semiconductor layer 230 is provided inside the opening portion 290 of the insulating layer 280. The transistor 200 has a structure in which a current flows in the vertical direction since one of a source electrode and a drain electrode (here, the conductive layer 220) is positioned below and the other of the source electrode and the drain electrode (here, the conductive layer 240) is positioned above. That is, a channel is formed along the sidewall of the opening portion 290a.

The oxide semiconductor layer 230 is in contact with the top surface of the conductive layer 220 and the side surface of the conductive layer 240 inside the opening portion 290. The oxide semiconductor layer 230 is also in contact with part of the top surface of the conductive layer 240. When the oxide semiconductor layer 230 is in contact with not only the side surface of the conductive layer 240 but also the top surface of the conductive layer 240 in this manner, the area where the oxide semiconductor layer 230 and the conductive layer 240 are in contact with each other can be increased as compared with the case where the oxide semiconductor layer 230 is not in contact with the top surface of the conductive layer 240 but in contact with the side surface of the conductive layer 240, for example. Thus, the contact resistance between the oxide semiconductor layer 230 and the conductive layer 240 can be reduced.

The conductive layer 240 includes the opening portion 290b in a region overlapping with the conductive layer 220. Furthermore, it is preferable that the conductive layer 240 not be provided inside the opening portion 290a of the insulating layer 280. That is, it is preferable that the conductive layer 240 not include a region in contact with the side surface of the insulating layer 280 in the opening portion 290a. With such a structure, the opening portion 290b of the conductive layer 240 and the opening portion 290a of the insulating layer 280 can be collectively formed. When the side surface of the conductive layer 240 in the opening portion 290b is aligned or substantially aligned with the side surface of the insulating layer 280 in the opening portion 290a, the thickness distribution of the oxide semiconductor layer 230 provided inside the opening portion 290 can be uniform. In addition, the oxide semiconductor layer 230 can be inhibited from being divided by a step between the conductive layer 240 and the insulating layer 280.

FIG. 9A is a cross-sectional view taken along the dashed-dotted line A1-A2 in FIG. 7A, and is a modification example of FIG. 7B. FIG. 9B is a cross-sectional view taken along the dashed-dotted line A3-A4 in FIG. 7A, and is a modification example of FIG. 7C. The conductive layer 240 illustrated in FIGS. 9A and 9B has a stacked-layer structure of a conductive layer 240a and a conductive layer 240b over the conductive layer 240a. The conductive layer 240 may have a single-layer structure or a stacked-layer structure of three or more layers. The details of the conductive layer 240a and the conductive layer 240b will be described later. Although the insulating layer 283 and the insulating layer 285 are not illustrated in FIGS. 9A and 9B and the subsequent drawings in some cases, the insulating layer 283 and the insulating layer 285 are preferably provided over the transistor 200.

The conductive layer 260 illustrated in FIGS. 9A and 9B has a stacked-layer structure of a conductive layer 260a and a conductive layer 260b over the conductive layer 260a. The conductive layer 260a is preferably formed by a film formation method that provides good coverage. Furthermore, when the thickness of the conductive layer 260a is reduced, coverage on the sidewall of the opening portion 290 can be further increased. The conductive layer 260b can have a larger thickness than the conductive layer 260a. When the thickness of the conductive layer is increased, the resistance of the conductive layer can be reduced. The conductive layer 240 may have a single-layer structure or a stacked-layer structure of three or more layers. The details of the conductive layer 260a and the conductive layer 260b will be described later.

The width of the opening portion 290 is referred to as a width D. The width D varies in the depth direction, in some cases. For example, the width D can be the width of an upper end of the opening portion 290 of the insulating layer 280. Alternatively, the width D can be the width of a lower end of the opening portion 290 of the insulating layer 280. Alternatively, the width D can be the width at half of the depth of the opening portion 290 in the insulating layer 280. Alternatively, the width of the opening portion 290 in the conductive layer 240 can be used.

Portions which are of the oxide semiconductor layer 230 and the insulating layer 250 and positioned inside the opening portion 290 reflect the shape of the opening portion 290. Specifically, the oxide semiconductor layer 230 is provided to cover the bottom and the sidewall of the opening portion 290, and the insulating layer 250 is provided to cover the oxide semiconductor layer 230. The oxide semiconductor layer 230 is preferably provided in contact with the sidewall of the insulating layer 280 in the opening portion 290a. The insulating layer 250 is positioned to face the sidewall of the insulating layer 280 in the opening portion 290a with the oxide semiconductor layer 230 therebetween.

The conductive layer 260 is provided to fill a depressed portion of the insulating layer 250 that reflects the shape of the opening portion 290. When the width D is small, the transistor 200 can be miniaturized, whereas when the width D is small and the aspect ratio of the opening portion 290 is high, only a part of the stacked-layer structure of the conductive layer 260 is positioned inside the opening portion 290 in some cases depending on a formation method, a thickness, or the like of the components placed inside the opening portion. Here, an example in which the conductive layer 260a is positioned inside the opening portion 290 and the conductive layer 260b is not positioned inside the opening portion 290 is described. The conductive layer 260a is preferably formed by a method that provides high coverage.

The sidewall of the opening portion 290 preferably has an angle perpendicular or substantially perpendicular to the top surface of the conductive layer 220. Such a structure of the opening portion 290 can reduce the area occupied by the transistor 200. Thus, the semiconductor device can be miniaturized.

The films provided inside the opening portion 290 can be formed by an atomic layer deposition (ALD) method, a sputtering method, a chemical vapor deposition (CVD) method, a vacuum evaporation method, a pulsed laser deposition (PLD) method, or the like.

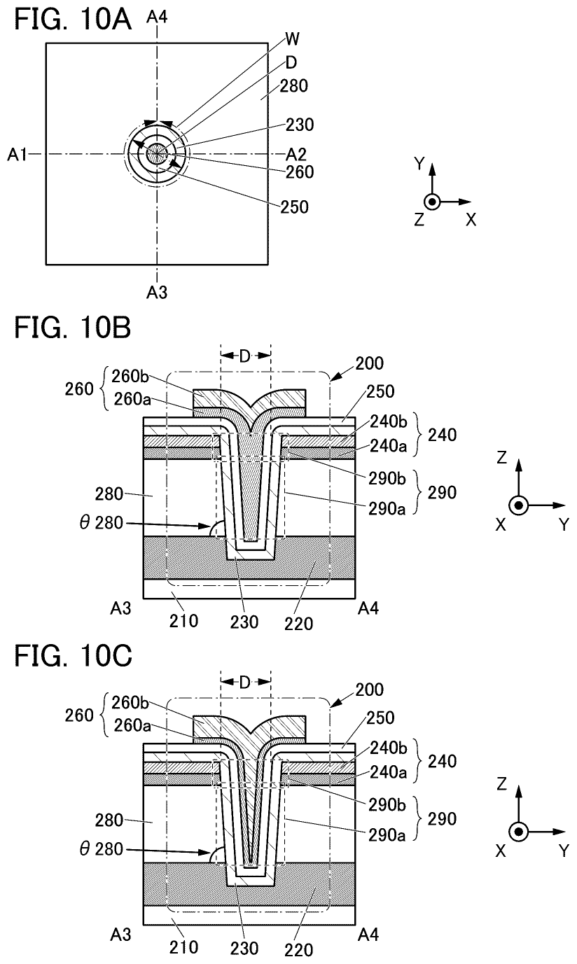

The structure illustrated in FIG. 10B is an example in which the sidewall of the opening portion 290 has a tapered shape as compared with the structure in FIG. 7B. The angle 6280 formed between the top surface of the conductive layer 220 (or the top surface of the insulating layer 210) and the sidewall of the insulating layer 280 in the opening portion 290 is preferably 90° or approximately 90°. For example, the angle θ280 is preferably greater than or equal to 75° and less than or equal to 90°.

The angle θ280 is sometimes less than 75°, less than 70°, less than 65°, or less than 60°. When the sidewall of the opening portion 290 has a tapered shape, the oxide semiconductor layer 230 and the insulating layer 250 can be formed with good coverage.

In particular, in the case where the sidewall of the opening portion 290 has a tapered shape, the coverage on the sidewall of the opening portion 290 can be increased. Thus, as illustrated in FIG. 10C, not only the conductive layer 260a having a small thickness but also the conductive layer 260b having a large thickness is provided in the opening portion 290 in some cases.

The opening portion 290 may have a tapered shape only at the upper end. In such a case, at least part of the sidewall of the region having the tapered shape can be covered with the conductive layer 260b, for example. The opening portion 290 preferably includes a region which is positioned deeper than the above-mentioned region having a tapered shape and which has a steeper sidewall than the upper end. When the opening portion 290 has such a shape, for example, the contact area with the conductive layer 240 is increased in the tapered region, so that the contact resistance between the oxide semiconductor layer 230 and the conductive layer 240 can be reduced. Furthermore, when the insulating layer 280 partly has a tapered shape, for example, the region may function as a region that relieves electric field between the conductive layer 240 and the conductive layer 260.

It is preferable that the insulating layer 250 favorably cover the sidewall of the opening portion 290 and inhibit a short circuit between the conductive layer 240 and the conductive layer 260.

The insulating layer 250 functions as a gate insulating layer of the transistor 200. When the gate insulating layer is thin, a gate potential applied during the operation of the transistor 200 can be reduced. In addition, the transistor 200 can operate at high speed.

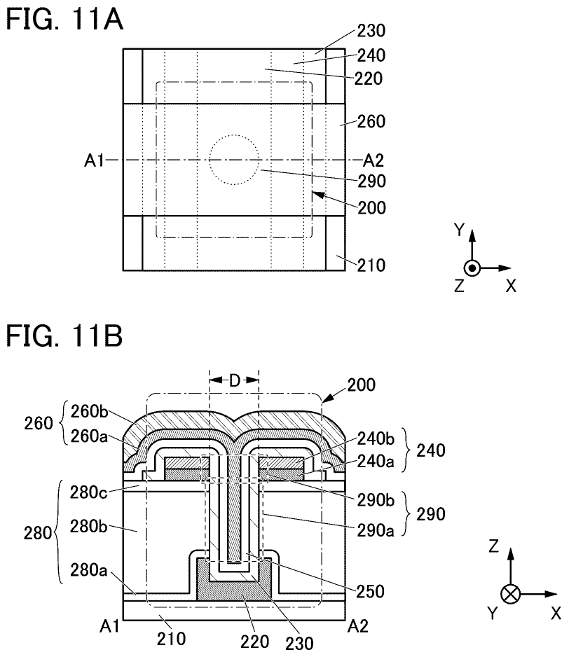

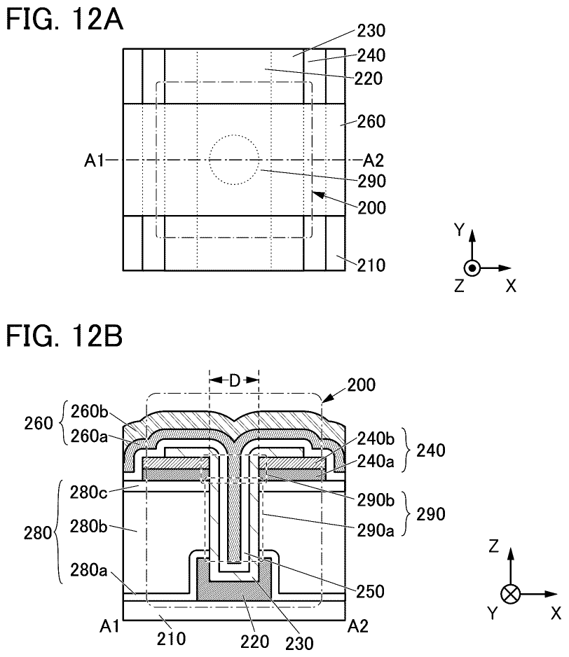

FIGS. 7B and 7C illustrate an example in which the end portion of the oxide semiconductor layer 230 and the end portion of the conductive layer 240 are aligned with each other at the outside of the opening portion 290. Note that the present invention is not limited to this example. For example, the semiconductor device illustrated in FIGS. 11A and 11B is different from the semiconductor device illustrated in FIGS. 7A and 7B in that the end portion of the oxide semiconductor layer 230 is positioned outward from the end portion of the conductive layer 240. When the end portion of the oxide semiconductor layer 230 is positioned outside the end portion of the conductive layer 240 and the oxide semiconductor layer 230 covers the end portion of the conductive layer 240, the withstand voltage between the conductive layer 240 and the conductive layer 260 can be further increased, and a leakage current that flows through the insulating layer 250 positioned between the conductive layer 240 and the conductive layer 260 can be further reduced in some cases. As illustrated in FIGS. 12A and 12B, the end portion of the oxide semiconductor layer 230 may be positioned inward from the end portion of the conductive layer 240.

### <Os Transistor>

In the transistor 200, a metal oxide functioning as a semiconductor (such a metal oxide is also referred to as an oxide semiconductor) is used for the oxide semiconductor layer 230 including a channel formation region. That is, the transistor 200 can be regarded as an OS transistor.

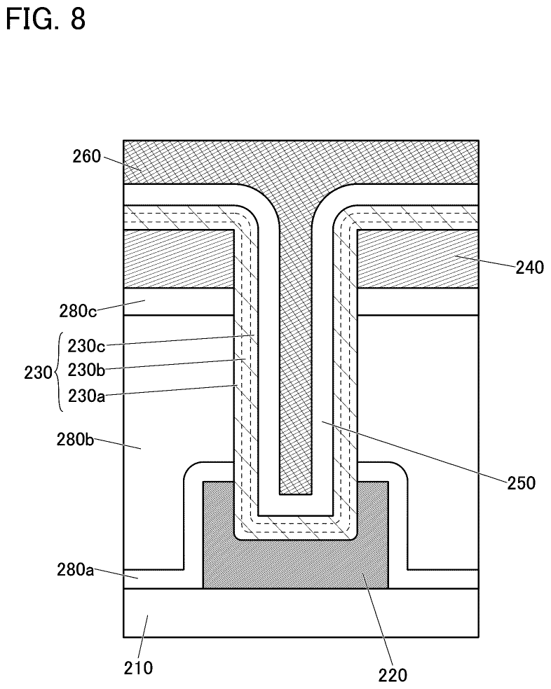

For the oxide semiconductor layer 230, the oxide semiconductor layer 230 described in the above embodiment can be used. The oxide semiconductor layer 230 described in the above embodiment can be formed by stacking the oxide semiconductor layers 230a, 230b, and 230c. FIG. 8 is an enlarged view of part of the cross-sectional view in FIG. 7B, which illustrates the oxide semiconductor layers 230a, 230b, and 230c. Note that for clarity of the drawings, the oxide semiconductor layers 230a, 230b, and 230c are omitted in some cases in other drawings. The oxide semiconductor layer 230a is in contact with the top surface of the conductive layer 220, the side surface of the depressed portion of the conductive layer 220, the side surface of the opening portion 290a of the insulating layer 280, the side surface of the opening portion 290b of the conductive layer 240, and the top surface of the conductive layer 240. The oxide semiconductor layer 230b is provided over the oxide semiconductor layer 230a. The oxide semiconductor layer 230c covers the top surface of the conductive layer 220, the side surface of the depressed portion of the conductive layer 220, the side surface of the opening portion 290a of the insulating layer 280, the side surface of the opening portion 290b of the conductive layer 240, and the top surface of the conductive layer 240 with the oxide semiconductor layer 230b therebetween. The insulating layer 250 is provided in contact with the oxide semiconductor layer 230c. The conductive layer 260 covers the oxide semiconductor layer 230c with the insulating layer 250 therebetween.

The oxide semiconductor layer 230 is provided in contact with the side surface of the opening portion 290a of the insulating layer 280. An angle formed by the side surface of the insulating layer 280 and the top surface of the conductive layer 220 (or the top surface of the insulating layer 210) is θ280. Thus, for example, the c-axis direction of the CAAC structure included in the oxide semiconductor layer 230 is a direction substantially perpendicular to the angle θ280.

When oxygen vacancies (V_{O}) and impurities are in a channel formation region of an oxide semiconductor in an OS transistor, electrical characteristics of the OS transistor easily vary and the reliability thereof might worsen. In some cases, hydrogen in the vicinity of an oxygen vacancy forms a defect that is an oxygen vacancy into which hydrogen enters (hereinafter sometimes referred to as V_{O}H), which generates an electron serving as a carrier. Thus, when the channel formation region of the oxide semiconductor includes oxygen vacancies, the OS transistor tends to have normally-on characteristics. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

Meanwhile, preferably, the source region and the drain region of the OS transistor include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

A region that is of the oxide semiconductor layer 230 and is in contact with the insulating layer 280 and the vicinity thereof function as a channel formation region of the transistor 200. One of a region that is of the oxide semiconductor layer 230 and is in contact with the conductive layer 220 and a region that is of the oxide semiconductor layer 230 and is in contact with the conductive layer 240 functions as a source region, and the other functions as a drain region. That is, the channel formation region is sandwiched between the source region and the drain region.

When the oxide semiconductor layer 230 and the conductive layer 220 are in contact with each other, a metal compound or oxygen vacancies are formed, so that the resistance of the region that is of the oxide semiconductor layer 230 and is in contact with the conductive layer 220 is reduced. Accordingly, the contact resistance between the oxide semiconductor layer 230 and the conductive layer 220 can be reduced. Similarly, when the oxide semiconductor layer 230 and the conductive layer 240 are in contact with each other, the resistance of a region that is of the oxide semiconductor layer 230 and is in contact with the conductive layer 240 is reduced. Accordingly, the contact resistance between the oxide semiconductor layer 230 and the conductive layer 240 can be reduced.

As illustrated in FIG. 10A, the insulating layer 280 is in contact with all the perimeter of the oxide semiconductor layer 230. Thus, the channel formation region of the transistor 200 can be formed in all the perimeter of the oxide semiconductor layer 230 in the opening portion 290 (the entire region in contact with the insulating layer 280). Note that FIG. 10A can be regarded as a cross-sectional view along the XY plane including the channel formation region of the oxide semiconductor layer 230.

The channel length of the transistor 200 is a distance between the source region and the drain region. That is, the channel length of the transistor 200 is determined by the thickness of the insulating layer 280 over the conductive layer 220. In FIG. 7C, a channel length L of the transistor 200 is indicated by a dashed double-headed arrow. The channel length L is a distance between an end portion of a region where the oxide semiconductor layer 230 and the conductive layer 220 are in contact with each other and an end portion of a region where the oxide semiconductor layer 230 and the conductive layer 240 are in contact with each other in a cross-sectional view. That is, the channel length L corresponds to the length of a side surface on the opening portion 290 side of the insulating layer 280 in the cross-sectional view.

The channel length of a planar transistor is limited by the light exposure limit of photolithography, and further miniaturization is difficult. In contrast, in the transistor included in the semiconductor device of one embodiment of the present invention, the channel length can be determined by the thickness of the insulating layer 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 200 can have a higher on-state current and higher frequency characteristics.

Since the channel length of the transistor included in the semiconductor device of one embodiment of the present invention is determined by the thickness of the insulating layer 280 over the conductive layer 220, even when the channel length is set greater than or equal to 60 nm, for example, the area occupied by the transistor, specifically, the area of the transistor seen from the above is roughly determined by the width of the opening portion 290. As described later, the width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. For example, even in the case where the channel length is 150 nm, the width of the opening portion 290 can be shorter than 150 nm. That is, a transistor having a width of the opening portion shorter than the channel length can be obtained, in which case the area occupied by the transistor can be reduced and the semiconductor device can be highly integrated.

When the channel length of the transistor is, for example, less than or equal to 1 μm, less than or equal to 500 nm, or less than or equal to 300 nm, the productivity, yield, and the like can be improved in formation of the insulating layer 280 and formation of the opening portion 290 in the insulating layer 280, for example.

Thus, the channel length of the transistor included in the semiconductor device of one embodiment of the present invention is preferably greater than or equal to 0.1 nm, greater than or equal to 1 nm, or greater than or equal to 5 nm, and less than or equal to 1 μm, less than or equal to 500 nm, or less than or equal to 300 nm.

In addition, as described above, the channel formation region, the source region, and the drain region can be formed in the opening portion 290. Thus, the area occupied by the transistor 200 can be reduced as compared with a planar transistor in which the channel formation region, the source region, and the drain region are provided separately on the X-Y plane. Thus, the semiconductor device can be highly integrated. In the case where the semiconductor device of one embodiment of the present invention is used in a memory device, the storage capacity per unit area can be increased.

As illustrated in FIG. 10A, the oxide semiconductor layer 230, the insulating layer 250, and the conductive layer 260 are provided concentrically. Therefore, a side surface of the conductive layer 260 provided at the center faces a side surface of the oxide semiconductor layer 230 with the insulating layer 250 therebetween. That is, in the top view, all the perimeter of the oxide semiconductor layer 230 serves as the channel formation region. In this case, for example, the channel width of the transistor 200 is determined by the length of the perimeter of the oxide semiconductor layer 230. In other words, the channel width of the transistor 200 is determined by the width of the opening portion 290 (the diameter in the case where the opening portion 290 is circular in the top view). In FIG. 7C and FIG. 10A, the width D of the opening portion 290 is indicated by a dashed double-dotted double-headed arrow. In FIG. 10A, a channel width W of the transistor 200 is indicated by a dashed-dotted double-headed arrow. By increasing the width D of the opening portion 290, the channel width per unit area can be increased and the on-state current can be increased.

In the case where the opening portion 290 is formed by a photolithography method, the width D of the opening portion 290 is limited by the light exposure limit of photolithography. In addition, the width D of the opening portion 290 is determined by the film thicknesses of the oxide semiconductor layer 230, the insulating layer 250, and the conductive layer 260 provided in the opening portion 290. The width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the top view, the width D of the opening portion 290 corresponds to the diameter of the opening portion 290, and the channel width W can be calculated to be “D×π”.

The channel length L of the transistor 200 is preferably shorter than at least the channel width W of the transistor 200. The channel length L of the transistor 200 is preferably greater than or equal to 0.1 times and less than or equal to 0.99 times, further preferably greater than or equal to 0.5 times and less than or equal to 0.8 times the channel width W of the transistor 200. This structure enables a transistor with favorable electrical characteristics and high reliability.

In the case where the opening portion 290 is formed to be circular in a top view, the oxide semiconductor layer 230, the insulating layer 250, and the conductive layer 260 are formed concentrically. This makes the distance between the conductive layer 260 and the oxide semiconductor layer 230 substantially uniform, so that a gate electric field can be substantially uniformly applied to the oxide semiconductor layer 230.

Although an example where the opening portion 290 is circular in the top view is described in this embodiment, the present invention is not limited thereto. For example, the opening portion 290 may have, in the top view, an almost circular shape such as an ellipse, a polygonal shape such as a square, or a polygonal shape with rounded corners such as a square with rounded corners.

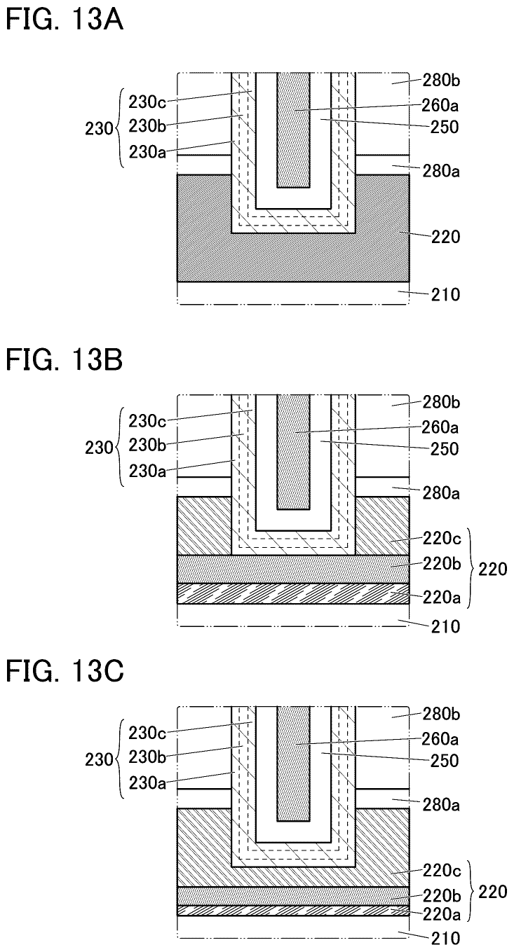

FIG. 13A is an enlarged view of part of the cross section illustrated in FIG. 7B. As illustrated in FIG. 13A, a depressed portion overlapping with the opening portion 290 is formed in the conductive layer 220, and at least part of the oxide semiconductor layer 230, part of the insulating layer 250, and part of the conductive layer 260 are formed to fill the depressed portion. With such a structure, the gate electric field of the conductive layer 260 can be easily applied to the oxide semiconductor layer 230 in the vicinity of the conductive layer 220. The depressed portion of the conductive layer 220 is formed by over etching at the time of forming the opening portion 290, for example.

In FIG. 13A, the opening portion 290 and the depressed portion of the conductive layer 220 form a continuous opening portion. In such a case, for example, the bottom of the continuous opening portion serves as the top surface of the conductive layer 220.

FIG. 13B illustrates an example in which the conductive layer 220 has a three-layer stacked structure of a conductive layer 220a, a conductive layer 220b over the conductive layer 220a, and a conductive layer 220c over the conductive layer 220b. The bottom surface of the depressed portion of the conductive layer 220 corresponds to the top surface of the conductive layer 220b, and a side surface of the depressed portion corresponds to a side surface on the opening portion 290 side of the conductive layer 220c. Here, the shortest distance from the top surface of the insulating layer 210 to the top surface of the conductive layer 220c that is in contact with the insulating layer 280 is preferably longer than the shortest distance from the top surface of the insulating layer 210 to the top surface of the insulating layer 250. Thus, the contact resistance between the side surface of the conductive layer 220c and the oxide semiconductor layer 230 can be reduced. Consequently, a decrease in the on-state current of the transistor 200 can be inhibited.

FIG. 13C is a variation of FIG. 13B. In FIG. 13C, the bottom surface of the depressed portion of the conductive layer 220 is positioned above the top surface of the conductive layer 220b. As illustrated in FIG. 13C, the oxide semiconductor layer 230 is not necessarily in contact with the conductive layer 220a or the conductive layer 220b.

Note that the depressed portion is not provided in the conductive layer 220 in some cases.

When the conductive layer 220 is in contact with the side surface of the oxide semiconductor layer 230, the contact area between the conductive layer 220 and the oxide semiconductor layer 230 can be increased, so that contact resistance can be reduced.

When a region where the conductive layer 220 and the conductive layer 260 overlap with each other is included, a gate electric field can be easily applied to the channel formation region of the oxide semiconductor layer 230, so that the electrical characteristics of the transistor can be improved, for example. Furthermore, a gate electric field is easily applied also to a region that is of the oxide semiconductor layer 230 and is in contact with the conductive layer 220, whereby the on-state current of the transistor can be increased, for example.

### <Modification Example of Semiconductor Device>

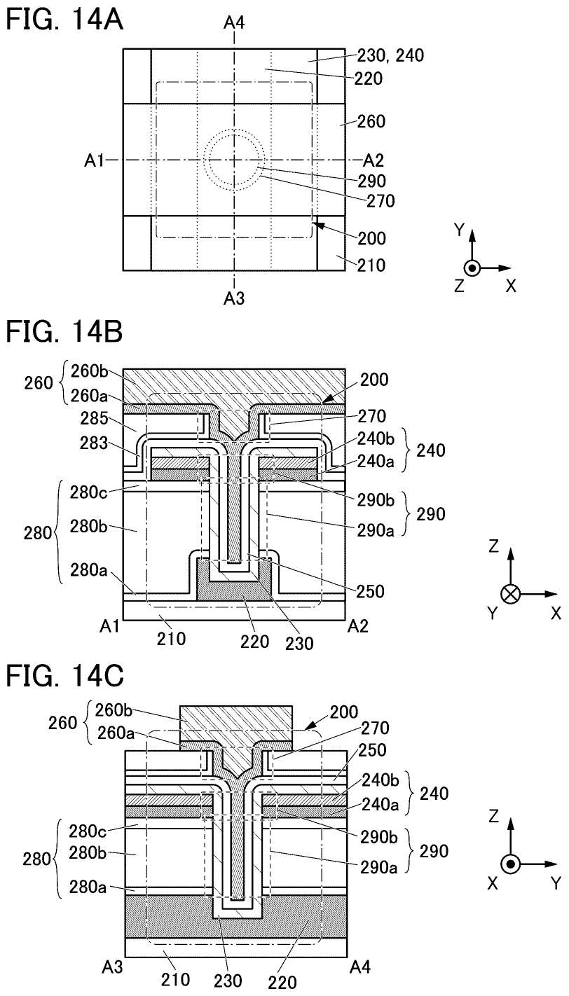

In the semiconductor device illustrated in FIGS. 14A to 14C, the insulating layer 283 and the insulating layer 285 are provided over the insulating layer 250, the insulating layer 285 includes an opening portion 270, and the conductive layer 260 is provided in the opening portion 270. FIG. 14A is a plan view of the semiconductor device including a transistor 200. FIG. 14B is a cross-sectional view taken along a dashed-dotted line A1-A2 in FIG. 14A. FIG. 14C is a cross-sectional view taken along a dashed-dotted line A3-A4 in FIG. 14A.

In the semiconductor device illustrated in FIGS. 14B and 14C, the opening portion 270 overlaps with the opening portion 290 in a plan view. The conductive layer 260 includes a region positioned in the opening portion 270 in the insulating layer 285 and a region in contact with the top surface of the insulating layer 285. The insulating layer 283 includes a region overlapping with the top surface of the conductive layer 240 with the insulating layer 250 and the oxide semiconductor layer 230 therebetween, and a region sandwiched between the side surface of the opening portion 270 and the side surface of the conductive layer 260. The conductive layer 240 and the conductive layer 260 overlap with each other with the insulating layer 285 therebetween.

In the semiconductor device illustrated in FIGS. 14B and 14C, the insulating layer 283 and the insulating layer 285 are provided between the conductive layer 240 and the conductive layer 260; thus, when the thickness of the insulating layer 285 is increased, the parasitic capacitance between the conductive layer 240 and the conductive layer 260 can be reduced.

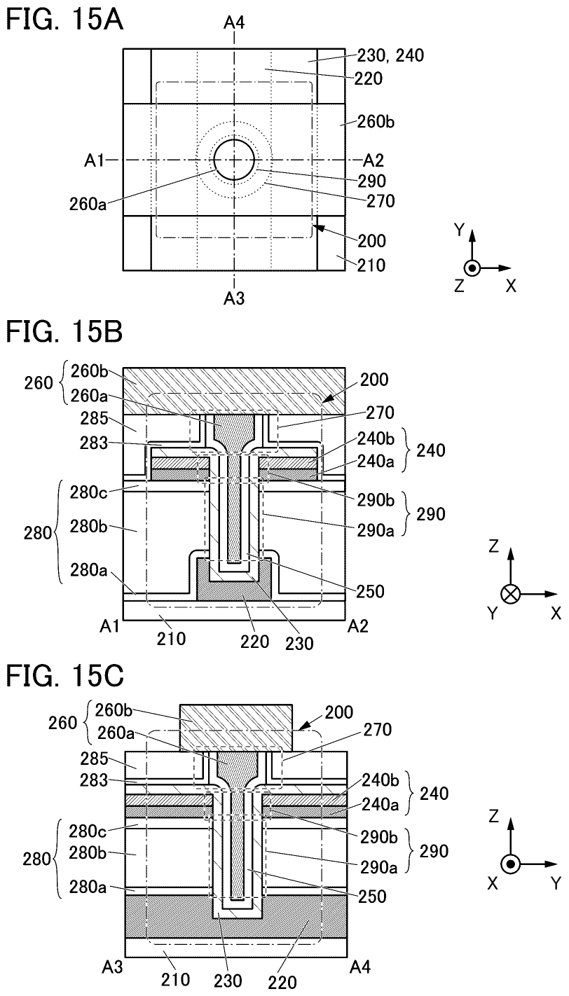

The semiconductor device illustrated in FIGS. 15A to 15C includes the insulating layer 283 and the insulating layer 285 over the insulating layer 250. The insulating layer 285 includes the opening portion 270, and the conductive layer 260a is provided in the opening portion 270. FIG. 15A is a plan view of the semiconductor device including a transistor 200. FIG. 15B is a cross-sectional view taken along a dashed-dotted line A1-A2 in FIG. 15A. FIG. 15C is a cross-sectional view taken along a dashed-dotted line A3-A4 in FIG. 15A.

In the semiconductor device illustrated in FIGS. 15B and 15C, the opening portion 270 overlaps with the opening portion 290 in a plan view. The conductive layer 260a includes a region positioned in the opening portion 270 in the insulating layer 285. The insulating layer 283 includes a region overlapping with the top surface of the conductive layer 240 with the oxide semiconductor layer 230 therebetween, and a region sandwiched between the side surface of the opening portion 270 and the side surface of the conductive layer 260a. It is preferable that the top surface of the conductive layer 260a be level with or substantially level with the top surface of the insulating layer 285. The conductive layer 260b is provided over the conductive layer 260a, the insulating layer 285, and the insulating layer 283. The conductive layer 240 and the conductive layer 260b overlap with each other with the insulating layer 285 therebetween. The conductive layer 260a is not provided in a region outside the opening portion 270 in the plan view.

In the semiconductor device illustrated in FIGS. 15B and 15C, the insulating layer 283 and the insulating layer 285 are provided between the conductive layer 240 and the conductive layer 260b; thus, when the thickness of the insulating layer 285 is increased, the parasitic capacitance between the conductive layer 240 and the conductive layer 260b can be reduced. Furthermore, since the conductive layer 260a is not provided in a region outside the opening portion 270 in the plan view, the area overlapping with the conductive layer 240 is small. Thus, the parasitic capacitance between the conductive layer 260a and the conductive layer 240 can be reduced.

### <Materials of Components of Semiconductor Device>

Materials that can be used for the semiconductor device of this embodiment are described below. Note that the layers included in the semiconductor device of this embodiment may have a single-layer structure or a stacked-layer structure.

### [Insulating Layers]

An inorganic insulating film is preferably used for each of the insulating layers (the insulating layer 210, the insulating layer 250, the insulating layer 280, the insulating layer 283, the insulating layer 285, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

Specifically, it is preferable to use a barrier insulating layer against impurities such as water and hydrogen and oxygen.

Note that in this specification and the like, a barrier insulating layer refers to an insulating layer having a barrier property. In addition, the barrier property refers to a property that does not easily allow diffusion of a target substance, a property that does not easily allow passage of a target substance, a property with low permeability of a target substance, a function of inhibiting diffusion of a target substance, or a function of inhibiting transmission of a target substance. Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

As the insulating layer having a function of inhibiting the passage of oxygen and impurities such as water and hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide can be given, for example. In addition, an oxide containing aluminum and hafnium (hafnium aluminate) can be given, for example. Furthermore, metal nitrides such as aluminum nitride, silicon nitride oxide, and silicon nitride can be given, for example.

In addition, an insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, the number of oxygen vacancies in the oxide semiconductor layer can be reduced. Examples of an insulating layer in which a region containing excess oxygen is easily formed include silicon oxide, silicon oxynitride, and porous silicon oxide.

With miniaturization and high integration of a transistor, for example, a problem such as generation of a leakage current may arise because of a thin gate insulating layer. When a material with a high dielectric constant (also referred to as a high-k material) is used for the gate insulating layer, the voltage at the time of operation of the transistor can be reduced while the physical thickness is maintained. Furthermore, the equivalent oxide thickness (EOT) of the gate insulating layer can be reduced. When a material with a high dielectric constant is used for a dielectric layer of a capacitor, the element can have a larger capacitance value. By contrast, when a material with a low dielectric constant is used for the insulating layer functioning as an interlayer film, parasitic capacitance generated between wirings can be reduced. Thus, a material is preferably selected depending on the function of an insulating layer. Note that a material with a low dielectric constant is a material with high dielectric strength.

Examples of a material with a high dielectric constant include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include resins such as polyester, polyolefin, polyamide (e.g., nylon and aramid), polyimide, polycarbonate, and acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

For example, an inorganic insulating material such as silicon oxide, silicon oxynitride, and silicon nitride oxide can be used for both a layer in which a material with a high dielectric constant is suitably used, such as a gate insulating layer, and a layer in which a material with a low dielectric constant is suitably used, such as an interlayer film. These materials have relatively low dielectric constants as compared with a high-k material such as hafnium oxide, for example, and thus are each expressed as a material with a low dielectric constant in this specification and the like in some cases.

A material that can show ferroelectricity may be used for an insulating layer included in the semiconductor device. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element MI is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element MI to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a K-alumina-type structure.

Note that although the metal oxide and the metal nitride are shown above as examples of the material that can have ferroelectricity, one embodiment of the present invention is not limited thereto. For example, a metal oxynitride in which nitrogen is added to any of the above-described metal oxides, a metal nitride oxide in which oxygen is added to any of the above-described metal nitrides, or the like may be used.

As the material that can show ferroelectricity, a mixture or compound containing a plurality of materials selected from the above-listed materials can be used, for example. Alternatively, the insulating layer can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

A metal oxide containing one or both of hafnium and zirconium is preferable because the metal oxide can have ferroelectricity even when being a thin film of several nanometers. A metal oxide containing one or both of hafnium and zirconium is preferable because the metal oxide can have ferroelectricity even with a minute area. Accordingly, the use of a metal oxide containing one or both of hafnium and zirconium enables miniaturization of the semiconductor device.

Note that in this specification and the like, the material that can show ferroelectricity processed into a layer shape is referred to as a ferroelectric layer in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer needs to include a crystal. It is particularly preferable that the insulating layer include a crystal having an orthorhombic crystal structure, in which case ferroelectricity is exhibited. A crystal included in the insulating layer may have one or more of crystal structures selected from cubic, tetragonal, orthorhombic, monoclinic, and hexagonal crystal structures. Alternatively, the insulating layer may have an amorphous structure. In that case, the insulating layer may have a composite structure including an amorphous structure and a crystal structure.

The insulating layer 250 functions as the gate insulating layer of the transistor 200. The insulating layer 250 is preferably formed using a material with a high dielectric constant.

The insulating layer 250 preferably has a function of trapping and fixing hydrogen. In this case, the hydrogen concentration in the oxide semiconductor layer 230 (in particular, the hydrogen concentration in the channel formation region of the transistor) can be reduced. Accordingly, V_{O}H in the channel formation region can be reduced, so that the channel formation region can be an i-type or substantially i-type region.

Examples of a material for an insulating layer having a function of capturing or fixing hydrogen include metal oxides such as an oxide containing hafnium, an oxide containing aluminum, an oxide containing aluminum and hafnium (hafnium aluminate), and an oxide containing magnesium. Furthermore, these metal oxides may further contain zirconium, and an example of such a metal oxide is an oxide containing hafnium and zirconium. Note that in a metal oxide having an amorphous structure, some oxygen atoms have a dangling bond, which allows the metal oxide to have a high property of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide may partly include one or both of a crystal region and a crystal grain boundary.

Note that a function of capturing or fixing a target substance can be rephrased as a property that does not easily allow diffusion of a target substance. Thus, a function of capturing or fixing a target substance can be rephrased as a barrier property.

In the case where the insulating layer 250 has a stacked-layer structure, it is preferable to use a layer having a function of capturing and fixing hydrogen as any of the layers (hereinafter referred to as a first insulating layer of the insulating layer 250). In the case where the insulating layer 250 has a stacked-layer structure of two layers, a layer having a function of capturing or fixing hydrogen is used as the layer in contact with the oxide semiconductor layer 230; and in the case where the insulating layer 250 has a stacked-layer structure of three or more layers, a layer having a function of capturing or fixing hydrogen is used as the layer that is close to the oxide semiconductor layer 230, whereby hydrogen contained in the oxide semiconductor layer 230 can be more effectively captured or fixed. Thus, the hydrogen concentration in the oxide semiconductor layer 230 can be lowered.

In addition to the first insulating layer, a second insulating layer of the insulating layer 250 is preferably formed using a barrier insulating layer against hydrogen. Examples of a barrier insulating layer against hydrogen include aluminum oxide, magnesium oxide, hafnium oxide, gallium oxide, silicon nitride, and silicon nitride oxide.

As the first insulating layer of the insulating layer 250, hafnium silicate or the like is preferably used, for example. The first insulating layer of the insulating layer 250 preferably has an amorphous structure. When the layer has an amorphous structure, formation of a crystal grain boundary can be inhibited. Inhibiting formation of a crystal grain boundary can increase the planarity of the insulating layer. This enables the insulating layer to have uniform thickness distribution and a reduced number of extremely thin portions, so that the withstand voltage of the insulating layer can be increased. Furthermore, the thickness distribution of the film provided over the insulating layer can be uniform.

Furthermore, inhibiting formation of a crystal grain boundary in the insulating layer can reduce a leakage current due to the defect states in the crystal grain boundary. Thus, the insulating layer can function as an insulating film with a low leakage current.

Since hafnium oxide is a material with a high dielectric constant, hafnium silicate is a material having a high dielectric constant depending on the content of silicon. Accordingly, when hafnium silicate is used for a gate insulating layer, a gate potential applied during operation of the transistor can be lowered while the physical thickness of the gate insulating layer is maintained. In addition, the equivalent oxide thickness (EOT) of the gate insulating layer can be reduced.

As described above, for the first insulating layer of the insulating layer 250, an oxide containing aluminum and/or hafnium is preferably used, an oxide containing aluminum and/or hafnium and having an amorphous structure is further preferably used, and aluminum oxide having an amorphous structure is still further preferably used.

When a barrier insulating layer against hydrogen is used as the second insulating layer of the insulating layer 250, diffusion of impurities contained in the conductive layer 260 into the oxide semiconductor layer 230 can be inhibited. Silicon nitride is suitable for the insulating layer 250 because of its high hydrogen barrier property. Here, the second insulating layer is preferably over the first insulating layer.

With such a structure, a semiconductor device having favorable electrical characteristics can be provided. A highly reliable semiconductor device can be provided. A semiconductor device with a small variation in transistor's electrical characteristics can be provided. A semiconductor device that has a high on-state current can be provided.

Furthermore, the insulating layer 250 may include a thermally stable insulating layer such as silicon oxide or silicon oxynitride. For example, the insulating layer 250 preferably includes silicon oxide.

Furthermore, the insulating layer 250 preferably includes a layer that can supply oxygen to the oxide semiconductor layer 230. An oxide can be used for the layer that can supply oxygen. When the insulating layer 250 contains silicon oxide or silicon oxynitride, oxygen can be adequately supplied from the insulating layer 250 to the oxide semiconductor layer 230.

The insulating layer 250 may include, between a pair of insulating layers having a function of capturing and fixing hydrogen, a thermally stable insulating layer.

The insulating layer 250 preferably includes a barrier insulating layer against oxygen. In this case, oxidation of the conductive layer 240, the conductive layer 260, and the like can be inhibited. In the case where the insulating layer 250 has a stacked-layer structure, a layer in contact with the conductive layer 240 and a layer in contact with the conductive layer 260 are each preferably a barrier insulating layer against oxygen.

The layer of the insulating layer 250 which is in contact with the conductive layer 240 is preferably less likely to transmit oxygen than at least the insulating layer 280. When the layer has a barrier property against oxygen, oxidation of the side surface of the conductive layer 240 can be inhibited, and accordingly formation of an oxide film on the side surface can be inhibited. It is thus possible to inhibit a reduction in the on-state current or field-effect mobility of the transistor 200.

When a barrier insulating layer against hydrogen and oxygen is used as the above-described second insulating layer, for example, oxidation of the conductive layer 260 can be inhibited. Furthermore, diffusion of oxygen contained in the oxide semiconductor layer 230 into the conductive layer 260 can be inhibited, and accordingly formation of oxygen vacancies in the oxide semiconductor layer 230 can be inhibited.

Examples of the barrier insulating layer against oxygen include an oxide containing hafnium, an oxide containing aluminum, an oxide containing aluminum and hafnium (hafnium aluminate), magnesium oxide, gallium oxide, gallium zinc oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate).

An oxide containing hafnium and silicon (hafnium silicate) is an excellent insulating layer that functions as a barrier insulating layer against oxygen and moreover easily has an amorphous structure and thereby has a function of capturing or fixing hydrogen as described above.

Silicon nitride is an excellent insulating layer that functions as a barrier insulating layer against oxygen and moreover has a high barrier property against hydrogen as described above.

The insulating layer 250 preferably has a two-layer structure in which the first insulating layer having a function of capturing or fixing hydrogen and the second insulating layer having a barrier property against hydrogen and oxygen are stacked in this order from the oxide semiconductor layer 230 side.

For example, an oxide containing one or both of aluminum and hafnium can be used for the first insulating layer, and silicon nitride can be used for the second insulating layer.

The insulating layer 250 preferably has a three-layer structure in which a third insulating layer containing a material with a relatively low dielectric constant, the first insulating layer having a function of capturing or fixing hydrogen, and the second insulating layer having a barrier property against hydrogen and oxygen are stacked in this order from the oxide semiconductor layer 230 side. The material with a relatively low dielectric constant contained in the third insulating layer refers to, for example, a material with a lower dielectric constant than any one or more of the other layers in the stacked-layer structure. Here, silicon oxide or silicon oxynitride can be used as the third insulating layer. The third insulating layer is a layer in contact with the oxide semiconductor layer 230. When an oxide is used for the third insulating layer, oxygen can be supplied to the oxide semiconductor layer 230. Providing the second insulating layer can inhibit oxygen contained in the third insulating layer from diffusing into the conductive layer 260 and inhibit the conductive layer 260 from being oxidized. Furthermore, a reduction in the amount of oxygen supplied from the third insulating layer to the oxide semiconductor layer 230 can be inhibited.

For example, silicon oxide or silicon oxynitride can be used for the third insulating layer, an oxide containing one or both of aluminum and hafnium can be used for the first insulating layer, and silicon nitride can be used for the second insulating layer.

The insulating layer 250 preferably has a four-layer structure where a fourth insulating layer having a barrier property against oxygen, a third insulating layer containing a material with a relatively low dielectric constant, a first insulating layer having a function of capturing or fixing hydrogen, and a second insulating layer having a barrier property against hydrogen and oxygen are stacked in this order from the oxide semiconductor layer 230 side. The first insulating layer to the third insulating layer can have a structure similar to that of the layers used in the above three-layer structure. The fourth insulating layer is in contact with the oxide semiconductor layer 230. When the fourth insulating layer has a barrier property against oxygen, release of oxygen from the oxide semiconductor layer 230 can be inhibited. For the fourth insulating layer, aluminum oxide is preferably used, for example. Aluminum oxide has a function of capturing or fixing hydrogen, and thus is suitably used for the fourth insulating layer in contact with the oxide semiconductor layer 230.

For example, aluminum oxide can be used for the fourth insulating layer, silicon oxide or silicon oxynitride can be used for the third insulating layer, an oxide containing one or both of aluminum and hafnium can be used for the first insulating layer, and silicon nitride can be used for the second insulating layer.

In the insulating layer 250, it is preferable that a region overlapping with the channel formation region of the oxide semiconductor layer 230 especially have a thickness greater than or equal to 0.1 nm and less than or equal to 30 nm, preferably greater than or equal to 0.1 nm and less than or equal to 20 nm, preferably greater than or equal to 0.1 nm and less than or equal to 10 nm, further preferably greater than or equal to 0.1 nm and less than or equal to 8.0 nm, further preferably greater than or equal to 0.5 nm and less than or equal to 7.0 nm.

The thickness of each layer included in the insulating layer 250 is preferably thin for miniaturization of the transistor. The thickness of each layer included in the insulating layer 250 is, for example, greater than or equal to 0.1 nm and less than or equal to 10 nm, greater than or equal to 0.1 nm and less than or equal to 5 nm, greater than or equal to 0.5 nm and less than or equal to 5 nm, greater than or equal to 1 nm and less than 5 nm, or greater than or equal to 1 nm and less than or equal to 3 nm. Note that each layer included in the insulating layer 250 at least partly includes a region with the above-described thickness.

Typically, the thicknesses of the fourth insulating layer, the third insulating layer, the first insulating layer, and the second insulating layer are 1 nm, 2 nm, 2 nm, and 1 nm, respectively. Such a structure enables the transistor to have favorable electrical characteristics even when the transistor is miniaturized or highly integrated.

The insulating layer 250 preferably has a three-layer structure where a fourth insulating layer having a barrier property against oxygen, a first insulating layer containing a material with a low dielectric constant, and a second insulating layer having a function of capturing or fixing hydrogen are stacked in this order from the oxide semiconductor layer 230 side. Specifically, a three-layer structure in which an aluminum oxide film, a silicon oxide film, and a hafnium oxide film are stacked in this order from the oxide semiconductor layer 230 side is preferably employed.

A silicon oxide film is an insulating film having a lower dielectric constant than another insulating film (typically a silicon nitride film). The silicon oxide film has a function of supplying oxygen to the oxide semiconductor layer 230 and the like by heat treatment or the like. The silicon oxide film included in the insulating layer 250 is preferably formed by a PEALD method. The thickness of the silicon oxide film included in the insulating layer 250 is preferably greater than or equal to 0.7 nm and less than or equal to 3 nm. The hafnium oxide film has a function of capturing and fixing hydrogen. Thus, the hydrogen concentration in the oxide semiconductor layer 230 can be reduced. It is particularly preferable to reduce the hydrogen concentration in the channel formation region of the oxide semiconductor layer 230. When the insulating film contains hafnium, the dielectric constant of the insulating film is increased in some cases.

An ALD method enables atomic layers to be deposited one by one, and has advantages such as deposition of an extremely thin film, deposition on a component with a high aspect ratio, deposition on a surface with a large step, deposition of a film with few defects such as pinholes, deposition with excellent coverage, and low-temperature deposition. Thus, by an ALD method, the coverage with the insulating layer 250 on the sidewall and bottom surface of the opening portion 290 can be increased in the transistor of one embodiment of the present invention, so that the insulating layer 250 with a uniform thickness can be formed. A PEALD method utilizing plasma enables deposition at a lower temperature. Furthermore, the use of plasma can increase the deposition rate and increase the productivity.

The insulating layer 250 preferably includes an insulating film that has a function of extracting hydrogen from the oxide semiconductor layer 230. The silicon oxide film and the hafnium oxide film each have a function of extracting hydrogen from the oxide semiconductor layer 230.

The insulating layer 250 is preferably formed with two or more kinds of different films. When the insulating layer 250 is formed with two or more kinds of different films, different functions can be given to the insulating layer 250. Examples of the different functions include a function of extracting hydrogen from the oxide semiconductor layer 230 and a function of inhibiting diffusion of hydrogen into the oxide semiconductor layer 230. Note that an ALD process is preferably performed twice or more in the formation of the insulating layer 250. For example, the insulating layer 250 preferably has a stacked-layer structure of a plurality of insulating films, and two or more of the plurality of insulating films are preferably formed by an ALD process. When at least two or more insulating films are formed by an ALD process, the coverage and the thickness uniformity of the insulating layer 250 can be improved. Moreover, the productivity can be increased when two or more kinds of different films, e.g., two or more insulating films, are successively formed by an ALD process.

Note that instead of the silicon oxide film included in the insulating layer 250, a silicon oxynitride film can also be used. Instead of the silicon nitride film included in the insulating layer 250, a silicon nitride oxide film can also be used. Instead of the hafnium oxide film included in the insulating layer 250, an oxide containing hafnium and aluminum, an oxide containing hafnium and silicon, or the like can also be used.

The insulating layer 210 functions as an interlayer film and preferably has a low dielectric constant. In the case where a material with a low dielectric constant is used for an interlayer film, the parasitic capacitance generated between wirings can be reduced. Silicon oxide and silicon oxynitride are thermally stable, and thus are suitable for the insulating layer 210.

The concentration of impurities such as water or hydrogen in the insulating layer 210 is preferably reduced. This can inhibit entry of impurities such as water or hydrogen into the channel formation region of the oxide semiconductor layer 230.

As the insulating layer 210, a barrier insulating layer against hydrogen is preferably used. When the insulating layer 210 provided outside the oxide semiconductor layer 230 has a barrier property against hydrogen, diffusion of hydrogen into the oxide semiconductor layer 230 can be inhibited.

Examples of a material for the barrier insulating layer against hydrogen include aluminum oxide, magnesium oxide, hafnium oxide, gallium oxide, silicon nitride, and silicon nitride oxide.

For example, a silicon nitride film is preferably used as the insulating layer 210.

Furthermore, the insulating layer 210 may have a stacked-layer structure of two layers. For example, an insulating layer having a function of capturing or fixing hydrogen can be used as the upper layer of the insulating layer 210. Accordingly, hydrogen in the oxide semiconductor layer 230 can be diffused into the upper layer of the insulating layer 210 through the conductive layer 220, and the hydrogen can be captured or fixed. Thus, the hydrogen concentration in the oxide semiconductor layer 230 can be lowered.

For example, a silicon nitride film is preferably used as the lower layer of the insulating layer 210 and an oxide film containing hafnium and silicon (hafnium silicate film) is preferably used as the upper layer.

As either or both of the insulating layer 283 and the insulating layer 285, a barrier insulating layer against hydrogen is preferably used. In this case, diffusion of hydrogen from above the insulating layer 283 into the oxide semiconductor layer 230 can be inhibited. A silicon nitride film and a silicon nitride oxide film can be suitably used for the insulating layer 283 because they release few impurities (e.g., water and hydrogen) and are less likely to transmit oxygen and hydrogen.

It is particularly preferable to use a silicon nitride film formed by a sputtering method as either or both of the insulating layer 283 and the insulating layer 285. A deposition gas in a sputtering method need not include molecules containing hydrogen; thus, the hydrogen concentration in the insulating layer 283 can be reduced. When the insulating layer 283 is formed by a sputtering method, a high-density silicon nitride film can be obtained.

As either or both of the insulating layer 283 and the insulating layer 285, an insulating layer having a function of capturing or fixing hydrogen may be used. With such a structure, diffusion of hydrogen from above the insulating layer 283 and the insulating layer 285 into the oxide semiconductor layer 230 can be inhibited, and hydrogen contained in the oxide semiconductor layer 230 can be captured or fixed. Thus, the hydrogen concentration in the oxide semiconductor layer 230 can be reduced. For either or both of the insulating layer 283 and the insulating layer 285, aluminum oxide, hafnium oxide, hafnium silicate, or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

Furthermore, the semiconductor device can have a structure that does not include either one of the insulating layer 283 and the insulating layer 285.

For the insulating layer 285, a material with a low dielectric constant can be used, for example. In the case where a material with a low dielectric constant is used for an interlayer film, parasitic capacitance between wirings can be reduced.

The concentration of impurities such as water or hydrogen in the insulating layer 285 is preferably reduced. This can inhibit entry of impurities such as water or hydrogen into the channel formation region of the oxide semiconductor layer 230.

The insulating layer 280 preferably includes the above-described barrier insulating layer against hydrogen. The insulating layer 280 is provided to surround the oxide semiconductor layer 230. When the insulating layer 280 provided outside the oxide semiconductor layer 230 has a barrier property against hydrogen, diffusion of hydrogen into the oxide semiconductor layer 230 can be inhibited. For example, the insulating layer 280 preferably includes a silicon nitride film.

Note that silicon nitride also has a barrier property against oxygen. Thus, using silicon nitride for the insulating layer 280 can inhibit extraction of oxygen from the oxide semiconductor layer 230, and accordingly can inhibit formation of an excess amount of oxygen vacancies in the oxide semiconductor layer 230.

Furthermore, when silicon nitride is used for the insulating layer 280, excess oxygen can be prevented from being supplied to the oxide semiconductor layer 230. Thus, the channel formation region of the oxide semiconductor layer 230 can be prevented from containing excess oxygen, whereby the reliability of the transistor 200 can be improved.

The insulating layer 280 preferably includes any of an oxide insulating film, an oxynitride film, and an insulating layer including a region containing excess oxygen, which are described above.

For example, the insulating layer including a region containing excess oxygen can be formed by deposition by a sputtering method in an atmosphere containing oxygen. Since a molecule containing hydrogen is not used as a deposition gas in the sputtering method, the hydrogen concentration in the insulating layer 280 can be reduced. When at least one layer in the insulating layer 280 is formed in this manner, oxygen can be supplied from the insulating layer 280 to the channel formation region of the oxide semiconductor layer 230, so that oxygen vacancies and V_{O}H therein can be reduced.

The concentration of impurities such as water or hydrogen in the insulating layer 280 is preferably reduced. This can inhibit entry of impurities such as water or hydrogen into the channel formation region of the oxide semiconductor layer 230.

Note that since the thickness of the insulating layer 280 over the conductive layer 220 corresponds to the channel length of the transistor 200, the thickness of the insulating layer 280 is set as appropriate depending on the design value of the channel length of the transistor 200.

The insulating layer 280 preferably has a stacked-layer structure including the insulating layer 280a, the insulating layer 280b over the insulating layer 280a, and the insulating layer 280c over the insulating layer 280b, for example.

The insulating layer 280b is a layer in contact with the channel formation region of the oxide semiconductor layer 230. When an insulating layer containing oxygen is used as the insulating layer 280b, oxygen can be supplied to the oxide semiconductor layer 230.

The insulating layer 280b preferably includes a region having a higher oxygen content than at least one of the insulating layers 280a and 280c. In particular, the insulating layer 280b preferably includes a region having a higher oxygen content than the insulating layers 280a and 280c. When the insulating layer 280b has a high oxygen content, an i-type region can be easily formed in the oxide semiconductor layer 230 in the vicinity of the insulating layer 280b.

It is further preferable that a film from which oxygen is released by heating be used for the insulating layer 280b. When the insulating layer 280b releases oxygen by being heated during the manufacturing process of the transistor 200, the oxygen can be supplied to the oxide semiconductor layer 230. The oxygen supply from the insulating layer 280b to the oxide semiconductor layer 230, particularly to the channel formation region of the oxide semiconductor layer 230, reduces the amount of oxygen vacancies and V_{O}H in the oxide semiconductor layer 230, so that the transistor can have favorable electrical characteristics and high reliability.

In order to improve the electrical characteristics and reliability of the OS transistor, it is important that the amount of oxygen supplied to the oxide semiconductor be optimized after the hydrogen concentration in the oxide semiconductor is sufficiently reduced.

For example, the amount of released oxygen molecules of the insulating layer 280b is preferably greater than or equal to 1.0×10¹⁴ molecules/cm² and less than 1.0×10¹⁵ molecules/cm². Note that the amount of released oxygen molecules can be measured by thermal desorption spectrometry.

In particular, when the channel length of the transistor 200 is short, the influence of oxygen vacancies and V_{O}H in the channel formation region on the electrical characteristics and reliability is especially large. Accordingly, when the amount of oxygen supplied to the oxide semiconductor layer 230 is optimized after the hydrogen concentration in the oxide semiconductor layer 230 is sufficiently reduced, a transistor with a short channel length, favorable electrical characteristics, and high reliability can be provided.

The insulating layer 280b is preferably formed by a deposition method such as a sputtering method or a PECVD method. It is particularly preferable to employ a sputtering method, in which a hydrogen gas does not need to be used as a film deposition gas, to form a film having an extremely low hydrogen content. Therefore, supply of hydrogen to the oxide semiconductor layer 230 is inhibited and electrical characteristics of the transistor 200 can be stabilized.

In the case where a large amount of oxygen is supplied to the oxide semiconductor layer 230, heat treatment in an oxygen-containing atmosphere or plasma treatment in an oxygen-containing atmosphere is preferably performed after formation of the insulating layer 280b, for example. Alternatively, an oxide film may be formed over the top surface of the insulating layer 280b by a sputtering method in an oxygen atmosphere to supply oxygen. After that, the oxide film may be removed. Such treatment can supply oxygen to the insulating layer 280b and increase the amount of oxygen supplied to the oxide semiconductor layer 230.

The contact region between the oxide semiconductor layer 230 and the insulating layer 280a and the contact region between the oxide semiconductor layer 230 and the insulating layer 280c are supplied with a smaller amount of oxygen than the contact region between the oxide semiconductor layer 230 and the insulating layer 280b. Thus, the contact region between the oxide semiconductor layer 230 and the insulating layer 280a and the contact region between the oxide semiconductor layer 230 and the insulating layer 280c each have a low resistance in some cases. That is, by adjusting the thickness of the insulating layer 280a, the range of a region functioning as one of the source region and the drain region can be controlled. Similarly, by adjusting the thickness of the insulating layer 280c, the range of a region functioning as the other of the source region and the drain region can be controlled. As described above, the thicknesses of the insulating layers 280a and 280c can be set as appropriate in accordance with the characteristics required for the transistor.

A material with a low dielectric constant is preferably used for the insulating layer 280b. In that case, parasitic capacitance generated between wirings can be reduced. For example, silicon oxide or silicon oxynitride can be suitably used for the insulating layer 280b.

For each of the insulating layer 280a and the insulating layer 280c, a barrier insulating layer against oxygen is preferably used. Provision of the insulating layer 280a between the insulating layer 280b and the conductive layer 220 can inhibit the conductive layer 220 from being oxidized and having high resistance. Furthermore, provision of the insulating layer 280c between the insulating layer 280b and the conductive layer 240 can inhibit the conductive layer 240 from being oxidized and having high resistance.

As the insulating layer 280a, an insulating layer having a function of capturing or fixing hydrogen may be used. With such a structure, diffusion of hydrogen from below the insulating layer 280a into the oxide semiconductor layer 230 can be inhibited, and hydrogen contained in the oxide semiconductor layer 230 can be captured or fixed. Thus, the hydrogen concentration in the oxide semiconductor layer 230 can be reduced. For the insulating layer 280a, magnesium oxide, aluminum oxide, hafnium oxide, an oxide containing hafnium and silicon, or the like can be used. Alternatively, for example, a stacked-layer film of aluminum oxide and silicon nitride over the aluminum oxide may be used as the insulating layer 280a. Similarly, an insulating layer having a function of capturing or fixing hydrogen may be used as the insulating layer 280c.

For example, silicon nitride can be used for the insulating layers 280a and 280c, and silicon oxide can be used for the insulating layer 280b.

### [Conductive Layer]

For the conductive layers (e.g., the conductive layer 220, the conductive layer 240, and the conductive layer 260) included in the semiconductor device, it is preferable to use a metal element selected from tungsten, copper, aluminum, chromium, silver, gold, platinum, zinc, tantalum, nickel, titanium, iron, cobalt, molybdenum, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, it is preferable to use tantalum nitride, titanium nitride, ruthenium nitride, a nitride containing molybdenum, a nitride containing tungsten, titanium, and aluminum, a nitride containing tantalum and aluminum, ruthenium oxide, an oxide containing strontium and ruthenium, an oxide containing lanthanum and nickel, or the like. Alternatively, a semiconductor having high electric conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (a registered trademark)), and indium zinc oxide containing tungsten oxide. In this specification and the like, a conductive film deposited using the conductive material containing oxygen may be referred to as an oxide conductive film.

In addition, a conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

For the conductive layer 260, any of the above metal elements, an alloy containing any of the above metal elements as a component, an alloy containing a combination of the above metal elements, or the like can be used. For example, a material having high conductivity, such as tungsten, is preferably used. For the conductive layer 260, a conductive material that is not easily oxidized, a conductive material having a function of inhibiting diffusion of oxygen, or the like is preferably used. As described above, examples of the conductive material include a conductive material containing nitrogen and a conductive material containing oxygen. Thus, a decrease in conductivity of the conductive layer 260 can be inhibited.

It is particularly preferable to use, for the conductive layer 260, a conductive material containing oxygen and a metal element contained in the metal oxide where a channel is formed. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With the use of such a material, hydrogen contained in the metal oxide where a channel is formed can be captured in some cases. Hydrogen entering from a surrounding insulating layer or the like can also be captured in some cases.

The conductive layer 260 has a thickness greater than or equal to 3 nm and less than or equal to 500 nm, for example. The thickness of the conductive layer 260 is, for example, larger than or equal to the thickness of the insulating layer 250. When the conductive layer 260 has a large thickness, the resistance of the conductive layer 260 can be reduced.

Furthermore, the conductive layer 260 preferably has a two-layer structure of the conductive layer 260a and the conductive layer 260b over the conductive layer 260a.

When the conductive layer 260a is formed using a conductive material having a function of inhibiting diffusion of oxygen, release of oxygen from the oxide semiconductor layer 230 can be inhibited and formation of oxygen vacancies in the oxide semiconductor layer 230 can be inhibited, for example.

Furthermore, the use of a conductive material that is not easily oxidized for the conductive layer 260a can inhibit the conductive layer 260a from being oxidized and thereby having a reduced conductivity owing to release of oxygen from the oxide semiconductor layer 230 or release of oxygen from the insulating layer 250, for example.

A material used for the conductive layer 260b preferably has higher conductivity than the material used for the conductive layer 260a, for example. When the conductive layer 260b has a large thickness, the amount of current flowing through the conductive layer 260b can be further increased.

When a deposition method with favorable coverage is used for the conductive layer 260a, the conductive layer 260a can be favorably formed along the sidewall of the opening portion 290.

For the conductive layer 260a, a conductive material containing nitrogen, a conductive material containing oxygen, or the like can be used, for example. For the conductive layer 260a, a conductive material containing oxygen and a metal element contained in the metal oxide where the channel is formed can be used, for example.

As the conductive layer 260a, for example, a conductive material containing the above metal element and nitrogen can be used; tantalum nitride, titanium nitride, ruthenium nitride, a nitride containing molybdenum, a nitride containing tungsten, titanium, and aluminum, a nitride containing tantalum and aluminum, or the like can be used, for example.

For the conductive layer 260a, a conductive material containing the above metal element and oxygen can be used, for example; examples of the conductive material include ruthenium oxide, an oxide containing strontium and ruthenium, and an oxide containing lanthanum and nickel.

One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may also be used.

For the conductive layer 260a, titanium, tantalum, ruthenium, or a material containing one or more selected from the metal elements is preferable because of being a conductive material that is not easily oxidized, a conductive material having a function of inhibiting diffusion of oxygen, or a material that maintains the conductivity even after absorbing oxygen.

For the conductive layer 260b, any of the above metal elements, an alloy containing any of the above metal elements as a component, an alloy containing a combination of the above metal elements, or the like can be used, for example. For example, tungsten can be used.

Furthermore, the conductive layer 260a may have a stacked-layer structure. Moreover, the conductive layer 260b may have a stacked-layer structure. In the case where the conductive layer 260a has a stacked-layer structure, a plurality of materials that can be used for the conductive layer 260a are stacked, for example. Alternatively, a plurality of materials selected from materials that can be used for the conductive layer of one embodiment of the present invention may be stacked. In the case where the conductive layer 260b has a stacked-layer structure, a plurality of materials that can be used for the conductive layer 260b are stacked, for example. Alternatively, a plurality of materials selected from materials that can be used for the conductive layer of one embodiment of the present invention may be stacked.

Each of the conductive layers 220 and 240 is in contact with the oxide semiconductor layer 230, and thus is preferably formed using a conductive material that is not easily oxidized, a conductive material that maintains its low electrical resistance even after being oxidized, an oxide conductive material, or a conductive material that has a function of inhibiting diffusion of oxygen. Examples of the conductive material include a conductive material containing nitrogen and a conductive material containing oxygen. Thus, a decrease in conductivity of the conductive layer 220 and the conductive layer 240 can be inhibited.

When a conductive material containing oxygen is used for the conductive layer 220 or the conductive layer 240, the conductive layer 220 or the conductive layer 240 can maintain its conductivity even after absorbing oxygen. It is also preferable that an insulating layer containing oxygen, such as hafnium oxide, be used as the insulating layer 210 in order that the conductive layer 220 can maintain its conductivity. For each of the conductive layers 220 and 240, ITO, ITSO, IZO (registered trademark), or the like is preferably used, for example.

In the case where the conductive layer 220 has a three-layer structure of a first conductive layer (e.g., the conductive layer 220a), a second conductive layer (e.g., the conductive layer 220b), and a third conductive layer (e.g., the conductive layer 220c) stacked in this order over the insulating layer 210, a conductive material that is not easily oxidized or a conductive material having a function of inhibiting diffusion of oxygen is preferably used for the first conductive layer, a material having high conductivity is preferably used for the second conductive layer, and a conductive material containing oxygen is preferably used for the third conductive layer. Specifically, for example, titanium nitride is preferably used for the first conductive layer, tungsten is preferably used for the second conductive layer, and ITO or ITSO is preferably used for the third conductive layer. In this case, titanium nitride is in contact with the insulating layer 210, and ITO or ITSO is in contact with the oxide semiconductor layer 230. Such a structure can maintain conductivity even when the conductive layer 220 is in contact with the oxide semiconductor layer 230. In the case of using an oxide insulating layer for the insulating layer 210, the conductive layer 220 can be inhibited from being excessively oxidized by the insulating layer 210. When tungsten with high conductivity is used for the second conductive layer, the conductivity of the conductive layer 220 can be increased.

In the case where the conductive layer 240 has a stacked-layer structure of two layers (e.g., the conductive layer 240a and the conductive layer 240b), for example, the lower layer is preferably formed using a material having higher conductivity than the upper layer and the upper layer is preferably formed using a conductive material containing oxygen. Specifically, for example, ruthenium, tungsten, titanium nitride, or tantalum nitride is preferably used for the lower layer, and ITO or ITSO is preferably used for the upper layer. In this case, ITO or ITSO is in contact with the oxide semiconductor layer 230. Such a structure can maintain conductivity even when the conductive layer 240 is in contact with the oxide semiconductor layer 230. When a material having higher conductivity than the upper layer is used for the lower layer, the conductivity of the conductive layer 240 can be increased.

In the case where the conductive layer 240 has a stacked-layer structure of two layers, a material having high conductivity may be used for the upper layer (e.g., the conductive layer 240b), and a conductive material containing oxygen may be used for the lower layer (e.g., the conductive layer 240a). In such a case, for example, when the oxide semiconductor layer 230 is in contact with the top surface of the conductive layer 240a, the contact resistance between the conductive layer 240 and the oxide semiconductor layer 230 can be reduced.

### [Oxide Semiconductor Layer 230]

As the oxide semiconductor layer 230, the oxide semiconductor layer 230 described in the above embodiment can be used.

Hydrogen contained in the oxide semiconductor reacts with oxygen bonded to a metal atom to be water, and thus sometimes forms an oxygen vacancy (V_{O}) in the oxide semiconductor. A defect where hydrogen enters an oxygen vacancy (hereinafter, referred to as V_{O}H) serves as a donor and generates an electron serving as a carrier in some cases. In other cases, bonding of part of hydrogen to oxygen bonded to a metal atom generates an electron serving as a carrier. Thus, a transistor including an oxide semiconductor that contains a large amount of hydrogen is likely to have normally-on characteristics (that is, the threshold voltage is likely to be a negative value). Moreover, hydrogen in an oxide semiconductor is easily transferred by a stress such as heat or an electric field; thus, a large amount of hydrogen in an oxide semiconductor might degrade the reliability of a transistor.

Accordingly, the amount of V_{O}H in the oxide semiconductor layer 230 is preferably reduced as much as possible so that the oxide semiconductor layer 230 becomes a highly purified intrinsic or substantially highly purified intrinsic oxide semiconductor. In sufficiently reducing the amount of V_{O}H in an oxide semiconductor, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as V_{O}H is used for the channel formation region of the transistor, the transistor can have stable electrical characteristics. Note that repairing oxygen vacancies by supplying oxygen to an oxide semiconductor is sometimes referred to as oxygen adding treatment.

The carrier concentration of the oxide semiconductor in a region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, and yet still further preferably lower than 1×10¹² cm⁻³. The minimum carrier density of an oxide semiconductor in the region functioning as the channel formation region is not limited and can be 1×10⁻⁹ cm⁻³, for example.

The influence of impurities in the metal oxide (oxide semiconductor) will be described here.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region in a transistor, the transistor can have stable electrical characteristics.

Note that for the semiconductor device of this embodiment, a transistor containing another semiconductor material in a channel formation region may be used. Examples of another semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also one kind of the compound semiconductor. These semiconductor materials may contain an impurity as a dopant.

Examples of silicon that can be used as a semiconductor material of a transistor include single crystal silicon, polycrystalline silicon, microcrystalline silicon, and amorphous silicon. An example of polycrystalline silicon is low-temperature polysilicon (LTPS).

Alternatively, a semiconductor layer of a transistor may include a layered material functioning as a semiconductor. The layered material generally refers to a group of materials having a layered crystal structure. In the layered crystal structure, layers formed by covalent bonding or ionic bonding are stacked with bonding such as the van der Waals bonding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include the above semiconductor substrates provided with an insulator region, such as a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided over the substrate include a capacitor, a resistor, a switching element, a light-emitting element, and a memory element.

### <Method for Manufacturing Semiconductor Device>

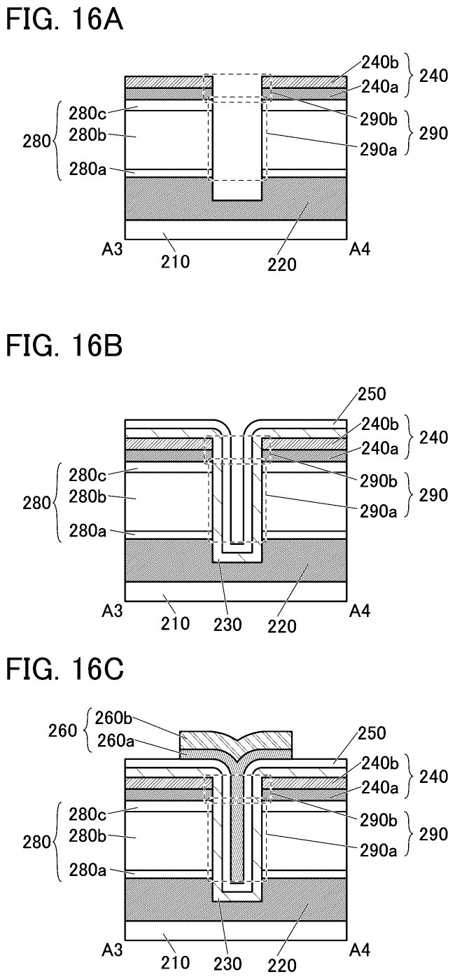

A method for manufacturing a semiconductor device is described with reference to FIGS. 16A to 16C. Here, a method for manufacturing the structure illustrated in FIGS. 7A to 7C is described as an example. Note that as for a material and a formation method of each component, portions similar to those described above are not described in some cases.

Thin films included in the semiconductor device (e.g., insulating films, semiconductor films, and conductive films) can be formed by a sputtering method, a CVD method, a vacuum evaporation method, a PLD method, an ALD method, or the like.

Examples of the sputtering method include an RF sputtering method in which a high-frequency power source is used for a sputtering power source, a DC sputtering method in which a DC power source is used, and a pulsed DC sputtering method in which a voltage is applied to an electrode while being changed in a pulsed manner. Furthermore, an RF superimposed DC sputtering method can be given. For deposition using an insulating target, an RF sputtering method is preferably used. A DC sputtering method is used mainly in the case of deposition using a conductive target. In a DC sputtering method, not only formation of a conductive film but also formation of an insulating film is possible when reactive sputtering is performed. The pulsed DC sputtering method is mainly used in the case where a compound such as an oxide, a nitride, or a carbide is deposited by a reactive sputtering method. In an RF superimposed DC sputtering method, the ion energy and the potential on the target side can be controlled during deposition. Thus, deposition-induced damage can be reduced as compared with that in the case of an RF sputtering method. Moreover, a high-quality film can be obtained.

As a sputtering method, for example, an ionization sputtering method, a long throw sputtering method, or the like can be used. The ionization sputtering method is a method in which a sputtering particle generated from a target is ionized by RF or the like and deposited with anisotropy by a self bias or the like. In the long throw sputtering method, the distance between a sputtering target and a substrate is long to enable deposition with anisotropy.

Note that CVD methods can be classified into a PECVD method, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during deposition.

As the ALD method, a thermal ALD method, in which a precursor and a reactant react with each other only by a thermal energy, a plasma-enhanced ALD (PEALD) method, in which a reactant excited by plasma is used, and the like can be used.

An ALD method enables atomic layers to be deposited one by one, and has advantages such as deposition of an extremely thin film, deposition on a component with a high aspect ratio, deposition of a film with few defects such as pinholes, deposition with excellent coverage, and low-temperature deposition. In the plasma-enhanced ALD (PEALD) method, the use of plasma is sometimes preferable for lower-temperature deposition. Note that a precursor used in the ALD method sometimes contains impurities such as carbon. Thus, a film formed by the ALD method may contain impurities such as carbon in a larger amount than a film formed by another film formation method. Note that impurities can be quantified by X-ray photoelectron spectroscopy (XPS) or secondary ion mass spectrometry (SIMS). The formation method of metal oxide of one embodiment of the present invention, which employs an ALD method and one or both of a deposition condition with a high substrate temperature and impurity removal treatment, might form a film with smaller amounts of carbon and chlorine than a method employing an ALD method and neither the condition nor the treatment.

Unlike in the film formation method in which particles ejected from a target or the like are deposited, a film is formed by reaction at a surface of an object in a CVD method and an ALD method. Thus, a CVD method and an ALD method can provide good step coverage, almost regardless of the shape of an object. In particular, an ALD method allows excellent step coverage and excellent thickness uniformity and can be suitably used to cover a surface of an opening portion with a high aspect ratio, for example. Note that an ALD method has a relatively low deposition rate; hence, in some cases, an ALD method is preferably combined with another deposition method with a high deposition rate, such as a sputtering method or a CVD method. For example, when the metal oxide has a stacked-layer structure of a first metal oxide and a second metal oxide, a method in which a sputtering method is used to form the first metal oxide, and an ALD method is used to form the second metal oxide over the first metal oxide can be given. For example, in the case where the first metal oxide has a crystal part, crystal growth occurs in the second metal oxide with the use of the crystal part as a nucleus.

When a CVD method or an ALD method is employed, the composition of a film can be controlled with the flow rate ratio of the source gases. For example, in a CVD method and an ALD method, a film with a certain composition can be formed by adjusting the flow rate ratio of the source gases. As another example, in a CVD method and an ALD method, by changing the flow rate ratio of the source gases during the film deposition, a film whose composition is continuously changed can be formed. In the case where a film is deposited while the flow rate ratio of the source gases is changed, as compared to the case where a film is deposited using a plurality of deposition chambers, the time taken for the deposition can be shortened because the time taken for transfer and pressure adjustment is omitted. Hence, the productivity of the semiconductor device can be improved in some cases.

In an ALD method, a film with a certain composition can be formed by adjusting the amount of introduced source gases, the number of times of introduction (also referred to as the number of pulses), and the time required for one pulse (also referred to as the pulse time) in an ALD method. Furthermore, an ALD method, with which a plurality of different kinds of precursors are introduced at a time, enables deposition of a film with desired composition. In the case where a plurality of different kinds of precursors are introduced, the cycle number of precursor deposition is controlled, whereby a film with desired composition can be deposited.

Thin films included in the semiconductor device (e.g., insulating films, semiconductor films, and conductive films) can be formed by a wet process such as spin coating, dipping, spray coating, ink-jetting, dispensing, screen printing, offset printing, doctor blade coating, slit coating, roll coating, curtain coating, or knife coating.

In processing a thin film included in the semiconductor device, a photolithography method or the like can be employed. Alternatively, the thin film may be processed by a nanoimprinting method, a sandblasting method, a lift-off method, or the like. Alternatively, an island-shaped thin film may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which any of the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV, X-rays, or an electron beam to perform extremely fine processing. Note that a photomask is not needed when light exposure is performed by scanning with a beam such as an electron beam.

For etching of a thin film, a dry etching method, a wet etching method, a sandblast method, or the like can be used.

First, the conductive layer 220 is formed over the insulating layer 210, the insulating layer 280 is formed over the conductive layer 220, and the conductive layer 240 is formed over the insulating layer 280. Here, the insulating layer 280 has a three-layer stacked structure of the insulating layer 280a, the insulating layer 280b, and the insulating layer 280c.

Note that it is preferable that the top surface of the deposited insulating layer 280 be planarized by planarization treatment by a chemical mechanical polishing (CMP) method (also referred to as CMP treatment). By the planarization treatment of the insulating layer 280, the surface on which the conductive layer 240 functioning as a wiring is to be formed can be made flat, whereby disconnection of the conductive layer 240 can be inhibited. Note that the planarization treatment is not necessarily performed, in which case the manufacturing cost can be reduced.

Next, the opening portion 290 is formed in the conductive layer 240 and the insulating layer 280 at a position overlapping with the conductive layer 220 (FIG. 16A). At this time, a depressed portion is formed in the conductive layer 220 at a position overlapping with the opening portion 290.

Since the opening portion 290 has a high aspect ratio, part of the conductive layer 240 and part of the insulating layer 280 are preferably processed by anisotropic etching. It is particularly preferable to use a dry etching method because it is suitable for microfabrication. The processing may be performed on the layers under different conditions.

Here, processing conditions which make the sidewalls of the conductive layer 240 and the insulating layer 280c have tapered shapes are preferably used. Furthermore, processing conditions which make the sidewall of the insulating layer 280b have a steep shape are preferably used.

The insulating layer 280a may be formed under processing conditions which make the sidewall of the insulating layer 280a have a tapered shape or processing conditions which make the sidewall of the insulating layer 280a have a steep shape.

Here, when the material of the insulating layer 280c and the material of the insulating layer 280b are appropriately selected, the insulating layer 280c and the insulating layer 280b can be formed into a tapered shape and a steep shape, respectively, by dry etching under the same conditions.

Next, heat treatment may be performed. For example, the heat treatment may be performed at a temperature higher than or equal to 100° C. and lower than or equal to 800° C., preferably higher than or equal to 250° C. and lower than or equal to 650° C., further preferably higher than or equal to 350° C. and lower than or equal to 550° C. For example, the treatment time at a temperature higher than or equal to 350° C. and lower than or equal to 550° C. is longer than or equal to 1 minute and shorter than or equal to 1 hour, or longer than or equal to 10 minutes and shorter than or equal to 30 minutes.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. By the above-described heat treatment, impurities such as water contained in the insulating layer 280, for example, can be reduced before the oxide semiconductor layer 230 is deposited.

The gas used in the above heat treatment preferably has high purity. For example, the amount of moisture contained in the gas used in the above heat treatment is preferably 1 ppb or less, further preferably 0.1 ppb or less, still further preferably 0.05 ppb or less. The heat treatment using a highly purified gas can prevent the entry of moisture or the like into the insulating layer 280 as much as possible.

An opening may be formed in the conductive layer 240 and the insulating layer 280 using the same mask or different masks.

Next, the oxide semiconductor layer 230 is formed to cover the opening portion 290. The oxide semiconductor layer 230 is formed in contact with the top surface of the conductive layer 220, the side surface of the insulating layer 280, and the top surface and the side surface of the conductive layer 240.

The oxide semiconductor layer 230 can be formed by stacking a plurality of layers. Here, a first layer, a second layer, and a third layer are formed in this order to form the oxide semiconductor layer 230.

The first layer is preferably formed by a film formation method that causes less damage to the insulating layer 280 and does not cause alloying with the insulating layer 280. For example, the first layer is preferably formed by an ALD method, a PECVD method, a thermal CVD method, an MOCVD method, an MBE method, or the like.

The oxide semiconductor layer 230 preferably has a high aspect ratio and high coverage on a sidewall and a bottom portion of the opening portion 290 with a minute aperture diameter. Thus, at least some layers of the plurality of layers formed as the oxide semiconductor layer 230 are preferably formed by a method that provides good coverage. In particular, by an ALD method, a film with a small variation in thickness can be formed along the top surface of the conductive layer 220, the side surface of the insulating layer 280, and the side surface of the conductive layer 240 in the opening portion 290.

The oxide semiconductor layer 230 preferably has high crystallinity. When the oxide semiconductor layer 230 has high crystallinity, diffusion of impurities in the oxide semiconductor layer 230 is inhibited, leading to a small variation in electrical characteristics and high reliability of the transistor. For example, a metal oxide deposited by a sputtering method is likely to have high crystallinity. Thus, when at least one layer of the plurality of layers formed as the oxide semiconductor layer 230 is formed by a sputtering method, the oxide semiconductor layer 230 can have crystallinity.

Meanwhile, a sputtering method provides lower coverage in some cases than an ALD method or the like. Thus, in consideration of the coverage on the sidewall and the bottom portion of the opening portion 290, in the case where one of the plurality of layers formed as the oxide semiconductor layer 230 is formed by a sputtering method, the other layers are preferably formed by a method that provides good coverage.

For the method for forming the oxide semiconductor layer 230, Embodiments described above can be referred to. Here, first, the oxide semiconductor layer 230a is formed (not illustrated).

Next, the oxide semiconductor layer 230b is formed by a sputtering method (not illustrated).

Next, the oxide semiconductor layer 230c is formed by an ALD method (not illustrated).

Heat treatment may be performed subsequent to the formation of the oxide semiconductor layer 230c. By performing the heat treatment, the crystallinity of the oxide semiconductor layer 230 can be increased, for example. In particular, the crystallinity of the oxide semiconductor layer 230a and the oxide semiconductor layer 230c can be increased. For the heat treatment, the heat treatment conditions and the heat treatment method described in Embodiment 1 can be used, for example. Heat treatment is not necessarily performed subsequent to the formation of the oxide semiconductor layer 230c. For example, the heat treatment may be performed after the formation of the insulating layer 250 described later. Alternatively, for example, the crystallinity of the oxide semiconductor layer 230 can be increased by using heat at the time of forming the conductive layer 260 described later.

Next, the conductive layer 240 and the oxide semiconductor layer 230 are processed into island shapes (FIG. 16B). Here, the conductive layer 240 and the oxide semiconductor layer 230 can be processed collectively with the use of the same mask.

Note that the step of processing the conductive layer 240 into an island shape and the step of processing the oxide semiconductor layer 230 into an island shape may be performed independently of each other. In this case, for example, the step of processing the conductive layer 240 into an island shape and the step of providing the opening portion 290 in the conductive layer 240 can be performed independently of each other, in which case, either of the steps may be performed first. Alternatively, after light exposure using a mask for processing into a quadrangular island shape and light exposure using a mask for providing a circular opening portion are performed, etching may be performed to collectively perform processing into the island shape and formation of the opening portion. Exposure using a multi-tone mask (typically a half-tone mask or a gray-tone mask) may be used.

Next, the insulating layer 250 is formed over the oxide semiconductor layer 230 and the insulating layer 280. The insulating layer 250 is formed in contact with the oxide semiconductor layer 230.

The crystallinity of the oxide semiconductor layer 230 can be increased in some cases by using heat in the formation of the insulating layer 250. For example, when the film formation temperature of the insulating layer is higher than or equal to 250° C., preferably higher than or equal to 350° C., the crystallinity of the oxide semiconductor layer 230 is sometimes increased by heat in the formation of the insulating layer.

Heat treatment may be performed subsequent to the formation of the insulating layer 250. By performing the heat treatment, the crystallinity of the oxide semiconductor layer 230 can be increased, for example. In particular, the crystallinity of the oxide semiconductor layer 230c and the oxide semiconductor layer 230b can be increased. Heat treatment is not necessarily performed subsequent to the formation of the insulating layer 250.

For example, the heat treatment may be performed at a temperature higher than or equal to 100° C. and lower than or equal to 800° C., preferably higher than or equal to 250° C. and lower than or equal to 650° C., further preferably higher than or equal to 350° C. and lower than or equal to 550° C. For example, the treatment time at a temperature higher than or equal to 350° C. and lower than or equal to 550° C. is longer than or equal to 1 minute and shorter than or equal to 1 hour, or longer than or equal to 10 minutes and shorter than or equal to 30 minutes.

As a gas used in the heat treatment, a nitrogen gas, an inert gas, or an oxidizing gas can be used. For example, the heat treatment is performed in a nitrogen gas atmosphere, an inert gas atmosphere, or an atmosphere containing an oxidizing gas at 10 ppm or more, 1% or more, or 10% or more. By the heat treatment using an oxygen gas, impurities such as carbon, water, and hydrogen in the oxide semiconductor layer 230 can be reduced.

This heat treatment may be performed under a reduced pressure.

In the case where the insulating layer 280 contains oxygen, oxygen is preferably supplied from the insulating layer 280 to the channel formation region of the oxide semiconductor layer 230 by the heat treatment. Accordingly, oxygen vacancies and V_{O}H can be reduced.

Next, a conductive layer to be the conductive layer 260a is formed over the insulating layer 250. The conductive layer to be the conductive layer 260a is formed to cover the top surface of the conductive layer 220, the side surface of the insulating layer 280, and the top and side surfaces of the conductive layer 240 with the oxide semiconductor layer 230 and the insulating layer 250 therebetween. Next, a conductive layer to be the conductive layer 260b is formed.

The conductive layer 260a and the conductive layer 260b are formed in contact with the insulating layer 250 provided in the opening portion 290 with a high aspect ratio. Thus, the conductive layer to be the conductive layer 260a and the conductive layer to be the conductive layer 260b are each preferably formed by a deposition method with favorable coverage, further preferably formed by an ALD method, a metal CVD method, or the like.

Here, the crystallinity of the oxide semiconductor layer 230 can be increased in some cases by using heat in the formation of a conductive layer to be the conductive layer 260. For example, when the film formation temperature of the conductive layer to be the conductive layer 260 is higher than or equal to 250° C., preferably higher than or equal to 350° C., the crystallinity of the oxide semiconductor layer 230 is sometimes increased by heat in the formation of the conductive layer. Here, for example, the conductive layer is formed by a metal CVD method at a temperature higher than or equal to 250° C.

Next, part of the conductive layer to be the conductive layer 260b and part of the conductive layer to be the conductive layer 260a are removed using a mask, whereby the conductive layer 260b and the conductive layer 260a are formed (FIG. 16C).

Next, the insulating layer 283 is formed over the conductive layer 260. Then, the insulating layer 285 is formed over the insulating layer 283.

Here, the crystallinity of the oxide semiconductor layer 230 can be increased in some cases by using heat in the formation of the insulating layer 283 and the insulating layer 285. For example, when the film formation temperature of the insulating layer is higher than or equal to 250° C., preferably higher than or equal to 350° C., the crystallinity of the oxide semiconductor layer 230 is sometimes increased by heat in the formation of the insulating layer. Here, for example, the insulating layer 283 is formed by an ALD method at a temperature higher than or equal to 250° C., and then the insulating layer 285 is formed by a sputtering method.

Through the above steps, the semiconductor device of one embodiment of the present invention can be manufactured.

This embodiment can be combined with any of the other embodiments as appropriate. In this specification, in the case where a plurality of structure examples are shown in one embodiment, the structure examples can be combined as appropriate.

### Embodiment 3

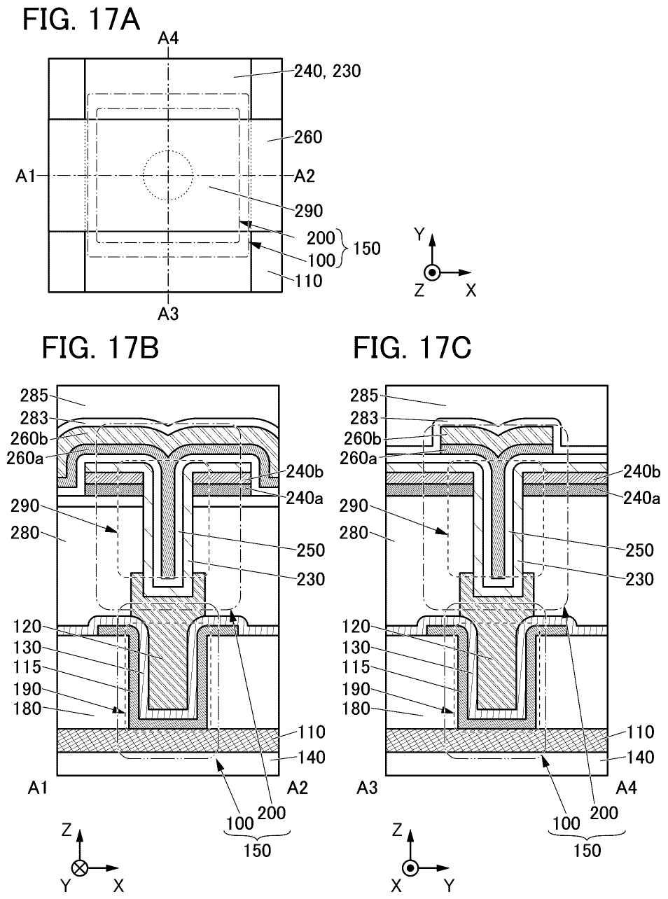

In this embodiment, memory devices of one embodiment of the present invention will be described with reference to FIGS. 17A to 17C, FIGS. 18A and 18B, FIGS. 19A and 19B, FIG. 20, and FIG. 21. The semiconductor device of one embodiment of the present invention can be used as a memory device. The memory device of one embodiment of the present invention includes a memory cell. The memory cell includes a transistor and a capacitor.

### <Structure Example 1 of Memory Device>

A structure of a memory device including a transistor and a capacitor is described with reference to FIGS. 17A to 17C. FIG. 17A is a plan view of a memory device including the transistor 200 and a capacitor 100. FIG. 17B is a cross-sectional view taken along dashed-dotted line A1-A2 in FIG. 17A. FIG. 17C is a cross-sectional view taken along dashed-dotted line A3-A4 in FIG. 17A.

The memory device illustrated in FIGS. 17A to 17C includes an insulating layer 140 over a substrate (not illustrated), a conductive layer 110 over the insulating layer 140, a memory cell 150 over the conductive layer 110, an insulating layer 180 over the conductive layer 110, the insulating layer 280, the insulating layer 283 over the memory cell 150. The insulating layer 140, the insulating layer 180, the insulating layer 280, and the insulating layer 283 function as interlayer films. The conductive layer 110 functions as a wiring.

The memory cell 150 includes the capacitor 100 over the conductive layer 110 and the transistor 200 over the capacitor 100.

The capacitor 100 includes a conductive layer 115 over the conductive layer 110, an insulating layer 130 over the conductive layer 115, and a conductive layer 120 over the insulating layer 130. The conductive layer 120 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 is a metal-insulator-metal (MIM) capacitor.

As illustrated in FIGS. 17B and 17C, the opening portion 190 reaching the conductive layer 110 is provided in the insulating layer 180. At least part of the conductive layer 115 is placed in the opening portion 190. Note that the conductive layer 115 includes a region in contact with the top surface of the conductive layer 110 in the opening portion 190, a region in contact with the side surface of the insulating layer 180 in the opening portion 190, and a region in contact with at least part of the top surface of the insulating layer 180. The insulating layer 130 is placed so that at least part of the insulating layer 130 is positioned in the opening portion 190. The conductive layer 120 is placed so that at least part of the conductive layer 120 is positioned in the opening portion 190. Note that the conductive layer 120 is preferably provided to fill the opening portion 190 as illustrated in FIGS. 17B and 17C. Note that the films provided inside the opening portion 190 are preferably formed by a method enabling high coverage, such as an ALD method. Thus, the coverage with the films can be improved. For example, the conductive layer 115, the insulating layer 130, and the conductive layer 120 are preferably formed by an ALD method, a metal CVD method, or the like.

The upper electrode and the lower electrode of the capacitor 100 face each other with the dielectric therebetween, along the side surface of the opening portion 190 as well as the bottom surface thereof; thus, the capacitance per unit area can be larger. Accordingly, the deeper the opening portion 190 is, the larger the capacitance of the capacitor 100 can be. Increasing the capacitance per unit area of the capacitor 100 in this manner allows stable reading operation of the memory device. This also allows further miniaturization or high integration of the memory device.

FIGS. 17B and 17C illustrate an example where the sidewall of the opening portion 190 is perpendicular to the top surface of the conductive layer 110. At this time, the opening portion 190 has a cylindrical shape. Such a structure enables miniaturization or high integration of the memory device.

The conductive layer 115 and the insulating layer 130 are stacked along the sidewall of the opening portion 190 and the top surface of the conductive layer 110. The conductive layer 120 is provided over the insulating layer 130 to fill the opening portion 190. The capacitor 100 having such a structure may be referred to as a trench-type capacitor or a trench capacitor.

The insulating layer 280 is provided over the capacitor 100. That is, the insulating layer 280 is positioned over the conductive layer 115, the insulating layer 130, and the conductive layer 120. In other words, the conductive layer 120 is positioned under the insulating layer 280.

The transistor 200 includes the conductive layer 120 (corresponding to the conductive layer 220 in FIG. 7B or the like), the conductive layer 240 over the insulating layer 280, the oxide semiconductor layer 230, the insulating layer 250 over the oxide semiconductor layer 230, and the conductive layer 260 over the insulating layer 250. The oxide semiconductor layer 230 functions as the semiconductor layer, the conductive layer 260 functions as the gate electrode, the insulating layer 250 functions as the gate insulating layer, the conductive layer 120 functions as one of the source electrode and the drain electrode, and the conductive layer 240 functions as the other of the source electrode and the drain electrode.

The description in Embodiment 1 (FIGS. 7A to 7C, FIGS. 9A and 9B, and the like) can be referred to for the transistor 200; thus, the detailed description thereof is omitted. The transistor included in the memory cell 150 is not limited to the transistor 200 in FIGS. 7A to 7C, FIGS. 9A and 9B, and the like, and any of the transistors described as examples in Embodiment 1 can be used.

As illustrated in FIGS. 17A to 17C, the transistor 200 is provided to overlap with the capacitor 100. The opening portion 290 where part of the components of the transistor 200 is provided includes a region overlapping with the opening portion 190 where part of the components of the capacitor 100 is provided. In particular, since the conductive layer 120 has a function of one of the source electrode and the drain electrode of the transistor 200 and a function of the upper electrode of the capacitor 100, the transistor 200 and the capacitor 100 share part of the structure. With such a structure, the transistor 200 and the capacitor 100 can be provided without an increase in the area in the plan view. Thus, the area of the memory cell 150 can be reduced, so that the memory cells 150 can be arranged densely and the storage capacity of the memory device can be increased. In other words, the memory device can be highly integrated.

When the transistor 200 is provided above the capacitor 100, the transistor 200 is not affected by heat treatment in manufacturing the capacitor 100. Thus, in the transistor 200, degradation of the electrical characteristics such as variation in threshold voltage or an increase in parasitic resistance, and an increase in variation in electrical characteristics due to the degradation of the electrical characteristics can be inhibited.

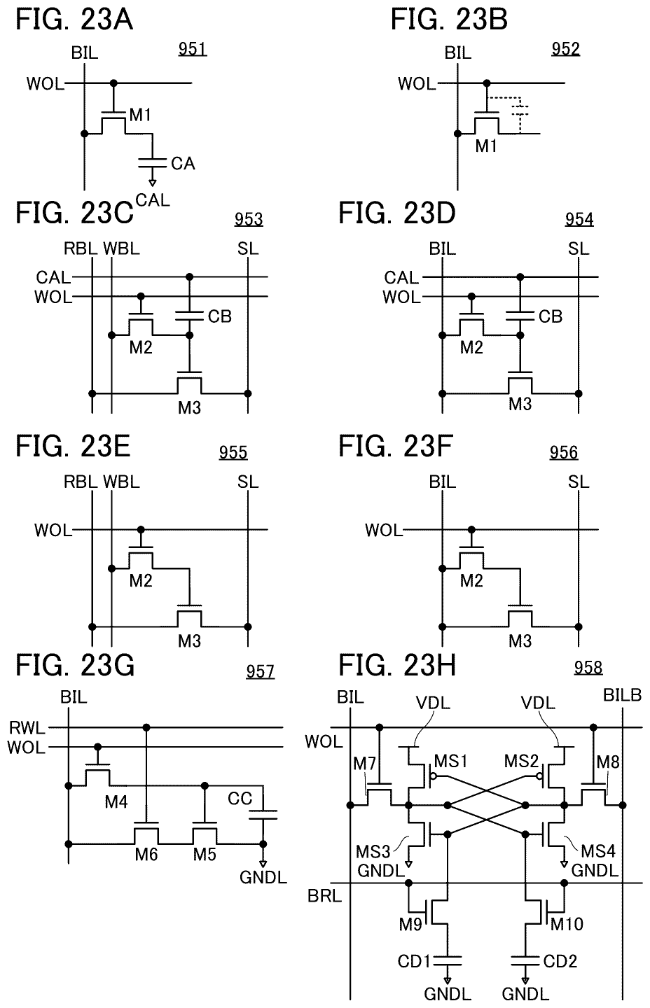

FIG. 23A is a circuit diagram of the memory device described in this embodiment. As illustrated in FIG. 23A, the structure illustrated in FIGS. 17A to 17C functions as a memory cell. A memory cell 951 includes a transistor MI and a capacitor CA. Here, the transistor M1 corresponds to the transistor 200, and the capacitor CA corresponds to the capacitor 100.

One of a source and a drain of the transistor M1 is connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to a wiring CAL.

Here, the wiring BIL corresponds to the conductive layer 240, the wiring WOL corresponds to the conductive layer 260, and the wiring CAL corresponds to the conductive layer 110. As illustrated in FIGS. 17A to 17C, it is preferable that the conductive layer 260 be provided to extend in the X direction and the conductive layer 240 be provided to extend in the Y direction. With such a structure, the wiring BIL and the wiring WOL are provided to intersect with each other. Although the wiring CAL (the conductive layer 110) is provided in a plane shape in FIG. 17A, the present invention is not limited thereto. For example, the wiring CAL may be provided parallel to the wiring WOL (the conductive layer 260) or the wiring BIL (the conductive layer 240).

Note that the memory cell will be described in detail in a later embodiment.

### [Capacitor 100]

The capacitor 100 includes the conductive layer 115, the insulating layer 130, and the conductive layer 120. The conductive layer 110 is provided below the conductive layer 115. The conductive layer 115 includes a region in contact with the conductive layer 110.

The conductive layer 110 is provided over the insulating layer 140. The conductive layer 110 functions as the wiring CAL and can be provided in a plane shape, for example. The conductive layer 110 can be formed as a single layer or stacked layers using the conductive material described in [Conductive layer] in Embodiment 1. For example, a conductive material with high conductivity such as tungsten can be used for the conductive layer 110. With the use of a conductive material with high conductivity, the conductivity of the conductive layer 110 can be improved and the wiring CAL can function sufficiently.

For the conductive layer 115, a single layer or stacked layers of a conductive material that is less likely to be oxidized, a conductive material having a function of inhibiting diffusion of oxygen, or the like is preferably used. For example, titanium nitride, indium tin oxide to which silicon is added, or the like may be used. Alternatively, a structure where titanium nitride is stacked over tungsten may be used, for example. Alternatively, a structure where tungsten is stacked over first titanium nitride and second titanium nitride is stacked over the tungsten may be used, for example. With such a structure, when an oxide is used for the insulating layer 130, the conductive layer 110 can be inhibited from being oxidized by the insulating layer 130. When an oxide is used for the insulating layer 180, the conductive layer 110 can be inhibited from being oxidized by the insulating layer 180.

The insulating layer 130 is provided over the conductive layer 115. The insulating layer 130 can be provided to be in contact with the top and side surfaces of the conductive layer 115. That is, the insulating layer 130 preferably covers the side end portion of the conductive layer 110. This can prevent a short circuit between the conductive layer 115 and the conductive layer 120.

Alternatively, the side end portion of the insulating layer 130 and the side end portion of the conductive layer 115 may be aligned with each other. With such a structure, the insulating layer 130 and the conductive layer 115 can be formed using the same mask, so that the manufacturing process of the memory device can be simplified.

For the insulating layer 130, a material with a high dielectric constant (a high-k material) is preferably used. Using such a high-k material for the insulating layer 130 allows the insulating layer 130 to be thick enough to inhibit a leakage current and the capacitor 100 to have a sufficiently high capacitance.

The insulating layer 130 preferably has a stacked-layer structure using an insulating layer that contains a high-k material. A stacked-layer structure containing a material with a high dielectric constant (a high-k material) and a material with higher dielectric strength than the high-k material is preferably used. For example, as the insulating layer 130, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulating layer having relatively high dielectric strength, such as aluminum oxide, can increase the dielectric strength and inhibit electrostatic breakdown of the capacitor 100.

Alternatively, a material that can have ferroelectricity may be used for the insulating layer 130. Description in Embodiment 1 can also be referred to for the details of the material that can have ferroelectricity.

A metal oxide containing one or both of hafnium and zirconium is preferable as the insulating layer 130 because the metal oxide can have ferroelectricity even when being a thin film of several nanometers. The thickness of the insulating layer 130 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). For example, the thickness is preferably greater than or equal to 8 nm and less than or equal to 12 nm. With the use of the ferroelectric layer that can have a small thickness, the capacitor 100 can be combined with a miniaturized semiconductor element such as a transistor to fabricate a semiconductor device.

A metal oxide containing one or both of hafnium and zirconium is preferable as the insulating layer 130 because the metal oxide can have ferroelectricity even with a minute area. For example, a ferroelectric layer can have ferroelectricity even with an area (occupying area) less than or equal to 100 μm², less than or equal to 10 μm², less than or equal to 1 μm², or less than or equal to 0.1 μm² in a plan view. Furthermore, even with an area of less than or equal to 10000 nm² or less than or equal to 1000 nm², a ferroelectric layer can have ferroelectricity in some cases. With a small-area ferroelectric layer, the area occupied by the capacitor 100 can be reduced.

The ferroelectric refers to an insulator having a property of causing internal polarization by application of an electric field from the outside and maintaining the polarization even after the electric field is made zero. Thus, with the use of a capacitor that contains this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

The conductive layer 120 is provided in contact with part of the top surface of the insulating layer 130. The side end portion of the conductive layer 120 is preferably positioned inside the side end portion of the conductive layer 115 in both the X direction and the Y direction. Note that in the structure where the insulating layer 130 covers the side end portion of the conductive layer 115, the side end portion of the conductive layer 120 may be positioned outside the side end portion of the conductive layer 115.

The conductive layer 120 can be formed to have a single-layer structure or a stacked-layer structure using any of the conductive materials described in [Conductive layer] in Embodiment 1. A conductive material that is not easily oxidized, a conductive material having a function of inhibiting diffusion of oxygen, or the like is preferably used for the conductive layer 120. For example, titanium nitride, tantalum nitride, or the like can be used. For example, a structure in which tantalum nitride is stacked over titanium nitride may be used. In that case, titanium nitride is in contact with the insulating layer 130 and tantalum nitride is in contact with the oxide semiconductor layer 230. With such a structure, the conductive layer 120 can be inhibited from being excessively oxidized by the oxide semiconductor layer 230. In the case of using an oxide for the insulating layer 130, the conductive layer 120 can be inhibited from being excessively oxidized by the insulating layer 130. Alternatively, the conductive layer 120 may have a structure in which tungsten is stacked over titanium nitride, for example.

The conductive layer 120 includes a region in contact with the oxide semiconductor layer 230 and thus is preferably formed using a conductive material containing oxygen. When a conductive material containing oxygen is used for the conductive layer 120, the conductive layer 120 can maintain its conductivity even when absorbing oxygen. It is also preferable that an insulating layer containing oxygen, such as zirconium oxide, be used as the insulating layer 130 in order that the conductive layer 120 can maintain its conductivity. As the conductive layer 120, a single layer or a stacked layer of ITO, ITSO, IZO (registered trademark), or the like can be used, for example.

The insulating layer 180 functions as an interlayer film and preferably has a low dielectric constant. In the case where a material with a low dielectric constant is used for an interlayer film, the parasitic capacitance between wirings can be reduced. As the insulating layer 180, an insulating layer containing a material with a low dielectric constant can be used as a single layer or stacked layers. Silicon oxide and silicon oxynitride, which have thermal stability, are preferable.

Although the insulating layer 180 has a single-layer structure in FIGS. 17B and 17C, the present invention is not limited thereto. The insulating layer 180 may have a stacked-layer structure of two layers or three or more layers.

### <Structure Example 2 of Memory Device>

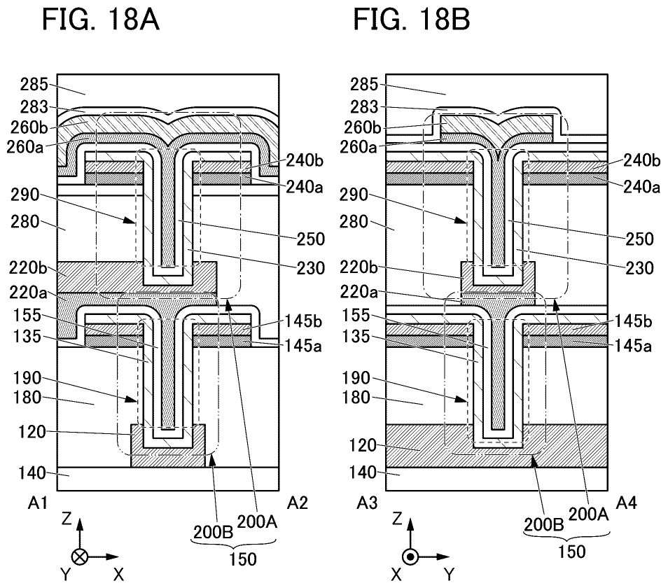

FIGS. 18A and 18B are cross-sectional views of a memory device including a transistor 200A and a transistor 200B.

The memory device illustrated in FIGS. 18A and 18B includes the insulating layer 140 over a substrate (not illustrated), the memory cell 150 over the insulating layer 140, the insulating layer 180 over the insulating layer 140, the insulating layer 280, the insulating layer 283, and the insulating layer 285. The insulating layer 140, the insulating layer 180, the insulating layer 280, the insulating layer 283, and the insulating layer 285 function as interlayer films.

The memory cell 150 includes the transistor 200B over the insulating layer 140 and the transistor 200A over the transistor 200B.

The description of the transistor 200 in FIGS. 9A and 9B and the like in Embodiment 2 can be referred to for the transistor 200A; thus, the detailed description thereof is omitted. The conductive layer 220 (a two-layer structure of the conductive layer 220a and the conductive layer 220b over the conductive layer 220a in FIGS. 18A and 18B) of the transistor 200A can function as a gate electrode of the transistor 200B. The insulating layer 180 and the conductive layer 145 include the opening portion 190. FIGS. 18A and 18B illustrate an example in which the conductive layer 145 has a stacked-layer structure of a conductive layer 145a and a conductive layer 145b over the conductive layer 145a. The conductive layer 120 has a depressed portion overlapping with the opening portion 190. The transistor 200B includes the conductive layer 120, the conductive layer 145 over the insulating layer 180, the semiconductor layer 135 provided to be in contact with the bottom surface and the side surface of the depressed portion of the conductive layer 120, the side surface of the opening portion 190, and the top surface of the insulating layer 180, and the insulating layer 155 over the semiconductor layer 135. The conductive layer 220a is provided over the insulating layer 155 and includes a region positioned in the opening portion 190. For the conductive layer 120, the conductive layer 145a, the conductive layer 145b, the semiconductor layer 135, and the insulating layer 155 of the transistor 200B, the conductive layer 220, the conductive layer 240a, the conductive layer 240b, the oxide semiconductor layer 230, and the insulating layer 250 included in the transistor 200 in FIGS. 9A and 9B in Embodiment 2 can be referred to. The transistors included in the memory cell 150 are not limited to the combination of the transistor 200A and the transistor 200B, and one or more kinds of the transistors described in Embodiment 2 can be used.

In the memory cell 150 illustrated in FIGS. 18A and 18B, the capacitance generated between the conductive layer 220a and the conductive layer 145 can be used; thus, data can be retained without forming of an additional capacitor.

As illustrated in FIGS. 18A and 18B, the transistor 200B is provided to overlap with the transistor 200A. The opening portion 290 includes a region overlapping with the opening portion 190. Since the conductive layer 220a and the conductive layer 220b have a function of one of the source electrode and the drain electrode of the transistor 200A and a function of the gate electrode of the transistor 200B, the transistor 200A and the transistor 200B share part of the structure. With such a structure, the transistor 200A and the transistor 200B can be provided without an increase in the area in a plan view. Thus, the area of the memory cell 150 can be reduced, so that the memory cells 150 can be arranged densely and the storage capacity of the memory device can be increased. In other words, the memory device can be highly integrated.

FIG. 23E is a circuit diagram of the memory device described in this embodiment. As illustrated in FIG. 23E, the structure illustrated in FIGS. 18A and 18B functions as a memory cell. A memory cell 955 includes a transistor M2 and a transistor M3. Here, the transistor M2 corresponds to the transistor 200A and the transistor M3 corresponds to the transistor 200B.

One of a source and a drain of the transistor M2 is electrically connected to a gate of the transistor M3. The other of the source and the drain of the transistor M1 is connected to a wiring WBL. A gate of the transistor M2 is connected to the wiring WOL. One of a source and a drain of the transistor M3 is electrically connected to a wiring RBL. The other of the source and the drain of the transistor M3 is connected to a wiring SL.

The wiring WBL corresponds to the conductive layer 240 and the wiring WOL corresponds to the conductive layer 260.

### <Structure Example 3 of Memory Device>

The memory cell 150 including the transistor 200 and the capacitor 100 described in this embodiment can be used as a memory cell of the memory device. The transistor 200 is a transistor whose channel is formed in a semiconductor layer containing an oxide semiconductor. Since the transistor 200 has a low off-state current, a memory device including the transistor 200 can retain stored data for a long time. In other words, such a memory device does not require refresh operation or has an extremely low frequency of refresh operation, leading to a sufficient reduction in power consumption. The transistor 200 has high frequency characteristics and thus enables the memory device to perform reading and writing at high speed.

The memory cells 150 are arranged in a matrix three-dimensionally, whereby a memory cell array can be formed.

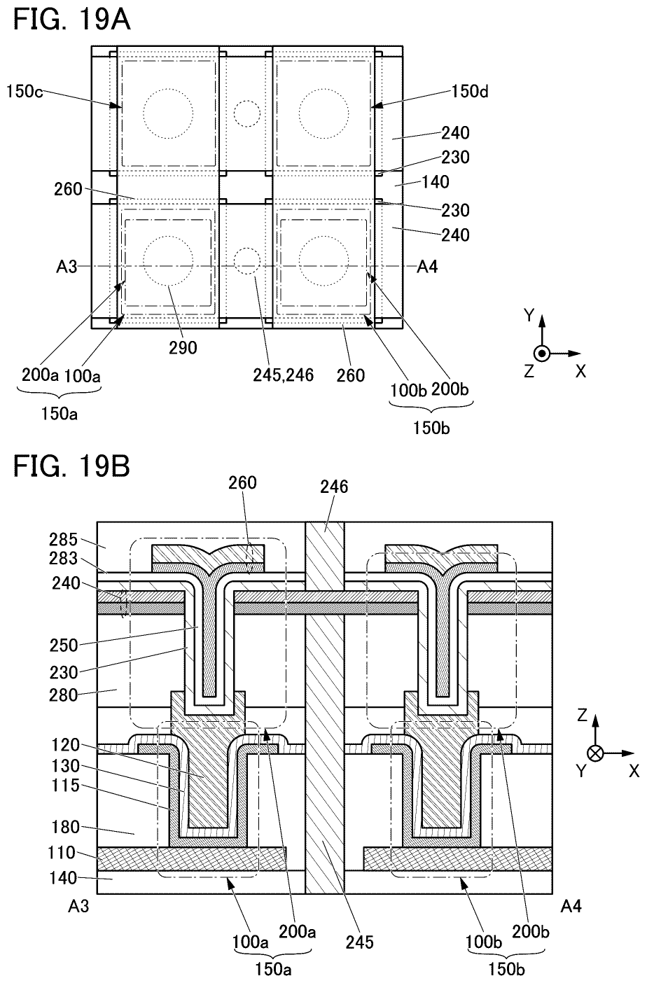

FIG. 19A is a plan view of a memory device. FIG. 19A illustrates an example where 2×2 memory cells (a memory cell 150a to a memory cell 150d) are arranged in the X direction and the Y direction.

FIG. 19B is a cross-sectional view taken along dashed-dotted line A3-A4 in FIG. 19A. In FIGS. 19A and 19B, two memory cells (the memory cells 150a and 150b in FIG. 19B) are connected to a common wiring (a conductive layer 246).

Here, the memory cells 150a and 150b illustrated in FIGS. 19A and 19B each have a structure similar to that of the memory cell 150. The memory cell 150a includes a capacitor 100a and a transistor 200a, and the memory cell 150b includes a capacitor 100b and a transistor 200b. The memory cells 150c and 150d illustrated in FIG. 19A each have a structure similar to that of the memory cell 150. Thus, in the memory device illustrated in FIGS. 19A and 19B, components having the same functions as the components of the memory device illustrated in FIGS. 17A to 17C are denoted by the same reference numerals. The description of the memory cell 150 in <Structure example 1 of memory device> can be referred to for the details of the memory cells 150a to 150d.

As illustrated in FIGS. 19A and 19B, the conductive layer 260 functioning as the wiring WOL is provided in each of the memory cells 150a and 150b. As illustrated in FIG. 19A, one conductive layer 260 is shared by the memory cells 150a and 150c, and another conductive layer 260 is shared by the memory cells 150b and 150d. One conductive layer 240 functioning as part of the wiring BIL is shared by the memory cells 150a and 150b. That is, the conductive layer 240 is in contact with the oxide semiconductor layer 230 of the memory cell 150a and the oxide semiconductor layer 230 of the memory cell 150b. Another conductive layer 240 is shared by the memory cells 150c and 150d.

Here, the memory device illustrated in FIGS. 19A and 19B includes the conductive layers 245 and 246 functioning as plugs (also can be referred to as connection electrodes) electrically connected to the memory cells 150a and 150b. The conductive layer 245 is placed in an opening portion formed in the insulating layers 140, 180, 130, and 280, and is in contact with the bottom surface of the conductive layer 240. The conductive layer 246 is placed in an opening portion formed in the insulating layer 285, the insulating layer 283, and the insulating layer 250, and is in contact with the top surface of the conductive layer 240. Note that a conductive material that can be used for the conductive layer 240, for example, can be used for the conductive layers 245 and 246.

The conductive layers 245 and 246 each function as a plug or a wiring for electrically connecting the memory cells 150a and 150b to a wiring, an electrode, a terminal, or a circuit element such as a switch, a transistor, a capacitor, an inductor, a resistor, or a diode. For example, the conductive layer 245 can be electrically connected to a sense amplifier (not illustrated) provided below the memory device illustrated in FIG. 19B, and the conductive layer 246 can be electrically connected to a similar memory device (not illustrated) provided above the memory device illustrated in FIG. 19B. In this case, the conductive layers 245 and 246 function as part of the wiring BIL. When the memory device or the like is provided above or below the memory device illustrated in FIG. 19B in this manner, the storage capacity per unit area can be increased.

The memory cells 150a and 150b have a line-symmetric structure with a perpendicular bisector of the dashed-dotted line A3-A4 as the symmetric axis. Thus, the transistors 200a and 200b are also placed symmetrically with the conductive layers 245 and 246 therebetween. Note that the conductive layer 240 has a function of the other of the source electrode and the drain electrode of the transistor 200a and a function of the other of the source electrode and the drain electrode of the transistor 200b. The transistors 200a and 200b share the conductive layers 245 and 246 functioning as plugs. With the above connection structure between the two transistors and the plugs, a memory device that can be miniaturized or highly integrated can be provided.

Note that the conductive layer 110 functioning as the wiring CAL may be provided in each of the memory cells 150a and 150b or may be provided in common to the memory cells 150a and 150b. However, as illustrated in FIG. 19B, the conductive layer 110 is provided to be apart from the conductive layer 245 so that the conductive layers 110 and 245 are not short-circuited.

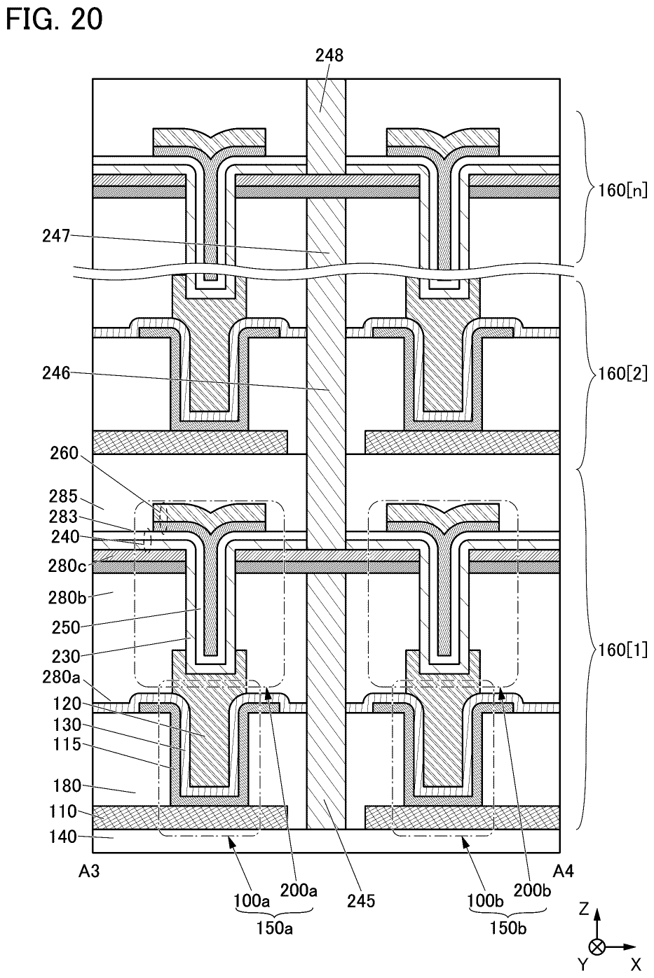

FIG. 20 illustrates an example where four memory cells illustrated in FIG. 19A are stacked in n layers (n is an integer greater than or equal to 3) in the Z direction. FIG. 20 is a cross-sectional view taken along dashed-dotted line A3-A4 in FIG. 19A.

The memory device illustrated in FIG. 20 includes n memory layers 160. Specifically, a memory layer 160 [2] is provided over a memory layer 160 [1], (n-2) memory layers are provided over the memory layer 160 [2], and a memory layer 160 [n] is provided in the uppermost stage. There is no particular limitation on the number of memory cells included in one memory layer 160, and two or more memory cells can be included. Through the conductive layer 245, the conductive layer 246, a conductive layer 247, a conductive layer 248, and the like, memory cells included in the n memory layers 160 are electrically connected to a sense amplifier (not illustrated) provided below the n memory layers 160.

When a plurality of memory cells are stacked as illustrated in FIG. 20, the cells can be provided in an integrated manner without increasing the area occupied by the memory cell array. That is, a 3D memory cell array can be formed.

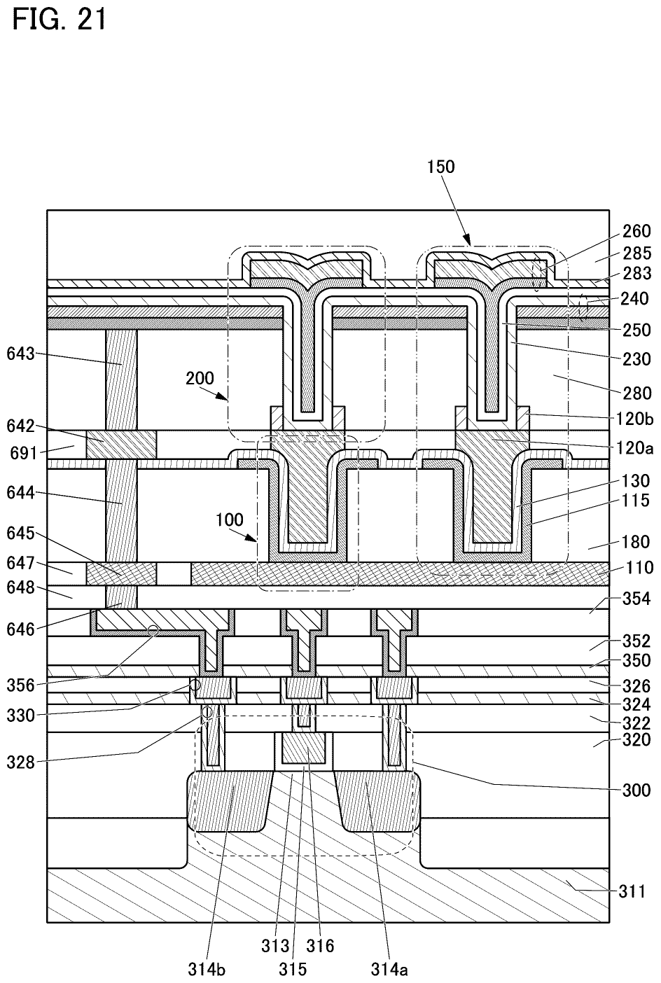

FIG. 21 illustrates a cross-sectional structure example of a memory device in which a layer including a memory cell is stacked over a layer including a driver circuit provided with a sense amplifier.

In FIG. 21, the memory cell 150 (the transistor 200 and the capacitor 100) is provided above a transistor 300.

The transistor 300 is one of the transistors included in the sense amplifier.

For the memory cell 150 illustrated in FIG. 21, the description of the memory cell 150 in <Structure example 1 of memory device> can be referred to. FIG. 21 illustrates an example in which the capacitor 100 includes, instead of the conductive layer 120, a conductive layer 120a and a conductive layer 120b over the conductive layer 120a. Here, a material that can be used for the conductive layer 220c can be used for the conductive layer 120b, for example. A material that can be used for the conductive layer 220a and the conductive layer 220b can be used for the conductive layer 120a, for example. Although FIG. 21 illustrates an example in which the oxide semiconductor layer 230 is in contact with the top surface of the conductive layer 120a, the oxide semiconductor layer 230 is not necessarily in contact with the top surface of the conductive layer 120a.

When the sense amplifier is provided to overlap with the memory cell 150 as illustrated in FIG. 21, the bit line can be shortened. This reduces bit line capacitance, resulting in a reduction in the storage capacitance of the memory cell. The reduced bit line capacitance allows the memory device to be driven at high speed.

The memory device illustrated in FIG. 21 can correspond to a semiconductor device 900 described in Embodiment 4. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 that is a part of the substrate 311, and a low-resistance region 314a and a low-resistance region 314b functioning as a source region and a drain region. The transistor 300 can be a p-channel transistor or an n-channel transistor.

In the transistor 300 illustrated in FIG. 21, the semiconductor region 313 (part of the substrate 311) where a channel is formed has a projecting shape. Furthermore, the conductive layer 316 is provided to cover the side and top surfaces of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 21 is just an example and is not limited to having the structure illustrated therein; an appropriate transistor can be used in accordance with a circuit structure or a driving method.

Wiring layers including an interlayer film, a wiring, a plug, and the like may be provided between the structure bodies. A plurality of wiring layers can be provided in accordance with the design. Here, a plurality of conductive layers functioning as plugs or wirings are collectively denoted by the same reference numeral in some cases. Furthermore, in this specification and the like, a wiring and a plug electrically connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are stacked over the transistor 300 in this order as interlayer insulating films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layer functioning as an interlayer film may function as a planarization film that covers a roughness thereunder. For example, the top surface of the insulating layer 322 may be planarized by planarization treatment using a CMP method or the like to improve the planarity.

A wiring layer may be provided over the insulating layer 326 and the conductive layer 330. For example, in FIG. 21, an insulating layer 350, an insulating layer 352, and an insulating layer 354 are stacked sequentially. Furthermore, a conductive layer 356 is formed in the insulating layers 350, 352, and 354. The conductive layer 356 functions as a plug or a wiring.

As the insulating layer 352, the insulating layer 354, and the like functioning as interlayer films, the above-described insulating layer that can be used for the semiconductor device or the memory device can be used.

As the conductive layer functioning as a plug or a wiring, such as the conductive layer 328, the conductive layer 330, and the conductive layer 356, a conductive material that can be used for the conductive layer 240 can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The conductive layer 240 included in the transistor 200 is electrically connected to the low-resistance region 314b functioning as the source region or the drain region of the transistor 300 through a conductive layer 643, a conductive layer 642, a conductive layer 644, a conductive layer 645, a conductive layer 646, the conductive layer 356, the conductive layer 330, and the conductive layer 328.

The conductive layer 643 is embedded in the insulating layer 280. The conductive layer 642 is provided over the insulating layer 130 and is embedded in an insulating layer 691. The conductive layers 642 and 120a can be formed using the same material in the same step. The conductive layer 644 is embedded in the insulating layers 180 and 130. The conductive layer 645 is embedded in an insulating layer 647. The conductive layers 645 and 110 can be formed using the same material in the same step. The conductive layer 646 is embedded in an insulating layer 648. The transistor 300 and the conductive layer 110 are electrically insulated from each other by the insulating layer 648.

As described above, the memory device of this embodiment includes a transistor with reduced parasitic capacitance, and thus can have higher operation speed. In addition, since the memory device of this embodiment includes a capacitor and a transistor that overlap with each other, the area occupied by the memory cell in a plan view can be reduced and a memory device with a high degree of integration can be obtained.

This embodiment can be combined with any of the other embodiments as appropriate.

### Embodiment 4

In this embodiment, the semiconductor device 900 of one embodiment of the present invention will be described. The semiconductor device 900 can function as a memory device.

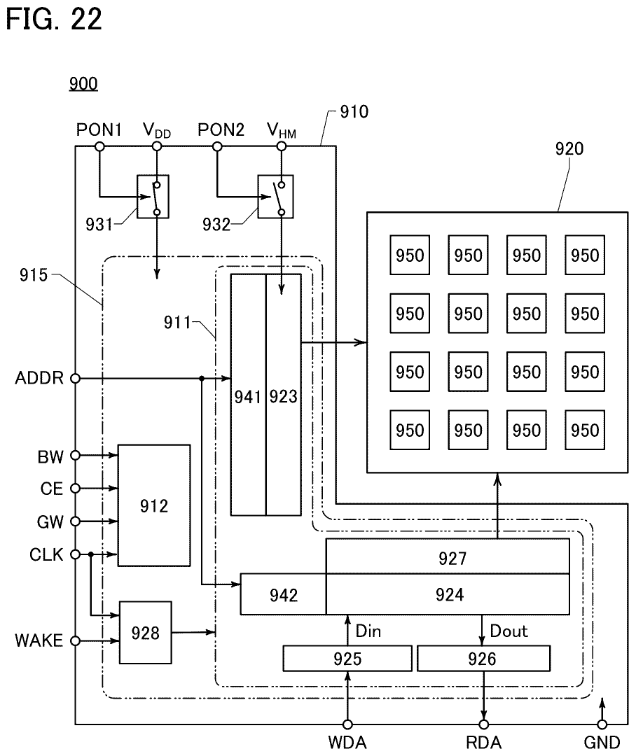

FIG. 22 is a block diagram illustrating a structure example of the semiconductor device 900. The semiconductor device 900 illustrated in FIG. 22 includes a driver circuit 910 and a memory array 920. The memory array 920 includes at least one memory cell 950. FIG. 22 illustrates an example in which the memory array 920 includes a plurality of memory cells 950 arranged in a matrix.

The memory device (e.g., the memory cell 150) described in Embodiment 2 can be used for the memory cell 950.

The driver circuit 910 includes a power switch (PSW) 931, a PSW 932, and a peripheral circuit 915. The peripheral circuit 915 includes a peripheral circuit 911, a control circuit 912 (Control Circuit), and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941 (Row Decoder), a column decoder 942 (Column Decoder), a row driver 923 (Row Driver), a column driver 924 (Column Driver), an input circuit 925 (Input Cir.), an output circuit 926 (Output Cir.), and a sense amplifier 927 (Sense Amplifier).

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used for setting a word line to high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 22 but can be more than one. In that case, a power switch is provided for each power domain.

Structure examples of other memory cells each of which can be used as the memory cell 950 are described with reference to FIGS. 23A to 23H.

In the following description, the expression “two components are connected to each other” includes the case where the two components are electrically connected through a circuit element (a transistor, a switch, a diode, a resistor, or the like). The term “electrical connection” means a possibility that a current flows between two components. Note that the case where two components are connected through a switch or a transistor is included as electrical connection because a current can flow when the components are in an on state.

### [DOSRAM]

FIG. 23A illustrates a circuit structure example of a memory cell for a DRAM. In this specification and the like, a DRAM using an OS transistor is referred to as a dynamic oxide semiconductor random access memory (DOSRAM). A memory cell 951 includes the transistor M1 and the capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (referred to as a reference potential in some cases) is preferably applied to the wiring CAL.

Data writing and data reading are performed in such a manner that a high-level potential is applied to the wiring WOL to turn on the transistor M1 and establish electrical continuity between the wiring BIL and the first terminal of the capacitor CA (make a state where a current can flow therethrough).

The memory cell that can be used as the memory cell 950 is not limited to the memory cell 951, and the circuit structure can be changed. For example, a memory cell 952 illustrated in FIG. 23B may be used. The memory cell 952 is an example including neither the capacitor CA nor the wiring CAL. The first terminal of the transistor MI is in an electrically floating state.

In the memory cell 952, a potential written through the transistor MI is retained in a capacitor (also referred to as parasitic capacitance) between the first terminal and the gate, which is shown by a dashed line. With such a structure, the structure of the memory cell can be greatly simplified.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 23C illustrates a circuit structure example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retention, and data reading, a low-level potential (sometimes referred to as a ground potential) is preferably applied to the wiring CAL.

Data writing is performed in such a manner that a high-level potential is applied to the wiring WOL to turn on the transistor M2 and establish electrical continuity between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit structure example of the memory cell is illustrated in FIG. 23D. In a memory cell 954, one wiring BIL is provided instead of the wiring WBL and the wiring RBL in the memory cell 953, and the second terminal of the transistor M2 and the first terminal of the transistor M3 are electrically connected to the wiring BIL. In other words, one wiring BIL operates as the write bit line and the read bit line in the memory cell 954.

A memory cell 955 illustrated in FIG. 23E is an example in which the capacitor CB and the wiring CAL in the memory cell 953 are omitted. A memory cell 956 illustrated in FIG. 23F is an example in which the capacitor CB and the wiring CAL in the memory cell 954 are omitted. Such structures enable high integration of memory cells.

Note that an OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with the transistors having the same conductivity type.

FIG. 23G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4 and establish electrical continuity between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than the OS transistor depending on the crystal state of silicon used in a semiconductor layer, for example.

When OS transistors are used as the transistors M5 and M6, the memory cell can be configured with the transistors having the same conductivity type.

### [OS-SRAM]

FIG. 23H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 23H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is connected to a wiring VDL. A second terminal of the transistor MS2 is connected to the wiring VDL. A second terminal of the transistor MS3 is connected to the wiring GNDL. A second terminal of the transistor MS4 is connected to the wiring GNDL.

A second terminal of the transistor M9 is connected to a first terminal of the capacitor CD1. The gate of the transistor M9 is connected to a wiring BRL. A second terminal of the transistor M10 is connected to a first terminal of the capacitor CD2. The gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistors M9 and M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CDI and the potential of the first terminal of the capacitor CD2 are retained.

Data reading is performed in such a manner that the wiring BIL and the wiring BILB are precharged with a predetermined potential, and then a high-level potential is applied to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with the use of the transistors M7 to M10, written data can be retained for a long time, and thus the frequency of refresh operation for the memory cell can be decreased. Alternatively, refresh operation for the memory cell can be omitted.

Note that the transistors MS1 to MS4 may be Si transistors.

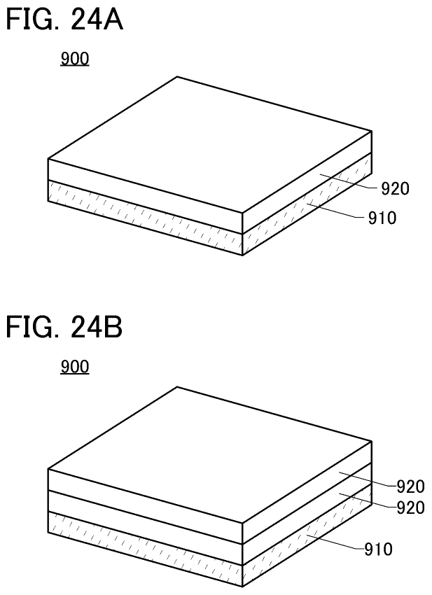

The driver circuit 910 and the memory array 920 included in the semiconductor device 900 may be provided on the same plane. Alternatively, as illustrated in FIG. 24A, the driver circuit 910 and the memory array 920 may be provided to overlap each other. Overlapping the driver circuit 910 and the memory array 920 can shorten a signal propagation distance. As illustrated in FIG. 24B, a plurality of memory arrays 920 may be stacked over the driver circuit 910.

Next, description is made on an example of an arithmetic processing device that can include the semiconductor device, such as the memory device described above.

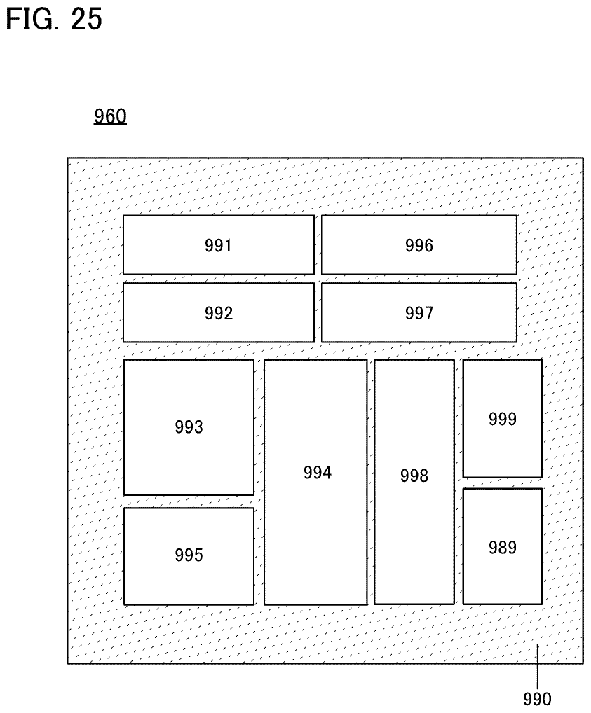

FIG. 25 is a block diagram of an arithmetic device 960. The arithmetic device 960 illustrated in FIG. 25 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 25 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 25 is only an example with a simplified structure, and the actual arithmetic device 960 has a variety of structures depending on the application. For example, what is called a multicore structure is preferably employed in which a plurality of cores each including the arithmetic device 960 in FIG. 25 operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 25, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply voltage is supplied to the memory cell in the register 996. When data retention by the capacitor is selected, the data is rewritten into the capacitor, and supply of the power supply voltage to the memory cell in the register 996 can be stopped.

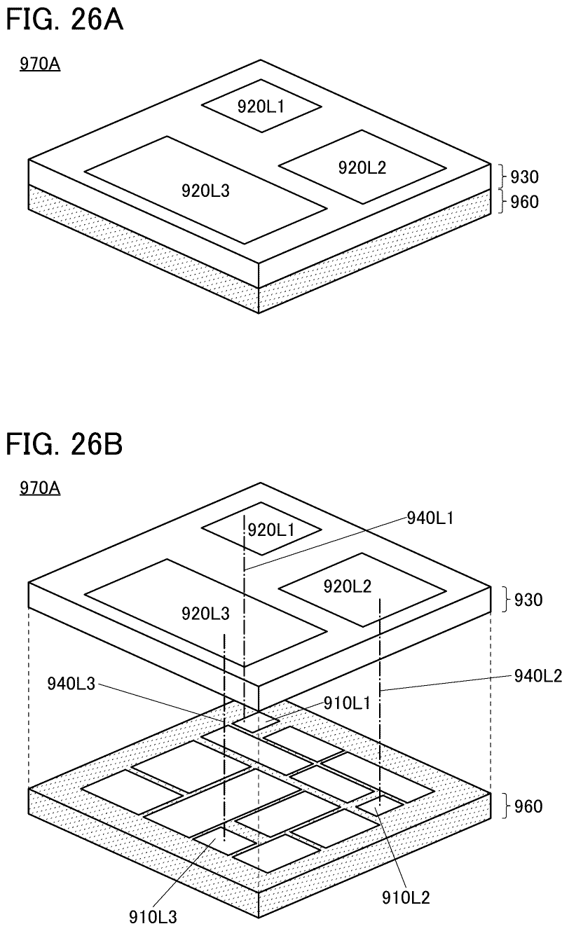

The memory array 920 and the arithmetic device 960 can be provided to overlap with each other. FIGS. 26A and 26B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 26B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu-Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 26B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

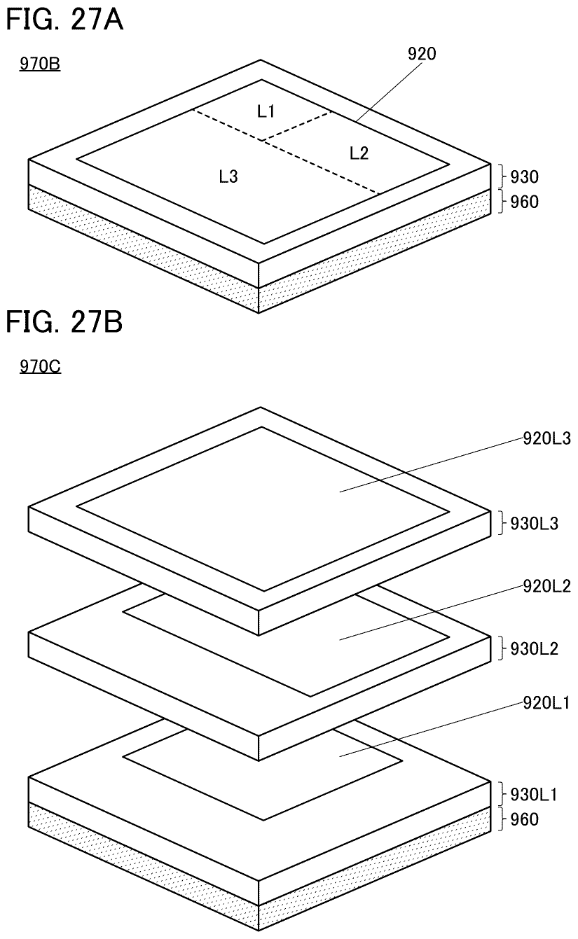

The layer 930 including one memory array 920 may be provided to overlap with the arithmetic device 960. FIG. 27A is a perspective view of a semiconductor device 970B.

In the semiconductor device 970B, one memory array 920 can be divided into a plurality of areas having different functions. FIG. 27A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 27B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments as appropriate.

### Embodiment 5

In this embodiment, application examples of the memory device of one embodiment of the present invention will be described.

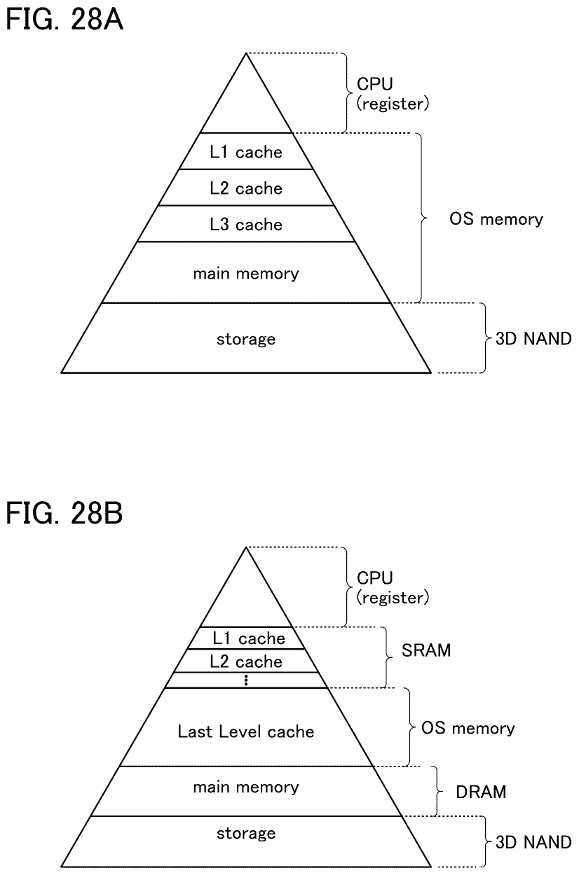

In general, a variety of memory devices are used in semiconductor devices such as computers in accordance with the intended use. FIG. 28A illustrates the hierarchy of various memory devices used in a semiconductor device. The memory devices at the upper levels require a higher operating speed, whereas the memory devices at the lower levels require a larger memory capacity and a higher memory density. FIG. 28A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

A memory included as a register in an arithmetic processing device such as a CPU is used for temporary storage of arithmetic operation results, for example, and thus is very frequently accessed by the arithmetic processing device. Accordingly, rapid operation is more important than the memory capacity of the memory. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program and data that are read from the storage.

The storage has a function of retaining data that needs to be stored for a long time and programs used in an arithmetic processing device, for example. Therefore, the storage needs to have a high memory capacity and a high memory density rather than operating speed. For example, a high-capacity nonvolatile memory device such as a 3D NAND memory device can be used.

The memory device including an oxide semiconductor (the OS memory) of one embodiment of the present invention operates fast and can retain data for a long time. Thus, as illustrated in FIG. 28A, the memory device of one embodiment of the present invention can be favorably used at both the level including the cache and the level including the main memory. The memory device of one embodiment of the present invention can also be used at the level including the storage.

FIG. 28B illustrates an example in which an SRAM is used as at least one of the caches and the OS memory of one embodiment of the present invention is used as the other cache.

The lowest-level cache can be referred to as a last level cache (LLC). The LLC does not require a higher operation speed than a higher-level cache, but desirably has large storage capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 28B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 28B.

This embodiment can be combined with any of the other embodiments as appropriate.

### Embodiment 6

In this embodiment, a display device of one embodiment of the present invention will be described.

The semiconductor device of one embodiment of the present invention can be used for a display device or a module including the display device. Examples of the module including the display device are a module in which a connector such as a flexible printed circuit board (hereinafter referred to as an FPC) or a tape carrier package (TCP) is attached to the display device, a module which is mounted with an integrated circuit (IC) by a chip on glass (COG) method, a chip on film (COF) method, or the like, and the like.

That is, the display device in this embodiment may have a function of a touch panel. The display device can employ any of a variety of sensor elements that can sense proximity or touch of a sensing target such as a finger, for example.

For example, a variety of types such as a capacitive type, a resistive type, a surface acoustic wave type, an infrared type, an optical type, and a pressure-sensitive type can be used for the sensor.

Examples of the capacitive touch sensor are a surface capacitive touch sensor and a projected capacitive touch sensor. Examples of the projected capacitive touch sensor include a self-capacitive touch sensor and a mutual capacitive touch sensor. The use of a mutual capacitive touch sensor is preferable because multiple points can be detected simultaneously.

Examples of a touch panel include an out-cell touch panel, an on-cell touch panel, and an in-cell touch panel. An in-cell touch panel has a structure where an electrode included in a sensor element is provided on one or both of a substrate supporting a display element and a counter substrate.

### [Display Module]

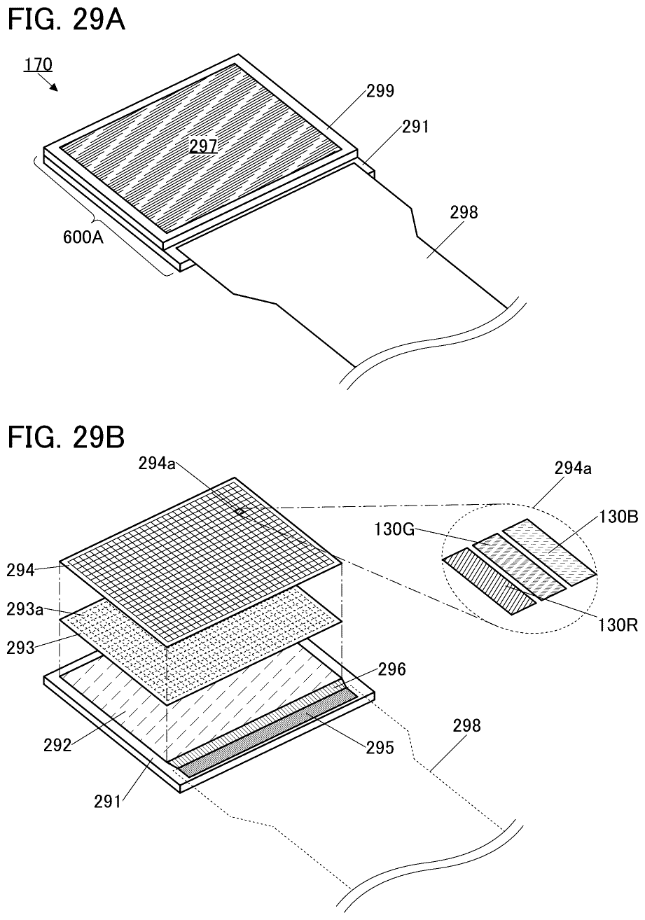

FIG. 29A is a perspective view of a display module 170. The display module 170 includes a display device 600A and an FPC 298. Note that the display device included in the display module 170 is not limited to the display device 600A and may be a display device 600B described later.

The display module 170 includes a substrate 291 and a substrate 299. The display module 170 includes a display portion 297. The display portion 297 is a region of the display module 170 where an image is displayed, and is a region where light emitted from pixels provided in a pixel portion 294 described later can be seen.

FIG. 29B is a perspective view schematically illustrating the structure on the substrate 291 side. Over the substrate 291, a circuit portion 292, a pixel circuit portion 293 over the circuit portion 292, and the pixel portion 294 over the pixel circuit portion 293 are stacked. In addition, a terminal portion 295 for connection to the FPC 298 is included in a portion over the substrate 291 that does not overlap with the pixel portion 294. The terminal portion 295 and the circuit portion 292 are electrically connected to each other through a wiring portion 296 formed of a plurality of wirings.

The semiconductor device of one embodiment of the present invention can be used for one or both of the circuit portion 292 and the pixel circuit portion 293.

The pixel portion 294 includes a plurality of pixels 294a arranged periodically. An enlarged view of one pixel 294a is illustrated on the right side in FIG. 29B. FIG. 29B illustrates an example where one pixel 294a includes a subpixel 130R emitting red light, a subpixel 130G emitting green light, and a subpixel 130B emitting blue light.

The subpixel includes a display element. Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials may be used.

As the light-emitting element, a self-luminous light-emitting element such as a light-emitting diode (LED), an organic LED (OLED), or a semiconductor laser can be used. Examples of the LED include a mini LED and a micro LED.

There is no particular limitation on the arrangement of pixels in the display device of one embodiment of the present invention, and a variety of arrangements can be employed. Examples of the arrangement of pixels include stripe arrangement, S-stripe arrangement, matrix arrangement, delta arrangement, Bayer arrangement, and PenTile arrangement. FIG. 29B illustrates an example where stripe arrangement is employed as the pixel arrangement.

The pixel circuit portion 293 includes a plurality of pixel circuits 293a arranged periodically.

One pixel circuit 293a is a circuit that controls driving of a plurality of elements included in one pixel 294a. One pixel circuit 293a can be provided with three circuits each of which controls light emission of one light-emitting element. For example, the pixel circuit 293a can include at least one selection transistor, one current control transistor (driving transistor), and a capacitor for one light-emitting element. In this case, a gate signal is input to a gate of the selection transistor, and a source signal is input to a source of the selection transistor. With such a structure, an active-matrix display device is achieved.

The circuit portion 292 includes a circuit for driving the pixel circuits 293a in the pixel circuit portion 293. For example, one or both of a gate line driver circuit and a source line driver circuit are preferably included. The circuit portion 292 may also include at least one of an arithmetic circuit, a memory circuit, a power supply circuit, and the like.

The FPC 298 functions as a wiring for supplying a video signal, a power supply potential, or the like to the circuit portion 292 from the outside. An IC may be mounted on the FPC 298.

The display module 170 can have a structure where one or both of the pixel circuit portion 293 and the circuit portion 292 are stacked below the pixel portion 294; thus, the aperture ratio (the effective display area ratio) of the display portion 297 can be significantly high. Furthermore, the pixels 294a can be arranged extremely densely and thus the display portion 297 can have a significantly high resolution.

Such a display module 170 has an extremely high resolution, and thus can be suitably used for a device for VR such as an HMD or a glasses-type device for AR. For example, even in the case of a structure where the display portion of the display module 170 is seen through a lens, pixels of the extremely-high-resolution display portion 297 included in the display module 170 are prevented from being seen when the display portion is enlarged by the lens, so that display providing a high sense of immersion can be performed. Without being limited thereto, the display module 170 can be suitably used for electronic devices including a relatively small display portion. For example, the display module 170 can be favorably used in a display portion of a wearable electronic device, such as a wrist watch.

### [Structure Example 1 of Display Device]

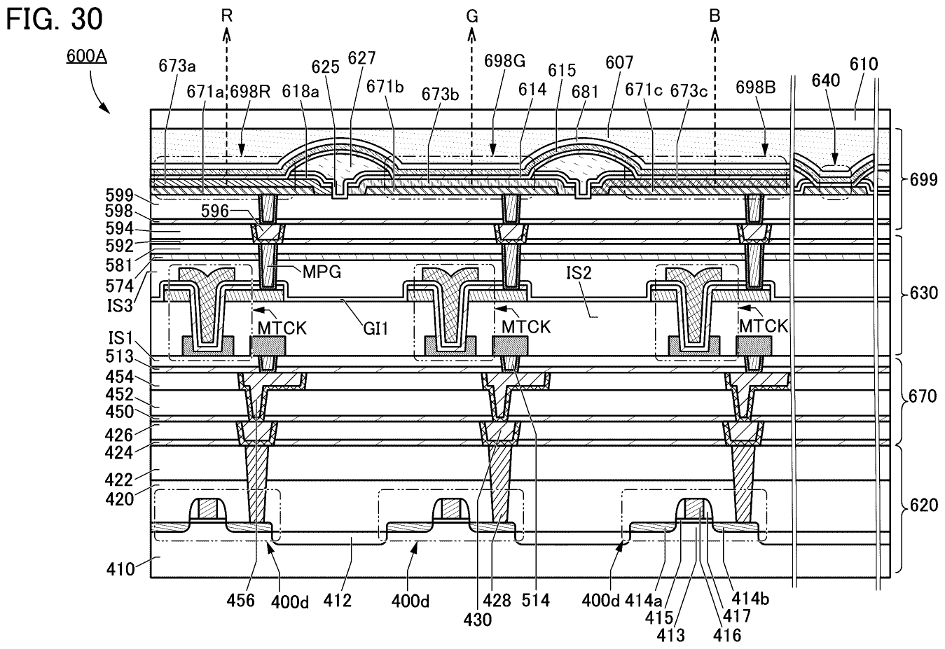

FIG. 30 is a cross-sectional view of the display device 600A. The display device 600A is an example of a display device having a metal maskless (MML) structure. In other words, the display device 600A includes a light-emitting element that is formed without using a fine metal mask.

An island-shaped light-emitting layer of the light-emitting element included in the display device having the MML structure is formed in such a manner that a light-emitting layer is formed on the entire surface and then the light-emitting layer is processed by a lithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element emitting blue light, a light-emitting element emitting green light, and a light-emitting element emitting red light, three kinds of island-shaped light-emitting layers can be formed by forming a light-emitting layer and performing processing three times by photolithography.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. Furthermore, for processing by photolithography, an apparatus that is the same as or similar to that used for manufacturing a transistor can be used; thus, there is no need to introduce a special apparatus to manufacture the device having the MML structure. The MML structure can reduce the manufacturing cost as described above, and thus is suitable for mass production of the device.

A display device having the MML structure does not require a pseudo improvement in resolution by employing a unique pixel arrangement such as a PenTile arrangement; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

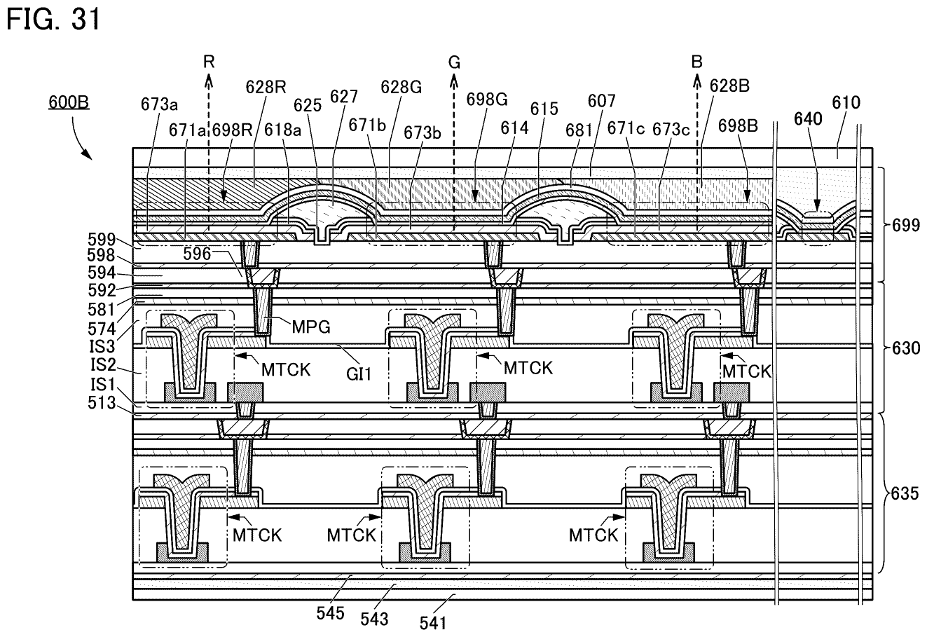

Moreover, providing a sacrificial layer over the light-emitting layer can reduce damage to the light-emitting layer in the manufacturing process of the display device, resulting in an increase in reliability of the light-emitting element. Note that the sacrificial layer may remain in the completed display device or may be removed in the manufacturing process. For example, a sacrificial layer 618a illustrated in FIG. 30 and FIG. 31 is part of the sacrificial layer provided over the light-emitting layer.

Employing a film formation step using an area mask and a processing step using a resist mask enables a light-emitting element to be manufactured by a relatively easy process.

FIG. 30 is a schematic cross-sectional view of the display device 600A (a semiconductor device) of one embodiment of the present invention. The display device 600A is provided with a pixel circuit, a driver circuit, and the like over a substrate 410. Note that in the display device 600A in FIG. 30, a wiring layer 670 is illustrated in addition to an element layer 620, an element layer 630, and an element layer 699. The wiring layer 670 is a layer provided with a wiring.

A pixel circuit of the display device is preferably provided in the element layer 630. A driver circuit (one or both of a gate driver and a source driver) of the display device is preferably provided in the element layer 620. One or more of a variety of circuits such as an arithmetic circuit and a memory circuit may be provided in the element layer 620.

For example, the element layer 620 includes the substrate 410 on which a transistor 400d is formed. The wiring layer 670 is provided above the transistor 400d, and a wiring for electrically connecting the transistor 400d to a conductive layer, a transistor, or the like provided in the element layer 630 (a conductive layer 514 in FIG. 30) is provided in the wiring layer 670. The element layer 630 and the element layer 699 are provided above the wiring layer 670, and the element layer 630 includes a transistor MTCK and the like, for example. The element layer 699 includes a light-emitting element 698 (a light-emitting element 698R, a light-emitting element 698G, and a light-emitting element 698B in FIG. 30) and the like.

The transistor 400d is an example of a transistor included in the element layer 620. The transistor MTCK is an example of a transistor included in the element layer 630. The light-emitting element (the light-emitting element 698R, the light-emitting element 698G, and the light-emitting element 698B) is an example of a light-emitting element included in the element layer 699.

As the transistor MTCK, an OS transistor can be used, for example. FIG. 30 illustrates an example in which the transistor 200 described in the above embodiments is used as the transistor MTCK.

As the substrate 410, a semiconductor substrate (e.g., a single crystal substrate formed of silicon or germanium) can be used, for example. Besides such a semiconductor substrate, any of the following can be used as the substrate 410: a silicon on insulator (SOI) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper or a base film including a fibrous material. In the description of this embodiment, the substrate 410 is a semiconductor substrate containing silicon as a material. Therefore, a transistor included in the element layer 620 can be a Si transistor.

The transistor 400d includes an element isolation layer 412, a conductive layer 416, an insulating layer 415, an insulating layer 417, a semiconductor region 413 that is part of the substrate 410, and low-resistance regions 414a and 414b functioning as source and drain regions. Thus, the transistor 400d is a Si transistor. Although FIG. 30 illustrates the structure where one of the source and the drain of the transistor 400d is electrically connected to the conductive layer 514 provided in the element layer 630 through the conductive layer 428, the conductive layer 430, and the conductive layer 456, the electrical connection structure of the display device of one embodiment of the present invention is not limited thereto.

The transistor 400d can have a fin-type structure when, for example, the top surface of the semiconductor region 413 and the side surface thereof in the channel width direction are covered with the conductive layer 416 with the insulating layer 415 as a gate insulating layer therebetween. The effective channel width can be increased in the fin-type transistor 400d, so that the on-state characteristics of the transistor 400d can be improved. In addition, contribution of the electric field of the gate electrode can be increased, so that the off-state characteristics of the transistor 400d can be improved. The transistor 400d may have a planar structure instead of a fin-type structure.

Note that the transistor 400d can be a p-channel transistor or an n-channel transistor. Alternatively, a plurality of transistors 400d including both the p-channel transistor and the n-channel transistor may be used.

A region of the semiconductor region 413 where a channel is formed, a region in the vicinity thereof, and the low-resistance regions 414a and 414b functioning as the source and drain regions preferably contain a silicon-based semiconductor, specifically, preferably contain single crystal silicon. Alternatively, the above-described regions may be formed using germanium, silicon germanium, gallium arsenide, aluminum gallium arsenide, or gallium nitride, for example. Alternatively, the transistor 400d may contain silicon whose effective mass is adjusted by applying stress to the crystal lattice and thereby changing the lattice spacing. Alternatively, the transistor 400d may be a high-electron-mobility transistor (HEMT) containing gallium arsenide and aluminum gallium arsenide, for example.

For the conductive layer 416 functioning as the gate electrode, a semiconductor material such as silicon that contains an element imparting n-type conductivity (e.g., arsenic or phosphorus) or an element imparting p-type conductivity (e.g., boron or aluminum) can be used. For another example, for the conductive layer 416, a conductive material such as a metal material, an alloy material, or a metal oxide material can be used.

Note that a material of a conductive layer determines the work function; thus, selecting the material of the conductive layer can adjust the threshold voltage of a transistor. Specifically, one or both of titanium nitride and tantalum nitride are preferably used for the conductive layer. Furthermore, in order to ensure the conductivity and embeddability of the conductive layer, one or both of tungsten and aluminum are preferably stacked over the conductive layer. In particular, tungsten is preferable in terms of heat resistance.

The element isolation layer 412 is provided to separate a plurality of transistors on the substrate 410 from each other. The element isolation layer can be formed by a local oxidation of silicon (LOCOS) method, a shallow trench isolation (STI) method, or a mesa isolation method.

Over the transistor 400d illustrated in FIG. 30, an insulating layer 420 and an insulating layer 422 are stacked in this order from the substrate 410 side.

For the insulating layers 420 and 422, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 422 may function as a planarization film for eliminating a level difference caused by the transistor 400d or the like covered with the insulating layers 420 and 422. For example, the top surface of the insulating layer 422 may be planarized by planarization treatment using a CMP method or the like to improve the planarity.

The conductive layer 428 connected to the transistor MTCK and the like provided above the insulating layer 422 is embedded in the insulating layer 420 and the insulating layer 422. Note that the conductive layer 428 has a function of a plug or a wiring.

In the display device 600A, the wiring layer 670 is provided over the transistor 400d. The wiring layer 670 includes, for example, an insulating layer 424, an insulating layer 426, the conductive layer 430, an insulating layer 450, an insulating layer 452, an insulating layer 454, and the conductive layer 456.

For example, over the insulating layers 422 and 428, the insulating layers 424 and 426 are stacked in this order. An opening portion is formed in the insulating layers 424 and 426 in each region overlapping with the conductive layer 428. In addition, the conductive layer 430 is embedded in the opening portion.

The insulating layer 450, the insulating layer 452, and the insulating layer 454 are sequentially stacked over the insulating layer 426 and the conductive layer 430. An opening portion is formed in the insulating layers 450, 452, and 454 in each region overlapping with the conductive layer 430. The conductive layer 456 is embedded in the opening portion.

The conductive layers 430 and 456 each have a function of a plug or a wiring that is connected to the transistor 400d.

Note that for example, the insulating layers 424 and 450 are preferably formed using an insulating layer having a barrier property against at least one of hydrogen, oxygen, and water, like an insulating layer 592 described later. The insulating layers 426, 452, and 454 are preferably formed using an insulating layer having a relatively low dielectric constant to reduce the parasitic capacitance generated between wirings, like an insulating layer 594 described later. The insulating layers 426, 452, and 454 each have functions of an interlayer insulating film and a planarization film.

The conductive layer 456 preferably includes a conductive layer having a barrier property against at least one of hydrogen, oxygen, and water.

Note that as the conductive layer having a barrier property against hydrogen, tantalum nitride is preferably used, for example. By stacking tantalum nitride and tungsten, which has high conductivity, diffusion of hydrogen from the transistor 400d can be inhibited while the conductivity of a wiring is ensured. In this case, a tantalum nitride layer having a barrier property against hydrogen is preferably in contact with the insulating layer 450 having a barrier property against hydrogen.

An insulating layer 513 is provided above the insulating layer 454 and the conductive layer 456. An insulating layer IS1 is provided over the insulating layer 513. A conductive layer functioning as a plug or a wiring is embedded in the insulating layer ISI and the insulating layer 513. Thus, the transistor 400d can be electrically connected to the conductive layer 514 provided in the element layer 630. Alternatively, one of a source and a drain of the transistor MTCK and one of the source and the drain of the transistor 400d may be electrically connected to each other.

The transistor MTCK is provided over the insulating layer IS1. An insulating layer IS3, an insulating layer 574, and an insulating layer 581 are stacked in this order over the transistor MTCK. A conductive layer MPG functioning as a plug or a wiring is embedded in the insulating layer IS3, the insulating layer 574, and the insulating layer 581.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits entry of the impurities into transistor MTCK. The insulating layer 574 also preferably has a function of inhibiting diffusion of oxygen (e.g., one or both of an oxygen atom and an oxygen molecule). For example, the insulating layer 574 preferably has lower oxygen permeability than the insulating layer IS2 and the insulating layer IS3. As the insulating layer IS2, the insulating layer 280 described in the above embodiments can be used.

Thus, the insulating layer 574 preferably functions as a barrier insulating film that inhibits diffusion of impurities such as water and hydrogen. Accordingly, the insulating layer 574 is preferably formed using an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the above impurities are less likely to pass). Alternatively, it is preferable to use an insulating material having a function of inhibiting diffusion of oxygen (e.g., one or both of an oxygen atom and an oxygen molecule) (an insulating material through which the above oxygen is less likely to pass).

For the insulating layer having a function of inhibiting passage of oxygen and impurities such as water and hydrogen, it is possible to use any of the materials that can be used for the insulating layer having a function of inhibiting passage of oxygen and impurities described in Embodiment 1.

In particular, aluminum oxide or silicon nitride is preferably used for the insulating layer 574. Accordingly, it is possible to inhibit diffusion of impurities such as water and hydrogen into the transistor MTCK from above the insulating layer 574. Alternatively, oxygen contained in the insulating layer IS3 and the like can be inhibited from diffusing above the insulating layer 574.

The insulating layer 581 is preferably a film functioning as an interlayer film and having a lower permittivity than the insulating layer 574. When a material with a low dielectric constant is used for an interlayer film, the parasitic capacitance generated between wirings can be reduced. For example, the dielectric constant of the insulating layer 581 is preferably lower than 4, further preferably lower than 3. For example, the dielectric constant of the insulating layer 581 is preferably less than or equal to 0.7 times that of the insulating layer 574, further preferably less than or equal to 0.6 times that of the insulating layer 574. When a material with a low dielectric constant is used for the insulating layer 581, the parasitic capacitance generated between wirings can be reduced.

The concentration of impurities such as water and hydrogen in the insulating layer 581 is preferably reduced. In that case, materials such as silicon oxide, silicon oxynitride, silicon nitride oxide, or silicon nitride can be used for the insulating layer 581. For example, silicon oxide to which fluorine is added, silicon oxide to which carbon is added, silicon oxide to which carbon and nitrogen are added, or porous silicon oxide can be used for the insulating layer 581. In particular, silicon oxide and silicon oxynitride are preferable because they are thermally stable. In particular, materials such as silicon oxide, silicon oxynitride, and porous silicon oxide are preferably used, in which case a region containing oxygen released by heating can be easily formed. Moreover, the insulating layer 581 can be formed using a resin. A material combined with any of the above materials as appropriate may be used for the insulating layer 581.

The insulating layer 592 and the insulating layer 594 are stacked in this order over the insulating layer 574 and the insulating layer 581.

For the insulating layer 592, it is preferable to use an insulating film having a barrier property (referred to as a barrier insulating film) which prevents diffusion of impurities such as water and hydrogen from the substrate 410 and the transistor MTCK into a region above the insulating layer 592 (e.g., the region including the light-emitting elements 698R, 698G, and 698B, and the like). Accordingly, the insulating layer 592 is preferably formed using an insulating material having a function of inhibiting diffusion of impurities such as a hydrogen atom, a hydrogen molecule, and a water molecule (an insulating material through which the above impurities are less likely to pass). Alternatively, depending on circumstances, the insulating layer 592 is preferably formed using an insulating material having a function of inhibiting diffusion of impurities such as a nitrogen atom, a nitrogen molecule, a nitrogen oxide molecule (e.g., N₂O, NO, or NO₂), and a copper atom (an insulating material through which the above impurities are less likely to pass). The insulating layer 592 preferably has a function of inhibiting diffusion of oxygen (e.g., at least one of an oxygen atom and an oxygen molecule).

For the film having a barrier property against hydrogen, for example, silicon nitride deposited by a CVD method can be used.

The amount of released hydrogen can be measured by thermal desorption spectrometry (TDS), for example. For example, the amount of hydrogen released from the insulating layer 424 that is converted into hydrogen atoms per unit area of the insulating layer 424 is preferably less than or equal to 10×10¹⁵ atoms/cm², further preferably less than or equal to 5×10¹⁵ atoms/cm² in TDS analysis in a film-surface temperature range of 50° C. to 500° C.

Like the insulating layer 581, the insulating layer 594 is preferably an interlayer film with a low permittivity. Thus, the insulating layer 594 can be formed using any of the materials that can be used for the insulating layer 581.

Note that the insulating layer 594 preferably has a lower permittivity than the insulating layer 592. For example, the dielectric constant of the insulating layer 594 is preferably lower than 4, further preferably lower than 3. For example, the dielectric constant of the insulating layer 594 is preferably less than or equal to 0.7 times that of the insulating layer 592, further preferably less than or equal to 0.6 times that of the insulating layer 592. When a material with a low dielectric constant is used for the insulating layer 594, the parasitic capacitance generated between wirings can be reduced.

The conductive layer MPG functioning as a plug or a wiring is embedded in an insulating layer GI1 and the insulating layer IS3, and a conductive layer 596 functioning as a plug or a wiring is embedded in the insulating layer 592 and the insulating layer 594. In particular, the conductive layer MPG and the conductive layer 596 are electrically connected to the light-emitting element or the like provided above the insulating layer 594. A plurality of conductive layers functioning as plugs or wirings are collectively denoted by the same reference numeral in some cases. In this specification and the like, a wiring and a plug connected to the wiring may be a single component. That is, in some cases, part of a conductive layer functions as a wiring or part of a conductive layer functions as a plug. As the insulating layer GI1, the insulating layer 250 described in the above embodiments can be used.

As a material of each of plugs and wirings (the conductors MPG, 428, 430, 456, 514, and 596), one or more conductive materials selected from a metal material, an alloy material, a metal nitride material, and a metal oxide material can be used in a single-layer structure or a stacked-layer structure. It is preferable to use a high-melting-point material that has both heat resistance and conductivity, such as tungsten or molybdenum, and it is particularly preferable to use tungsten. A low-resistance conductive material such as aluminum or copper is preferably used. The use of a low-resistance conductive material can reduce wiring resistance.

An insulating layer 598 and an insulating layer 599 are sequentially formed over the insulating layer 594 and the conductive layer 596.

For example, the insulating layer 598 is preferably formed using an insulating layer having a barrier property against one or more of hydrogen, oxygen, and water, like the insulating layer 592. The insulating layer 599 is preferably formed using an insulating layer having a relatively low dielectric constant to reduce the parasitic capacitance generated between wirings, like the insulating layer 594. The insulating layer 599 has functions of an interlayer insulating film and a planarization film.

The light-emitting element 698 and a connection portion 640 are formed over the insulating layer 599.

The connection portion 640 is referred to as a cathode contact portion in some cases, and is electrically connected to cathodes of the light-emitting element 698R, the light-emitting element 698G, and the light-emitting element 698B. In the connection portion 640 illustrated in FIG. 30, a conductive layer formed using the same material in the same step as a conductive layer 671a to a conductive layer 671c is electrically connected to a common electrode 615 described later. Although FIG. 30 illustrates an example where the conductive layer is electrically connected to the common electrode 615 through a common layer 614 described later, the conductive layer and the common electrode 615 may be in direct contact with each other.

Note that the connection portion 640 may be provided to surround four sides of the display portion in a plan view or may be provided in the display portion (e.g., between adjacent light-emitting elements 698) (not illustrated).

The light-emitting element 698R includes the conductive layer 671a as a pixel electrode. Similarly, the light-emitting element 698G includes the conductive layer 671b as a pixel electrode, and the light-emitting element 698B includes the conductive layer 671c as a pixel electrode.

The conductive layer 671a, the conductive layer 671b, and the conductive layer 671c are connected to the conductive layer 596 embedded in the insulating layer 594 through a conductive layer (plug) embedded in the insulating layer 599.

The light-emitting element 698R includes a layer 673a, the common layer 614 over the layer 673a, and the common electrode 615 over the common layer 614. The light-emitting element 698G includes a layer 673b, the common layer 614 over the layer 673b, and the common electrode 615 over the common layer 614. The light-emitting element 698B includes a layer 673c, the common layer 614 over the layer 673c, and the common electrode 615 over the common layer 614.

For the pair of electrodes (the pixel electrode and the common electrode) of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (also referred to as In—Sn oxide or ITO), an In—Si—Sn oxide (also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The display device 600A employs an SBS structure. The SBS structure can optimize materials and structures of light-emitting elements and thus can extend freedom of choice of materials and structures, whereby the luminance and the reliability can be easily improved.

The display device 600A has a top-emission structure. The aperture ratio of pixels in a top-emission structure can be higher than that of pixels in a bottom-emission structure because a transistor and the like can be provided to overlap with a light-emitting region of a light-emitting element in the top-emission structure.

Note that the layer 673a is formed to cover the top and side surfaces of the conductive layer 671a. Similarly, the layer 673b is formed to cover the top and side surfaces of the conductive layer 671b. Similarly, the layer 673c is formed to cover the top and side surfaces of the conductive layer 671c. Accordingly, regions provided with the conductive layers 671a, 671b, and 671c can be entirely used as the light-emitting regions of the light-emitting elements 698R, 698G, and 698B, thereby increasing the aperture ratio of the pixels.

In the light-emitting element 698R, the layer 673a and the common layer 614 can be collectively referred to as an EL layer. Similarly, in the light-emitting element 698G, the layer 673b and the common layer 614 can be collectively referred to as an EL layer. Similarly, in the light-emitting element 698B, the layer 673c and the common layer 614 can be collectively referred to as an EL layer.

The EL layer includes at least a light-emitting layer. The light-emitting layer contains one or more kinds of light-emitting substances. As the light-emitting substance, a substance emitting light of blue, violet, bluish violet, green, yellowish green, yellow, orange, red, or the like is appropriately used. Alternatively, as the light-emitting substance, a substance emitting near-infrared light can be used.

Examples of a light-emitting substance contained in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material).

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further include one or both of a bipolar substance and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. The tandem structure enables a light-emitting element capable of high-luminance light emission. Furthermore, the amount of current needed for obtaining a predetermined luminance can be smaller in the tandem structure than in the single structure; thus, the tandem structure enables higher reliability. The tandem structure may be referred to as a stack structure.

When the light-emitting element has a microcavity structure, higher color purity can be achieved.

The layers 673a, 673b, and 673c are each processed into an island shape by a photolithography method. At each of end portions of the layers 673a, 673b, and 673c, the angle between the top surface and the side surface is approximately 90°. By contrast, for example, an organic film formed using a fine metal mask (FMM) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top and side surfaces of each of the layers 673a, 673b, and 673c are clearly distinguished from each other. Accordingly, as for the layers 673a and 673b which are adjacent to each other, one of the side surfaces of the layer 673a and one of the side surfaces of the layer 673b face each other. This applies to a combination of any two of the layers 673a, 673b, and 673c.

The layers 673a, 673b, and 673c each include at least a light-emitting layer. Preferably, the layer 673a, the layer 673b, and the layer 673c include a red-light-emitting layer, a green-light-emitting layer, and a blue-light-emitting layer, respectively, for example. Other than the above colors, cyan, magenta, yellow, or white can be employed as colors of light emitted from the light-emitting layers.

The layers 673a, 673b, and 673c each preferably include a light-emitting layer and a carrier-transport layer (an electron-transport layer or a hole-transport layer) over the light-emitting layer. Since the surfaces of the layers 673a, 673b, and 673c are exposed in the manufacturing process of the display device in some cases, providing the carrier-transport layer over the light-emitting layer inhibits the light-emitting layer from being exposed on the outermost surface, so that damage to the light-emitting layer can be reduced. Thus, the reliability of the light-emitting element can be increased.

The common layer 614 includes, for example, an electron-injection layer or a hole-injection layer. Alternatively, the common layer 614 may be a stack of an electron-transport layer and an electron-injection layer, or may be a stack of a hole-transport layer and a hole-injection layer. The common layer 614 is shared by the light-emitting elements 698R, 698G, and 698B. Note that the common layer 614 is not necessarily provided, and the whole EL layer included in the light-emitting element may be provided in an island shape like the layer 673a, the layer 673b, and the layer 673c.

The common electrode 615 is shared by the light-emitting element 698R, the light-emitting element 698G, and the light-emitting element 698B. As illustrated in FIG. 30, the common electrode 615 shared by the plurality of light-emitting elements is electrically connected to the conductive layer included in the connection portion 640.

The insulating layer 625 preferably has a function of a barrier insulating layer against at least one of water and oxygen. Alternatively, the insulating layer 625 preferably has a function of inhibiting diffusion of at least one of water and oxygen. Alternatively, the insulating layer 625 preferably has a function of capturing or fixing (also referred to as gettering) at least one of water and oxygen. When the insulating layer 625 has a function of a barrier insulating layer or a gettering function, entry of impurities (typically, one or both of water and oxygen) that would diffuse into the light-emitting elements from the outside can be inhibited. With this structure, a highly reliable light-emitting element and a highly reliable display device can be provided.

The insulating layer 625 preferably has a low impurity concentration. Accordingly, degradation of the EL layer, which is caused by entry of impurities into the EL layer from the insulating layer 625, can be inhibited. In addition, when the impurity concentration is reduced in the insulating layer 625, a barrier property against at least one of water and oxygen can be increased. For example, the insulating layer 625 preferably has a sufficiently low hydrogen concentration or a sufficiently low carbon concentration, and further preferably has both a sufficiently low hydrogen concentration and a sufficiently low carbon concentration.

As the insulating layer 627, an insulating layer containing an organic material can be favorably used. As the organic material, a photosensitive organic resin is preferably used, and for example, a photosensitive resin composite containing an acrylic resin is used. Note that in this specification and the like, an acrylic resin refers to not only a polymethacrylic acid ester or a methacrylic resin, but also all the acrylic polymer in a broad sense in some cases.

An organic material that can be used for the insulating layer 627 is not limited to the above. For example, for the insulating layer 627, an acrylic resin, a polyimide resin, an epoxy resin, a polyamide resin, a polyimide-amide resin, a silicone resin, a siloxane resin, a benzocyclobutene-based resin, a phenol resin, or precursors of these resins can be used in some cases. An organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used for the insulating layer 627 in some cases. A photoresist, which is a photosensitive resin, can be used for the insulating layer 627 in some cases. Examples of the photosensitive resin include positive-type materials and negative-type materials.

The insulating layer 627 may be formed using a material absorbing visible light. When the insulating layer 627 absorbs light emitted from the light-emitting element, light leakage (stray light) from the light-emitting element to an adjacent light-emitting element through the insulating layer 627 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

For example, the insulating layer 627 can be formed by a wet process such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 627 is preferably formed by spin coating.

The insulating layer 627 is formed at a temperature lower than the upper temperature limit of the EL layer. The typical substrate temperature in formation of layer 627 is lower than or equal to 200° C., preferably lower than or equal to 180° C., further preferably lower than or equal to 160° C., still further preferably lower than or equal to 150° C., yet still further preferably lower than or equal to 140° C.

Note that the side surface of the insulating layer 627 preferably has a tapered shape. When the end portion of the side surface of the insulating layer 627 has a forward tapered shape (with an angle less than 90°, preferably less than or equal to 60°, further preferably less than or equal to) 45°, the common layer 614 and the common electrode 615 that are provided over the end portion of the side surface of the insulating layer 627 can be formed with good coverage without disconnection, local thinning, or the like. Consequently, the in-plane uniformity of the common layer 614 and the common electrode 615 can be increased, so that the display quality of the display device can be improved.

In a cross-sectional view of the display device, the top surface of the insulating layer 627 preferably has a convex shape. The convex top surface of the insulating layer 627 preferably has a shape that expands gradually toward the center. When the insulating layer 627 has such a shape, the common layer 614 and the common electrode 615 can be formed with good coverage over the whole insulating layer 627.

The insulating layer 627 is formed in a region between two EL layers (e.g., a region between the layer 673a and the layer 673b). In that case, part of the insulating layer 627 is positioned between the side end portion of one of the two EL layers (e.g., the layer 673a) and the side end portion of the other of the two EL layers (e.g., the layer 673b).

One end portion of the insulating layer 627 preferably overlaps with the conductive layer 671a functioning as a pixel electrode, and the other end portion of the insulating layer 627 preferably overlaps with the conductive layer 671b functioning as a pixel electrode. Such a structure enables the end portion of the insulating layer 627 to be formed over a flat or substantially flat region of the layer 673a (the layer 673b). This makes it relatively easy to process the insulating layer 627 to have a tapered shape as described above.

By providing the insulating layer 627 and the like in the above manner, a disconnected portion and a locally thinned portion can be prevented from being formed in the common layer 614 and the common electrode 615 from a flat or substantially flat region of the layer 673a to a flat or substantially flat region of the layer 673b. Thus, a connection defect due to a disconnected portion and an increase in electrical resistance due to a locally thinned portion can be inhibited from occurring in the common layer 614 and the common electrode 615 between the light-emitting elements.

In the display device of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device in this embodiment includes a region where a distance between two adjacent island-shaped EL layers is less than or equal to 1 μm, preferably less than or equal to 0.5 μm (500 nm), further preferably less than or equal to 100 nm. Shortening the distance between the light-emitting elements in this manner enables a display device with a high definition and a high aperture ratio to be provided.

A protective layer 681 is provided over the light-emitting element 698. The protective layer 681 functions as a passivation film for protecting the light-emitting element 698. Providing the protective layer 681 that covers the light-emitting element can prevent entry of impurities such as water and oxygen into the light-emitting element and increase the reliability of the light-emitting element 698. The protective layer 681 preferably has, for example, a single-layer structure or a stacked-layer structure at least including an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material such as an indium gallium oxide or an indium gallium zinc oxide may be used for the protective layer 681. The protective layer 681 can be formed by an ALD method, a CVD method, a sputtering method, or the like. Although the protective layer 681 includes an inorganic insulating film in this example, the present invention is not limited thereto. For example, the protective layer 681 may have a stacked-layer structure of an inorganic insulating film and an organic insulating film.

The protective layer 681 and the substrate 610 are bonded to each other with an adhesive layer 607. A solid sealing structure, a hollow sealing structure, or the like can be employed to seal the light-emitting elements. In FIG. 30, a solid sealing structure is employed, in which a space between the substrate 410 and the substrate 610 is filled with the adhesive layer 607. Alternatively, a hollow scaling structure may be employed, in which the space is filled with an inert gas (e.g., nitrogen or argon). In that case, the adhesive layer 607 may be provided not to overlap with the light-emitting element. Alternatively, the space may be filled with a resin other than the frame-like adhesive layer 607.

As the adhesive layer 607, any of a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component-mixture-type resin may be used. An adhesive sheet may be used.

The display device 600A is a top-emission display device. Light from the light-emitting element is emitted to the substrate 610 side. For this reason, a material having a high visible-light-transmitting property is preferably used for the substrate 610. For example, a substrate having a high visible-light-transmitting property is selected as the substrate 610 among substrates usable as the substrate 410. The pixel electrode contains a material reflecting visible light, and the counter electrode (the common electrode 615) contains a material transmitting visible light.

Note that the display device of one embodiment of the present invention may be not a top-emission display device but a bottom-emission display device where light from the light-emitting element is emitted to the substrate 410 side. In that case, a substrate having a high visible-light-transmitting property is selected as the substrate 410.

### [Structure Example 2 of Display Device]

FIG. 31 is a cross-sectional view of the display device 600B. The element layer 699 of the display device 600B is different from the element layer 699 of the display device 600A in that the layer 673a, the layer 673b, and the layer 673c have the same structure and that a coloring layer 628R, a coloring layer 628G, and a coloring layer 628B are provided. Furthermore, the display device 600B is different from the display device 600A in not including the element layer 620 and in including an element layer 635. The element layer 635 has a structure similar to that of the element layer 630.

The display device 600B can be a flexible display device when a flexible substrate is used as each of a substrate 541 and the substrate 610. The substrate 541 is bonded to an insulating layer 545 with an adhesive layer 543. The substrate 610 is bonded to the protective layer 681 with the adhesive layer 607.

In the element layer 699 of the display device 600B, the layer 673a, the layer 673b, and the layer 673c have the same structure and the coloring layer 628R, the coloring layer 628G, and the coloring layer 628B are included.

The layer 673a, the layer 673b, and the layer 673c are formed using the same material in the same step. The layer 673a, the layer 673b, and the layer 673c are isolated from each other. When the EL layer is provided in an island shape for each light-emitting element, a leakage current between adjacent light-emitting elements (sometimes referred to as horizontal-direction leakage current, horizontal leakage current, or lateral leakage current) can be inhibited. Accordingly, unintentional light emission due to crosstalk can be prevented, and color mixture between adjacent light-emitting elements can be inhibited, so that a display device with extremely high contrast can be obtained.

The light-emitting elements 698R, 698G, and 698B illustrated in FIG. 31 emit white light, for example. White light emitted from the light-emitting elements 698R, 698G, and 698B passes through the coloring layers 628R, 628G, and 628B, whereby light of a desired color can be obtained.

In the case where the light-emitting element configured to emit white light has a microcavity structure, light with a specific wavelength (e.g., red, green, or blue) is sometimes intensified and emitted.

Light emitted from the light-emitting element 698R is extracted as red light to the outside of the display device 600B through the coloring layer 628R. Similarly, light emitted from the light-emitting element 698G is extracted as green light to the outside of the display device 600B through the coloring layer 628G. Light emitted from the light-emitting element 698B is extracted as blue light to the outside of the display device 600B through the coloring layer 628B.

A light-emitting element emitting white light preferably has a tandem structure.

Alternatively, the light-emitting elements 698R, 698G, and 698B illustrated in FIG. 31 emit blue light, for example. In this case, the layers 673a, 673b, and 673c each include one or more light-emitting layers emitting blue light. In a subpixel emitting blue light, blue light emitted from the light-emitting element 698B can be extracted as it is. In each of the subpixel emitting red light and the subpixel emitting green light, a color conversion layer is provided between the light-emitting element 698R and the coloring layer 628R and between the light-emitting element 698G and the coloring layer 628G, so that blue light emitted from the light-emitting element 698R or 698G is converted into light with a longer wavelength, whereby red light or green light can be extracted. When light passing through the color conversion layer is extracted through the coloring layer, light other than light of a desired color can be absorbed by the coloring layer, and color purity of light emitted from a subpixel can be improved.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

The element layer 630 of the display device 600B has a structure similar to that of the element layer 630 of the display device 600A; thus, the detailed description thereof is omitted.

The display device 600B includes the element layer 635 and the element layer 630 over the element layer 635. The element layer 635 has a structure similar to that of the element layer 630.

At least part of the transistor included in the element layer 635 is electrically connected to a conductive layer or a transistor included in the element layer 630 through a plug, a wiring, and the like. Note that the wiring layer 670 may be provided between the element layer 630 and the element layer 635.

One or both of a pixel circuit and a driver circuit of the display device are preferably provided in the element layer 635.

Although FIG. 31 illustrates an example where two element layers (the element layer 630 and the element layer 635) including OS transistors are stacked, the number of stacked element layers is not limited thereto, and three or more layers may be stacked. For example, in the case where three or more element layers including OS transistors are stacked, it is preferable that the lowermost layer be used for the driver circuit (one or both of the gate driver and the source driver) of the display device, the uppermost layer be used for the pixel circuit of the display device, and one or more layers between them be used for the pixel circuit or the driver circuit.

A Si transistor is typically formed over a single crystal Si wafer, and thus is difficult to have flexibility. Meanwhile, as illustrated in FIG. 31, in the case where the display device is formed using only OS transistors without using a Si transistor, the display device can have flexibility through a relatively simple manufacturing process.

### [Structure Example of Light-Emitting Element]

Next, light-emitting elements that can be used for the display device of one embodiment of the present invention are described. Structure examples of a light-emitting element, which are different from the structures illustrated in FIG. 30 and FIG. 31, are mainly described below.

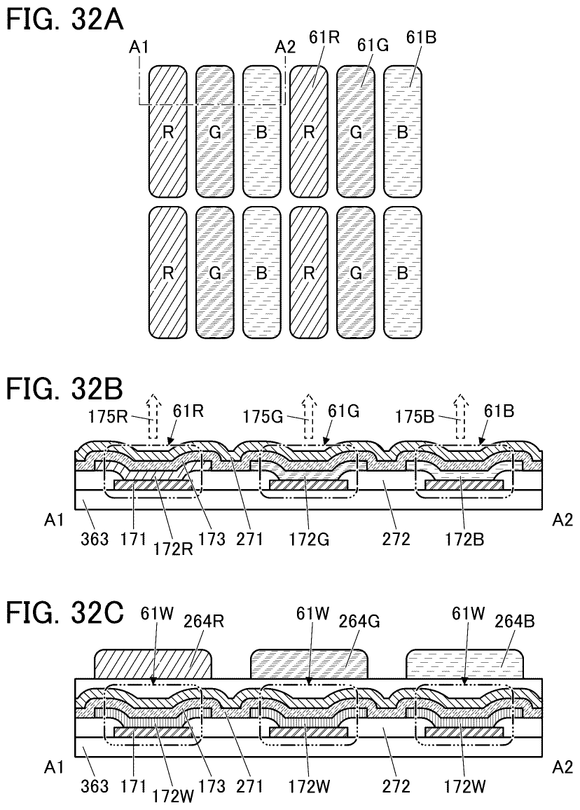

FIG. 32A is a schematic top view of part of a display portion including a plurality of light-emitting elements. The display portion includes a plurality of light-emitting elements 61R emitting red light, a plurality of light-emitting elements 61G emitting green light, and a plurality of light-emitting elements 61B emitting blue light. In FIG. 32A, light-emitting regions of the light-emitting elements are denoted by R, G, and B to easily differentiate the light-emitting elements. Although the structure illustrated in FIG. 32A has three emission colors of red (R), green (G), and blue (B), one embodiment of the present invention is not limited thereto. For example, the structure may have four or more colors.

FIG. 32B is a cross-sectional view taken along dashed-dotted line A1-A2 in FIG. 32A. The light-emitting elements 61R, 61G, and 61B illustrated in FIG. 32B are provided over an insulating layer 363, and include a conductive layer 171 functioning as a pixel electrode and a conductive layer 173 functioning as a common electrode. For the insulating layer 363, one or both of an inorganic insulating film and an organic insulating film can be used.

The light-emitting element 61R includes an EL layer 172R between the conductive layer 171 functioning as a pixel electrode and the conductive layer 173 functions as a common electrode. The EL layer 172R contains at least a light-emitting compound that emits light having a peak in a red wavelength range. An EL layer 172G included in the light-emitting element 61G contains at least a light-emitting compound that emits light having a peak in a green wavelength range. An EL layer 172B included in the light-emitting element 61B contains at least a light-emitting compound that emits light having a peak in a blue wavelength range.

The conductive layer 171 functioning as a pixel electrode is provided for each light-emitting element. The conductive layer 173 functioning as a common electrode is provided as a continuous layer shared by the light-emitting elements. A conductive film having a visible-light-transmitting property is used for either the conductive layer 171 functioning as a pixel electrode or the conductive layer 173 functioning as a common electrode, and a reflective conductive film is used for the other.

For example, in the case where the light-emitting element 61R has a top-emission structure, light 175R is emitted from the light-emitting element 61R to the conductive layer 173 side. In the case where the light-emitting element 61G has a top-emission structure, light 175G is emitted from the light-emitting element 61G to the conductive layer 173 side. In the case where the light-emitting element 61B has a top-emission structure, light 175B is emitted from the light-emitting element 61B to the conductive layer 173 side.

An insulating layer 272 is provided to cover an end portion of the conductive layer 171 functioning as a pixel electrode. An end portion of the insulating layer 272 is preferably tapered. For the insulating layer 272, one or both of an inorganic insulating film and an organic insulating film can be used.

The insulating layer 272 is provided to prevent an unintentional electric short-circuit between adjacent light-emitting elements and unintended light emission therefrom. The insulating layer 272 also has a function of preventing the contact of a metal mask with the conductive layer 171 in the case where the metal mask is used to form the EL layer.

The EL layers 172R, 172G, and 172B each include a region in contact with the top surface of the conductive layer 171 functioning as a pixel electrode and a region in contact with a surface of the insulating layer 272. End portions of the EL layers 172R, 172G, and 172B are positioned over the insulating layer 272.

As illustrated in FIG. 32B, there is a gap between the EL layers of two light-emitting elements with different emission colors. The EL layers 172R, 172G, and 172B are thus preferably provided not to be in contact with each other. This suitably prevents unintentional light emission (also referred to as crosstalk) from being caused by a current flowing through two adjacent EL layers. As a result, the contrast can be increased to achieve a display device with high display quality.

The EL layers 172R, 172G, and 172B can be formed separately by a vacuum evaporation method or the like using a shadow mask such as a metal mask. These layers may be formed separately by a photolithography method. The photolithography method achieves a display device with a high resolution, which is difficult to obtain in the case of using a metal mask.

A protective layer 271 is provided over the conductive layer 173 functioning as a common electrode to cover the light-emitting elements 61R, 61G, and 61B. The protective layer 271 has a function of preventing diffusion of impurities such as water into each light-emitting element from the above. For the material of the protective layer 271, the above-described material of the protective layer 681 can be referred to.

FIG. 32C illustrates a light-emitting element 61W emitting white light. The light-emitting element 61W includes an EL layer 172W emitting white light between the conductive layer 171 functioning as a pixel electrode and the conductive layer 173 functioning as a common electrode.

The EL layer 172W can have, for example, a stacked structure of two or more light-emitting layers that are selected so as to emit light of complementary colors. It is also possible to use a tandem EL layer in which a charge-generation layer is provided between light-emitting layers.

FIG. 32C illustrates three light-emitting elements 61W side by side. A coloring layer 264R is provided above the left light-emitting element 61W. The coloring layer 264R functions as a band path filter transmitting red light. Similarly, a coloring layer 264G transmitting green light is provided above the middle light-emitting element 61W, and a coloring layer 264B transmitting blue light is provided above the right light-emitting element 61W. This enables the display device to display a color image.

Here, the EL layer 172W is separated between two adjacent light-emitting elements 61W. This suitably prevents unintentional light emission from being caused by a current flowing through the EL layers 172W in the two adjacent light-emitting elements 61W. Particularly when the EL layer 172W is a stacked EL layer in which a charge-generation layer is provided between two light-emitting layers, the effect of crosstalk is more significant as the resolution increases, i.e., as the distance between adjacent pixels decreases, leading to lower contrast. Thus, the above structure can achieve a display device having both a high resolution and high contrast.

The EL layers 172W are preferably separated by a photolithography method. This can reduce the distance between light-emitting elements, achieving a display device with a higher aperture ratio than that formed using, for example, a shadow mask such as a metal mask.

This embodiment can be combined with any of the other embodiments as appropriate.

### Embodiment 7

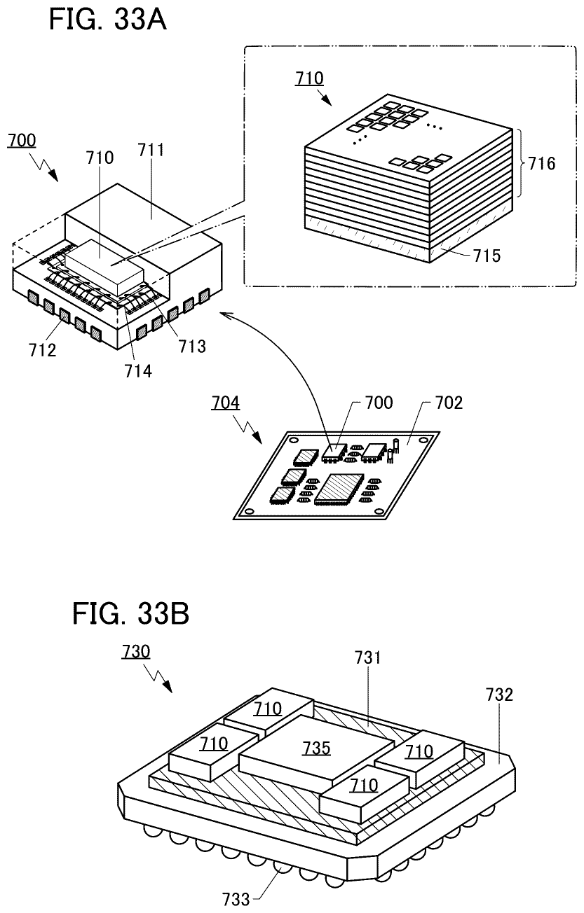

In this embodiment, application examples of the semiconductor device of one embodiment of the present invention are described with reference to FIGS. 33A and 33B, FIGS. 34A to 34E, FIGS. 35A to 35F, FIGS. 36A to 36G, and FIGS. 37A to 37F.

The semiconductor device of one embodiment of the present invention can be used for an electronic component, a large computer, a device for space, a data center (also referred to as DC), and a variety of electronic devices, for example. With the use of the semiconductor device of one embodiment of the present invention, an electronic component, a large computer, a device for space, a data center, and a variety of electronic devices can have lower power consumption and higher performance.

A display device including the semiconductor device of one embodiment of the present invention can be used for a display portion of any of a variety of electronic devices. The display device including the semiconductor device of one embodiment of the present invention can be easily increased in resolution and definition.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display device having one or both of such a high definition and a high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 33A is a perspective view of a substrate (a circuit board 704) provided with an electronic component 700. The electronic component 700 illustrated in FIG. 33A includes a semiconductor device 710 in a mold 711. FIG. 33A omits some components to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. Monolithically stacking the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 33B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 33B illustrates an example where the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

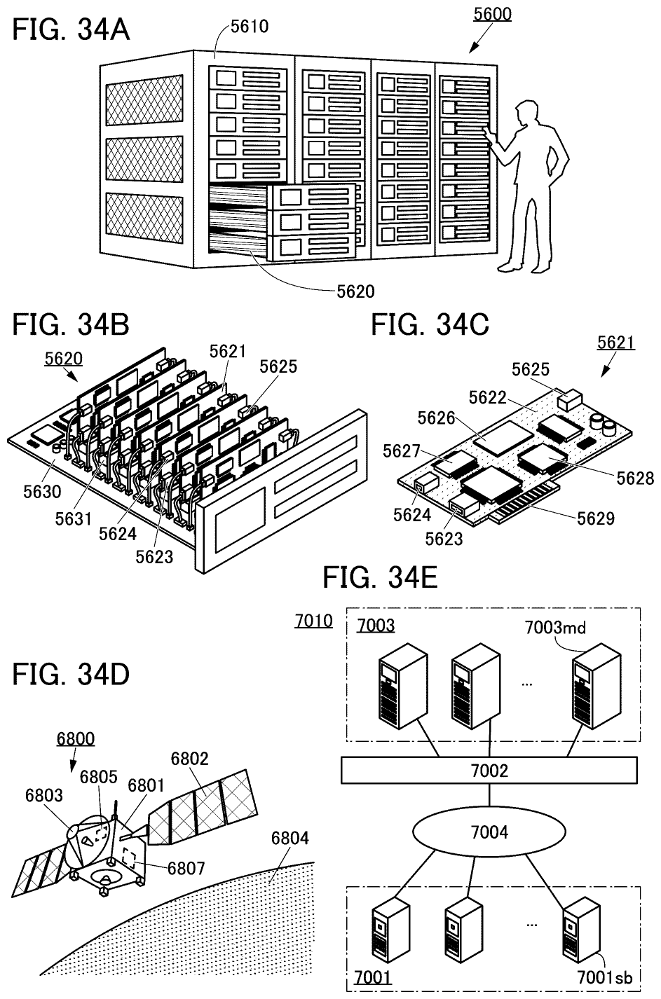

FIG. 34A is a perspective view of a large computer 5600. In the large computer 5600 illustrated in FIG. 34A, a plurality of rack mount computers 5620 are stored in a rack 5610. Note that the large computer 5600 may be referred to as a supercomputer.

The computer 5620 can have a structure illustrated in a perspective view in FIG. 34B, for example. In FIG. 34B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 34C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 34C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used as a device for space.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that although outer space refers to, for example, space at an altitude greater than or equal to 100 km, outer space described in this specification may include one or more of thermosphere, mesosphere, and stratosphere.

FIG. 34D illustrates an artificial satellite 6800 as an example of a device for space. The artificial satellite 6800 includes a body 6801, a solar panel 6802, an antenna 6803, a secondary battery 6805, and a control device 6807. In FIG. 34D, a planet 6804 in outer space is illustrated as an example.

Although not illustrated in FIG. 34D, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and high radiation tolerance as compared with a Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs setting a storage and a server for retaining a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 34E illustrates a storage system that can be used in a data center. A storage system 7010 illustrated in FIG. 34E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

### [Electronic Device]

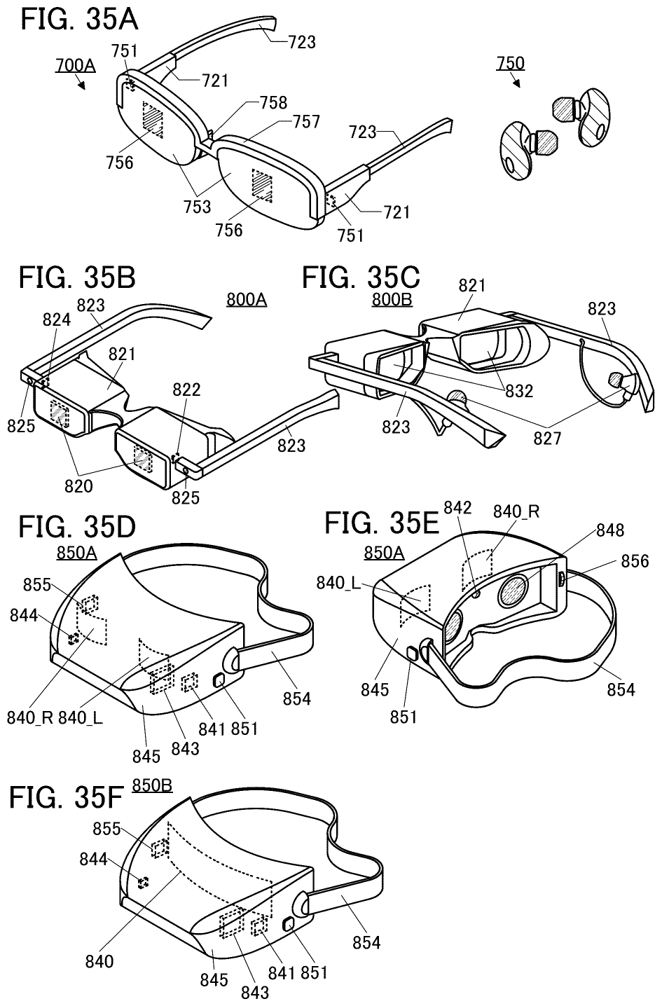

Examples of head-mounted wearable devices are described with reference to FIGS. 35A to 35F. These wearable devices have at least one of a function of displaying AR contents, a function of displaying VR contents, a function of displaying SR contents, and a function of displaying MR contents. The electronic device having a function of displaying contents of at least one of AR, VR,

SR, MR, and the like enables the user to feel a higher level of immersion.

An electronic device 700A illustrated in FIG. 35A includes a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display. The semiconductor device of one embodiment of the present invention can be used for the control portion (not illustrated). In that case, power consumption of the electronic device can be reduced.

The electronic device 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A is ana electronic device capable of AR display.

In the electronic device 700A, a camera capable of capturing images of the front side may be provided as the image capturing portion. Furthermore, when the electronic device 700A is provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A is provided with a battery so that charging can be performed wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

An electronic device 800A illustrated in FIG. 35B and an electronic device 800B illustrated in FIG. 35C each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic devices are capable of performing ultrahigh-resolution display. Such electronic devices provide a high sense of immersion to the user. The semiconductor device of one embodiment of the present invention can be used for the control portion 824. In that case, power consumption of the electronic devices can be reduced.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user wearing the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 35B and the like illustrate examples where the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 35A has a function of transmitting information to the earphones 750 with the wireless communication function.

The electronic device may include an earphone portion. The electronic device 800B in FIG. 35C includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

FIGS. 35D and 35E are perspective views of a goggle-type electronic device 850A for VR. FIGS. 35D and 35E illustrate an example where a housing 845 includes a pair of curved display devices 840 (a display device 840_R and a display device 840_L). The electronic device 850A includes a motion detection portion 841, an eye-gaze detection portion 842, an arithmetic portion 843, a communication portion 844, lenses 848, an operation button 851, a wearing tool 854, a sensor 855, a dial 856, and the like.

When the two display devices 840 are provided, the user's eyes can see the respective display devices. This allows a high-resolution image to be displayed even when three-dimensional display using parallax or the like is performed. In addition, the display device 840 is curved around an arc with an approximate center at the user's eye. This keeps a certain distance between the user's eye and the display surface of the display device 840, enabling the user to see a more natural image. Even when having what is called viewing angle dependence where the luminance or chromaticity of light changes depending on the viewing angle, the display device 840 can have a structure where the user's eye is positioned in the normal direction of the display surface of the display device 840; accordingly, the influence of the viewing angle dependence particularly in the horizontal direction can be practically ignored, enabling display of a more realistic video.

As illustrated in FIG. 35E, the lenses 848 are positioned between the display devices 840 and the user's eyes. FIG. 35E illustrates an example where the dial 856 for changing the positions of the lenses for visibility adjustment is provided. Note that in the case where the electronic device 850A has an autofocus function, the dial 856 for visibility adjustment is not necessarily provided.

FIG. 35F illustrates a goggles-type electronic device 850B including one display device 840. Such a structure can reduce the number of components.

The display device 840 can display an image for the right eye and an image for the left eye side by side on a right region and a left region, respectively. Thus, a three-dimensional image using binocular parallax can be displayed. Note that the display device 840 may display two different images side by side using parallax, or may display two same images side by side without using parallax.

One image which can be seen with both eyes may be displayed on the entire display device 840. Thus, a panorama image can be displayed from end to end of the field of view, which can provide a higher sense of reality.

The display device of one embodiment of the present invention can be used as the display device 840. Since the display device of one embodiment of the present invention has an extremely high resolution, even when an image is magnified using the lenses 848, the pixels are not perceived by the user, and thus a more realistic image can be displayed.

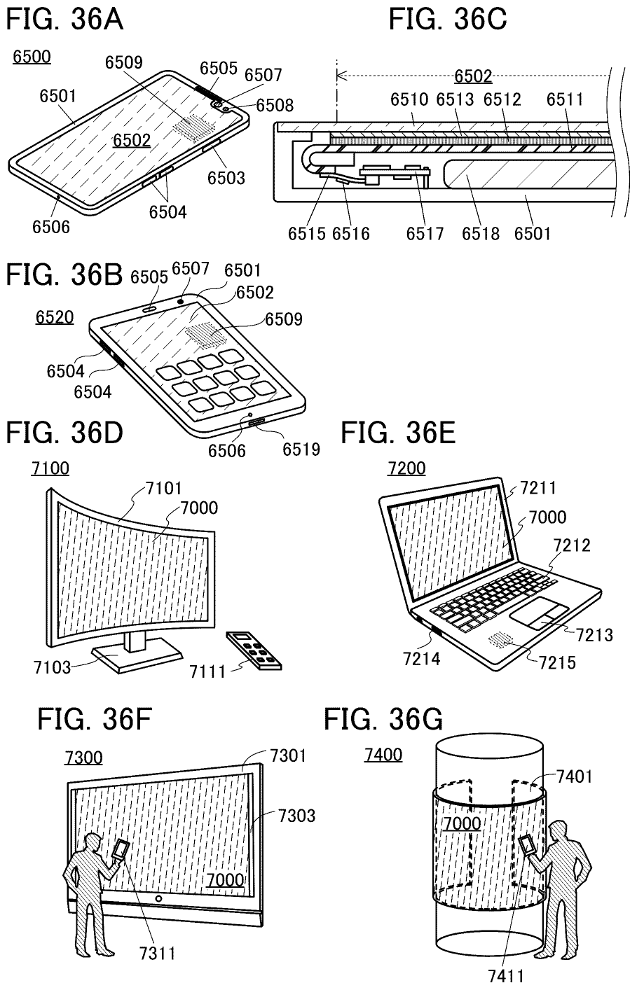

An electronic device 6500 in FIG. 36A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 in FIG. 36B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. Note that the control device 6509 includes, for example, one or more selected from a CPU, a GPU, and a memory device. The semiconductor device of one embodiment of the present invention can be used for one or both of the display portion 6502 and the control device 6509.

FIG. 36C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A display device of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic appliance. An electronic device with a narrow bezel can be obtained when part of the display panel 6511 is folded back so that the portion connected to the FPC 6515 is provided on the back side of a pixel portion.

FIG. 36D illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 36D can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 36E illustrates an example of a laptop personal computer. The laptop personal computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device of one embodiment of the present invention can be used for one or both of the display portion 7000 and the control device 7215.

FIGS. 36F and 36G illustrate examples of digital signage.

Digital signage 7300 illustrated in FIG. 36F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 36G is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIGS. 36F and 36G.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 36F and 36G, it is preferable that the digital signage 7300 or the digital signage 7400 can work with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The semiconductor device and the display device of one embodiment of the present invention can be used around a driver's seat in a car, which is a vehicle.

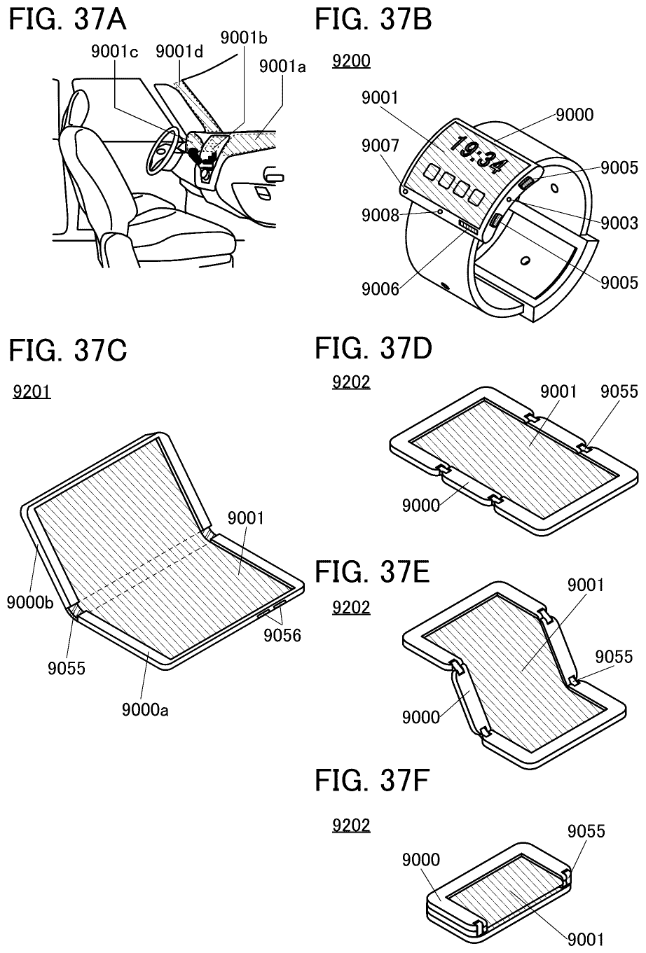

FIG. 37A illustrates the vicinity of a windshield inside a car. FIG. 37A illustrates a display panel 9001a, a display panel 9001b, and a display panel 9001c attached to a dashboard and a display panel 9001d attached to a pillar.

The display panels 9001a to 9001c can provide various kinds of information by displaying navigation data, a speedometer, a tachometer, a mileage, a fuel meter, a gearshift state, air-conditioning settings, and the like. Items displayed on the display panel, their layout, and the like can be changed as appropriate to suit the user's preferences, resulting in more sophisticated design. The display panels 9001a to 9001c can also be used as lighting devices.

The display panel 9001d can compensate for the view hindered by the pillar (blind areas) by displaying an image taken by an imaging unit provided for the car body. That is, displaying an image taken by the imaging unit provided on the outside of the car body leads to elimination of blind areas and enhancement of safety. Moreover, showing an image to compensate for the area that a driver cannot see makes it possible for the driver to confirm safety more easily and comfortably. The display panel 9001d can also be used as a lighting device.

FIG. 37B is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 37B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

FIG. 37C is a perspective view of a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housing 9000a and the housing 9000b) joined together with the hinge 9055.

FIGS. 37D to 37F are perspective views illustrating a foldable portable information terminal 9202. FIG. 37D is a perspective view of an opened state of the portable information terminal 9202, FIG. 37F is a perspective view of a folded state thereof, and FIG. 37E is a perspective view of a state in the middle of change from one of FIG. 37D and FIG. 37F to the other. In this manner, the portable information terminal 9202 can be folded in three.

The display portion 9001 of the portable information terminal 9202 is supported by three housings 9000 joined together with the hinges 9055.

In FIGS. 37C to 37F, the display device of one embodiment of the present invention can be used for the display portion 9001. The display portion 9001 can be folded with a radius of curvature greater than or equal to 0.1 mm and less than or equal to 150 mm, for example.

The portable information terminals 9201 and 9202 are highly portable when folded. When the portable information terminals 9201 and 9202 are opened, a seamless large display region is highly browsable.

The use of the semiconductor device of one embodiment of the present invention for one or more selected from an electronic component, a large computer, a device for space, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with any of the other embodiments as appropriate.

### Example 1

In this example, a semiconductor device including a transistor was fabricated, and electrical characteristics of the transistor were evaluated.

### <Fabrication 1 of Semiconductor Device>

Sample T1-1 was fabricated as a semiconductor device with reference to the structure of the transistor included in the semiconductor device illustrated in FIGS. 7A to 7C.

A silicon oxide film was provided over a silicon nitride film, and an oxide film containing silicon and hafnium was provided over the silicon oxide film. Next, the conductive layer 220 was provided over the oxide film containing silicon and hafnium. The conductive layer 220a was formed using a 5-nm-thick titanium nitride film formed by a sputtering method. The conductive layer 220b was formed using a 20-nm-thick tungsten film formed by a sputtering method. The conductive layer 220c was formed using a 20-nm-thick ITSO film formed by a sputtering method.

Next, the insulating layer 280 was formed.

The insulating layer 280a was formed using a 5-nm-thick silicon nitride film formed by a PEALD method. Next, as an insulating layer to be the insulating layer 280b, a 135-nm-thick silicon oxide film was deposited by a sputtering method. Then, a 100-nm-thick silicon nitride film was formed over the 135-nm-thick silicon oxide film. After that, the silicon nitride film was removed by CMP treatment, so that the top surface of the silicon oxide film was planarized. By the CMP treatment, a 80-nm-thick silicon oxide film was formed as the insulating layer 280b over the conductive layer 220.

As the insulating layer 280c, a 10-nm-thick silicon nitride film formed by a sputtering method was used.

Next, the conductive layer 240a was formed using 15-nm-thick tungsten deposited by a sputtering method. Next, the conductive layer 240b was formed using a 10 nm-thick ITSO film formed by a sputtering method.

Next, as described below, the opening portion 290 was formed by a dry etching method or the like.

First, an SOC film, an SOG film, and a resist film were formed in this order by a coating method. Then, a resist pattern was formed by photolithography, and the SOG film and the SOC film were processed using the resist pattern, whereby a mask pattern was formed.

The opening portion 290 was formed by dry etching using the formed mask pattern. As a dry etching gas for etching the conductive layer 240b, CH₄ and Ar were used. Then, washing was performed using dilute hydrofluoric acid. After that, Cl₂, O₂, and CF4 were used as a dry etching gas for etching the conductive layer 240a. For etching of the insulating layer 280, after etching using C₄F₈, C₄F₆, O₂, and Ar as a dry etching gas was performed, plasma treatment using Ar and O₂ was performed and plasma treatment using O₂ was performed. Then, washing was performed using dilute hydrofluoric acid. Through the above steps, the opening portion 290 was formed.

Next, the oxide semiconductor layer 230 was formed.

First, as the oxide semiconductor layer 230a, an indium oxide film was formed to a thickness of 2 nm by a thermal ALD method. Triethylindium was used as a precursor containing indium, and ozone (O₃) and oxygen (O₂) were used as oxidizers. The precursor and the oxidizers were alternately introduced repeatedly to form indium oxide. The substrate heating temperature was set to 200° C.

Next, as the oxide semiconductor layer 230b, an In—Ga—Zn oxide film was formed to a thickness of 5 nm by an RF sputtering method. For the formation of the oxide semiconductor layer 230b, an oxide target with an atomic ratio In:Ga:Zn=1:1:1.2 was used. Oxygen and argon were used as deposition gases, and the proportion of the flow rate of oxygen in the sum of the flow rates of oxygen and argon was 90%. The substrate heating temperature was set to 250° C.

Then, as the oxide semiconductor layer 230c, an indium oxide film was formed to a thickness of 3 nm by a thermal ALD method. Triethylindium was used as a precursor containing indium, and ozone (03) and oxygen (O₂) were used as oxidizers. The precursor and the oxidizers were alternately introduced repeatedly to form indium oxide. The substrate heating temperature was set to 200° C.

Next, the insulating layer 250 was formed. The insulating layer 250 had a three-layer structure.

The first layer was formed using a 1-nm-thick aluminum oxide film formed by a thermal ALD method. As a precursor, trimethylaluminum was used. Ozone was used as an oxidizer. The substrate heating temperature was set to 300° C. The second layer over the first layer was formed using a 2-nm-thick silicon oxide film formed by a PEALD method. As a precursor, an aminosilane compound was used. As an oxidizer, oxygen was used and argon plasma treatment was performed. The substrate heating temperature was set to 350° C. The third layer over the second layer was formed using a 2-nm-thick hafnium oxide film formed by a thermal ALD method. As a precursor, hafnium tetrachloride was used. Ozone was used as an oxidizer. The substrate heating temperature was set to 250° C.

Next, the conductive layer 260 was formed.

The conductive layer 260a was formed using a 5-nm-thick titanium nitride film formed by a metal CVD method. The substrate heating temperature was set to 400° C. The conductive layer 260b was formed using a 20-nm-thick tungsten film formed by a metal CVD method. The substrate heating temperature was set to 400° C.

Next, as the insulating layer 283, a silicon nitride film was formed to a thickness of 5 nm by a PEALD method. The substrate heating temperature was set to 400° C. Then, a silicon oxide film was formed to a thickness of approximately 40 nm as the insulating layer 285. The silicon nitride film was formed in such a manner that a silicon oxide film was formed by a sputtering method and then planarization treatment was performed thereon by CMP.

In the above-described manner, the transistor included in Sample T1-1, which is a semiconductor device, was fabricated.

### <Evaluation 1 of Electrical Characteristics of Transistor>

The electrical characteristics of the transistor included in Sample T1-1 were evaluated. Evaluated here were the electrical characteristics of the transistor where the opening portion 290 has a width of 60 nm and a substantially circular shape in a plan view. As the electrical characteristics, I_{d}-V_{g} characteristics and I_{d}-V_{d} characteristics were each measured. In each of the graphs described below showing the I_{d}-V_{g} characteristics, the vertical axis represents a drain current I_{d} [A], and the horizontal axis represents gate-source voltage (V_{g}) [V]. Furthermore, in each of the graphs showing the I_{d}-V_{d} characteristics, the vertical axis represents a drain current I_{d} [A], and the horizontal axis represents drain-source voltage (V_{d}) [V].

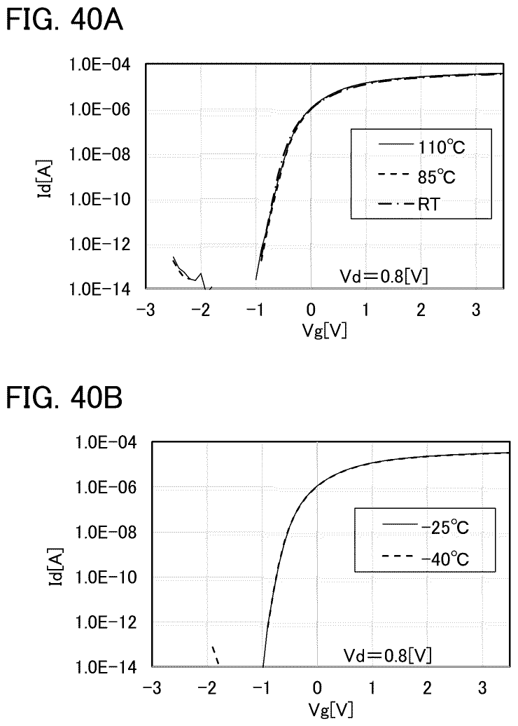

FIGS. 40A and 40B show measurement results of the I_{d}-V_{g} characteristics. The drain voltage V_{d} was set to 0.8 V, the source voltage Vs was set to 0 V, and the gate voltage V_{g} was swept from −2.5 V to +3.5 V in increments of 0.05 V. The measurement was performed under five temperature conditions of 110° C., 85° C., room temperature, −25° C., and −40° C. FIG. 40A shows data of 110° C., 85° C., and room temperature, and FIG. 40B shows data of −25° C. and −40° C.

### <Evaluation 2 of Electrical Characteristics of Transistor>

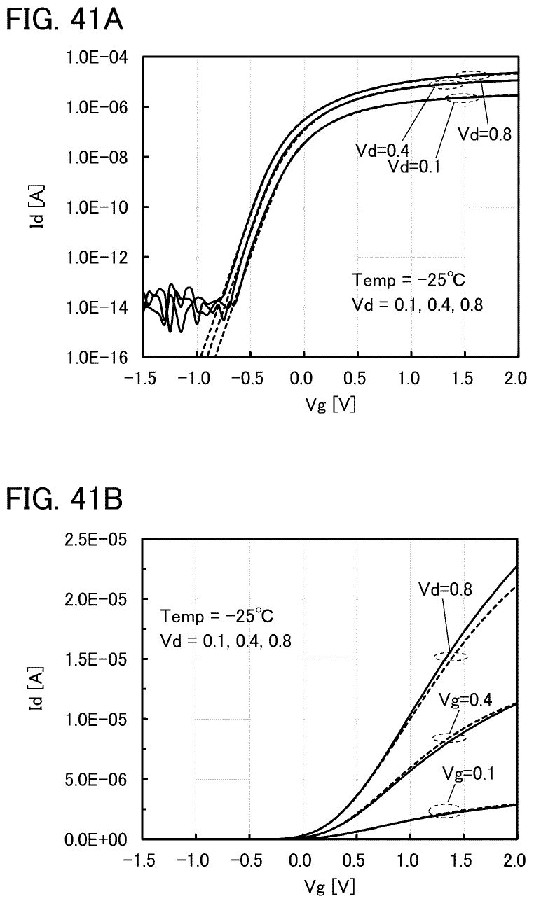

The I_{d}-V_{g} characteristics and the I_{d}-V_{d} characteristics were measured at −25° C. and −40° C., and the results of evaluation of the correspondence with the results obtained by simulation are shown in FIGS. 41A and 41B, FIGS. 42A and 42B, and FIGS. 43A and 43B. In the measurement of the I_{d}-V_{g} characteristics, the drain voltage V_{d} was set to three conditions: 0.1 V, 0.4 V, and 0.8 V. In the measurement of the I_{d}-V_{d} characteristics, the gate voltage V_{g} was set to three conditions: 1.0 V, 2.0 V, and 3.0 V; the source voltage Vs was set to 0 V; and the drain voltage V_{d} was swept from 0 V to +1.2 V in increments of 0.05 V.

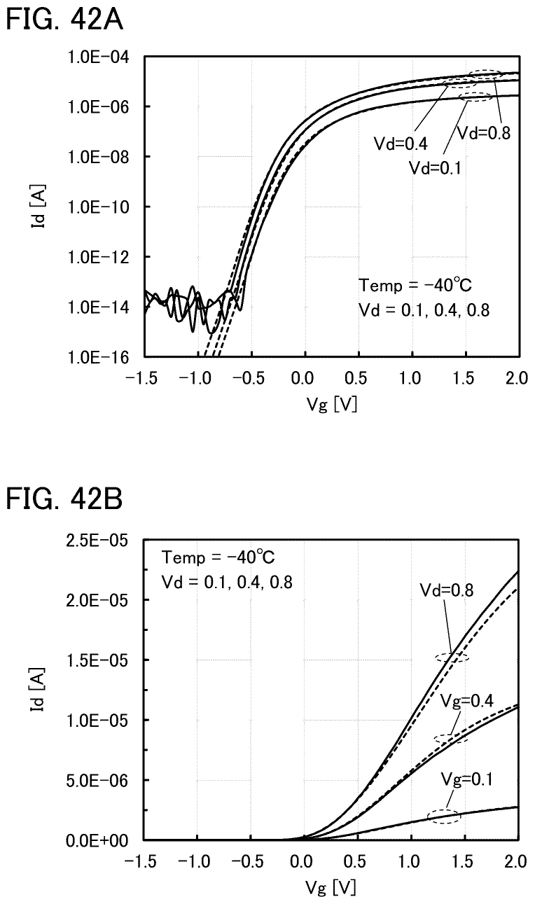

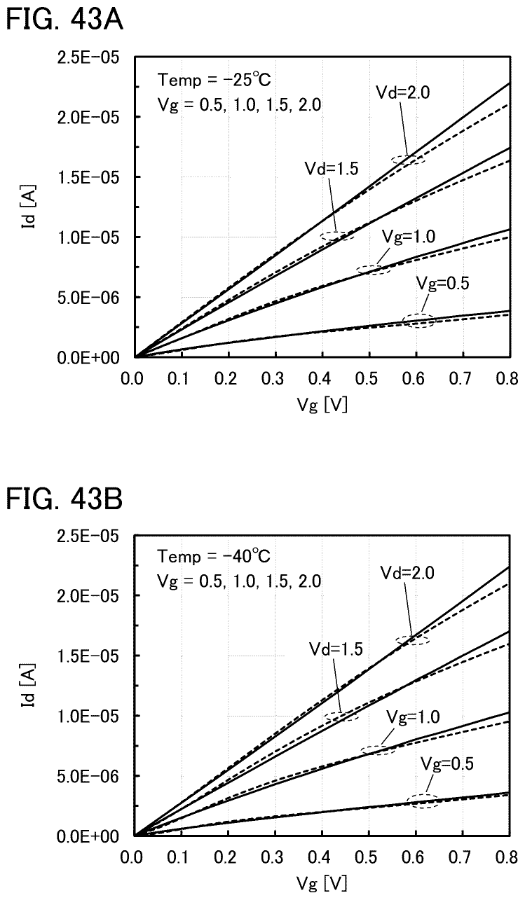

FIGS. 41A and 41B show the I_{d}-V_{g} characteristics at −25° C.; the vertical axis in FIG. 41A is on a logarithmic scale and the vertical axis in FIG. 41B is on a linear scale. FIGS. 42A and 42B show the I_{d}-V_{g} characteristics at −40° C.; the vertical axis in FIG. 42A is on a logarithmic scale and the vertical axis in FIG. 42B is on a linear scale. The horizontal axes represent the gate voltage V_{g}. FIGS. 43A and 43B show the I_{d}-V_{d} characteristics at −25° C. and −40° C., respectively. The solid lines in each of the graphs indicate measured values. The dashed lines indicate the results obtained by simulation. The measured values and the values obtained by simulation showed favorable agreement, and it was confirmed that a suitable simulation program with integrated circuit emphasis (SPICE) model was created.

It was confirmed that the semiconductor device fabricated in this example includes a transistor having favorable characteristics.

### Example 2

In this example, data for simulation was extracted by measurement using the transistor included in Sample T1-1 fabricated in Example 1 and circuit simulation was performed.

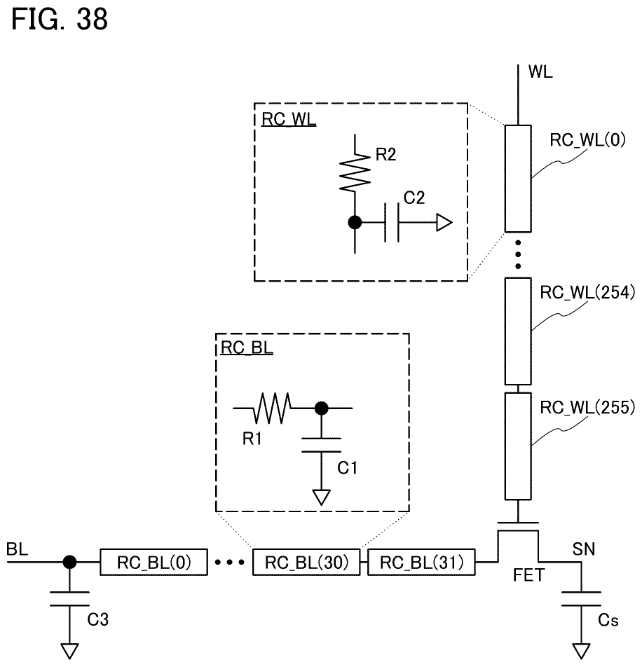

FIG. 38 is a circuit diagram which was used for the circuit simulation. FIG. 38 shows a memory cell included in a memory array and circuits connected to the wirings of the memory cell. Specifically, the memory cell has a configuration similar to that of the memory cell 951 shown in FIG. 23A. In addition, 32 circuits RC_BL corresponding to loads applied to the wiring BL from the other memory cells in the memory array are connected to the wiring BL, and 256 circuits RC_WL corresponding to loads applied to the wiring WL from the other memory cells in the memory array are connected to the wiring WL. The characteristics of the transistor fabricated in Example 1 were used for circuit simulation. Note that the measured threshold of the I_{d}-V_{g} characteristics of the transistor was shifted to a threshold suitable for circuit operation, and the threshold suitable for circuit operation was used in simulation.

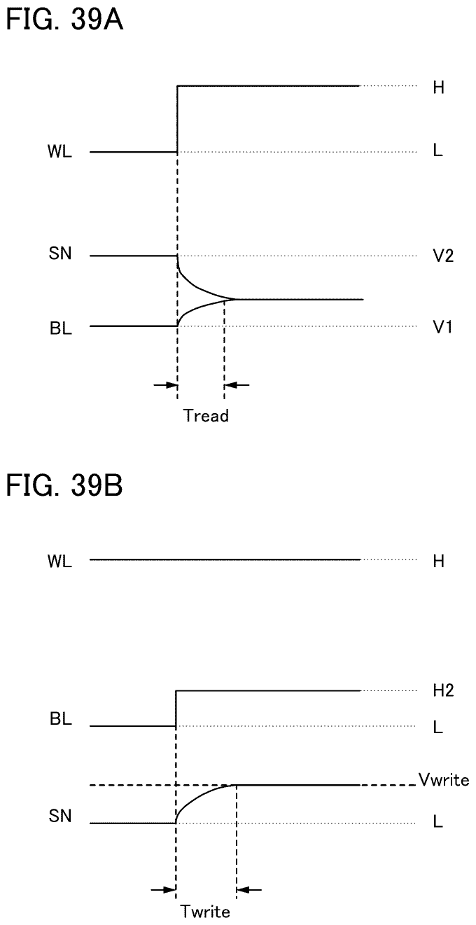

FIGS. 39A and 39B are timing charts showing the operation of the circuit illustrated in FIG. 38.

In FIG. 39A, the high voltage potential H of a wiring WL had two conditions: 2.5 V and 1.8 V, and the low voltage potential L was set to 0 V. A potential V2 of a node SN was set to 0.54 V. A potential V1 of the wiring BL was set to 0.40 V. In addition, the read time T_{read} was the time until the potentials of the wiring BL and the node SN matched 95%.

In FIG. 39B, the high voltage potential H of the wiring WL had two conditions: 2.5 V and 1.8 V. The high voltage potential H₂ of the wiring BL was set to 0.8 V, and the low voltage potential L was set to 0 V. In addition, V_{write} was set to 80% (0.64 V) of the high voltage potential H₂ of the wiring BL, and the write time T_{write} was the time taken for charging the node SN from 0 V to V_{write}.

The writing and reading operations were simulated at −25° C. Note that in the model used in the circuit simulation, the threshold voltage was changed from the measured electrical characteristics such that a current value corresponds to the retention time of 0.64 seconds at 85° C. under the conditions where the wiring WL and wiring BL had the low voltage potential L and the node SN had a potential of V2.

Table 1 and Table 2 show parameters used for the circuit simulation. Parameters in Table 1 were employed assuming a structure in which an interlayer film is provided between the conductive layer 260 and the conductive layer 240 to reduce the capacitance between the wirings as in the transistor illustrated in FIGS. 15A and 15B or the like in the above embodiment. Parameters in Table 2 were employed assuming a structure in which the insulating layer 250 is provided between the conductive layer 260 and the conductive layer 240 as in the transistor illustrated in FIGS. 7B and 7C or the like in the above embodiment.

TABLE 1

| | | |
|---|---|---|
| Cs | 1.77 | fF |
| C1 | 0.073 | fF |
| R1 | 32.2 | Ω |
| C2 | 0.079 | fF |
| R2 | 45 | Ω |
| C3 | 1.2 | fF |

TABLE 2

| | | |
|---|---|---|
| Cs | 3.0 | fF |
| C1 | 0.15 | fF |
| R1 | 32.2 | Ω |
| C2 | 0.15 | fF |
| R2 | 45 | Ω |
| C3 | 1.2 | fF |

Table 3 and Table 4 show calculation results of the write time T_{write} and the read time T_{read} at −25° C. Note that simulation whose results are shown in Table 3 and Table 4 was performed on the assumption that variation in threshold value in the characteristics of the transistors used for the circuit simulation was 5σ=250 mV. Table 3 shows calculation results using the parameters shown in Table 1, and Table 4 shows calculation results using the parameters shown in Table 2.

TABLE 3
5σ = 250 mV

| WL | T_{write} [ns] | T_{read} [ns] |
|---|---|---|
| 1.8 V | 2365.0 | 100.0 |
| 2.5 V | 0.58 | 0.47 |

TABLE 4
5σ = 250 mV

| WL | T_{write} [ns] | T_{read} [ns] |
|---|---|---|
| 1.8 V | 2388.0 | 122.8 |
| 2.5 V | 0.90 | 0.47 |

When the wiring WL was set to 2.5 V, the write time and the read time were each shorter than or equal to 1 ns.

Note that simulation whose results are shown in Table 5 and Table 6 was performed on the assumption that there was no variation in threshold value in the characteristics of the transistors used for the circuit simulation. Table 5 and Table 6 show calculation results of the write time T_{write} and the read time T_{read} at −25° C. Table 5 shows calculation results using the parameters shown in Table 1, and Table 6 shows calculation results using the parameters shown in Table 2.

TABLE 5
σ = 0 mV

| WL | T_{write} [ns] | T_{read} [ns] |
|---|---|---|
| 1.8 V | 1.49 | 0.77 |
| 2.5 V | 0.19 | 0.24 |

TABLE 6
σ = 0 mV

| WL | T_{write} [ns] | T_{read} [ns] |
|---|---|---|
| 1.8 V | 2.21 | 1.52 |
| 2.5 V | 0.31 | 0.51 |

### Example 3

In this example, samples (Sample H11 and Sample H12) in each of which a metal oxide layer was formed were fabricated, and crystal orientations of the metal oxides were evaluated.

### <Sample Fabrication 1>

First, a 100-nm-thick silicon oxide layer was formed over a silicon substrate by thermal oxidation treatment. Next, a metal oxide layer (corresponding to the oxide semiconductor layer 230) was formed over the silicon oxide layer.

The metal oxide layer of Sample H11 was formed in the following manner: an indium oxide film was formed to a thickness of 2 nm by a thermal ALD method, an In—Ga—Zn oxide film was formed to a thickness of 5 nm by an RF sputtering method using an oxide target with an atomic ratio In:Ga:Zn=1:1:1.2, and then an indium oxide film was formed to a thickness of 3 nm by a thermal ALD method. For the conditions of forming the indium oxide films by a thermal ALD method, Example 1 was referred to. For the formation of the In—Ga—Zn oxide film by a sputtering method, Example 1 was referred to.

The metal oxide layer of Sample H12 was formed in the following manner: an In—Ga—Zn oxide film was formed to a thickness of 2 nm by a thermal ALD method to have an atomic ratio In:Ga:Zn=1:1:1, an In—Ga—Zn oxide film was formed to a thickness of 5 nm by an RF sputtering method using an oxide target with an atomic ratio In:Ga:Zn=1:1:1.2, and then an In—Ga—Zn oxide film was formed to a thickness of 3 nm by a thermal ALD method to have an atomic ratio In:Ga:Zn=1:1:1.

In the In—Ga—Zn oxide film formed by a thermal ALD method, triethylindium, triethylgallium, and diethylzinc were used as a precursor containing indium, a precursor containing gallium, and a precursor containing zinc, respectively, and ozone (O₃) and oxygen (O₂) were used as oxidizers. The substrate heating temperature was set to 200° C.

Next, heat treatment was performed on each of Sample H11 and Sample H12 fabricated. Sample H11 subjected to the heat treatment is referred to as Sample H11_T. Sample H12 subjected to the heat treatment is referred to as Sample H12_T. The heat treatment was performed in a mixed atmosphere of an N₂ gas at a flow rate of 4 slm and an O₂ gas at a flow rate of 1 slm at 400° C. under atmospheric pressure for one hour.

### <TEM Observation and Evaluation of Crystal Orientation>

First, as a protective film for TEM observation, a carbon film was formed over the metal oxide layer.

Samples H11, H12, H11_T, and H12_T in each of which the carbon film was formed were thinned with a focused ion beam (FIB) and their cross sections were observed with a TEM. The TEM images were obtained using an atomic resolution analytical electron microscope JEM-ARM200F manufactured by JEOL Ltd. at an acceleration voltage of 200 kV by irradiation with an electron beam having a diameter of approximately 0.2 nmϕ.

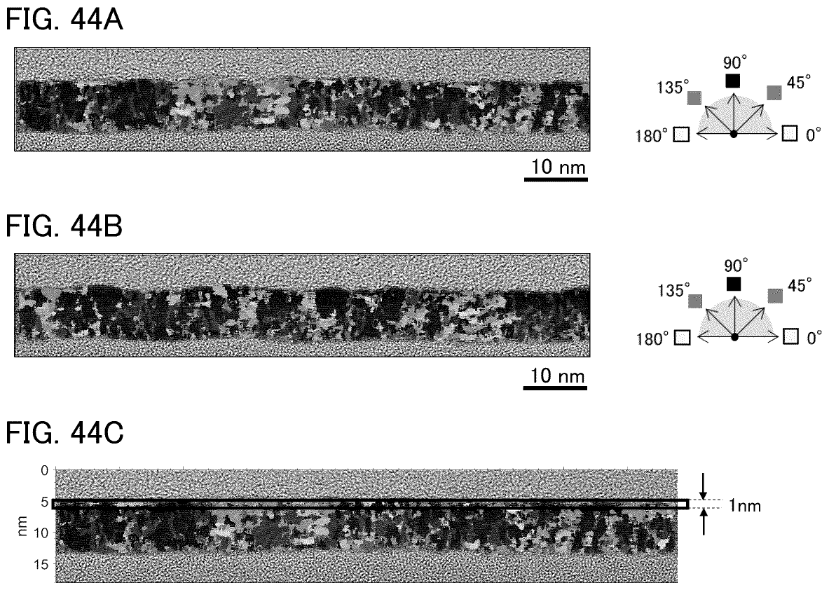

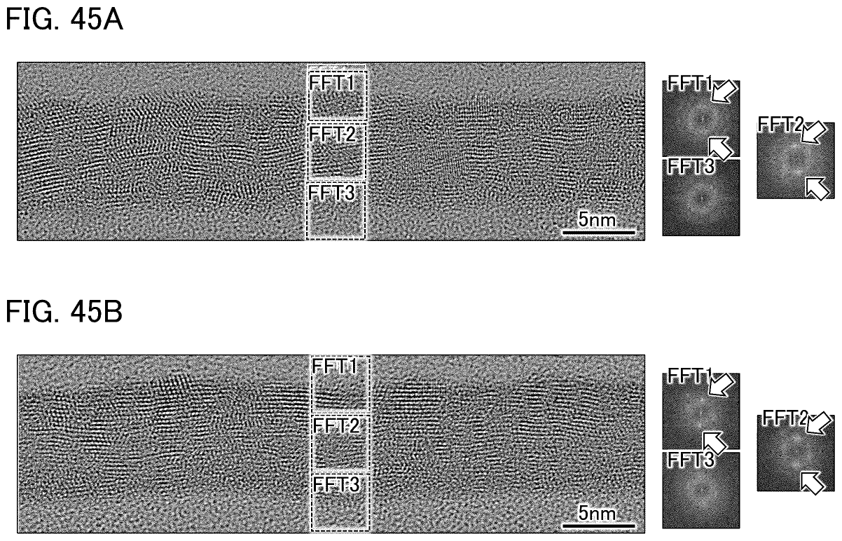

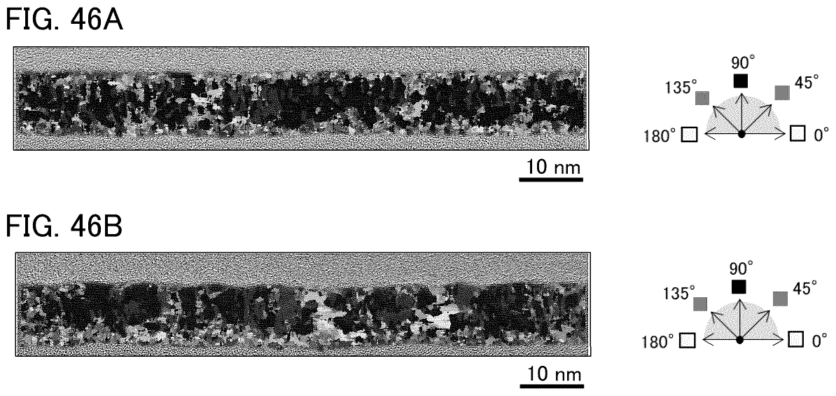

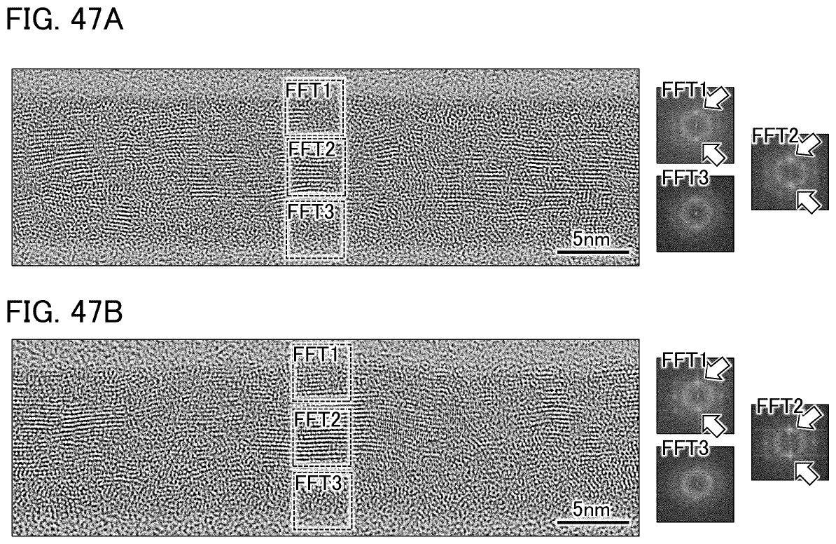

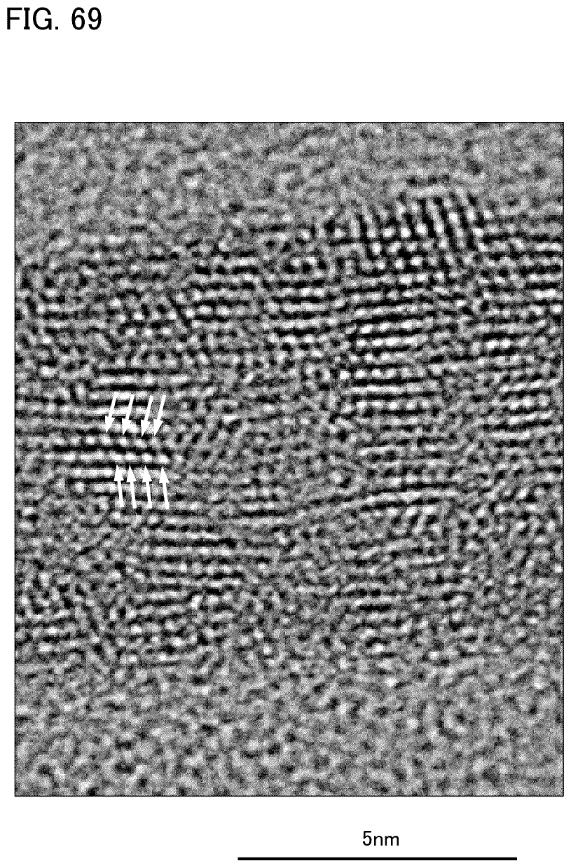

FIG. 44A and FIG. 45A are a diagram showing crystal orientation (hereinafter referred to as a map showing crystal orientation) and a cross-sectional TEM image, respectively, of Sample H11. FIG. 44B and FIG. 45B are a map showing crystal orientation and a cross-sectional TEM image, respectively, of Sample H11_T. FIG. 46A and FIG. 47A are a map showing crystal orientation and a cross-sectional TEM image, respectively, of Sample H12. FIG. 46B and FIG. 47B are a map showing crystal orientation and a cross-sectional TEM image, respectively, of Sample H12_T. FFT patterns of regions surrounded by squares (a region FFT1, a region FFT2, and a region FFT3) in the TEM images are shown on the right side of the cross-sectional TEM images. As an apparatus for the TEM image observation, JEM-ARM200F manufactured by JEOL Ltd. was used. The accelerating voltage was 200 kV. As the cross-sectional TEM image, an image having a total magnification of 4,000,000 times is shown. As the map showing crystal orientation, an image having a total magnification of 2,000,000 times was used. FIG. 69 is an enlarged view of a part of the TEM image shown in FIG. 45B. The metal atoms arranged in a layered manner are observed as arranged bright spots in the TEM image. In FIG. 69, the state where bright spots are arranged in a layered manner in a direction parallel to the surface on which the metal oxide layer is formed is indicated by arrows.

The map showing crystal orientation was obtained by performing FFT processing on each region in a cross-sectional TEM image to obtain an FFT pattern and analyzing the orientations of crystal axes in the regions. Note that a region where FFT was performed (also referred to as an FFT window) was a circle with a diameter of 1.0 nm.

In the maps showing crystal orientation, the directions of the crystal axes with respect to the surface on which the metal oxide layer is formed (the top surface of the silicon oxide layer) are represented by grayscale; black (a deep color) represents 90° and white (a light color) represents 0° and 180°. That is, the black (deep-color) region is a region where the c-axes of crystals are aligned in a direction perpendicular to the surface on which the metal oxide layer is formed (the top surface of the silicon oxide layer). In other words, the black (deep-color) region is a c-axis-aligned crystal region.

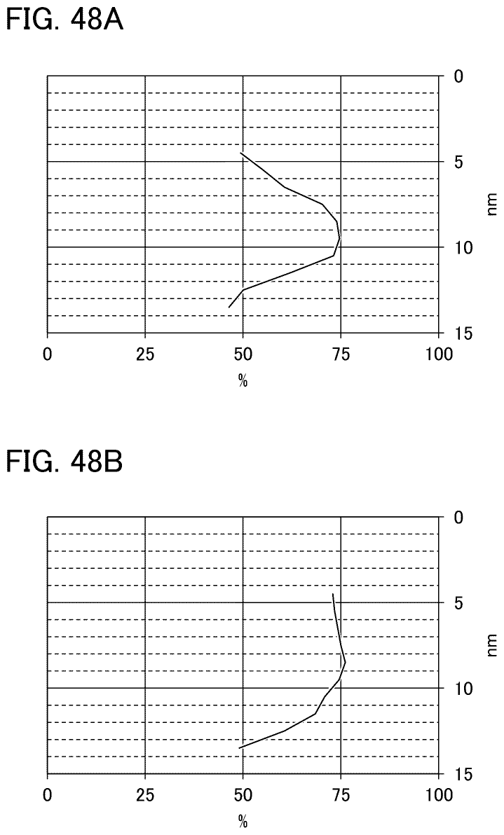

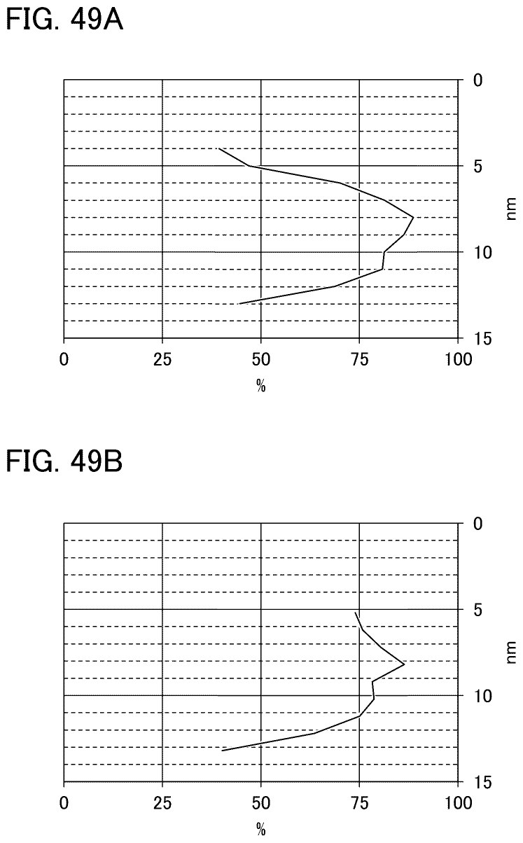

FIGS. 48A and 48B and FIGS. 49A and 49B show the c-axis alignment proportions of Sample H11, Sample 11_T, Sample 12, and Sample 12_T. A method for calculating the c-axis alignment proportion is described with reference to FIG. 44C. FIG. 44C is a map including the region shown in FIG. 44A. First, as shown in the example of FIG. 44C, the map showing crystal orientation is divided into strip regions each having a width in the height direction of 1 nm. The area proportion of the c-axis aligned crystal region in each divided strip region is calculated and plotted in a graph of the c-axis alignment proportion. Here, a region with the alignment angle in the range from 70° to 110° is the c-axis alignment region. In FIGS. 48A and 48B and FIGS. 49A and 49B, the vertical axis represents a distance from the top side of the map showing crystal orientation (FIGS. 44A and 44B and FIGS. 46A and 46B) in the strip regions, and the horizontal axis represents the proportion of the c-axis aligned crystal region in the strip regions.

It was suggested that in the oxide semiconductor layer of one embodiment of the present invention, not only the layer formed by a sputtering method but also a region formed over the layer by an ALD method and a region formed under the layer by an ALD method have excellent crystallinity.

### Example 4

In this example, SIMS analysis was performed on the oxide semiconductor layers of the samples formed in Example 3 and newly formed samples (Samples H13, H14, and H15).

### <Sample Fabrication 2>

First, a 100-nm-thick silicon oxide layer was formed over a silicon substrate by thermal oxidation treatment. Next, a metal oxide layer (corresponding to the oxide semiconductor layer 230) was formed over the silicon oxide layer.

As the metal oxide layer of Sample H13, a 5-nm-thick In—Ga—Zn oxide film was formed by an RF sputtering method using an oxide target with an atomic ratio In:Ga:Zn=1:1:1.2.

As the metal oxide layer of Sample H14, a 5-nm-thick In—Ga—Zn oxide film was formed by a thermal ALD method to have an atomic ratio of In:Ga:Zn=1:1:1.

The metal oxide layer of Sample H15 was formed in the following manner: an In—Ga—Zn oxide film was formed to a thickness of 5 nm by an RF sputtering method using an oxide target with an atomic ratio In:Ga:Zn=1:1:1.2, and then an In—Ga—Zn oxide film was formed to a thickness of 5 nm by a thermal ALD method to have an atomic ratio In:Ga:Zn=1:1:1.

In the In—Ga—Zn oxide film formed by a thermal ALD method, triethylindium, triethylgallium, and diethylzinc were used as a precursor containing indium, a precursor containing gallium, and a precursor containing zinc, respectively, and ozone (03) and oxygen (O₂) were used as oxidizers.

Next, heat treatment was performed on each of Samples H13 to H15 fabricated. Samples H13, H14, and H15 subjected to the heat treatment are referred to as Samples H13_T, H14_T, and H15_T, respectively. The heat treatment was performed in a mixed atmosphere of an N₂ gas at a flow rate of 4 slm and an O₂ gas at a flow rate of 1 slm at 400° C. under atmospheric pressure for one hour.

### <Sims Analysis>

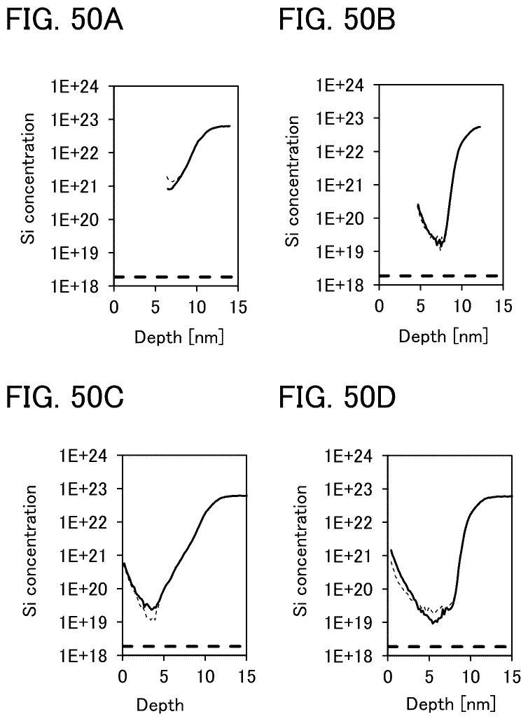

The profile of Si was evaluated by SIMS analysis of the fabricated samples. The direction of the SIMS analysis is from the surface of the oxide semiconductor layer to the substrate side. A PHI ADEPT-1010 quadrupole SIMS instrument manufactured by ULVAC-PHI, Inc was used as the apparatus for the measurement (D-SIMS). As the ion source of the primary ion beam, Cs was used. The accelerating voltage was 2 kV. Si was detected as a negative secondary ion “28Si−(M/z=28)”. The obtained secondary ion intensity was converted into a concentration (unit: atoms/cm³) by referring to data of a standard sample with known concentration which was obtained at the same time. The dashed lines in FIG. 50A, FIG. 50B, FIG. 50C, and FIG. 50D show the SIMS analysis results of Samples H13, H14, H15, and H12, respectively. The solid lines in FIG. 50A, FIG. 50B, FIG. 50C, and FIG. 50D show the SIMS analysis results of Samples H13_T, H14_T, H15_T, and H12_T, respectively.

In Samples H12, H12_T, H11, and H11_T in which a metal oxide layer was formed by an ALD method as a layer in contact with the silicon oxide layer, the metal oxide layer had a low silicon concentration, which suggested that formation of a mixed layer of the metal oxide layer and the silicon oxide layer was inhibited. Furthermore, the silicon concentration in Sample H12_T was lowered by heat treatment.

### Example 5

In this example, a semiconductor device including a transistor was fabricated, and electrical characteristics of the transistor were evaluated.

### <Fabrication 2 of Semiconductor Device>

With reference to the fabrication method described in Example 1, three samples, Samples T1-2, T2, and T3, were fabricated as semiconductor devices including transistors.

For Sample T1-2, the fabrication conditions of Sample T1-1 described in Example 1 were used. For Sample T2, the thickness of the silicon oxide film in the second layer of the insulating layer 250 was set to 1.5 nm, and the other fabrication conditions were the conditions of Sample T1-1 described in Example 1. For Sample T3, the thickness of the silicon oxide film in the second layer of the insulating layer 250 was set to 1 nm, and the other fabrication conditions were the conditions of Sample T1-1 described in Example 1.

### <Evaluation 3 of Electrical Characteristics of Transistor>

The I_{d}-V_{g} characteristics of transistors included in Sample T1-1 fabricated in Example 1 and Samples T1-2, T2, and T3 fabricated in this example were measured. In the transistors evaluated here, the opening portion 290 has a width of 60 nm and a substantially circular shape in a plan view.

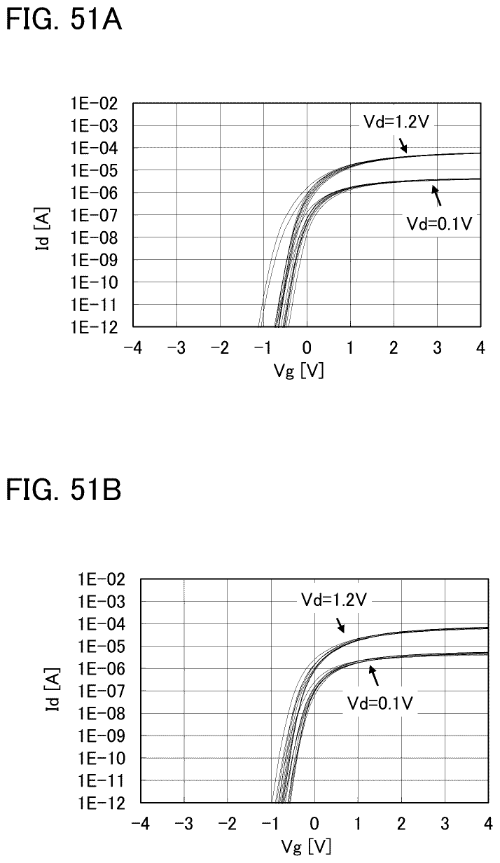

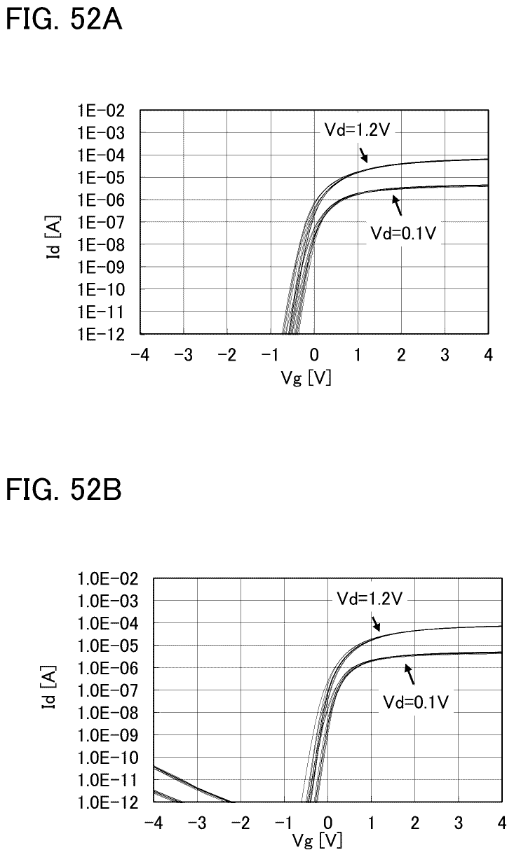

In the measurement, the drain voltage V_{d} was set to two conditions: 0.1 V and 1.2 V, and the gate voltage was swept from −4 V to +4 V in increments of 0.1 V. The measurement temperature was room temperature. FIG. 51A, FIG. 51B, FIG. 52A, and FIG. 52B show the I_{d}-V_{g} characteristics of the transistors of Sample T1-1, Sample T1-2, Sample T2, and Sample T3, respectively. The on-state current Iₒₙ, the shift voltage Vₛₕ, and the S value of the transistors were calculated. The on-state current Iₒₙ was a value of a drain current at V_{g}=Vₛₕ+2.5 V in the I_{d}-V_{g} characteristics at a drain voltage V_{d} of 1.2 V. The shift voltage Vₛₕ was obtained as the value of the gate voltage V_{g} at a drain current I_{d} of 1 pA in the I_{d}-V_{g} characteristics at a drain voltage V_{d} of 1.2 V. The S value was calculated at a drain current I_{d} of 1 pA in the I_{d}-V_{g} characteristics at a drain voltage V_{d} of 1.2 V. Table 7 shows the on-state currents Iₒₙ, the shift voltages Vₛₕ, and the S values of the transistors included in the samples.

TABLE 7

| | T1-1 | T1-2 | T2 | T3 |
|---|---|---|---|---|
| Iₒₙ [μA] | 30.54 | 33.75 | 36.15 | 45.56 |
| Vₛₕ [V] | −0.72 | −0.80 | −0.59 | −0.44 |
| S value [mV/dec] | 84.84 | 83.77 | 80.88 | 75.43 |

As the thickness of the insulating layer 250 functioning as the gate insulating layer was reduced, the S value was improved, i.e., decreased. As the thickness of the insulating layer 250 was reduced, the on-state current was increased.

### <Evaluation 4 of Electrical Characteristics of Transistor>

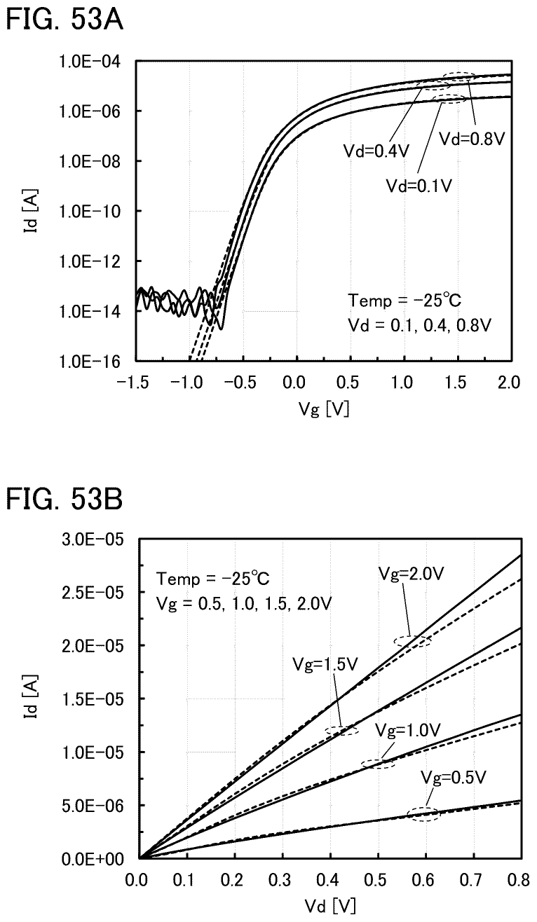

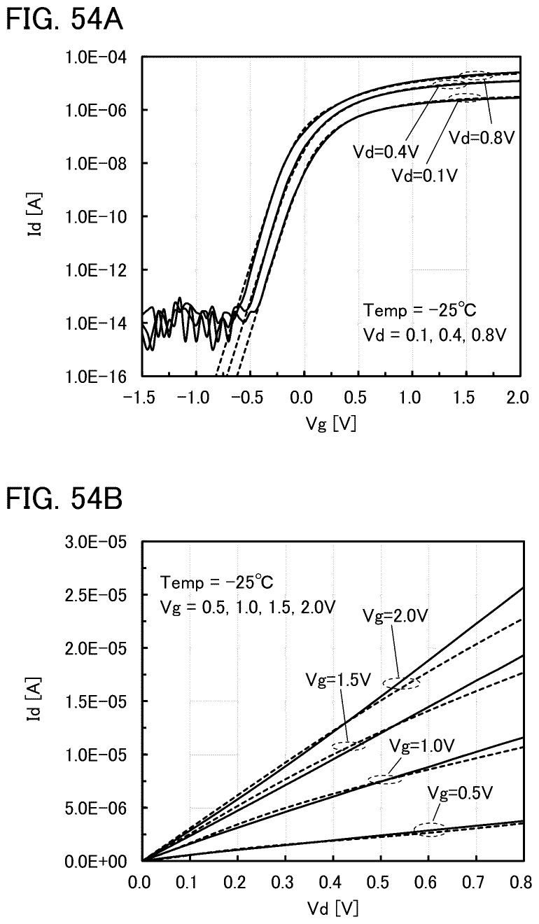

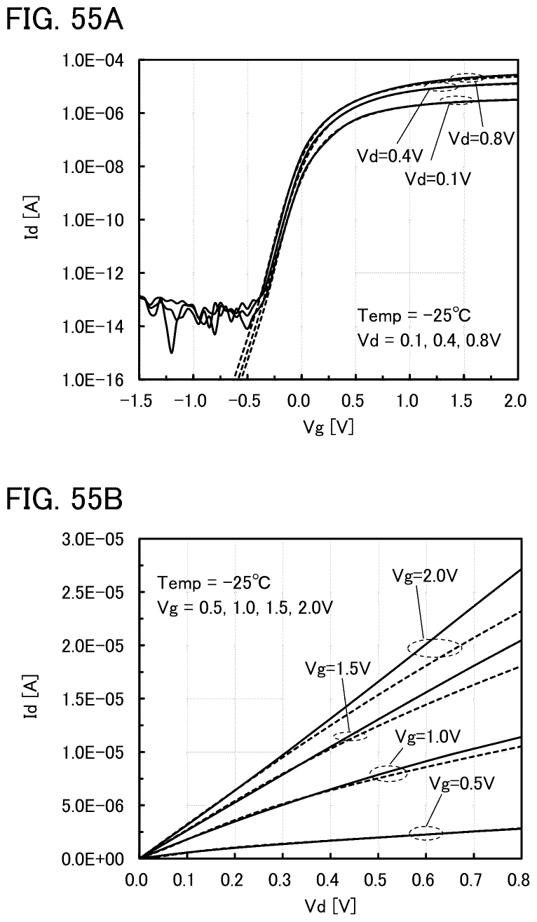

The I_{d}-V_{g} characteristics and the I_{d}-V_{d} characteristics of Samples T1-2, T2, and T3 were measured; FIG. 53A, FIG. 53B, FIG. 54A, FIG. 54B, FIG. 55A, and FIG. 55B show the results of evaluation of agreement between the measured results and the results obtained by simulation. In the transistors evaluated here, the opening portion 290 has a width of 60 nm and a substantially circular shape in a plan view. In the measurement of the I_{d}-V_{g} characteristics, the drain voltage V_{d} was set to three conditions: 0.1 V, 0.4 V, and 0.8 V; and the gate voltage V_{g} was swept from −1.5 V to +2.0 V in increments of 0.1 V. In the measurement of the I_{d}-V_{d} characteristics, the gate voltage V_{g} was set to four conditions: 0.5 V, 1.0 V, 1.5 V, and 2.0 V; the source voltage Vs was set to 0 V; and the drain voltage V_{d} was swept from 0 V to +0.8 V in increments of 0.05 V.

FIGS. 53A and 53B show the I_{d}-V_{g} characteristics and the I_{d}-V_{d} characteristics of Sample T1-2 at −25° C. FIGS. 54A and 54B show the I_{d}-V_{g} characteristics and the I_{d}-V_{d} characteristics of Sample T2 at −25° C. FIGS. 55A and 55B show the I_{d}-V_{g} characteristics and the I_{d}-V_{d} characteristics of Sample T3 at −25° C. The solid lines in each of the graphs indicate measured values. The dashed lines indicate the results obtained by simulation. The measured values and the values obtained by simulation showed favorable agreement, and it was confirmed that a suitable simulation program with integrated circuit emphasis (SPICE) model was created.

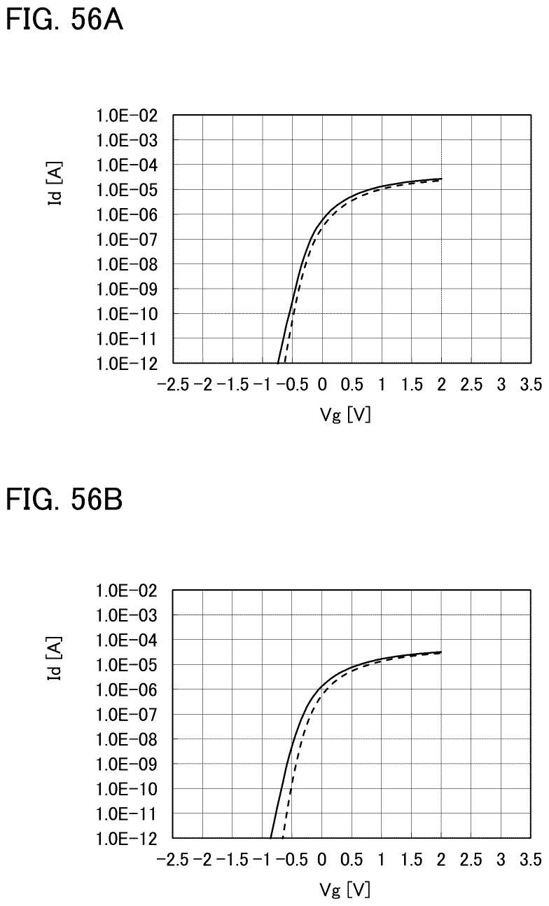

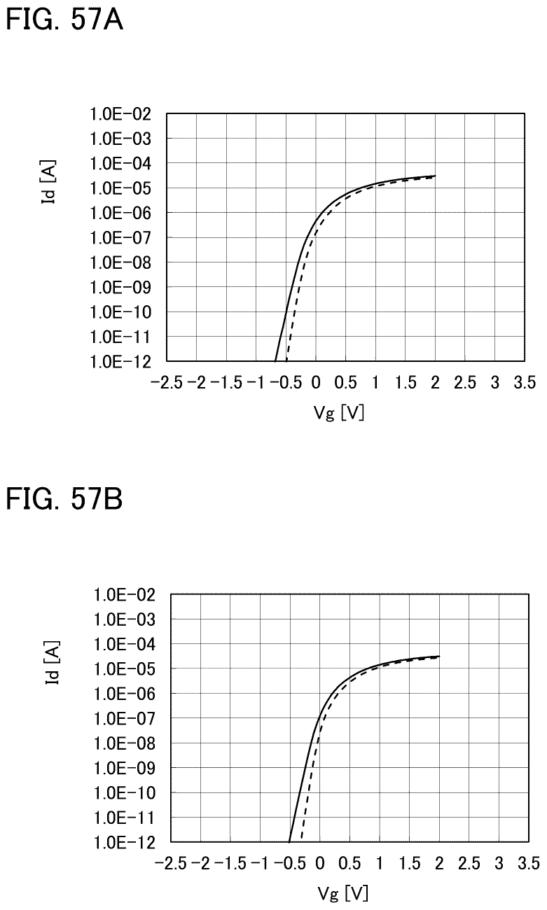

FIG. 56A shows the I_{d}-V_{g} characteristics of Sample T1-1 at 85° C. and −25° C. FIG. 56B shows the I_{d}-V_{g} characteristics of Sample T1-2 at 85° C. and −25° C. FIG. 57A shows the I_{d}-V_{g} characteristics of Sample T2 at 85° C. and −25° C. FIG. 57B shows the I_{d}-V_{g} characteristics of Sample T3 at −25° C. FIGS. 56A and 56B and FIGS. 57A and 57B show characteristics with a drain voltage V_{d} of 0.8 V. The solid lines correspond to data at 85° C. and the dashed lines correspond to data at −25° C.

### Example 6

In this example, data for simulation was extracted by measurement using the transistors included in Samples T1-2, T2, and T3 fabricated in Example 5 and circuit simulation was performed. The circuit simulation was performed using the circuit diagram, timing chart of circuit operation, parameters, and operation conditions in Example 2.

Table 8 to Table 10 show calculation results of the write time T_{write} and the read time T_{read} at −25° C. Note that Table 8 to Table 10 show the results of circuit simulation performed on the assumption that variation in threshold value was 5 σ in the transistor characteristics. Furthermore, it was assumed that σ=50 mV. Table 8 shows the calculation results of Sample T1-2, Table 9 shows the calculation results of Sample T2, and Table 10 shows the calculation results of Sample T3. In each of the tables, the description “PU” in the structure represents calculation results using the parameters shown in Table 1, and the description “N” in the structure represents calculation results using the parameters shown in Table 2.

TABLE 8
T1-2 5σ = 250 mV

| WL | |
|---|---|
| Twrite [ns] | Tread [ns] |

Structure

| | N | PU | N | PU |
|---|---|---|---|---|
| 1.8 V | 8.2 × 10³ | 8.8 × 10³ | 221.9 | 186.1 |
| 2.5 V | 0.9 | 0.55 | 0.96 | 0.47 |

TABLE 9
T2 5σ = 250 mV

| WL | |
|---|---|
| Twrite [ns] | Tread [ns] |

Structure

| | N | PU | N | PU |
|---|---|---|---|---|
| 1.8 V | 4.0 × 10⁴ | 4.3 × 10⁴ | 1114 | 1104 |
| 2.5 V | 0.78 | 0.52 | 0.93 | 0.46 |

TABLE 10
T3 5σ = 250 mV

| WL | |
|---|---|
| Twrite [ns] | Tread [ns] |

Structure

| | N | PU | N | PU |
|---|---|---|---|---|
| 1.8 V | 633.7 | 672.4 | 21.21 | 13.48 |
| 2.5 V | 0.45 | 0.30 | 0.61 | 0.29 |

In each of Samples T1-2, T2, and T3, the write time and the read time were each shorter than or equal to 1 ns when the wiring WL was set to 2.5 V.

Simulation was performed on the assumption that there was no variation in threshold value (σ=0 mV) in the transistor characteristics used for the circuit simulation; Table 11 to Table 13 show the simulation results. Table 11 shows the calculation results of Sample T1-2, Table 12 shows the calculation results of Sample T2, and Table 13 shows the calculation results of Sample T3.

TABLE 11
T1-2 σ = 0 mV

| WL | |
|---|---|
| Twrite [ns] | Tread [ns] |

Structure

| | N | PU | N | PU |
|---|---|---|---|---|
| 1.8 V | 2.14 | 1.45 | 1.65 | 0.82 |
| 2.5 V | 0.28 | 0.18 | 0.50 | 0.24 |

TABLE 12
T2 σ = 0 mV

| WL | |
|---|---|
| Twrite [ns] | Tread [ns] |

Structure

| | N | PU | N | PU |
|---|---|---|---|---|
| 1.8 V | 2.26 | 1.58 | 1.58 | 0.81 |
| 2.5 V | 0.26 | 0.17 | 0.48 | 0.24 |

TABLE 13
T3 σ = 0 mV

| WL | |
|---|---|
| Twrite [ns] | Tread [ns] |

Structure

| | N | PU | N | PU |
|---|---|---|---|---|
| 1.8 V | 0.88 | 0.58 | 0.77 | 0.37 |
| 2.5 V | 0.23 | 0.14 | 0.38 | 0.17 |

### Example 7

In this example, a semiconductor device including a transistor was fabricated, and electrical characteristics of the transistor were evaluated.

### <Fabrication 3 of Semiconductor Device>

With reference to the fabrication method described in Example 1, two samples, Samples T4-1 and T4-2, were fabricated as semiconductor devices including transistors.

Samples T4-1 and T4-2 were fabricated under the same conditions in different fabrication lots. For the fabrication of Samples T4-1 and T4-2, the fabrication conditions of Sample T1-1 described in Example 1 were used. Note that as described below, the fabrication methods of Samples T4-1 and T4-2 were different from that of Sample T1-1 mainly in three points: formation of the opening portion 290, formation of the oxide semiconductor layer 230, and microwave treatment after formation of the insulating layer 250.

In the formation of the opening portion 290, CH₂F₂, CHF₃, CF₄, O₂, and Ar were used as dry etching gases in etching of the insulating layer 280.

The oxide semiconductor layer 230 was formed in the following manner.

First, as the oxide semiconductor layer 230a, an In—Zn oxide film was formed to a thickness of 2 nm by a thermal ALD method. Triethylindium was used as a precursor containing indium. Diethylzinc was used as a precursor containing zinc, and ozone (O₃) and oxygen (O₂) were used as oxidizers. The precursors and the oxidizers were alternately introduced repeatedly to form an In—Zn oxide film having an atomic ratio In:Zn=2:1. The substrate heating temperature was set to 200° C.

Next, as the oxide semiconductor layer 230b, an In—Sn—Zn oxide film was formed to a thickness of 5 nm by a pulsed DC sputtering method. For the formation of the oxide semiconductor layer 230b, an oxide target with an atomic ratio In:Sn:Zn=4:0.1:1 was used. Oxygen and argon were used as deposition gases, and the proportion of the flow rate of oxygen in the sum of the flow rates of oxygen and argon was 10%. The substrate heating temperature was set to 250° C.

Then, as the oxide semiconductor layer 230c, an In—Zn oxide film was formed to a thickness of 3 nm by a thermal ALD method. The In—Zn oxide film was formed under the same conditions as those for the oxide semiconductor layer 230a to have an atomic ratio In:Zn=2:1.

After the insulating film to be the insulating layer 250 was formed, microwave treatment was performed. In the microwave treatment, an argon gas at 150 sccm and an oxygen gas at 50 sccm were used as treatment gases, the power was 4000 W, the pressure was 400 Pa, the treatment temperature was 400° C., and the treatment time was 600 seconds.

### <Evaluation 5 of Electrical Characteristics of Transistor>

The I_{d}-V_{g} characteristics of transistors included in Samples T4-1 and T4-2 fabricated in this example were measured. Evaluated were the electrical characteristics of the transistor where the opening portion 290 has a width of 60 nm and a substantially circular shape in a plan view.

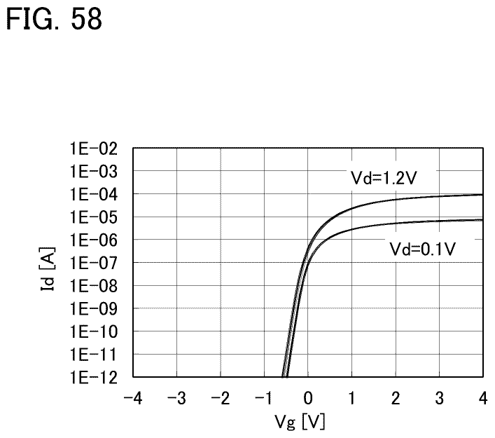

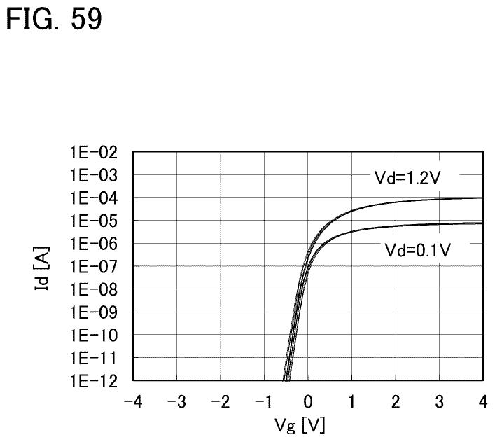

In the measurement, the drain voltage V_{d} was set to two conditions: 0.1 V and 1.2 V, and the gate voltage was swept from −4 V to +4 V in increments of 0.1 V. The measurement temperature was room temperature. FIG. 58 and FIG. 59 show the I_{d}-V_{g} characteristics of the transistors of Sample T4-1 and Sample T4-2, respectively. The on-state current Iₒₙ, the shift voltage Vₛₕ, and the S value of the transistors were calculated. The on-state current Iₒₙ was a value of a drain current at V_{g}=Vₛₕ+2.5 V in the I_{d}-V_{g} characteristics at a drain voltage V_{d} of 1.2 V. The shift voltage Vₛₕ was obtained as the value of the gate voltage V_{g} at a drain current I_{d} of 1 pA in the I_{d}-V_{g} characteristics at a drain voltage I_{d} of 1.2 V. The S value was calculated at a drain current I_{d} of 1 pA in the I_{d}-V_{g} characteristics at a drain voltage V_{d} of 1.2 V. Table 14 shows the on-state currents Iₒₙ, the shift voltages Vₛₕ, and the S values of the transistors included in the samples.

TABLE 14

| | T4-1 | T4-2 |
|---|---|---|
| Ion [μA] | 53.9 | 61.6 |
| Vsh [V] | −0.59 | −0.55 |
| S Value [mV/dec] | 83.9 | 79.9 |

### <Circuit Simulation>

Data for simulation was extracted by a method similar to that described in the above example and circuit simulation was performed on Samples T4-1 and T4-2. For the circuit simulation, FIG. 38, FIG. 39A, FIG. 39B, and the like were referred to and timing of circuit operation, parameters, and operation conditions in Example 2 were used.

A reading operation is described. In FIG. 39A, the high voltage potential H of a wiring WL had two conditions: 2.0 V and 1.8 V, and the low voltage potential L was set to 0 V. A potential V2 of a node SN was set to 0.54 V. A potential V1 of the wiring BL was set to 0.40 V. In addition, the read time T_{read} was the time until the potentials of the wiring BL and the node SN matched 95%.

A writing operation is described. In FIG. 39B, the high voltage potential H of the wiring WL had two conditions: 2.0 V and 1.8 V. The high voltage potential H₂ of the wiring BL was set to 0.8 V, and the low voltage potential L was set to 0 V. In addition, V_{write} was set to 80% (0.64 V) of the high voltage potential H₂ of the wiring BL, and the write time T_{write} was the time taken for charging the node SN from 0 V to V_{write}.

The simulation of the writing and reading operations was performed on the assumption that the temperature was from −25° C. to 85° C. Note that in the model used in the circuit simulation, the threshold voltage was changed from the measured electrical characteristics such that a current value corresponds to the retention time of 0.64 seconds.

The necessary amount of change in threshold value was estimated as follows.

In the first method, assuming that the off-leakage current flowing through the transistor was constant and the potential of the node SN was changed by continuous flow of the off-leakage current at 85° C. for 0.64 seconds, a necessary amount of change was estimated such that a change in the potential of the node SN was less than or equal to 0.1 V. Note that the estimation was performed on the assumption that the voltage between the wiring BL and the node SN was the highest and that the voltage between the source and the drain of the transistor was 0.8 V.

In the second method, a necessary amount of change was estimated such that a change in the potential of the node SN was less than or equal to 0.1 V in consideration of a change in the gate-source voltage of the transistor and a change in the off-leakage current due to the change in the potential of the node SN. Specifically, the potential of the node SN was changed in increments of 0.1 mV to calculate the time required for the change. The amount of change in current due to a change in the potential of the node SN by 0.1 mV was obtained using the S value calculated from the I_{d}-V_{g} characteristics, and the amount of change was subtracted from the off-leakage current. The necessary amount of change in threshold value was estimated using the off-leakage current at the time when the time required for the change reached 0.64 seconds, the S value calculated above, and the like.

Table 15 shows the necessary amount of change in threshold value obtained by the above-described first method (M1 in Table 15) and second method (M2 in Table 15).

TABLE 15
[V]

| | M1 | M2 |
|---|---|---|
| T4-1 | −0.967 | −0.884 |
| T4-2 | −0.896 | −0.822 |

Table 16 and Table 17 show parameters used for the circuit simulation. Table 16 shows parameters assuming a structure in which the insulating layer 250 is placed between the conductive layer 260 and the conductive layer 240 as in the transistors in FIGS. 7B and 7C or the like in the above embodiment. Parameters in Table 17 were employed assuming a structure in which an interlayer film is provided between the conductive layer 260 and the conductive layer 240 to reduce the capacitance between the wirings as in the transistor illustrated in FIGS. 15A and 15B or the like in the above embodiment.

TABLE 16

| | | |
|---|---|---|
| Cs | 3.0 | fF |
| C1 | 0.15 | fF |
| R1 | 32.2 | Ω |
| C2 | 0.15 | fF |
| R2 | 45 | Ω |
| C3 | 1.2 | fF |

TABLE 17

| | | |
|---|---|---|
| Cs | 1.77 | fF |
| C1 | 0.073 | fF |
| R1 | 32.2 | Ω |
| C2 | 0.079 | fF |
| R2 | 45 | Ω |
| C3 | 1.2 | fF |

Tables 18 to 21 show calculation results of the write time T_{write} and the read time T_{read} calculated assuming the operation at from −25° C. to 85° C. Note that Tables 18 and 19 show the results of calculating variation in the required threshold value in the transistor characteristics used in the circuit simulation by the first method (M1), and Tables 20 and 21 show the results of calculating variation in the required threshold value in the transistor characteristics used in the circuit simulation by the second method (M2). Tables 18 and 20 show the results of using the transistors of Sample T4-1, and Tables 19 and 21 show the results of using the transistors of Sample T4-2.

The simulation was performed on the assumption that the variation was ±5σ. In Sample T4-1, nine transistors were measured and the standard deviation σ was calculated, so that σ=19.4 mV. In Sample T4-2, nine transistors were measured and the standard deviation σ was calculated, so that σ=30.2 mV.

In each of the tables, the description “N” in the structure represents calculation results using the parameters shown in Table 16, and the description “PU” in the structure represents calculation results using the parameters shown in Table 17.

TABLE 18
T4-1 ±5σ = ±97 mV

| WL | |
|---|---|
| Twrite [ns] | Tread [ns] |

Structure

| | N | PU | N | PU |
|---|---|---|---|---|
| 1.8 V | 7.76 | 6.10 | 2.30 | 1.27 |
| 2.0 V | 1.39 | 0.95 | 1.03 | 0.52 |

TABLE 19
T4-2 ±5σ = ±151 mV

| WL | |
|---|---|
| Twrite [ns] | Tread [ns] |

Structure

| | N | PU | N | PU |
|---|---|---|---|---|
| 1.8 V | 8.74 | 7.26 | 2.50 | 1.31 |
| 2.0 V | 1.17 | 0.79 | 1.01 | 0.50 |

TABLE 20
T4-1 ±5σ = ±97 mV

| WL | |
|---|---|
| Twrite [ns] | Tread [ns] |

Structure

| | N | PU | N | PU |
|---|---|---|---|---|
| 1.8 V | 3.28 | 2.38 | 1.50 | 0.79 |
| 2.0 V | 0.89 | 0.58 | 0.84 | 0.42 |

TABLE 21
T4-2 ±5σ = ±151 mV

| WL | |
|---|---|
| Twrite [ns] | Tread [ns] |

Structure

| | N | PU | N | PU |
|---|---|---|---|---|
| 1.8 V | 3.33 | 2.49 | 1.60 | 0.81 |
| 2.0 V | 0.77 | 0.5 | 0.84 | 0.42 |

An interlayer film was provided between the conductive layer 260 and the conductive layer 240 to reduce the capacitance between the wirings, whereby both the write time and the read time were able to be shortened.

Note that in order to examine the influence of variation in transistor characteristics on the writing characteristics and the reading characteristics, the writing characteristics and the reading characteristics of the case where the standard deviation σ was changed were estimated. The high voltage potential H of the wiring WL was set to 1.8 V.

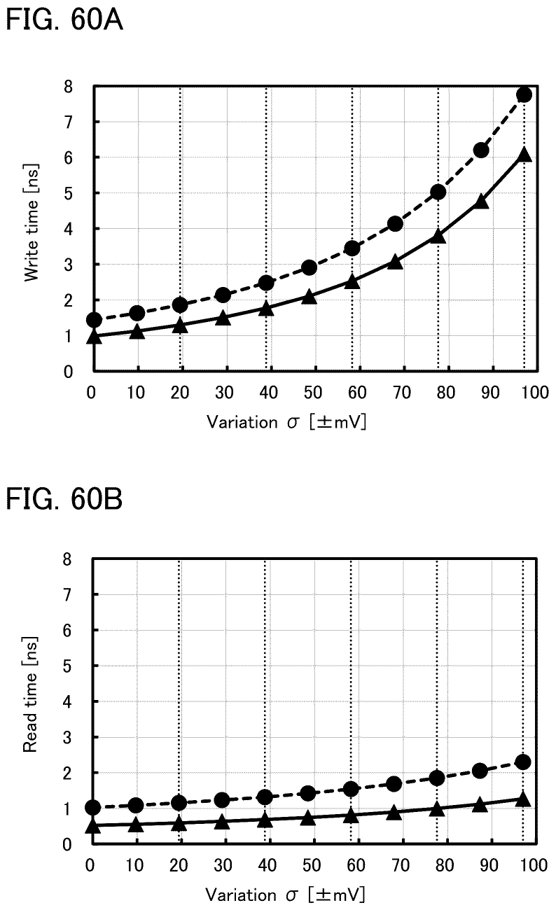

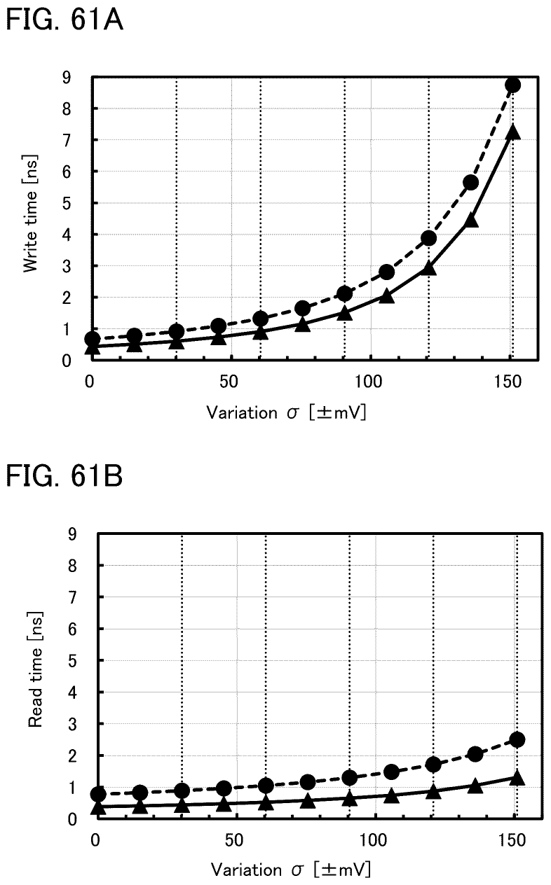

FIGS. 60A and 60B show the results of calculating the write time and the read time of Sample T4-1 by the first method (M1). FIGS. 61A and 61B show the results of calculating the write time and the read time of Sample T4-2 by the first method (M1). Note that the solid line represents the case where the parameters shown in Table 17 are used (PU), and the dashed line represents the case where the parameters shown in Table 16 are used (N). In each graph, the horizontal axis represents the value of the standard deviation σ as variation. The vertical axes in FIG. 60A and FIG. 61A represent write time, and the vertical axes in FIG. 60B and FIG. 61B represent read time.

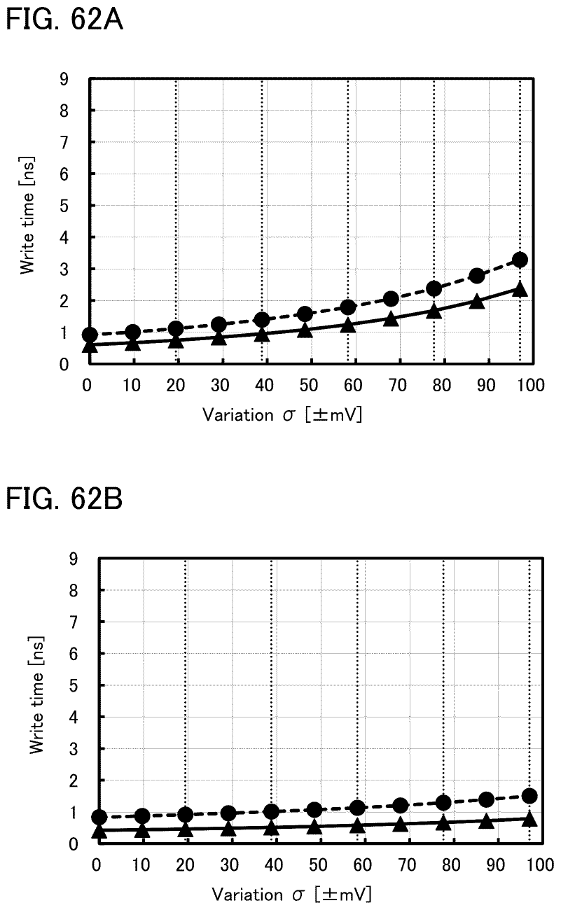

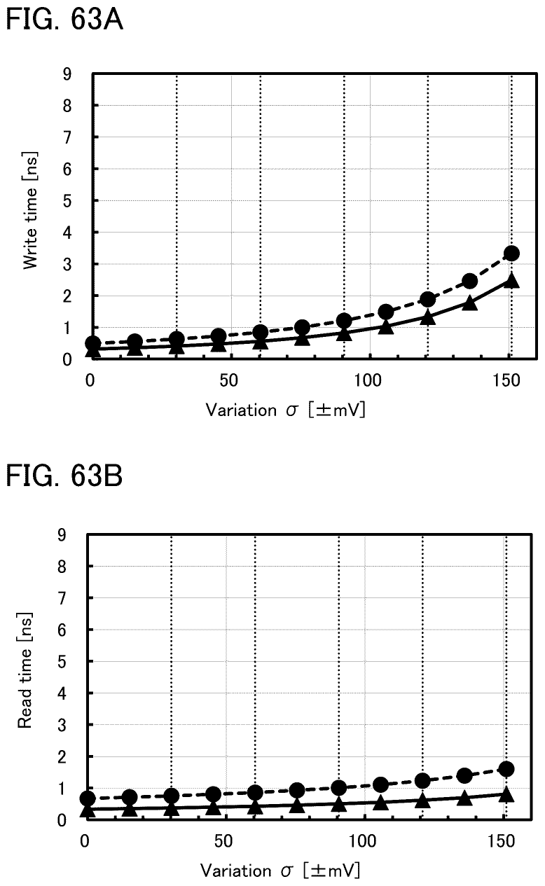

FIGS. 62A and 62B show the results of calculating the write time and the read time of Sample T4-1 by the second method (M2). FIGS. 63A and 63B show the results of calculating the write time and the read time of Sample T4-2 by the second method (M2). Note that the solid line represents the case where the parameters shown in Table 17 are used (PU), and the dashed line represents the case where the parameters shown in Table 16 are used (N).

### Example 8

In this example, the cutoff frequency of transistors was measured.

### <Fabrication 4 of Semiconductor Device>

With reference to the fabrication method described in Example 1, Sample T5 was fabricated as a semiconductor device including transistors.

For the fabrication of Sample T5, the fabrication conditions of Sample T1-1 described in Example 1 were used. Note that as described below, the fabrication method of Sample T5 was different from that of Sample T1-1 mainly in three points: formation of the opening portion 290, formation of the oxide semiconductor layer 230, and microwave treatment after formation of the insulating layer 250.

In the formation of the opening portion 290, CH₂F₂, CHF₃, CF₄, O₂, and Ar were used as dry etching gases in etching of the insulating layer 280.

For the formation of the oxide semiconductor layer 230, the conditions of Sample T4-1 were used.

After the insulating film to be the insulating layer 250 was formed, microwave treatment was performed. For the microwave treatment, the conditions of Sample T4-1 were used.

### <Cutoff Frequency>

The cutoff frequency of the transistor included in the fabricated sample was measured. The transistor used for the measurement has a structure including an interlayer film between the conductive layer 260 and the conductive layer 240, like the transistor illustrated in FIGS. 14A and 14B and the like in the above embodiment. As the interlayer film, silicon oxide with a thickness of approximately 55 nm was used.

In the measurement of the cutoff frequency, the drain voltage V_{d} was set to 2.5 V and the top gate voltage V_{g} was set to 1.9 V. The measurement was performed at room temperature (here, at 27° C.). For the measurement, 1000 transistors were connected in parallel. Evaluated here were the electrical characteristics of the transistor where the channel length is 95 nm and the opening portion 290 has a width of 60 nm and a substantially circular shape in a plan view.

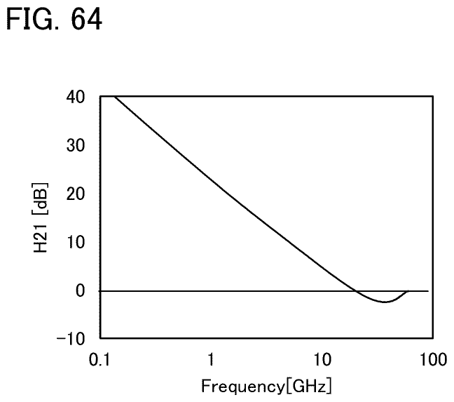

FIG. 64 shows the measurement result of the cutoff frequency. In FIG. 64, the vertical axis represents the current gain (|H21|) [dB], and the horizontal axis represents the frequency [GHz]. The frequency at which the current amplification rate was 1, i.e., the current gain |H21| was 0 dB, was obtained by extrapolation to obtain the cutoff frequency f_{T}.

As the result of the measurement, the cutoff frequency f_{T} of the transistor was estimated to be 20 GHz.

Therefore, it was found that the transistor included in the fabricated sample had excellent frequency characteristics.

### Example 9

In this example, the sample fabricated in Example 4 (Sample H15) and a newly fabricated sample (Sample H17) were analyzed by XPS.

### <Sample Fabrication 3>

A method for fabricating Sample H17 will be described below.

First, a 100-nm-thick silicon oxide layer was formed over a silicon substrate by thermal oxidation treatment. Next, a metal oxide layer (corresponding to the oxide semiconductor layer 230) was formed over the silicon oxide layer.

The metal oxide layer of Sample H17 was formed in the following manner: an In—Ga—Zn oxide film was formed to a thickness of 5 nm by a thermal ALD method to have an atomic ratio In:Ga:Zn=1:1:1, and then an In—Ga—Zn oxide film was formed to a thickness of 5 nm by an RF sputtering method using an oxide target with an atomic ratio In:Ga:Zn=1:1:1.2.

In the In—Ga—Zn oxide film formed by a thermal ALD method, triethylindium, triethylgallium, and diethylzinc were used as a precursor containing indium, a precursor containing gallium, and a precursor containing zinc, respectively, and ozone (O₃) and oxygen (O₂) were used as oxidizers.

### <Xps Analysis>

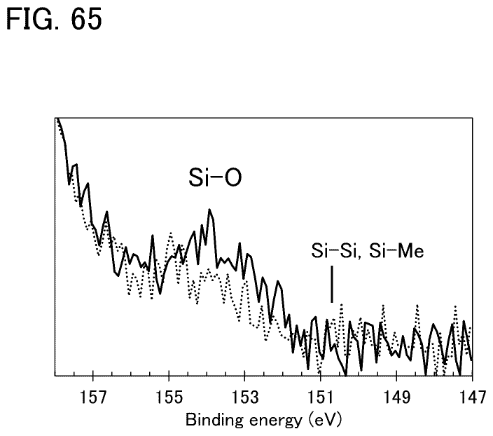

FIG. 65 shows the XPS analysis results of Sample H15 and Sample H17. FIG. 65 shows the Si2s spectrum, the solid line represents the result of Sample H15, and the dashed line represents the result of Sample H17. For the XPS measurement, Quantera II manufactured by PHI, Inc. was used. A monochromatic Al Kα ray (1486.6 eV) was used for an X-ray source. A detection area was set to 200 μmϕ. An extraction angle was set to 45°. Thus, the detection depth might be approximately 4 nm to 5 nm.

According to the results shown in FIG. 65, a peak probably derived from a Si—O bond was detected in Sample H15. This suggests that silicon enters from the silicon oxide layer into the In—Ga—Zn oxide film at the time of forming the In—Ga—Zn oxide film by a sputtering method. It is also suggested that the silicon which enters the In—Ga—Zn oxide film forms a Si—O bond in the In—Ga—Zn oxide film.

### Example 10

In this example, transistor characteristics were evaluated using Sample T1-2, Sample T2, and Sample T3 fabricated in Example 5.

Evaluated were the electrical characteristics of an element obtained by connecting 20000 transistors in parallel; in each of the transistors, the channel length is 95 nm and the opening portion 290 has a width of 60 nm and a substantially circular shape in a plan view.

### <Evaluation 6 of Electrical Characteristics of Transistor>

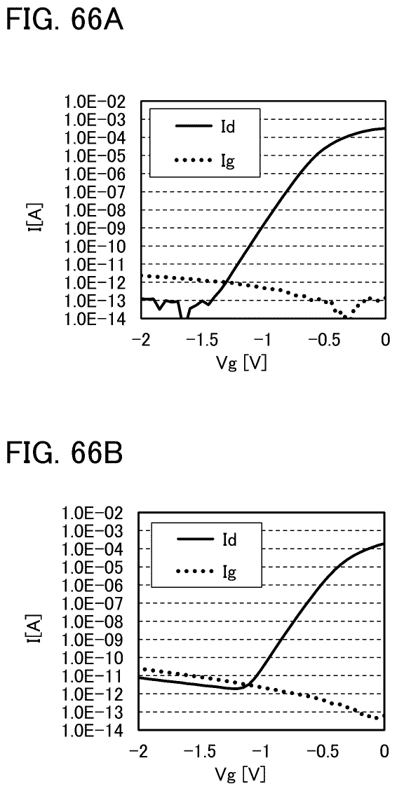

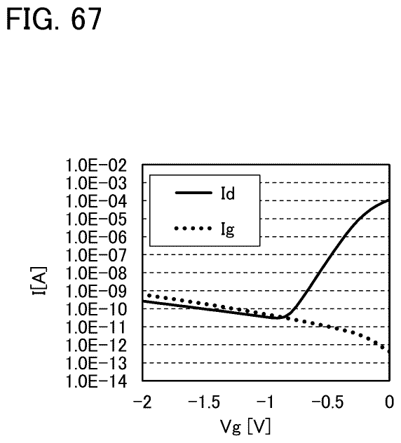

FIG. 66A, FIG. 66B, and FIG. 67 show I_{d}-V_{g} characteristics and I_{g}-V_{g} characteristics of Sample T1-2, Sample T2, and Sample T3, respectively. In each transistor, source-drain voltage was set to 0.8 V. In the I_{d}-V_{g} characteristics, the horizontal axis represents the gate-source voltage V_{g} and the vertical axis represents the drain current I_{d}. In the I_{g}-V_{g} characteristics, the horizontal axis represents the voltage V_{g} between the gate and the source and the vertical axis represents a gate-source current I_{g}.

According to the results of Sample T1-2 in FIG. 66A, in the case where a 1-nm-thick aluminum oxide film formed by a thermal ALD method was used as the first layer in a gate insulating layer, a 2-nm-thick silicon oxide film formed by a PEALD method was used as the second layer therein, and a 2-nm-thick hafnium oxide film formed by a thermal ALD method was used as the third layer therein, when the gate-source voltage V_{g} was lower than or equal to −1.25 V, the gate-source current I_{g} and the drain current I_{d} were each lower than or equal to 9×10⁻¹² A (the current per transistor was lower than or equal to 450 aA).

According to FIG. 66B and FIG. 67, in Sample T2 with 1.5-nm-thick silicon oxide and Sample T3 with 1-nm-thick silicon oxide, the gate-source current tends to increase as the thickness of the silicon oxide is smaller, and in accordance with this, drain current in an off state also tends to increase. Note that also in Sample T2, it was found that at a gate-source voltage V_{g} of higher than or equal to −1.5 V and lower than or equal to −1 V, both the gate-source current I_{g} and the drain current I_{d} were lower than or equal to 9×10⁻¹² A (the current per transistor was lower than or equal to 450 aA).

### Example 11

In this example, SIMS analysis was performed on the oxide semiconductor layer.

### <Sims Analysis>

The profile of Si was evaluated by SIMS analysis of Sample H17 fabricated in Example 9. The analysis method was as described in Example 4.

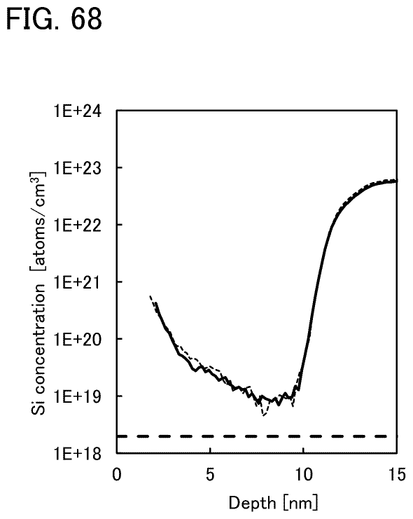

The dashed line in FIG. 68 shows the SIMS analysis results of Sample H17. The solid line in FIG. 68 shows the SIMS analysis results of the sample H17 subjected to atmospheric pressure treatment at 400° C. in a mixed atmosphere of an N₂ gas (at a flow rate of 4 slm) and an O₂ gas (gas flow rate: 1 slm) for one hour.

It was suggested that forming a metal oxide by an ALD method as a layer in contact with the silicon oxide layer inhibits formation of a mixed layer with the silicon oxide layer.

This application is based on Japanese Patent Application Serial No. 2023-111713 filed with Japan Patent Office on Jul. 6, 2023, Japanese Patent Application Serial No. 2023-131436 filed with Japan Patent Office on Aug. 10, 2023, and Japanese Patent Application Serial No. 2023-152146 filed with Japan Patent Office on Sep. 20, 2023, the entire contents of which are hereby incorporated by reference.

What is claimed is:

1. An oxide semiconductor layer comprising indium,
wherein the oxide semiconductor layer comprises a first region, a second region over the first region, and a third region over the second region,
wherein the first region is located in a range from a surface on which the oxide semiconductor layer is formed to greater than or equal to 0 nm to less than or equal to 3 nm in a direction substantially perpendicular to the surface, and
wherein in cross-sectional observation of the oxide semiconductor layer using a transmission electron microscope, bright spots arranged in a layered manner in a direction parallel to the surface are observed in each of the first region, the second region, and the third region.

2. The oxide semiconductor layer according to claim 1,
wherein the second region comprises zinc,
wherein the second region comprises crystal, and
wherein a c-axis of the crystal is substantially parallel to a normal direction of the surface.

3. The oxide semiconductor layer according to claim 1,
wherein a c-axis alignment proportion in the second region is higher than a c-axis alignment proportion in the first region.

4. The oxide semiconductor layer according to claim 1,
wherein a c-axis alignment proportion in the third region is higher than a c-axis alignment proportion in the first region.

5. The oxide semiconductor layer according to claim 1,
wherein a content of indium in the first region is higher than a content of indium in the second region, and
wherein a content of indium in the third region is higher than the content of indium in the second region.

6. A method for forming an oxide semiconductor layer, comprising the steps of:
forming a first metal oxide on a surface of a layer;
forming a second metal oxide over the first metal oxide; and
forming a third metal oxide over the second metal oxide,
wherein each of the first metal oxide and the third metal oxide is formed by an ALD method using an oxidizer and a precursor comprising indium, and
wherein the second metal oxide is formed by a sputtering method using a sputtering target comprising indium.

7. The method for forming an oxide semiconductor layer, according to claim 6,
wherein the sputtering target comprises zinc, and
wherein the sputtering method is performed in an atmosphere comprising oxygen.

8. The method for forming an oxide semiconductor layer, according to claim 6,
wherein the substrate heating temperature in the ALD method is higher than or equal to 100° C. and lower than or equal to 350° C.

9. The method for forming an oxide semiconductor layer, according to claim 6,
wherein in cross-sectional observation of the oxide semiconductor layer using a transmission electron microscope, bright spots arranged in a layered manner in a direction parallel to the surface of the layer are observed in each of the first metal oxide, the second metal oxide, and the third metal oxide.

10. The method for forming an oxide semiconductor layer, according to claim 6,
wherein no clear boundary is observed between the first metal oxide and the second metal oxide, and
wherein no clear boundary is observed between the second metal oxide and the third metal oxide.

11. The method for forming an oxide semiconductor layer, according to claim 6,
wherein after the third metal oxide is formed over the second metal oxide, heat treatment at higher than or equal to 350° C. and lower than or equal to 550° C. is performed.

12. A semiconductor device comprising:
a transistor over a first insulating layer; and
a second insulating layer,
wherein the transistor comprises a first conductive layer over the first insulating layer, a second conductive layer, an oxide semiconductor layer, a gate insulating layer, and a gate electrode,
wherein the second insulating layer is positioned between the first conductive layer and the second conductive layer,
wherein the second conductive layer is positioned over the second insulating layer,
wherein the second insulating layer and the second conductive layer comprise a first opening portion reaching the first conductive layer,
wherein the oxide semiconductor layer is in contact with a side surface of the second insulating layer in the first opening portion and a side surface of the second conductive layer in the first opening portion,
wherein the gate insulating layer is positioned over the oxide semiconductor layer,
wherein in the first opening portion, the gate electrode comprises a region overlapping with the oxide semiconductor layer with the gate insulating layer therebetween,
wherein the oxide semiconductor layer comprises a first region, a second region over the first region, and a third region over the second region,
wherein the first region is located in a range from a surface on which the oxide semiconductor layer is formed to greater than or equal to 0 nm to less than or equal to 3 nm in a direction substantially perpendicular to the surface, and
wherein in cross-sectional observation of the oxide semiconductor layer using a transmission electron microscope, bright spots arranged in a layered manner in a direction parallel to the surface are observed in each of the first region, the second region, and the third region.

13. The semiconductor device according to claim 12,
wherein the side surface of the second insulating layer in the first opening portion comprises a fourth region,
wherein an angle formed by a top surface of the first conductive layer and the fourth region is greater than or equal to 75° and less than or equal to 90°, and
wherein the first region is in contact with the fourth region.

14. A method for manufacturing a semiconductor device, comprising the steps of:
forming a first insulating layer over a first conductive layer;
forming a second conductive layer over the first insulating layer;
removing a part of the second conductive layer and a part of the first insulating layer, thereby forming a first opening portion reaching the first conductive layer and exposing a top surface of the first conductive layer;
forming a first metal oxide in contact with the top surface of the first conductive layer, a side surface of the first opening portion of the first insulating layer, a side surface of the first opening portion of the second conductive layer, and a top surface of the second conductive layer;
forming a second metal oxide over the first metal oxide;
forming a third metal oxide over the second metal oxide;
forming a second insulating layer in contact with a top surface of the third metal oxide; and
forming a third conductive layer over the second insulating layer,
wherein each of the first metal oxide and the third metal oxide is formed by an ALD method using an oxidizer and a precursor comprising indium, and
wherein the second metal oxide is formed by a sputtering method using a sputtering target comprising indium.

15. The method for manufacturing a semiconductor device, according to claim 14,
wherein the third conductive layer is formed by a metal CVD method at a temperature higher than or equal to 250° C.
